(19) United States
(12) Patent Application Publication
(10) Pub. No.: US 2025/0311581 A1
(43) Pub. Date: Oct. 2, 2025

(54) Display Apparatus

(71) Applicant: Semiconductor Energy Laboratory Co, Ltd., Kanagawa-ken (JP)

(72) Inventors: Satoshi SEO, Sagamihara (JP); Nobuharu OHSAWA, Zama (JP); Hiromi SEO, Sagamihara (JP); Hiromitsu KIDO, Kanagawa (JP); Yuki HAYASHI, Kanagawa (JP)

(73) Assignee: Semiconductor Energy Laboratory Co, Ltd., Kanagawa-ken (JP)

(21) Appl. No.: 19/086,371

(22) Filed: Mar. 21, 2025

(30) Foreign Application Priority Data
Mar. 29, 2024 (JP) 2024-056317

(51) Int. Cl. H10K 59/35; H10K 50/11; H10K 85/60; H10K 101/25

(52) U.S. Cl. CPC H10K 59/353; H10K 50/11; H10K 85/615; H10K 85/626; H10K 85/654; H10K 85/657; H10K 85/6572; H10K 85/6574; H10K 85/6576; H10K 2101/25

(57) ABSTRACT

A highly reliable display apparatus is provided. The display apparatus includes a pixel including a first subpixel and a second subpixel. The area of the first subpixel is smaller than the area of the second subpixel. The first subpixel includes a first tandem light-emitting device. The second subpixel includes a second tandem light-emitting device. Light-emitting layers included in the first light-emitting device each include an emission center substance, a first organic compound including a π-electron deficient heteroaromatic ring, and a second organic compound including a π-electron rich heteroaromatic ring or an aromatic amine skeleton. At least one of the first organic compound and the second organic compound includes deuterium. Light-emitting layers included in the second light-emitting device emit light with a hue different from a hue of light emitted from the light-emitting layers included in the first light-emitting device.

### BACKGROUND OF THE INVENTION

### 1. Field of the Invention

One embodiment of the present invention relates to an organic compound, an organic semiconductor element, a light-emitting device, a photodiode sensor, a display module, a lighting module, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display apparatus, a liquid crystal display apparatus, a lighting device, a power storage device, a memory device, an image capturing device, a driving method thereof, and a manufacturing method thereof.

### 2. Description of the Related Art

Light-emitting devices (also referred to as organic EL elements) including organic compounds and utilizing electroluminescence (EL) have been put into practical use. In the basic structure of such light-emitting devices, an organic compound layer including an emission center substance is located between a pair of electrodes. Carriers are injected by application of voltage to the device, and recombination energy of the carriers is used, whereby light emission can be obtained from the emission center substance.

Since such light-emitting devices are of self-luminous type, display apparatuses in which the light-emitting devices are used in pixels have higher visibility than liquid crystal display apparatuses and do not need a backlight. Display apparatuses that include such light-emitting devices are also highly advantageous in that they can be thin and lightweight. Another feature of such light-emitting devices is that they have an extremely fast response speed.

Since light-emitting layers of such light-emitting devices can be formed as continuous planar layers, planar light emission can be achieved. This feature is difficult to realize with point light sources typified by incandescent lamps and LEDs or linear light sources typified by fluorescent lamps; thus, the light-emitting devices also have great potential as planar light sources, which can be used for lighting devices and the like.

Display apparatuses or lighting devices that include light-emitting devices are suitable for a variety of electronic appliances as described above, and research and development of light-emitting devices have progressed for better characteristics.

Tandem light-emitting devices have attracted particular attention because of their high current efficiency.

Patent Documents 1 and 2 disclose tandem light-emitting devices fabricated by a side-by-side patterning method.

### REFERENCES

[Patent Document 1] Japanese Published Patent Application No. 2005-317548
[Patent Document 2] Japanese Published Patent Application No. 2023-161850

### SUMMARY OF THE INVENTION

An object of one embodiment of the present invention is to provide a light-emitting device having favorable characteristics. Another object of one embodiment of the present invention is to provide a light-emitting device having high emission efficiency. Another object of one embodiment of the present invention is to provide a light-emitting device having high reliability. Another object of one embodiment of the present invention is to provide a light-emitting device having a low driving voltage. Another object of one embodiment of the present invention is to provide a light-emitting device having high reliability and a low driving voltage.

Another object of one embodiment of the present invention is to provide a light-emitting device that enables a display apparatus to have favorable characteristics. Another object of one embodiment of the present invention is to provide a light-emitting device that enables a display apparatus to have high emission efficiency. Another object of one embodiment of the present invention is to provide a light-emitting device that enables a display apparatus to have high reliability. Another object of one embodiment of the present invention is to provide a display apparatus having a low driving voltage. Another object of one embodiment of the present invention is to provide a light-emitting device that enables a display apparatus to have a low driving voltage and high reliability.

Another object of one embodiment of the present invention is to provide any of an organic semiconductor device, a light-emitting device, a light-receiving device, a display apparatus, an electronic appliance, and a lighting device each having low power consumption. Another object of one embodiment of the present invention is to provide an electronic appliance having high reliability or a lighting device having high reliability. Another object of one embodiment of the present invention is to provide any of a novel organic semiconductor device, a novel light-emitting device, a novel light-receiving device, a novel display apparatus, a novel electronic appliance, and a novel lighting device.

It is only necessary that at least one of the above-described objects be achieved in the present invention. Note that the description of these objects does not preclude the existence of other objects. One embodiment of the present invention does not need to achieve all these objects. Other objects will be apparent from and can be derived from the description of the specification, the drawings, the claims, and the like.

One embodiment of the present invention is a display apparatus including a pixel including a first subpixel and a second subpixel. The area of the first subpixel is smaller than the area of the second subpixel. The first subpixel includes a first light-emitting device. The second subpixel includes a second light-emitting device. The first light-emitting device includes a first electrode, a second electrode, a first intermediate layer, a first light-emitting layer, and a second light-emitting layer. The first intermediate layer is positioned between the first electrode and the second electrode. The first light-emitting layer is positioned between the first electrode and the first intermediate layer. The second light-emitting layer is positioned between the first intermediate layer and the second electrode. The first light-emitting layer includes a first emission center substance, a first organic compound, and a second organic compound. The second light-emitting layer includes a second emission center substance, a third organic compound, and a fourth organic compound. The first organic compound and the third organic compound each include a π-electron deficient heteroaromatic ring. The second organic compound and the fourth organic compound each include a π-electron rich heteroaromatic ring or an aromatic amine skeleton. At least one of the first organic compound, the second organic compound, the third organic compound, and the fourth organic compound includes deuterium. A difference between a maximum peak wavelength of an emission spectrum of the first emission center substance and a maximum peak wavelength of an emission spectrum of the second emission center substance is less than or equal to 30 nm. The second light-emitting device includes a third electrode, a fourth electrode, a second intermediate layer, a third light-emitting layer, and a fourth light-emitting layer. The second intermediate layer is positioned between the third electrode and the fourth electrode. The third light-emitting layer is positioned between the third electrode and the second intermediate layer. The fourth light-emitting layer is positioned between the second intermediate layer and the fourth electrode. The third light-emitting layer and the fourth light-emitting layer emit light with a hue different from a hue of light emitted from the first light-emitting layer and a hue of light emitted from the second light-emitting layer.

Another embodiment of the present invention is a display apparatus having the above structure in which the third light-emitting layer includes a third emission center substance, a fifth organic compound, and a sixth organic compound, the fourth light-emitting layer includes a fourth emission center substance, a seventh organic compound, and an eighth organic compound, the fifth organic compound and the seventh organic compound each include a π-electron deficient heteroaromatic ring, the sixth organic compound and the eighth organic compound each include a π-electron rich heteroaromatic ring or an aromatic amine skeleton, and a difference between a maximum peak wavelength of an emission spectrum of the third emission center substance and a maximum peak wavelength of an emission spectrum of the fourth emission center substance is less than or equal to 30 nm.

Another embodiment of the present invention is a display apparatus having the above structure in which the third light-emitting layer includes a third emission center substance and a fifth organic compound, the fourth light-emitting layer includes a fourth emission center substance and a seventh organic compound, the third emission center substance and the fourth emission center substance are each a fluorescent substance, and a difference between the maximum peak wavelength of the emission spectrum of the third emission center substance and the maximum peak wavelength of the emission spectrum of the fourth emission center substance is less than or equal to 30 nm.

One embodiment of the present invention is a display apparatus including a pixel including a first subpixel, a second subpixel, and a third subpixel. The area of the first subpixel is smaller than the area of the second subpixel. The area of the second subpixel is smaller than the area of the third subpixel. The first subpixel includes a first light-emitting device. The second subpixel includes a second light-emitting device. The third subpixel includes a third light-emitting device. The first light-emitting device includes a first electrode, a second electrode, a first intermediate layer, a first light-emitting layer, and a second light-emitting layer. The first intermediate layer is positioned between the first electrode and the second electrode. The first light-emitting layer is positioned between the first electrode and the first intermediate layer. The second light-emitting layer is positioned between the first intermediate layer and the second electrode. The first light-emitting layer includes a first emission center substance, a first organic compound, and a second organic compound. The second light-emitting layer includes a second emission center substance, a third organic compound, and a fourth organic compound. The first organic compound and the third organic compound each include a π-electron deficient heteroaromatic ring. The second organic compound and the fourth organic compound each include a π-electron rich heteroaromatic ring or an aromatic amine skeleton. At least one of the first organic compound, the second organic compound, the third organic compound, and the fourth organic compound includes deuterium. A difference between a maximum peak wavelength of an emission spectrum of the first emission center substance and a maximum peak wavelength of an emission spectrum of the second emission center substance is less than or equal to 30 nm. The second light-emitting device includes a third electrode, a fourth electrode, a second intermediate layer, a third light-emitting layer, and a fourth light-emitting layer. The second intermediate layer is positioned between the third electrode and the fourth electrode. The third light-emitting layer is positioned between the third electrode and the second intermediate layer. The fourth light-emitting layer is positioned between the second intermediate layer and the fourth electrode. The third light-emitting layer includes a third emission center substance, a fifth organic compound, and a sixth organic compound. The fourth light-emitting layer includes a fourth emission center substance, a seventh organic compound, and an eighth organic compound. The fifth organic compound and the seventh organic compound each include a π-electron deficient heteroaromatic ring. The sixth organic compound and the eighth organic compound each include a π-electron rich heteroaromatic ring or an aromatic amine skeleton. A difference between a maximum peak wavelength of an emission spectrum of the third emission center substance and a maximum peak wavelength of an emission spectrum of the fourth emission center substance is less than or equal to 30 nm. The third light-emitting layer and the fourth light-emitting layer emit light with a hue different from a hue of light emitted from the first light-emitting layer and a hue of light emitted from the second light-emitting layer. The third light-emitting device includes a fifth electrode, a sixth electrode, a third intermediate layer, a fifth light-emitting layer, and a sixth light-emitting layer. The third intermediate layer is positioned between the fifth electrode and the sixth electrode. The fifth light-emitting layer is positioned between the fifth electrode and the third intermediate layer. The sixth light-emitting layer is positioned between the third intermediate layer and the sixth electrode. The fifth light-emitting layer and the sixth light-emitting layer emit light with a hue different from the hue of light emitted from the first light-emitting layer, the second light-emitting layer, the third light-emitting layer, and the fourth light-emitting layer.

One embodiment of the present invention is a display apparatus including a pixel including a first subpixel, a second subpixel, and a third subpixel. The area of the first subpixel and the area of the second subpixel are each smaller than the area of the third subpixel. The first subpixel includes a first light-emitting device. The second subpixel includes a second light-emitting device. The third subpixel includes a third light-emitting device. The first light-emitting device includes a first electrode, a second electrode, a first intermediate layer, a first light-emitting layer, and a second light-emitting layer. The first intermediate layer is positioned between the first electrode and the second electrode. The first light-emitting layer is positioned between the first electrode and the first intermediate layer. The second light-emitting layer is positioned between the first intermediate layer and the second electrode. The first light-emitting layer includes a first emission center substance, a first organic compound, and a second organic compound. The second light-emitting layer includes a second emission center substance, a third organic compound, and a fourth organic compound. The first organic compound and the third organic compound each include a π-electron deficient heteroaromatic ring. The second organic compound and the fourth organic compound each include a π-electron rich heteroaromatic ring or an aromatic amine skeleton. At least one of the first organic compound, the second organic compound, the third organic compound, and the fourth organic compound includes deuterium. A difference between a maximum peak wavelength of an emission spectrum of the first emission center substance and a maximum peak wavelength of an emission spectrum of the second emission center substance is less than or equal to 30 nm. The second light-emitting device includes a third electrode, a fourth electrode, a second intermediate layer, a third light-emitting layer, and a fourth light-emitting layer. The second intermediate layer is positioned between the third electrode and the fourth electrode. The third light-emitting layer is positioned between the third electrode and the second intermediate layer. The fourth light-emitting layer is positioned between the second intermediate layer and the fourth electrode. The third light-emitting layer includes a third emission center substance, a fifth organic compound, and a sixth organic compound. The fourth light-emitting layer includes a fourth emission center substance, a seventh organic compound, and an eighth organic compound. The fifth organic compound and the seventh organic compound each include a π-electron deficient heteroaromatic ring. The sixth organic compound and the eighth organic compound each include a π-electron rich heteroaromatic ring or an aromatic amine skeleton. At least one of the fifth organic compound, the sixth organic compound, the seventh organic compound, and the eighth organic compound includes deuterium. A difference between a maximum peak wavelength of an emission spectrum of the third emission center substance and a maximum peak wavelength of an emission spectrum of the fourth emission center substance is less than or equal to 30 nm. The third light-emitting layer and the fourth light-emitting layer emit light with a hue different from a hue of light emitted from the first light-emitting layer and a hue of light emitted from the second light-emitting layer. The third light-emitting device includes a fifth electrode, a sixth electrode, a third intermediate layer, a fifth light-emitting layer, and a sixth light-emitting layer. The third intermediate layer is positioned between the fifth electrode and the sixth electrode. The fifth light-emitting layer is positioned between the fifth electrode and the third intermediate layer. The sixth light-emitting layer is positioned between the third intermediate layer and the sixth electrode. The fifth light-emitting layer and the sixth light-emitting layer emit light with a hue different from the hue of light emitted from the first light-emitting layer, the second light-emitting layer, the third light-emitting layer, and the fourth light-emitting layer.

In the display apparatus of one embodiment of the present invention having any of the above structures, it is preferable that a combination of the first organic compound and the second organic compound form a first exciplex and a combination of the third organic compound and the fourth organic compound form a second exciplex.

In the display apparatus of one embodiment of the present invention having any of the above structures, in the case where the combination of the first organic compound and the second organic compound forms the first exciplex and the combination of the third organic compound and the fourth organic compound forms the second exciplex, a difference between the lowest triplet excited level of the first organic compound and the lowest triplet excited level of the second organic compound is preferably less than or equal to 0.30 eV, and a difference between the lowest triplet excited level of the third organic compound and the lowest triplet excited level of the fourth organic compound is preferably less than or equal to 0.30 eV.

In the display apparatus of one embodiment of the present invention having any of the above structures, in the case where the combination of the first organic compound and the second organic compound forms the first exciplex and the combination of the third organic compound and the fourth organic compound forms the second exciplex, an emission edge on a shorter wavelength side of the first exciplex is preferably positioned at a shorter wavelength than an absorption edge on a longer wavelength side of the first emission center substance, and an emission edge on a shorter wavelength side of the second exciplex is preferably positioned at a shorter wavelength than an absorption edge on a longer wavelength side of the second emission center substance.

In the display apparatus of one embodiment of the present invention having any of the above structures, in the case where the combination of the first organic compound and the second organic compound forms the first exciplex and the combination of the third organic compound and the fourth organic compound forms the second exciplex, it is preferable that an energy of an emission spectrum peak of the first exciplex be higher than an energy of an emission spectrum peak of the first emission center substance, a difference between the energy of the emission spectrum peak of the first exciplex and the energy of the emission spectrum peak of the first emission center substance be less than or equal to 0.35 eV, an energy of an emission spectrum peak of the second exciplex be higher than an energy of an emission spectrum peak of the second emission center substance, and a difference between the energy of the emission spectrum peak of the second exciplex and the energy of the emission spectrum peak of the second emission center substance be less than or equal to 0.35 eV.

In the display apparatus of one embodiment of the present invention having any of the above structures, it is preferable that a combination of the fifth organic compound and the sixth organic compound form a third exciplex, and a combination of the seventh organic compound and the eighth organic compound form a fourth exciplex.

In the display apparatus of one embodiment of the present invention having any of the above structures, in the case where the combination of the fifth organic compound and the sixth organic compound forms the third exciplex and the combination of the seventh organic compound and the eighth organic compound forms the fourth exciplex, a difference between the lowest triplet excited level of the fifth organic compound and the lowest triplet excited level of the sixth organic compound is preferably less than or equal to 0.20 eV, and a difference between the lowest triplet excited level of the seventh organic compound and the lowest triplet excited level of the eighth organic compound is less than or equal to 0.20 eV.

In the display apparatus of one embodiment of the present invention having any of the above structures, in the case where the combination of the fifth organic compound and the sixth organic compound forms the third exciplex and the combination of the seventh organic compound and the eighth organic compound forms the fourth exciplex, an emission edge on a shorter wavelength side of the third exciplex is preferably positioned at a shorter wavelength than an absorption edge on a longer wavelength side of the third emission center substance, and an emission edge on a shorter wavelength side of the fourth exciplex is preferably positioned at a shorter wavelength than an absorption edge on a longer wavelength side of the fourth emission center substance.

In the display apparatus of one embodiment of the present invention having any of the above structures, in the case where the combination of the fifth organic compound and the sixth organic compound forms the third exciplex and the combination of the seventh organic compound and the eighth organic compound forms the fourth exciplex, it is preferable that an energy of an emission spectrum peak of the third exciplex be higher than an energy of an emission spectrum peak of the third emission center substance, a difference between the energy of the emission spectrum peak of the third exciplex and the energy of the emission spectrum peak of the third emission center substance be less than or equal to 0.20 eV, an energy of an emission spectrum peak of the fourth exciplex be higher than an energy of an emission spectrum peak of the fourth emission center substance, and a difference between the energy of the emission spectrum peak of the fourth exciplex and the energy of the emission spectrum peak of the fourth emission center substance be less than or equal to 0.20 eV.

Another embodiment of the present invention is a display apparatus having any of the above structures in which the fifth light-emitting layer includes a fifth emission center substance and a ninth organic compound, the sixth light-emitting layer includes a sixth emission center substance and a tenth organic compound, the fifth emission center substance and the sixth emission center substance are each a fluorescent substance, and the difference between the maximum peak wavelength of the emission spectrum of the fifth emission center substance and the maximum peak wavelength of the emission spectrum of the sixth emission center substance is less than or equal to 30 nm.

In the display apparatus of one embodiment of the present invention having any of the above structures, at least one of the first intermediate layer and the second intermediate layer preferably includes a mixed layer including an eleventh organic compound and one of lithium and a lithium compound, and the eleventh organic compound preferably includes a phenanthroline skeleton.

In the display apparatus of one embodiment of the present invention having any of the above structures, it is preferable that the first light-emitting device include a first electron-transport layer between the first light-emitting layer and the first intermediate layer, and a second electron-transport layer between the second light-emitting layer and the second electrode; the second light-emitting device include a third electron-transport layer between the third light-emitting layer and the second intermediate layer, and a fourth electron-transport layer between the fourth light-emitting layer and the fourth electrode; at least one of the second electron-transport layer and the fourth electron-transport layer include a twelfth organic compound; and the twelfth organic compound include a triazine skeleton.

Embodiments of the present invention are not limited to the above embodiments.

One embodiment of the present invention can provide a light-emitting device having favorable characteristics. Another embodiment of the present invention can provide a light-emitting device having high emission efficiency. Another embodiment of the present invention can provide a light-emitting device having high reliability. Another embodiment of the present invention can provide a light-emitting device having a low driving voltage. Another embodiment of the present invention can provide a light-emitting device having high reliability and a low driving voltage.

Another embodiment of the present invention can provide a light-emitting device that enables a display apparatus to have favorable characteristics. Another embodiment of the present invention can provide a light-emitting device that enables a display apparatus to have high emission efficiency. Another embodiment of the present invention can provide a light-emitting device that enables a display apparatus to have high reliability. Another object of one embodiment of the present invention can provide a display apparatus having a low driving voltage. Another embodiment of the present invention can provide a light-emitting device that enables a display apparatus to have a low driving voltage and high reliability.

Another embodiment of the present invention can provide any of an organic semiconductor device, a light-emitting device, a light-receiving device, a display apparatus, an electronic appliance, and a lighting device each having low power consumption. Another embodiment of the present invention can provide an electronic appliance having high reliability or a lighting device having high reliability.

### BRIEF DESCRIPTION OF THE DRAWINGS

In the accompanying drawings:

FIGS. 1A and 1B illustrate a display apparatus of one embodiment of the present invention;

FIGS. 2A to 2G are top views each illustrating a structure example of a pixel;

FIGS. 3A to 3F are top views each illustrating a structure example of a pixel;

FIGS. 4A to 4C are top views each illustrating a structure example of a pixel;

FIGS. 5A to 5C are schematic views of light-emitting devices that can be used in a display apparatus of one embodiment of the present invention;

FIGS. 6A and 6B are schematic views of light-emitting devices that can be used in a display apparatus of one embodiment of the present invention;

FIGS. 7A and 7B illustrate a display apparatus of one embodiment of the present invention;

FIGS. 8A to 8E are cross-sectional views illustrating an example of a method for manufacturing a display apparatus;

FIGS. 9A and 9B are cross-sectional views illustrating the example of the method for manufacturing the display apparatus;

FIGS. 10A to 10D are cross-sectional views illustrating the example of the method for manufacturing the display apparatus;

FIGS. 11A to 11C are cross-sectional views illustrating the example of the method for manufacturing the display apparatus;

FIGS. 12A to 12C are cross-sectional views illustrating the example of the method for manufacturing the display apparatus;

FIGS. 13A to 13C are cross-sectional views illustrating the example of the method for manufacturing the display apparatus;

FIGS. 14A and 14B are perspective views illustrating a structure example of a display module;

FIGS. 15A and 15B are cross-sectional views illustrating structure examples of a display apparatus;

FIG. 16 is a perspective view illustrating a structure example of a display apparatus;

FIG. 17 is a cross-sectional view illustrating a structure example of a display apparatus;

FIG. 18 is a cross-sectional view illustrating a structure example of a display apparatus;

FIGS. 19A to 19C are a cross-sectional view and top views illustrating a structure example of a display apparatus;

FIG. 20 is a cross-sectional view illustrating a structure example of a display apparatus;

FIGS. 21A to 21C are a cross-sectional view and top views illustrating a structure example of a display apparatus;

FIGS. 22A to 22D illustrate examples of wearable devices;

FIGS. 23A to 23F illustrate examples of electronic appliances;

FIGS. 24A to 24G illustrate examples of electronic appliances;

FIG. 25 shows a method for calculating emission lifetime;

FIG. 26 shows the luminance-current density characteristics of light-emitting devices R1-a to R1-c and a comparative light-emitting device R1;

FIG. 27 shows the current efficiency-luminance characteristics of the light-emitting devices R1-a to R1-c and the comparative light-emitting device R1;

FIG. 28 shows the current density-voltage characteristics of the light-emitting devices R1-a to R1-c and the comparative light-emitting device R1;

FIG. 29 shows the power efficiency-luminance characteristics of the light-emitting devices R1-a to R1-c and the comparative light-emitting device R1;

FIG. 30 shows the electroluminescence spectra of the light-emitting devices R1-a to R1-c and the comparative light-emitting device R1;

FIG. 31 shows the luminance-current density characteristics of a light-emitting device G1 and a comparative light-emitting device G1;

FIG. 32 shows the current efficiency-luminance characteristics of the light-emitting device G1 and the comparative light-emitting device G1;

FIG. 33 shows the current density-voltage characteristics of the light-emitting device G1 and the comparative light-emitting device G1;

FIG. 34 shows the power efficiency-luminance characteristics of the light-emitting device G1 and the comparative light-emitting device G1;

FIG. 35 shows the electroluminescence spectra of the light-emitting device G1 and the comparative light-emitting device G1;

FIG. 36 shows the luminance-current density characteristics of a light-emitting device B1 and a comparative light-emitting device B1;

FIG. 37 shows the current efficiency-luminance characteristics of the light-emitting device B1 and the comparative light-emitting device B1;

FIG. 38 shows the current density-voltage characteristics of the light-emitting device B1 and the comparative light-emitting device B1;

FIG. 39 shows the power efficiency-luminance characteristics of the light-emitting device B1 and the comparative light-emitting device B1;

FIG. 40 shows the blue index-luminance characteristics of the light-emitting device B1 and the comparative light-emitting device B1;

FIG. 41 shows the electroluminescence spectra of the light-emitting device B1 and the comparative light-emitting device B1;

FIG. 42 shows the emission spectra of 8mpTP-4mDBtPBfpm-d₁₃, PNCCP-d₂₆, and an exciplex of 8mpTP-4mDBtPBfpm-d₁₃ and PNCCP-d₂₆;

FIG. 43 shows the PL spectrum of an exciplex of 8mpTP-4mDBtPBfpm-d₁₃ and βNCCP-d₂₆ and the absorption spectrum and the PL spectrum of OCPG-006;

FIG. 44 shows an example of determining an absorption edge on a longer wavelength side of an absorption spectrum;

FIG. 45 shows a method for measuring the T₁ level of 8mpTP-4mDBtPBfpm-d₁₃;

FIG. 46 shows a method for measuring the T₁ level of 8mpTP-4mDBtPBfpm;

FIG. 47 shows a method for measuring the T₁ level of βNCCP-d₂₆;

FIG. 48 shows a method for measuring the T₁ level of βNCCP;

FIG. 49 shows the time dependence of normalized luminance of the light-emitting devices R1-a to R1-c and the comparative light-emitting device R1;

FIG. 50 shows the emission spectra of 8mpTP-4mDBtPBfpm, βNCCP, and an exciplex of 8mpTP-4mDBtPBfpm and βNCCP;

FIG. 51 shows the PL spectrum of an exciplex of 8mpTP-4mDBtPBfpm and βNCCP and the absorption spectrum and the PL spectrum of Ir(5mppy-d₃)₂(mbfpypy-d₃);

FIG. 52 shows an example of determining an absorption edge on a longer wavelength side of an absorption spectrum;

FIG. 53 shows the luminance-current density characteristics of a light-emitting device G2 and a comparative light-emitting device G2;

FIG. 54 shows the current efficiency-luminance characteristics of the light-emitting device G2 and the comparative light-emitting device G2;

FIG. 55 shows the current density-voltage characteristics of the light-emitting device G2 and the comparative light-emitting device G2;

FIG. 56 shows the power efficiency-luminance characteristics of the light-emitting device G2 and the comparative light-emitting device G2;

FIG. 57 shows the electroluminescence spectra of the light-emitting device G2 and the comparative light-emitting device G2;

FIG. 58 shows the PL spectrum of an exciplex of 8mpTP-4mDBtPBfpm-d₁₃ and βNCCP-d₂₆ and the absorption spectrum and the PL spectrum of Ir(5mppy-d₃)₂(mbfpypy-d₃);

FIG. 59 shows the time dependence of normalized luminance of the light-emitting device G2 and the comparative light-emitting device G2;

FIG. 60 shows the luminance-current density characteristics of a light-emitting device R3-a, a light-emitting device R3-b, a comparative light-emitting device R3-a, and a comparative light-emitting device R3-b;

FIG. 61 shows the current efficiency-luminance characteristics of the light-emitting device R3-a, the light-emitting device R3-b, the comparative light-emitting device R3-a, and the comparative light-emitting device R3-b;

FIG. 62 shows the current density-voltage characteristics of the light-emitting device R3-a, the light-emitting device R3-b, the comparative light-emitting device R3-a, and the comparative light-emitting device R3-b;

FIG. 63 shows the power efficiency-luminance characteristics of the light-emitting device R3-a, the light-emitting device R3-b, the comparative light-emitting device R3-a, and the comparative light-emitting device R3-b;

FIG. 64 shows the electroluminescence spectra of the light-emitting device R3-a, the light-emitting device R3-b, the comparative light-emitting device R3-a, and the comparative light-emitting device R3-b;

FIG. 65 shows a method for measuring the T₁ level of PCBBiF;

FIG. 66 shows the time dependence of normalized luminance of the light-emitting device R3-a and the comparative light-emitting device R3-a;

FIG. 67 shows the emission spectra of 11mDBtBPPnfpr, βNCCP-d₂₆, and an exciplex of 11mDBtBPPnfpr and βNCCP-d₂₆;

FIG. 68 shows the PL spectrum of an exciplex of 11mDBtBPPnfpr and βNCCP-d₂₆ and the absorption spectrum and the PL spectrum of OCPG-006;

FIG. 69 shows the emission spectra of 8mpTP-4mDBtPBfpm-d₁₃, PCBBiF, and an exciplex of 8mpTP-4mDBtPBfpm-d₁₃ and PCBBiF;

FIG. 70 shows the PL spectrum of an exciplex of 8mpTP-4mDBtPBfpm-d₁₃ and PCBBiF and the absorption spectrum and the PL spectrum of OCPG-006;

FIG. 71 shows the luminance-current density characteristics of a light-emitting device R5, a light-emitting device G5, a comparative light-emitting device G5, and a light-emitting device B5;

FIG. 72 shows the current efficiency-luminance characteristics of the light-emitting device R5, the light-emitting device G5, the comparative light-emitting device G5, and the light-emitting device B5;

FIG. 73 shows the current density-voltage characteristics of the light-emitting device R5, the light-emitting device G5, the comparative light-emitting device G5, and the light-emitting device B5;

FIG. 74 shows the power efficiency-luminance characteristics of the light-emitting device R5, the light-emitting device G5, the comparative light-emitting device G5, and the light-emitting device B5;

FIG. 75 shows the blue index-luminance characteristics of the light-emitting device B5;

FIG. 76 shows the electroluminescence spectra of the light-emitting device R5, the light-emitting device G5, the comparative light-emitting device G5, and the light-emitting device B5;

FIG. 77 shows the PL spectrum of an exciplex of 8mpTP-4mDBtPBfpm-d₁₃ and βNCCP-d₂₆ and the absorption spectrum and the PL spectrum of Pt(tBudppymmtBubiz-tBubp); and

FIG. 78 shows the time dependence of normalized luminance of the light-emitting device G5 and the comparative light-emitting device G5.

### DETAILED DESCRIPTION OF THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device manufactured using a metal mask or a fine metal mask (FMM) is sometimes referred to as a device having a metal mask (MM) structure. In this specification and the like, a device manufactured without using a metal mask or an FMM is sometimes referred to as a device having a metal maskless (MML) structure.

In this specification, the terms “organic compound including deuterium” and “deuterated organic compound” refer to an organic compound in which, with a focus on hydrogen (including deuterium) present at a certain position(s), the proportion of the hydrogen (including the deuterium) being deuterium is higher than the natural abundance ratio of deuterium. This proportion is preferably adequately higher than the natural abundance ratio. Here, “adequately” means that 7.5% or more of hydrogen has been replaced with deuterium, for example. Note that deuteration of an organic compound can be verified by NMR, mass spectrometry, or the like.

In this specification and the like, the light-emitting area in a subpixel including a light-emitting device is sometimes referred to as the area of the subpixel. In this specification and the like, the aperture ratio of a subpixel refers to the ratio of the area of the subpixel to the unit area of a display region (which can also be referred to as the pixel area).

### Embodiment 1

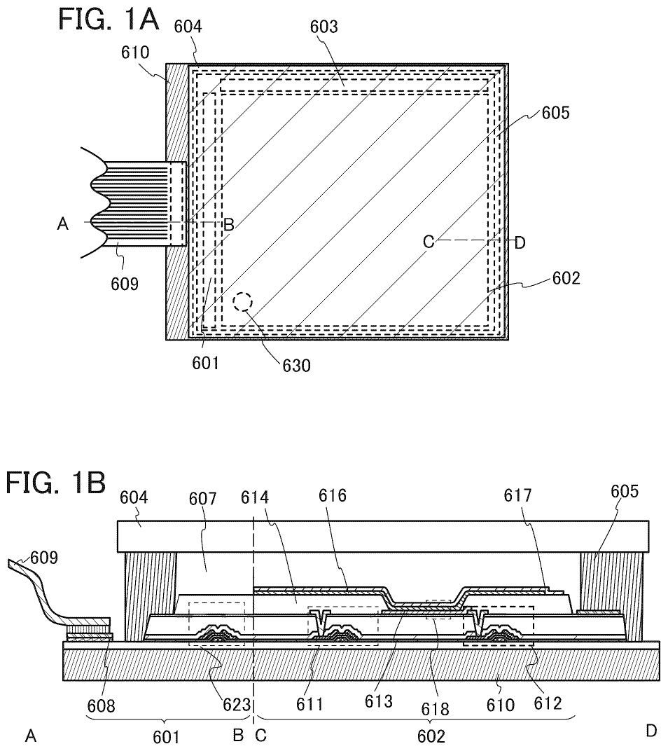

In this embodiment, a display apparatus of one embodiment of the present invention will be described with reference to FIGS. 1A and 1B, FIGS. 2A to 2G, FIGS. 3A to 3F, and FIGS. 4A to 4C. FIG. 1A is a top view of the display apparatus and FIG. 1B is a cross-sectional view along the lines A-B and C-D in FIG. 1A. The display apparatus includes a driver circuit portion (source line driver circuit) 601, a pixel portion 602, and a driver circuit portion (gate line driver circuit) 603 that are to control light emission of a light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display apparatus in this specification includes, in its category, not only the display apparatus itself but also the display apparatus provided with an FPC or a PWB.

Next, a cross-sectional structure is described with reference to FIG. 1B. The driver circuit portions and the pixel portion are formed over an element substrate 610; FIG. 1B illustrates the source line driver circuit 601, which is a driver circuit portion, and one pixel in the pixel portion 602.

The element substrate 610 can be, for example, a substrate formed of glass, quartz, an organic resin, a metal, an alloy, or a semiconductor or a plastic substrate formed of fiber reinforced plastic (FRP), polyvinyl fluoride (PVF), polyester, or an acrylic resin.

There is no particular limitation on the structure of transistors used in pixels and the driver circuits. For example, inverted staggered transistors may be used, or staggered transistors may be used. Furthermore, top-gate transistors or bottom-gate transistors may be used. There is no particular limitation on a semiconductor material used for the transistors, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

Here, an oxide semiconductor is preferably used for semiconductor devices such as the transistors provided in the pixels and the driver circuits and transistors used for touch sensors described later. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and having no grain boundary between adjacent crystal parts.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image in each display region is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

An FET 623 is illustrated as a transistor formed in the driver circuit portion 601. The driver circuit can be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate and can be formed outside.

The pixel portion 602 includes a plurality of pixels each including a switching FET 611, a current controlling FET 612, and a first electrode 613 electrically connected to a drain of the current controlling FET 612. One embodiment of the present invention is not limited to this structure, and the pixel portion 602 may employ a combination of three or more FETs and a capacitor.

An insulator 614 is formed to cover an end portion of the first electrode 613. Here, the insulator 614 can be formed using a positive photosensitive acrylic resin film.

In order to improve coverage with an organic compound layer and the like that are formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). For the insulator 614, either a negative photosensitive resin or a positive photosensitive resin can be used.

An organic compound layer 616 and a second electrode 617 are formed over the first electrode 613, and a light-emitting device is composed of the first electrode 613, the organic compound layer 616, and the second electrode 617. Preferred structures of the light-emitting device will be described later in this embodiment and the following embodiments. In the display apparatus in this embodiment, the pixel portion, which includes a plurality of light-emitting devices, may include both the light-emitting device described later in this specification and the like and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler and may be filled with an inert gas (such as nitrogen or argon), or the sealing material. The structure of the sealing substrate having a recessed portion where a desiccant is provided is preferable, in which case deterioration due to the influence of moisture can be inhibited.

An epoxy resin or glass frit is preferably used for the sealing material 605. It is desirable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, acrylic resin, or the like can be used.

Although not illustrated in FIGS. 1A and 1B, a protective film may be provided over the second electrode. As the protective film, an organic resin film or an inorganic insulating film can be formed. The protective film may be formed so as to cover an exposed portion of the sealing material 605. The protective film can be provided to cover surfaces and side surfaces of the pair of substrates and exposed side surfaces of a sealing layer, an insulating layer, and the like.

The protective film can be formed using a material that is less likely to transmit impurities such as water easily. Thus, diffusion of impurities such as water from the outside into the inside can be effectively suppressed.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a film formation method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

The display apparatus of one embodiment of the present invention can have, for example, a top-emission structure where light is emitted toward the sealing substrate 604, which is opposite to the element substrate 610. Note that the display apparatus of one embodiment of the present invention may have a bottom-emission structure.

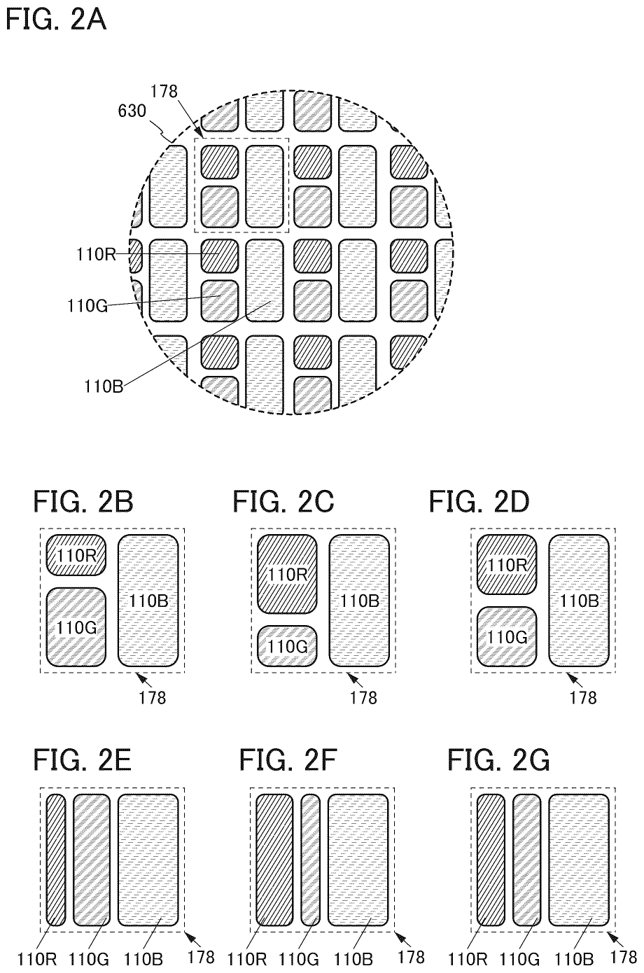

In the case where the display apparatus of one embodiment of the present invention has a top-emission structure, the sealing substrate 604 includes a display region where light emitted from pixels provided in the pixel portion 602 can be seen. FIG. 1A illustrates a circle 630 that indicates part of the display region, and FIG. 2A is an enlarged view of the region enclosed by the circle 630.

As illustrated in FIG. 2A, pixels 178 are arranged in a matrix in the pixel portion 602. The pixels 178 are periodically arranged. Each of the pixels 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 602. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels that emit light of four colors of R, G, B, and white (W), subpixels that emit light of four colors of R, G, B, and yellow (Y), and four subpixels that emit light of R, G, and B and infrared (IR) light.

In the display apparatus of one embodiment of the present invention, the area of any one of the subpixels 110R, 110G, and 110B is preferably different from those of the other two. Moreover, in the display apparatus of one embodiment of the present invention, the subpixels 110R, 110G, and 110B preferably have different areas. When the area of a subpixel of one emission color that includes a light-emitting device with higher reliability is made smaller and the areas of the subpixels of the other emission colors are made larger, the reliability of the whole pixel 178 can be increased.

In particular, in the display apparatus of one embodiment of the present invention, a highly reliable light-emitting device that will be described later in this embodiment and Embodiment 2 is preferably used in at least one of the subpixels 110R, 110G, and 110B. Structure example 1 of a highly reliable light-emitting device will be described in this embodiment, and Structure example 2 of a highly reliable light-emitting device will be described in Embodiment 2. In the display apparatus of one embodiment of the present invention, Structure example 3 described later in Embodiment 3 can be used in another one or two of the subpixels 110R, 110G, and 110B. Although the details will be described later, a light-emitting device employing Structure example 1 has higher reliability than a light-emitting device employing Structure example 2 owing to the use of an organic compound including deuterium. Thus, for example, Structure example 1 is preferably used in any one of the subpixels 110R, 110G, and 110B and Structure example 2 is preferably used in another one of the subpixels 110R, 110G, and 110B. Alternatively, Structure example 1 is preferably used in any two of the subpixels 110R, 110G, and 110B. Alternatively, Structure example 2 is preferably used in any two of the subpixels 110R, 110G, and 110B.

In this embodiment, the case where the highly reliable light-emitting device described later in this embodiment and Embodiment 2 is used in the subpixels 110R and 110G and Structure example 3 is used in the subpixel 110B is given as an example, and the relation of the areas of the subpixels of different emission colors is described. For example, in the case where Structure examples 1, 2, and 3 are respectively used in the subpixels 110R, 110G, and 110B, it is preferable that the area of the subpixel 110R be smaller than the area of the subpixel 110G and the area of the subpixel 110G be smaller than the area of the subpixel 110B. In the case where Structure examples 2, 1, and 3 are respectively used in the subpixels 110R, 110G, and 110B, it is preferable that the area of the subpixel 110G be smaller than the area of the subpixel 110R and the area of the subpixel 110R be smaller than the area of the subpixel 110B. In the case where Structure example 1 is used in both the subpixel 110R and the subpixel 110G and Structure example 3 is used in the subpixel 110B, the area of the subpixel 110R and the area of the subpixel 110G are each preferably smaller than the area of the subpixel 110B. In the case where Structure example 2 is used in both the subpixel 110R and the subpixel 110G and Structure example 3 is used in the subpixel 110B, the area of the subpixel 110R and the area of the subpixel 110G are each preferably smaller than the area of the subpixel 110B. Such structures can increase the area of the subpixel 110B, so that the reliability of the subpixel 110B can be increased, and thus the reliability of the whole pixel 178 can be increased.

Note that in this specification and the like, the aperture ratio of a subpixel is the ratio of the area of the subpixel to the unit area of a display region (which can also be referred to as the pixel area); thus, the case where the area of the subpixel 110R is smaller than the area of the subpixel 110G and the area of the subpixel 110G is smaller than the area of the subpixel 110B can also be said that the aperture ratio of the subpixel 110R is lower than the aperture ratio of the subpixel 110G and the aperture ratio of the subpixel 110G is lower than the aperture ratio of the subpixel 110B. The case where the area of the subpixel 110G is smaller than the area of the subpixel 110R and the area of the subpixel 110R is smaller than the area of the subpixel 110B can also be said that the aperture ratio of the subpixel 110G is lower than the aperture ratio of the subpixel 110R and the aperture ratio of the subpixel 110R is lower than the aperture ratio of the subpixel 110B. The case where the area of the subpixel 110R and the area of the subpixel 110G are each smaller than the area of the subpixel 110B can also be said that the aperture ratio of the subpixel 110R and the aperture ratio of the subpixel 110G are each lower than the aperture ratio of the subpixel 110B.

In the display apparatus of one embodiment of the present invention, there is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement. Examples of a top surface shape of the subpixel include polygons such as a triangle, a tetragon (including a rectangle and a square), and a pentagon; these polygons with rounded corners; an ellipse; and a circle. The circuit constituting the subpixel is not necessarily placed within the dimensions of the subpixel illustrated in the diagrams and may be placed outside the subpixel.

Structure examples of the pixel 178 will be described with reference to FIGS. 2B to 2G. Note that in this embodiment, the top surface shapes of the subpixels shown in the diagrams correspond to top surface shapes of light-emitting regions.

The pixels 178 illustrated in FIGS. 2B to 2D employ S-stripe arrangement and consist of three subpixels: the subpixel 110R, the subpixel 110G, and the subpixel 110B. The pixels 178 illustrated in FIGS. 2E to 2G employ stripe arrangement and consist of three subpixels: the subpixel 110R, the subpixel 110G, and the subpixel 110B. In FIGS. 2B and 2E, the area of the subpixel 110R is smaller than the area of the subpixel 110G, and the area of the subpixel 110G is smaller than the area of the subpixel 110B. In FIGS. 2C and 2F, the area of the subpixel 110G is smaller than the area of the subpixel 110R, and the area of the subpixel 110R is smaller than the area of the subpixel 110B. In FIGS. 2D and 2G, the area of the subpixel 110R and the area of the subpixel 110G are substantially equal to each other and smaller than the area of the subpixel 110B.

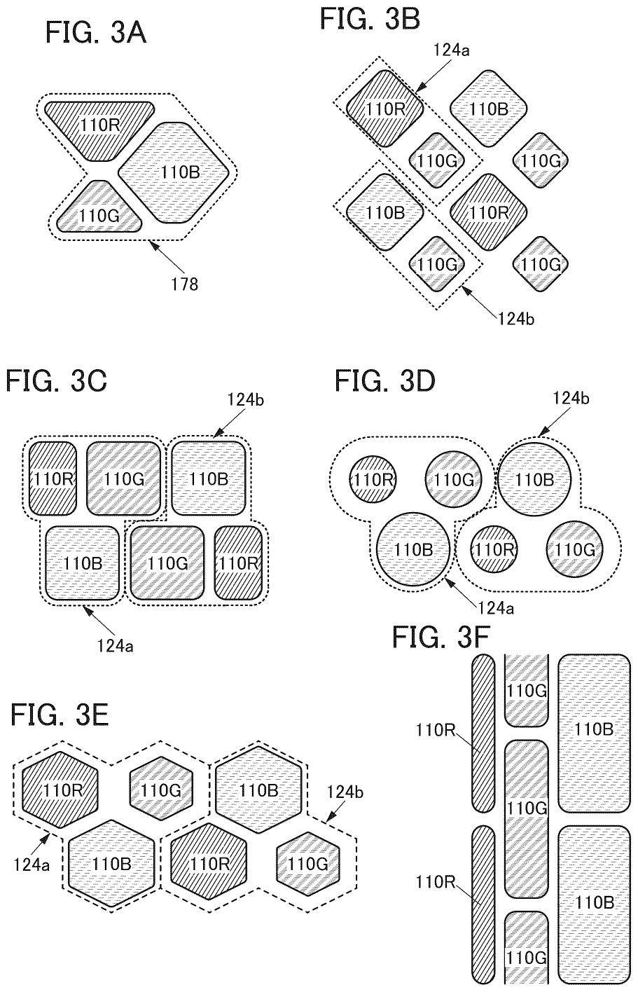

The pixel 178 illustrated in FIG. 3A includes the subpixel 110R whose top surface has a rough trapezoidal or triangular shape with rounded corners, the subpixel 110G whose top surface has a rough trapezoidal or triangular shape with rounded corners, and the subpixel 110B whose top surface has a rough tetragonal or hexagonal shape with rounded corners. The area of the subpixel 110G is smaller than the area of the subpixel 110R, and the area of the subpixel 110R is smaller than the area of the subpixel 110B. In this manner, the shapes and sizes of the subpixels can be determined independently.

Pixels 124a and 124b illustrated in FIG. 3B employ PenTile arrangement. FIG. 3B illustrates an example where the pixels 124a including the subpixels 110R and 110G and the pixels 124b including the subpixels 110G and 110B are alternately arranged. In the case where a plurality of types of pixels with different layouts are provided in the pixel portion as described above, the area of the subpixel of each emission color is calculated by summing up the areas of the subpixels included in the pixels. For example, in the structure illustrated in FIG. 3B, the area of the green subpixel can be calculated by summing up the area of the subpixel 110G included in the pixel 124a and the area of the subpixel 110G included in the pixel 124b. In the structure illustrated in FIG. 3B, the area of the green subpixel is larger than the areas of the subpixel 110R and the subpixel 110B.

The pixels 124a and 124b illustrated in FIGS. 3C to 3E employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row). Even in the case where a plurality of types of pixels are provided in the pixel portion as described above, when the areas of subpixels of one emission color are the same among the plurality of types of pixels, the area of the subpixel of the emission color can be calculated from the area of the subpixel in any of the plurality of types of pixels.

FIG. 3C illustrates an example where the top surface of each subpixel has a rough tetragonal shape with rounded corners. FIG. 3D illustrates an example where the top surface of each subpixel is circular. FIG. 3E illustrates an example where the top surface of each subpixel has a rough hexagonal shape with rounded corners. In FIG. 3C, the area of the subpixel 110R is smaller than the areas of the subpixel 110G and the subpixel 110B. In FIG. 3D, the area of the subpixel 110R is smaller than the area of the subpixel 110G, and the area of the subpixel 110G is smaller than the area of the subpixel 110B. In FIG. 3E, the area of the subpixel 110G is smaller than the area of the subpixel 110R, and the area of the subpixel 110R is smaller than the area of the subpixel 110B.

In FIG. 3E, the subpixels are placed in respective hexagonal regions that are arranged densely. One subpixel of the subpixels is placed so as to be surrounded by six subpixels. The subpixels are arranged such that subpixels that emit light of the same color are not adjacent to each other. For example, one subpixel 110R is surrounded by three subpixels 110G and three subpixels 110B that are alternately arranged.

FIG. 3F shows an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view. In FIG. 3F, the area of the subpixel 110R is smaller than the area of the subpixel 110G, and the area of the subpixel 110G is smaller than the area of the subpixel 110B.

Note that the subpixel 110R and the subpixel 110G may be interchanged with each other in the pixels illustrated in FIGS. 3A to 3F.

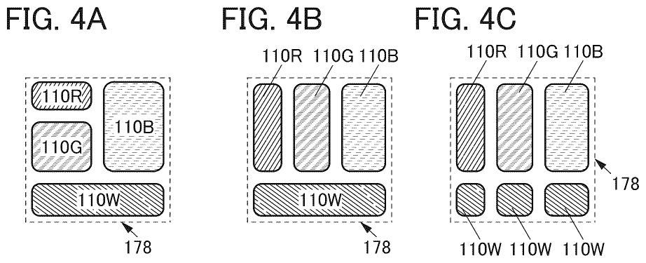

In addition, the pixel can include four types of subpixels as illustrated in FIGS. 4A to 4C.

FIG. 4A illustrates an example where one pixel 178 is composed of three rows and two columns.

The pixel 178 illustrated in FIG. 4A includes the subpixel 110R in the upper row (first row), the subpixel 110G in the middle row (second row), the subpixel 110B across the first row and the second row, and one subpixel (a subpixel 110W) in the lower row (third row). In other words, the pixel 178 includes the subpixels 110R and 110G in the left column (first column), the subpixel 110B in the right column (second column), and the subpixel 110W across these two columns.

FIGS. 4B and 4C each illustrate an example where one pixel 178 is composed of two rows and three columns.

The pixel 178 illustrated in FIG. 4B includes three subpixels (the subpixels 110R, 110G, and 110B) in the upper row (first row) and one subpixel (the subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 4C includes three subpixels (the subpixels 110R, 110G, and 110B) in the upper row (first row) and three subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 4C enables dust that would be produced in the fabrication process, for example, to be removed efficiently. Thus, a display apparatus having high display quality can be provided.

In the pixels 178 illustrated in FIGS. 4B and 4C, the subpixels 110R, 110G, and 110B are arranged in a stripe pattern, whereby the display quality can be improved.

In this manner, the display apparatus of one embodiment of the present invention can be obtained.

With the use of the light-emitting device described later in this embodiment, the display apparatus in this embodiment can have favorable characteristics. Specifically, since the light-emitting device described later in this embodiment has high emission efficiency, the display apparatus can achieve low power consumption. Since the light-emitting device described later in this embodiment has high reliability, the display apparatus can be highly reliable. When the area of a subpixel including the light-emitting device described later in this embodiment is made smaller than the areas of the other subpixels, the reliability of the whole pixel can be increased. In addition, since the light-emitting device described later in this embodiment can have favorable chromaticity and high color purity, the display apparatus can achieve high display quality.

Next, Structure example 1 of a light-emitting device that can be used in the display apparatus of one embodiment of the present invention will be described.

### Structure Example 1

A tandem light-emitting device has a structure in which a plurality of light-emitting units are stacked between a pair of electrodes with an intermediate layer (a charge-generation layer) therebetween. The tandem light-emitting device having such a structure has much higher current efficiency than a non-tandem light-emitting device, and can thus be suitably used for a display apparatus that requires high-luminance display or high reliability.

Since the tandem light-emitting device includes a plurality of light-emitting layers and can thus easily provide white light emission, many full-color display apparatuses including the tandem light-emitting device employ a “white+color filter” method. A color conversion method is also in practical use in which light-emitting layers that emit blue light are stacked and a color conversion layer typified by quantum dots is used.

Meanwhile, some full-color display apparatuses employing a side-by-side patterning method and the tandem light-emitting device have also been put into practical use. A light-emitting device fabricated by the side-by-side patterning method has little or no energy loss due to a color filter or a color conversion layer and can thus have a higher emission efficiency than light-emitting devices fabricated by the above-described two methods.

At least one of the light-emitting layers included in the tandem light-emitting device includes an emission center material, a first host material, and a second host material. The emission center material is preferably a phosphorescent substance. In a light-emitting device in which excitation is caused by current, the light-emitting device can have high emission efficiency when using a substance that can convert triplet energy into light emission (a phosphorescent substance or a substance exhibiting thermally activated delayed fluorescence) as a light-emitting substance (a guest material).

In another known structure, two kinds of organic compounds (specifically, an organic compound having an electron-transport property and an organic compound having a hole-transport property) are used as host materials in combination with a light-emitting substance (a guest material) in a light-emitting layer.

In particular, a technology using a structure where an exciplex formed by two kinds of organic compounds is used as an energy donor and a substance that can convert triplet energy into light emission (a phosphorescent substance or a substance exhibiting thermally activated delayed fluorescence) is used as an energy acceptor in a light-emitting layer, which is called exciplex-triplet energy transfer (ExTET), is a capable technology that achieves high efficiency, a low driving voltage, and a long lifetime.

That is, a light-emitting device whose light-emitting layer includes an exciplex as an energy donor and a substance that can convert triplet energy into light emission as an energy acceptor, i.e., a light-emitting substance, can have excellent characteristics.

When one or both of two kinds of substances functioning as the host materials (the first host material and the second host material) include deuterium, the light-emitting device can have higher reliability.

In particular, as described later, in the case where a difference in the lowest triplet excited level (T₁ level) between the first and second host materials is small, i.e., in the case where the T₁ levels of the first and second host materials are close to each other, the triplet excitation energy is less likely to be localized in one of the organic compounds, and energy transfer from the organic compounds in the triplet excited state to the substance that can convert triplet energy into light emission might occur. The efficiency of the energy transfer from the compounds is improved by the influence of deuterium, thereby inhibiting deterioration of the first and second host materials, at least one of which includes deuterium.

This effect is significant particularly when the two kinds of substances form an exciplex. The singlet excitation energy of the exciplex is transferred from the exciplex to the light-emitting substance. Meanwhile, the triplet excitation energy of the exciplex can be transferred not only directly to the light-emitting substance but also indirectly to the light-emitting substance through the first host material or the second host material in the triplet excited state. In particular, as described later, in the case where the difference in the lowest triplet excited level (T₁ level) between the first host material and the second host material is small, i.e., in the case where the T₁ levels of the first and second host materials are close to each other, the triplet energy can be transferred through the compounds in the triplet excited state to the substance capable of converting triplet energy into light emission. This is because the excitation energy is less likely to be localized in one of the organic compounds. The efficiency of the energy transfer from the compounds in the triplet excited state is improved by the influence of the deuterium, whereby deterioration of the first and second host materials can be inhibited. Specifically, the difference in the T₁ level between the first host material and the second host material is preferably less than or equal to 0.30 eV, further preferably less than or equal to 0.20 eV, still further preferably less than or equal to 0.10 eV.

Accordingly, a light-emitting device that uses an exciplex formed by including a deuterated organic compound as an energy donor has less deterioration than a light-emitting device that uses an exciplex formed only by non-deuterated organic compounds as an energy donor, and thus can have high reliability.

In one or both of the first host material and the second host material, all the hydrogens in the molecule may be substituted by deuterium; at least a group or a skeleton having a localized lowest triplet excited level needs to be deuterated, and hydrogen contained in the other groups or skeletons is preferably protium. This enables the first or second host material to be obtained at low cost as compared with the case where all hydrogen in the molecule is substituted by deuterium.

Note that the first host material is an organic compound having an electron-transport property and preferably includes a π-electron deficient heteroaromatic ring. The second host material is an organic compound having a hole-transport property and preferably includes a π-electron rich heteroaromatic ring or an aromatic amine skeleton.

In the case where the first host material is an organic compound having an electron-transport property and the second host material is an organic compound having a hole-transport property, the HOMO level of the organic compound having a hole-transport property is preferably higher than or equal to the HOMO level of the organic compound having an electron-transport property. The LUMO level of the organic compound having a hole-transport property is preferably higher than or equal to the LUMO level of the organic compound having an electron-transport property, in which case the exciplex can be formed more efficiently.

The HOMO level and the LUMO level can be obtained through a cyclic voltammetry (CV) measurement.

In the cyclic voltammetry (CV) measurement, the values (E) of the HOMO and LUMO levels can be calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level can be obtained by potential scanning in the positive direction and potential scanning in the negative direction, respectively. The scanning speed in the measurement is 0.1 V/s.

Specifically, a standard oxidation-reduction potential (Eₒ) (=(Eₚₐ+E_{pc})/2) is calculated from an oxidation peak potential (Eₚₐ) and a reduction peak potential (E_{pc}), which are obtained by the cyclic voltammogram of a material. Then, the standard oxidation-reduction potential (Eₒ) is subtracted from the potential energy (Eₓ) of the reference electrode with respect to a vacuum level, whereby the values (E) (=Eₓ−Eₒ) of the HOMO and LUMO levels can be obtained.

Note that the reversible oxidation-reduction wave was obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) is assumed to be an oxidation peak potential (Eₚₐ), and a standard oxidation-reduction potential (Eₒ) is calculated to one decimal place.

In the light-emitting device described in this embodiment, an improvement in energy transfer efficiency due to deuterium included in one or both of the first and second host materials is derived from the fact that the phosphorescence lifetime or delayed fluorescence lifetime of the deuterated organic compound is longer than that of a non-deuterated organic compound. This is because a deuterated organic compound in the lowest triplet excited state (T₁ state) has less intramolecular vibration than a non-deuterated organic compound in the T₁ state and accordingly has less non-radiative transition from the T₁ state to a more stable state.

The energy transfer efficiency ϕ_{ET} from an energy donor (an exciplex in one embodiment of the present invention) to an energy acceptor (a substance that can convert triplet excitation energy into light emission in one embodiment of the present invention) is expressed by Formula (1) below. According to this formula, it is found that the energy transfer efficiency ϕ_{ET} can be increased by increasing the rate constant k_{h*→g} of energy transfer so that another competing rate constant kᵣ+kₙᵣ (=1/τ) becomes relatively small.

In Formula (1), kᵣ represents the rate constant of a light emission process (fluorescence in the case where energy transfer from a singlet excited state is discussed, and phosphorescence or delayed fluorescence in the case where energy transfer from a triplet excited state is discussed) of the energy donor, kₙᵣ represents the rate constant of a non-light-emission process (thermal deactivation and intersystem crossing) of the energy donor, and τ represents a measured lifetime of an excited state of the energy donor. In addition, k_{h*→g} represents the rate constant of energy transfer (Förster mechanism or Dexter mechanism).

$$\begin{matrix}[ Formula 1 ] & \\ {∅}_{ET} = \frac{{k}_{{h}^{*} \to g}}{{k}_{r} + {k}_{nr} + {k}_{{h}^{*} \to g}} = \frac{{k}_{{h}^{*} \to g}}{( \frac{1}{τ} ) + {k}_{{h}^{*} \to g}} & ( 1 )\end{matrix}$$

A deuterated organic compound and a non-deuterated organic compound have substantially the same atomic arrangement in a molecule and substantially the same spectrum shape, for example, and thus have substantially the same rate constant k_{h*→g} of energy transfer (see Formula (2) or (3) below). Thus, in comparison between the deuterated organic compound and the non-deuterated organic compound, the rate constant k_{h*→g} of energy transfer is found to be greatly affected by the emission lifetime (phosphorescence lifetime or delayed fluorescence lifetime) τ. That is, the energy transfer efficiency is improved as the emission lifetime (phosphorescence lifetime or delayed fluorescence lifetime) is longer.

$$\begin{matrix}[ Formula 2 ] & \\ {k}_{{h}^{*} \to g} = \frac{9000 {K}^{2} ∅ ln 10}{128 {π}^{5} {n}^{4} N τ {R}^{6}} \int \frac{{f}_{h}^{′} ( v ) {ε}_{g} ( v )}{{v}^{4}} dv & ( 2 )\end{matrix}$$

$$\begin{matrix}[ Formula 3 ] & \\ {k}_{{h}^{*} \to g} = ( \frac{2 π}{h} ) {K}^{2} exp ( - \frac{2 R}{L} ) \int {f}_{h}^{′} ( v ) {ε}_{g}^{′} ( v ) dv & ( 3 )\end{matrix}$$

Formula (2) is a formula of the rate constant k_{h*→g} of the Forster mechanism, and Formula (3) is a formula of the rate constant k_{h*→g} of the Dexter mechanism.

In Formula (2), ν represents a frequency, f′ₕ(ν) represents a normalized emission spectrum of the host material (a fluorescent spectrum in the case where energy transfer from a singlet excited state is discussed, and a phosphorescent spectrum in the case where energy transfer from a triplet excited state is discussed), ε_{g}(ν) represents a molar absorption coefficient of the guest material, N represents Avogadro's number, n represents a refractive index of a medium, R represents an intermolecular distance between the host material and the guest material, τ represents a measured lifetime of an excited state (fluorescence lifetime or phosphorescence lifetime), ϕ represents an emission quantum yield (a fluorescence quantum yield in the case where energy transfer from a singlet excited state is discussed, and a phosphorescence quantum yield in the case where energy transfer from a triplet excited state is discussed), and K² represents a coefficient (0 to 4) of orientation of a transition dipole moment between the host material and the guest material. Note that K² is ⅔ in random orientation.

In Formula (3), h represents a Planck constant, K represents a constant having an energy dimension, ν represents a frequency, f′ₕ(ν) represents a normalized emission spectrum of the host material (a fluorescent spectrum in the case where energy transfer from a singlet excited state is discussed, and a phosphorescent spectrum in the case where energy transfer from a triplet excited state is discussed), ε′_{g}(ν) represents a normalized absorption spectrum of the guest material, L represents an effective molecular radius, and R represents an intermolecular distance between the host material and the guest material.

As described above, in energy transfer from the first and second host materials, the efficiency of energy transfer from the triplet excited state is important and thus the lifetime of the triplet excited state is important. That is, the phosphorescence lifetime or delayed fluorescence lifetime is increased when one or both of the first host material and the second host material are deuterated; hence, the efficiency of energy transfer is improved, and deterioration of the deuterated organic compound(s) can be inhibited. Accordingly, a light-emitting device using a deuterated organic compound as an energy donor has less deterioration of the organic compound than a light-emitting device not using a deuterated organic compound as an energy donor, and thus can have high reliability.

The phosphorescence lifetime and the delayed fluorescence lifetime are calculated by measuring the transient PL by time-resolved measurement, in which the intensity of light attenuating after the excitation light is blocked by a shutter is measured at certain intervals. In this measurement, a graph is sometimes not linear because fluorescence components can be mixed at the initial stage of attenuation. In such a case, a starting point is set in a portion where the graph is straight, and the time taken for the intensity at the starting point to attenuate to 1/e is regarded as the phosphorescence lifetime or the delayed fluorescence lifetime.

Note that in the light-emitting device described in this embodiment, the exciplex formed by the first and second host materials preferably serves as an energy donor; however, as described above, regarding the triplet excited state, there can be a path of energy transfer from the triplet excited state of the exciplex through the triplet excited states of the first and second host materials. Thus, the phosphorescence lifetime or delayed fluorescence lifetime of the first and second host materials forming the exciplex is important. In the light-emitting device described in this embodiment including the exciplex as the energy donor, it is found that the phosphorescence lifetime or delayed fluorescence lifetime is increased by a certain length owing to deuterium included in one of, preferably both of, the first and second host materials, thereby significantly improving the reliability of the light-emitting device.

That is, the first host material is preferably an organic compound whose phosphorescence lifetime or delayed fluorescence lifetime is 1.50 or more times the phosphorescence lifetime or delayed fluorescence lifetime of a first material in which deuterium of the first host material is replaced with protium. The second host material is preferably an organic compound whose phosphorescence lifetime or delayed fluorescence lifetime is 3.00 or more times the phosphorescence lifetime or delayed fluorescence lifetime of a second material in which deuterium of the second host material is replaced with protium. Here, it is preferable that light emitted from the substance that can convert triplet excitation energy into light emission (the light-emitting substance included in the light-emitting layer) be in the green region, that is, the peak wavelength be typically greater than or equal to 500 nm and less than or equal to 600 nm. Alternatively, it is preferable that light emitted from the substance that can convert triplet excitation energy into light emission (the light-emitting substance included in the light-emitting layer) be in the red region, that is, the peak wavelength be typically greater than or equal to 600 nm and less than or equal to 700 nm.

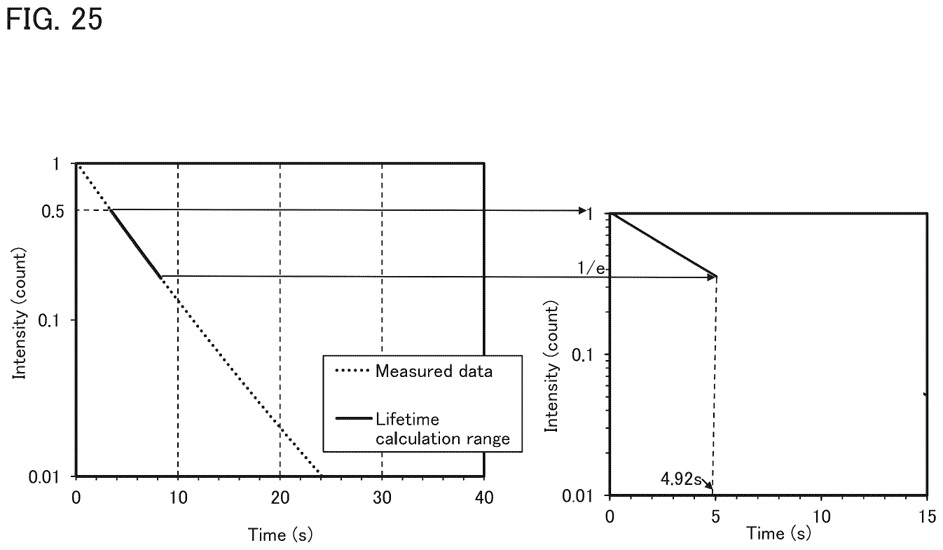

From the measured data shown in the left graph of FIG. 25, the starting point is set as t=0 within the range where the graph is straight (here, the time at which the light amount becomes 50% of that at the start of the measurement is set as t=0 in the right graph of FIG. 25). The time taken for the light amount to attenuate to 1/e that at t=0 is regarded as a phosphorescence lifetime or a delayed fluorescence lifetime. In the right graph of FIG. 25, the time at which the intensity reaches 50% of that at the start of the measurement in the measured data is set as time 0 s, the light amount at 0 s is regarded as 1, and the time taken for the light amount to become 1/e is the phosphorescence lifetime or the delayed fluorescence lifetime. Although the point where the intensity becomes 50% of that at the start of the measurement is easily used as the starting point, a point with another intensity may be used as the starting point.

The phosphorescence lifetime can be measured at liquid nitrogen temperature (77 K) with a fluorescence spectrophotometer such as FP-8600 produced by JASCO Corporation, in which a liquid nitrogen cooling unit is set. A solution of a material is prepared in a glove box in the following manner: a sample is dissolved in 2-MeTHF that has been deoxidized, and then stirring is performed with a stirrer at room temperature for approximately 30 minutes (heating is also performed in the case where the material has low solubility) so that the concentration of the solution is adjusted to approximately 1.2 E⁻⁴ M.

The time-resolved measurement can be performed in the following manner: a sample cell is irradiated with excitation light for approximately 30 seconds and the emission intensity attenuating after the excitation light is blocked by a shutter is measured at 10 ms intervals. The peak wavelength of the phosphorescence spectrum is preferably used to measure the phosphorescence lifetime. In the case where the phosphorescence spectrum has a plurality of peaks, a wavelength with the highest peak intensity is preferably selected. Depending on the wavelength, the measurement cannot be performed accurately because of a mixed fluorescence spectrum in some cases. In such a case, in comparison between an emission spectrum measured at low temperature (e.g., 77 K) (an emission spectrum including phosphorescence components) and an emission spectrum measured at normal temperature (an emission spectrum including only fluorescence components and not including phosphorescence components), it is preferable to select a wavelength of the emission spectrum that includes fluorescence components as little as possible. Alternatively, a wavelength of a peak on the longest wavelength side in the phosphorescence spectrum can be selected. In the case of a frozen solution, light emission from a state other than the lowest triplet excited state may also be observed. In this case, a peak on the longest wavelength side is selected.

Note that the excitation wavelength is appropriately selected within a wavelength range where a solvent has no influence. As long as the material can be excited sufficiently, measurement is preferably performed at a wavelength of 330 nm because there is no influence by a solvent. The band widths of the excitation light and the measured light are each approximately 10 nm. Ideally, light emission attenuates single-exponentially; thus, a starting point is set in a portion where a graph is straight, and the time taken for the intensity at the starting point to attenuate to 1/e can be defined as the phosphorescence lifetime or the delayed fluorescence lifetime.

The fluorescence lifetime can be distinguished from the phosphorescence lifetime and the delayed fluorescence lifetime by the length of the lifetime in the time-resolved measurement. An emission lifetime on the order of nanoseconds is the fluorescence lifetime, and an emission lifetime on the order of microseconds to milliseconds or more is the phosphorescence lifetime or the delayed fluorescence lifetime.

In the light-emitting device described in this embodiment, the reliability is improved in relation to the increase in the phosphorescence lifetime, that is, the lifetime of triplet excitons, of the first and second host materials. The increase in the lifetime of triplet excitons is caused by inhibited non-radiative deactivation of the triplet excitation energy, which is due to inhibited vibration owing to deuteration. At this time, the difference in the lowest triplet excited level (T₁ level) between the first and second host materials is preferably small, in which case the excitation energy is less likely to be localized in one of the organic compounds and thus significant deterioration of one of the organic compounds can be prevented, leading to high reliability of the light-emitting device. Specifically, the difference in the T₁ level between the first and second host materials is preferably less than or equal to 0.30 eV, further preferably less than or equal to 0.20 eV, still further preferably less than or equal to 0.15 eV, yet further preferably less than or equal to 0.10 eV.

For calculation of the lowest triplet excitation energy level (T₁ level), an emission spectrum (phosphorescence spectrum) is measured at a measurement temperature of 10 K using a 50-nm-thick thin film of a sample formed over a quartz substrate. The measurement is preferably performed with a PL microscope (LabRAM HR-PL, produced by HORIBA, Ltd.) and a He—Cd laser (325 nm) as excitation light. Note that the emission edge can be determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

In one embodiment of the present invention, the sublimation temperatures of the first and second host materials are preferably close to each other. For example, the difference in the 5% weight loss temperature measured by thermogravimetry between the first host material and the second host material is preferably less than or equal to 60° C., further preferably less than or equal to 45° C., still further preferably less than or equal to 20° C., yet further preferably less than or equal to 10° C. This enables evaporation using a mixed material of the first and second host materials, thereby reducing the number of evaporation sources and providing a light-emitting device with favorable characteristics at low cost.

The 5% weight loss temperature can be obtained from the relation between weight and temperature (thermogravimetric measurement) by performing thermogravimetry-differential thermal analysis (TG-DTA). In the case where the pressure for the evaporation is determined in advance, it is preferable to use a value measured under the pressure.

Note that the light-emitting device can have more favorable characteristics owing to a preferred combination of the increasing rate of the phosphorescence lifetime or the delayed fluorescence lifetime due to deuteration, the product of the increasing rates, the difference in T₁ level, and the difference in sublimation temperature of the first and second host materials.

In addition, the photoluminescence (PL) spectrum of the exciplex formed by the first and second host materials and that of the light-emitting substance (the substance that can convert triplet energy into light emission) preferably have an overlap. This is because the driving voltage of the light-emitting device can be lowered when the excitation energy of the energy donor is close to the excitation energy of the light-emitting substance. Thus, the energy difference between the maximum peak wavelengths of the exciplex and the light-emitting substance is preferably less than or equal to 0.35 eV, further preferably less than or equal to 0.30 eV, still further preferably less than or equal to 0.25 eV, yet further preferably less than or equal to 0.20 eV, most preferably less than or equal to 0.15 eV. Alternatively, in the light-emitting device, the difference between the energy of the maximum peak in the PL spectrum of the exciplex and the energy at the wavelength of the absorption edge on the longer wavelength side in the absorption spectrum of the light-emitting substance is preferably less than or equal to 0.35 eV, further preferably less than or equal to 0.30 eV, still preferably less than or equal to 0.25 eV, yet further preferably less than or equal to 0.20 eV, most preferably less than or equal to 0.15 eV, in which case the driving voltage can be lowered.

The PL spectrum of the exciplex is preferably measured using a film formed by co-evaporation of the first and second host materials. A sample used for measuring the PL spectrum of the light-emitting substance (the substance that can convert triplet energy into light emission) may be in the form of a thin film or a solution, but is preferably in the form of a solution for examining the state of an isolated molecule. There is no particular limitation on a solvent of the solution as long as the same solvent is used for a comparison between the PL spectra. A solvent with relatively low polarity, such as toluene or chloroform, is preferred. The ratio of the first host material to the second host material can be measured using a thin film having a weight ratio or a volume ratio of 1:1.

In the case where the substance that can convert triplet excitation energy into light emission (the light-emitting substance included in the light-emitting layer) emits light in the blue region, that is, in the case where the peak wavelength is typically greater than or equal to 450 nm and less than 500 nm, the first host material is preferably an organic compound including a triazine skeleton or a diazine skeleton, and the second host material is preferably a material including a carbazole skeleton. Specifically, an example of the first host material includes 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7,8′-d₁₆) (abbreviation: SiTrzCz2-d₁₆), and examples of the second host material include 9-(3-(triphenylsilyl)phenyl)-3,9′-(bi-9H-carbazole-d₁₅) (abbreviation: PSiCzCz-d₁₅), 9′-(phenyl-d₅)-9′H-9,3′:6′,9″-tercarbazole-1,1′,1″,2,2′,2″,3,3″,4,4′,4″,5,5′,5″,6,6″ ?,7,7′,7″,8,8′,8″-d₂₂ (abbreviation: PhCzGI-d₂₇), and 9′-[3-(triphenylsilyl)phenyl]-9′H-9,3′:6′,9″-tercarbazole-1,1′,1″,2,2′,2″,3,3″,4,4′,4″,5,5′,5″,6,6″,7,7′,7″,8,8′,8″-d₂₂ (abbreviation: PSiCzGI-d₂₂).

In the case where the substance that can convert triplet excitation energy into light emission (the light-emitting substance included in the light-emitting layer) emits light in the green region or the red region, that is, in the case where the peak wavelength is typically greater than or equal to 500 nm and less than or equal to 700 nm, the first host material is preferably an organic compound including a diazine skeleton or a triazine skeleton, and the second host material is preferably a material including a carbazole skeleton. Specific examples of the first host material include 8-(1,1′:4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃), 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), and 11-[4-(biphenyl-4-yl-2,2′,3,3′,4′,5,5′,6,6′-d₉)-6-(phenyl-2,3,4,5,6-d₅)-1,3,5-triazin-2-yl]-11,12-dihydro-12-(biphenyl-3-yl)indolo[2,3-a]carbazole-1,2,3,4,5,6,7,8,9,10-d₁₀. Specific examples of the second host material include 9-(2-naphthyl-1,3,4,5,6,7,8-d)-9′-(phenyl-2,3,4,5,6-d₅)-3,3′-bi-9H-carbazole-1,1′,2,2′,4,4′,5,5′,6,6′,7,7,8,8′-d₁₄ (abbreviation: βNCCP-d₂₆) and 9-phenyl-9′-(phenyl-2,3,4,5,6-d₅)-3,3′-bis(9H-carbazole) (abbreviation: PCCP-d₅).

The light-emitting device described in this embodiment, which is a tandem light-emitting device, includes a plurality of light-emitting layers. Although the structure of the light-emitting layer described above may be applied to only some of the light-emitting layers, it is preferable that all the light-emitting layers have this structure.

For example, in a tandem light-emitting device including two light-emitting layers of a first light-emitting layer and a second light-emitting layer, it is preferable that the first light-emitting layer include a first emission center substance, a first organic compound, and a second organic compound; the second light-emitting layer include a third organic compound and a fourth organic compound; one or both of the first and second organic compounds be deuterated; and one or both of the third and fourth organic compounds be deuterated. Preferably, the first organic compound and the third organic compound each correspond to the first host material, the second organic compound and the fourth organic compound each correspond to the second host material, and the first light-emitting layer and the second light-emitting layer each have the above-described structure of the light-emitting layer.

Specifically, the first organic compound and the third organic compound have an electron-transport property, and preferably include a π-electron deficient heteroaromatic ring. The second organic compound and the fourth organic compound have a hole-transport property, and preferably include a π-electron rich heteroaromatic ring or an aromatic amine skeleton. A combination of the first and second organic compounds and a combination of the third and fourth organic compounds each preferably form an exciplex. The difference in the T₁ level between the first and second organic compounds and between the third and fourth organic compounds is preferably less than or equal to 0.30 eV, further preferably less than or equal to 0.20 eV, still further preferably less than or equal to 0.15 eV, yet further preferably less than or equal to 0.10 eV. The other structures described above can also be used for each light-emitting layer by replacing the first host material with “first organic compound” or “third organic compound” and replacing the second host material with “second organic compound” or “fourth organic compound”.

Note that what to call the first host material is not limited to “first organic compound” and “third organic compound”. In addition, what to call the second host material is not limited to “second organic compound” and “fourth organic compound”. For example, in the case where Structure example 1 is used in any two of the subpixels 110R, 110G, and 110B illustrated in FIG. 2B, in order to distinguish the first host materials and the second host materials included in the two light-emitting devices, the first host materials included in a first light-emitting device are referred to as a “first organic compound” and a “third organic compound”, the second host materials included in the first light-emitting device are referred to as a “second organic compound” and a “fourth organic compound”, the first host materials included in a second light-emitting device are referred to as a “fifth organic compound” and a “seventh organic compound”, and the second host materials included in the second light-emitting device are referred to as a “sixth organic compound” and an “eighth organic compound” in some cases.

The formation of an exciplex can be ensured by a phenomenon in which the emission spectrum of a mixed film where an organic compound having a hole-transport property and an organic compound having an electron-transport property are mixed is shifted to the longer wavelength side than the emission spectrum of each of the organic compounds (or has another peak on the longer wavelength side) observed by comparison of the emission spectra of the organic compound having a hole-transport property, the organic compound having an electron-transport property, and the mixed film of these organic compounds, for example. Alternatively, the formation of an exciplex can be ensured by a difference in transient response, such as a phenomenon in which the transient photoluminescence (PL) lifetime of the mixed film has a longer lifetime component or has a larger proportion of delayed components than that of each of the organic compounds, observed by comparison of transient PL of the organic compound having a hole-transport property, the organic compound having an electron-transport property, and the mixed film of these materials. The transient PL can be rephrased as transient electroluminescence (EL). That is, the formation of an exciplex can also be ensured by a difference in transient response observed by comparison of the transient EL of the organic compound having a hole-transport property, the organic compound having an electron-transport property, and the mixed film of these organic compounds.

Here, the emission edge on the shorter wavelength side of the PL spectrum of the exciplex formed by the first and second host materials is preferably positioned at a shorter wavelength than the absorption edge on the longer wavelength side in the absorption spectrum of the emission center substance. When the PL spectrum of the exciplex and the absorption edge of the emission center substance have such a positional relation, energy can be efficiently transferred.

Alternatively, the peak wavelength of the PL spectrum of the exciplex formed by the first and second host materials is preferably shorter than the peak wavelength of the PL spectrum of the emission center substance. The difference between the energy at the peak wavelength of the PL spectrum of the exciplex and the energy at the peak wavelength of the PL spectrum of the emission center substance is preferably less than or equal to 0.35 eV, further preferably less than or equal to 0.30 eV, still further preferably less than or equal to 0.25 eV, yet further preferably less than or equal to 0.20 eV, most preferably less than or equal to 0.15 eV. When the peak wavelength of the PL spectrum of the exciplex and the peak wavelength of the PL spectrum of the emission center substance have such a relation, energy can be efficiently transferred.

Alternatively, the difference between the energy at the peak wavelength of the PL spectrum of the exciplex formed by the first and second host materials and the energy at the wavelength of the absorption edge on the longer wavelength side in the absorption spectrum of the emission center substance is preferably less than or equal to 0.35 eV, further preferably less than or equal to 0.30 eV, still further preferably less than or equal to 0.25 eV, yet further preferably less than or equal to 0.20 eV, most preferably less than or equal to 0.15 eV. When the energy at the peak wavelength of the PL spectrum of the exciplex and the energy at the wavelength of the absorption edge on the longer wavelength side in the absorption spectrum of the emission center substance have such a relation, energy can be efficiently transferred.

The PL spectrum of the exciplex is preferably measured using a film formed by co-evaporation of the first and second host materials. Meanwhile, the PL spectrum or the absorption spectrum of the emission center substance may be measured using a sample in the form of a thin film or a solution; the sample is preferably in the form of solution for examination of the state of an isolated molecule. A solvent of the solution is preferably a solvent with relatively low polarity, such as toluene or chloroform.

The absorption edge of the absorption spectrum can be determined as the intersection between a tangent and the horizontal axis or the baseline. The tangent is drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum can be determined as the intersection between a tangent and the horizontal axis or the baseline. The tangent is drawn at a point at which the slope on a shorter wavelength side of the shortest-wavelength peak (or the shortest-wavelength shoulder peak) of the PL spectrum has the maximum value.

As described above, in one embodiment of the present invention, it is preferable that the first host material be an organic compound having an electron-transport property and the second host material be an organic compound having a hole-transport property.

The organic compound having an electron-transport property, which serves as the first host material, preferably has an electron mobility higher than or equal to 1×10⁻⁷ cm²/Vs, preferably higher than or equal to 1×10⁻⁶ cm²/Vs, when the square root of electric field strength [V/cm] is 600.

An organic compound having a π-electron deficient heteroaromatic ring is preferable as the organic compound having an electron-transport property. Examples of the organic compound having a π-electron deficient heteroaromatic ring include an organic compound that includes a heteroaromatic ring having an azole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have high electron-transport properties to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

The organic compound that has a π-electron deficient heteroaromatic ring and can be used as the organic compound having an electron-transport property is preferably any of the following organic compounds, for example. Examples include organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), and 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm); and organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn). In the case where the first host material is an organic compound including deuterium, any of the above organic compounds in which some or all of hydrogens are substituted by deuterium can be used. It is particularly preferable to use an organic compound in which a group or a skeleton where a triplet excited level is localized is deuterated.

The organic compound having a hole-transport property is preferably an organic compound having an amine skeleton or a π-electron rich heteroaromatic ring, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group bonds to nitrogen of an amine through an arylene group may be used. Note that the substance having a hole-transport property is preferably an organic compound having an N,N-bis(4-biphenyl)amino group to enable fabrication of a light-emitting device having a long lifetime.

As such an organic compound, any of the following organic compounds is preferable, for example. Examples include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′: 6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In the case where the second host material is an organic compound including deuterium, any of the above organic compounds in which some or all of hydrogens are substituted by deuterium can be used. It is particularly preferable to use an organic compound in which a group or a skeleton where a triplet excited level is localized is deuterated.

As described above, it is preferable that the first host material be an organic compound having an electron-transport property and the second host material be an organic compound having a hole-transport property. For a higher carrier-transport property and more efficient exciplex formation, it is preferable that the first host material be an organic compound having a π-electron deficient heteroaromatic ring and the second host material be an organic compound having an amine skeleton or a π-electron rich heteroaromatic ring. For higher triplet excitation energy, it is preferable that the first host material be an organic compound that has a heteroaromatic ring having a diazine (pyrimidine or pyrazine) skeleton or an organic compound that has a heteroaromatic ring having a triazine skeleton and the second host material be an organic compound that has any of a carbazole skeleton, a dibenzofuran skeleton, a dibenzothiophene skeleton, and an anthracene skeleton. For higher stability and reliability, it is preferable that the first host material be an organic compound having a triazine skeleton or a pyrimidine skeleton and the second host material be an organic compound having a carbazole skeleton. As the organic compound having a carbazole skeleton, an organic compound having a 3,3′-bicarbazole skeleton is particularly preferable because of its high donor property and high heat resistance. The second host material being an organic compound having a 3,3′-bicarbazole skeleton and the first host material being an organic compound having a triazine skeleton are highly preferable, in which case the triplet excitation energy is high and the stability and reliability are high.

By mixing the organic compound having an electron-transport property with the organic compound having a hole-transport property, the transport property of the light-emitting layer can be easily adjusted and a recombination region can be easily controlled. The weight ratio of the content of the organic compound having a hole-transport property to the content of the organic compound having an electron-transport property is 1:19 to 19:1, preferably 3:7 to 7:3.

The light-emitting layer included in the tandem light-emitting device that is described in this embodiment and includes such a light-emitting layer is preferably separated from the light-emitting layer included in at least one of the adjacent light-emitting devices. Alternatively, the light-emitting layer included in the tandem light-emitting device is preferably different from the light-emitting layer included in at least one of the adjacent light-emitting devices. Alternatively, the emission color of the tandem light-emitting device is preferably different from the emission color of at least one of the adjacent light-emitting devices. Alternatively, the emission center substance included in the light-emitting layer of the tandem light-emitting device preferably has a structure different from that of the emission center substance included in the light-emitting layer of at least one of the adjacent light-emitting devices.

In the tandem light-emitting device described in this embodiment, an electron-transport layer included in a light-emitting unit on the cathode side preferably includes an eleventh organic compound having a triazine skeleton, and the intermediate layer preferably includes a twelfth organic compound having a phenanthroline skeleton. When the electron-transport layer of the light-emitting unit on the cathode side includes the eleventh organic compound and the intermediate layer includes the twelfth organic compound, the tandem light-emitting device can have a low driving voltage. When the electron-transport layer of the light-emitting unit on the cathode side includes the eleventh organic compound, the intermediate layer includes the twelfth organic compound, and any of the light-emitting layers includes the emission center substance as well as the first host material and the second host material at least one of which is deuterated, the tandem light-emitting device can have a lower driving voltage and higher emission efficiency, and thus can have high power efficiency and high energy efficiency.

When the light-emitting layer included in the tandem light-emitting device is separated from the light-emitting layer included in at least one of the adjacent light-emitting devices as described above or is different from the light-emitting layer included in at least one of the adjacent light-emitting devices, when the emission color of the tandem light-emitting device is different from the emission color of at least one of the adjacent light-emitting devices, or when the emission center substance included in the light-emitting layer of the tandem light-emitting device has a structure different from that of the emission center substance included in the light-emitting layer of at least one of the adjacent light-emitting devices, the light-emitting device can have excellent current efficiency and thus can have higher power efficiency and higher energy efficiency.

As a result, the display apparatus of one embodiment of the present invention that includes such a light-emitting device can achieve low power consumption, high reliability, high-luminance display, and high visibility. In addition, the display apparatus can have favorable display quality.

The eleventh organic compound having a triazine skeleton preferably has an electron-transport property with an electron mobility higher than or equal to 1×10⁻⁷ cm²/Vs, preferably higher than or equal to 1×10⁻⁶ cm²/Vs when the square root of the electric field intensity [V/cm] is 600. Note that any other substance can also be used as long as the substance has an electron-transport property higher than a hole-transport property.

The eleventh organic compound having a triazine skeleton preferably has the triazine skeleton and an aromatic ring. The aromatic ring can be a monocyclic aromatic ring, a polycyclic aromatic ring, an aromatic ring having an alkyl group as a substituent, an aromatic ring having a fluoro group as a substituent, an aromatic ring having a cyano group as a substituent, or the like. The triazine skeleton may have a substituent other than the above-described aromatic ring, and the aromatic ring may have a substituent other than the above-described fluoro group, cyano group, or alkyl group. Note that a triazine skeleton is also referred to as a triazine ring, and other skeletons can also be rephrased as rings.

Examples of a monocyclic aromatic ring include aromatic hydrocarbon rings such as a benzene ring and heteroaromatic rings such as a pyrrole ring, a pyridine ring, a pyrimidine ring, and a triazine ring. Having an aromatic ring as a substituent has the effect of improving heat resistance, specifically, a glass transition temperature (T_{g}), and the effect of improving an electron-transport property, for example.

Examples of a polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, a xanthene ring, an indolocarbazole ring, and an indenocarbazole ring. A compound having a polycyclic aromatic ring as a substituent is preferable to a compound having a monocyclic aromatic ring such as a benzene ring because it can improve heat resistance. A compound having as a substituent a ring in which an aromatic ring (e.g., a benzene ring, a naphthalene ring, or a pyridine ring) is further fused to any of the above polycyclic aromatic rings can further improve heat resistance. Examples of the ring in which an aromatic ring is further fused to the polycyclic aromatic ring include a benzofluorene ring, a benzonaphthofuran ring, a benzoxanthene ring, and a benzonaphthothiophene ring. Providing a layer including a compound having high heat resistance in the vicinity of the cathode can inhibit heat damage to the device when high-temperature treatment in a patterning step or the like is performed after the layer or the cathode is formed.

Examples of an alkyl group include a methyl group, an ethyl group, a propyl group, a tertiary butyl group, a cyclohexyl group, and an adamantyl group. A layer including a compound having an alkyl group as a substituent can have a low refractive index. This can reduce total reflection at the interface between the layer and another layer and improve the light extraction efficiency. When a compound having such a substituent is used also for a hole-transport layer, the refractive index can be lowered. In particular, when a compound having a triazine skeleton and an alkyl group is used for the electron-transport layer and a compound having an aromatic amine skeleton and an alkyl group is used for the hole-transport layer, the effect of improving the light extraction efficiency can be synergistically enhanced. An organic compound having an alkyl group having a plurality of carbon atoms, preferably three or more carbon atoms, further preferably four or more carbon atoms, still further preferably five or more carbon atoms, can enhance the effect. A layer including a compound having a fluoro group as a substituent is also preferable because it can lower the refractive index. In particular, an organic compound having a plurality of fluoro groups can enhance the effect of improving the light extraction efficiency due to a lower refractive index. It is also effective to use a compound having a fluoro group for both the electron-transport layer and the hole-transport layer. A compound having a structure in which a plurality of alkyl groups are bonded to one aromatic ring can further lower the refractive index of the layer. In one example, two or three or more tertiary butyl groups are bonded as substituents to one benzene ring. Without limitation to a benzene ring, the plurality of alkyl groups may be bonded to another monocyclic aromatic ring such as a pyridine ring or a polycyclic aromatic ring such as a fluorene ring. In addition, the plurality of alkyl groups are suitably bonded to one or more rings included in a polycyclic aromatic ring (e.g., a naphthalene ring, a fluorene ring, a carbazole ring, a quinoline ring, or a xanthene ring). In one example, a plurality of tertiary butyl groups are bonded to one benzene ring included in a fluorene ring. Without limitation to an alkyl group, a structure in which a plurality of fluoro groups are bonded to one aromatic ring and a structure in which a plurality of fluoro groups are bonded to one or more rings included in a polycyclic aromatic rings are preferable.

A compound having a cyano group as a substituent is preferable because it can improve the electron-transport property.

A combination of some of polycyclic aromatic rings, alkyl groups, fluoro groups, and cyano groups is also suitable for substituents. Having a polycyclic aromatic ring and a cyano group as substituents, for example, can improve both the heat resistance and the electron-transport property. Having a polycyclic aromatic ring and an alkyl group can improve both the heat resistance and the light extraction efficiency. In this manner, substituents can be used in combination in accordance with the required function.

Having a plurality of polycyclic aromatic rings as substituents can further improve the heat resistance. Here, a compound preferably has the aromatic hydrocarbon ring and the heteroaromatic ring.

The eleventh organic compound having a triazine skeleton can be specifically, for example, an organic compound that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluoren-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-pheny-9-[4-phenyl-6-(9-phenyl-3-dibenzofuranyl-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), 2,4-diphenyl-6-[3′-(spiro[7H-benzo[c]fluorene-7,9′-[9H]xanthen]-2′-yl)biphenyl-3-yl]-1,3,5-triazine (abbreviation: mSbfxBPTzn), 3′-[4-phenyl-6-(spiro[9H-fluorene-9,9′-[9H]xanthen]-2′-yl)-1,3,5-triazin-2-yl]biphenyl-4-carbonitrile (abbreviation: mpCNBP-SFxTzn), or 2,2′-[1,2-naphthalenediyldi(4,1-phenylene)]bis(4,6-diphenyl-1,3,5-triazine) (abbreviation: TznP2N), and is particularly preferably TznP2N (100), mSbfxBPTzn (101), mpCNBP-SFxTzn (102), CNBPNPTzn (103), PNP-SFx(4)Tzn (104), mmtBuBP-mDMePyPTzn (105), or mBnfBPTzn (106) represented by Structural Formulae (100) to (106) below or the like.

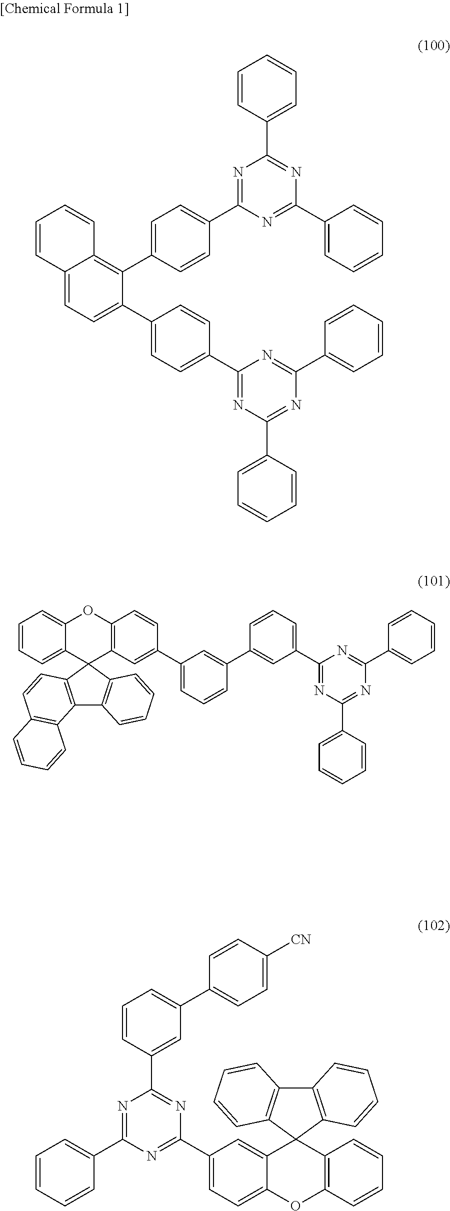 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1 ; c1ccc(-c2nc(-c3ccccc3)nc(-c3cccc(-c4cccc(-c5ccc6c(c5)C5(c7ccccc7O6)c6ccccc6-c6c5ccc5ccccc65)c4)c3)n2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1]

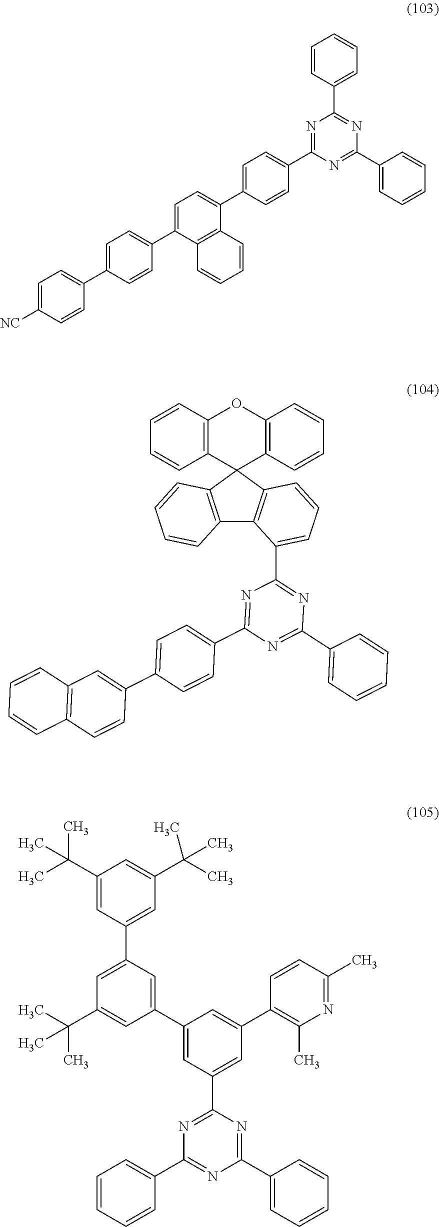 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; c1ccc(-c2nc(-c3ccc(-c4ccc5ccccc5c4)cc3)nc(-c3cccc4c3-c3ccccc3C43c4ccccc4Oc4ccccc43)n2)cc1 ; Cc1ccc(-c2cc(-c3cc(-c4cc(C(C)(C)C)cc(C(C)(C)C)c4)cc(C(C)(C)C)c3)cc(-c3nc(-c4ccccc4)nc(-c4ccccc4)n3)c2)c(C)n1]

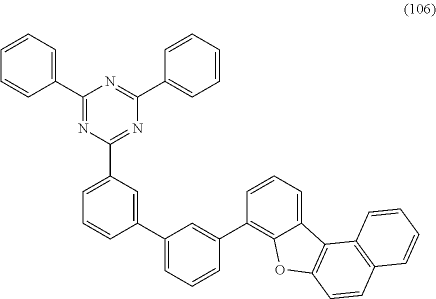 [SMILES: c1ccc(-c2nc(-c3ccccc3)nc(-c3cccc(-c4cccc(-c5cccc6c5oc5ccc7ccccc7c56)c4)c3)n2)cc1]

Note that an electron-transport layer included in a light-emitting unit on the anode side may include an organic compound having a triazine skeleton, like the electron-transport layer included in the light-emitting unit on the cathode side, or may include an organic compound not having a triazine skeleton.

The electron-transport layer included in the light-emitting unit on the anode side preferably includes an organic compound having a triazine skeleton in order to reduce power consumption. It is particularly preferable for the layer to include the organic compound identical to the eleventh organic compound in order to prevent a manufacturing apparatus from being complex and offer a cost advantage in raw material procurement.

When the electron-transport layer included in the light-emitting unit on the anode side includes an organic compound not having a triazine skeleton, the carrier-transport property can be easily controlled to provide a light-emitting device with better characteristics. The organic compound not having a triazine skeleton is preferably an organic compound that has a heteroaromatic ring having a pyridine skeleton or an organic compound that has a heteroaromatic ring having a diazine (pyrimidine or pyrazine) skeleton. Note that any of the above organic compounds deuterated as appropriate can also be used.

The twelfth organic compound having a phenanthroline skeleton, which is included in the intermediate layer, preferably has an electron mobility higher than or equal to 1×10⁻⁷ cm²/Vs, preferably higher than or equal to 1×10⁻⁶ cm²/Vs when the square root of the electric field intensity [V/cm] is 600. Note that any other substance can also be used as long as the substance has an electron-transport property higher than a hole-transport property.

The twelfth organic compound having a phenanthroline skeleton preferably has the phenanthroline skeleton and an aromatic ring. The aromatic ring is preferably a monocyclic aromatic ring, a polycyclic aromatic ring, or the like.

Examples of a monocyclic aromatic ring include a benzene ring, a pyrrole ring, a pyridine ring, and a pyrimidine ring. Preferable examples of a polycyclic aromatic ring include heteroaromatic rings such as a phenanthroline ring and a pyrrole ring, as well as aromatic hydrocarbon rings such as a naphthalene ring, a phenanthrene ring, a chrysene ring, a triphenylene ring, and a fluorene ring. It is particularly preferable that the twelfth organic compound have a plurality of such polycyclic aromatic rings to improve its heat resistance or electron-transport property.

The twelfth organic compound having a phenanthroline skeleton can be, for example, an organic compound that has a heteroaromatic ring having a phenanthroline skeleton, such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen), and is particularly preferably PnNPhen (200) or mPPhen2P (201) represented by Structural Formula (200) or (201) below, or the like.

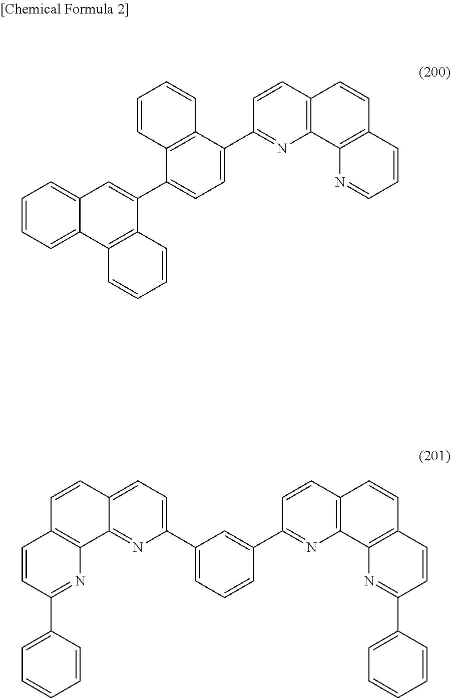 [SMILES: c1ccc2c(c1)cc(-c1ccc(-c3ccc4ccc5cccnc5c4n3)c3ccccc13)c1ccccc12 ; c1ccc(-c2ccc3ccc4ccc(-c5cccc(-c6ccc7ccc8ccc(-c9ccccc9)nc8c7n6)c5)nc4c3n2)cc1]

In the light-emitting device described in this embodiment, the intermediate layer can have any structure as long as it includes the twelfth organic compound having a phenanthroline skeleton and can inject electrons and holes respectively into the light-emitting unit on the anode side and the light-emitting unit on the cathode side, which are in contact with the intermediate layer, by voltage application between a first electrode and a second electrode. Note that the intermediate layer preferably has a stacked-layer structure of a first layer including the twelfth organic compound and a second layer positioned closer to the cathode than the first layer is.

The first layer preferably includes a metal or a metal compound in addition to the twelfth organic compound. The metal or a metal of the metal compound is preferably an alkali metal (Group 1 element) such as Li, an alkaline earth metal (Group 2 element) such as Mg or Ca, a Group 3 element including Y and lanthanoids such as Eu and Yb, a Group 11 element such as Cu, Ag, or Au, a Group 12 element such as Zn, an earth metal (Group 13 element) such as Al or In.

Note that the first layer may have a stacked-layer structure of a layer including an organic compound and a layer that includes a metal or a metal compound and is positioned closer to the cathode than the layer including an organic compound is, or may be a mixed layer of an organic compound and a metal or a metal compound. The first layer is preferably the mixed layer, in which case it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer is analyzed in the thickness direction. That is, when the organic compound is uniformly distributed, the metal or the metal compound is also substantially uniformly distributed. In the case of the stacked-layer structure of the organic compound and the metal or the metal compound, the metal or the metal compound is sometimes diffused from the layer including the metal or the metal compound and detected also in a region other than the layer but shows a different distribution from the organic compound; thus, the analysis results of diffusion and mixing can be distinguished from each other.

In the case where the metal or the metal compound is detected over a region having a thickness greater than or equal to 10 nm, preferably greater than or equal to 15 nm, further preferably greater than or equal to 20 nm when the first layer is analyzed in the thickness direction, the first layer can be regarded as including a mixed layer in which the organic compound and the metal or the metal compound are mixed.

The metal or a metal of the metal compound is preferably a substance exhibiting a donor property with respect to the twelfth organic compound. Examples of the substance exhibiting a donor property with respect to the twelfth organic compound include metals belonging to Groups 1 and 2; lithium or a lithium compound is particularly preferable. Specifically, Li, lithium fluoride (LiF), lithium oxide (Li₂O), 8-hydroxyquinolinato-lithium (abbreviation: Liq), or the like is preferable. In the case where the first layer includes the twelfth organic compound and the substance exhibiting a donor property with respect to the twelfth organic compound, electrons are generated by charge separation, and the electrons are injected into the light-emitting unit on the anode side through the twelfth organic compound when voltage is applied between the first electrode and the second electrode. Thus, the light-emitting device described in this embodiment can have a low driving voltage.

The twelfth organic compound is preferably an organic compound having a phenanthroline skeleton having an electron-donating substituent, as well as the above-described organic compound. A phenanthroline skeleton is likely to interact with the metal or the like, and when the twelfth organic compound having such a phenanthroline skeleton further has an electron-donating group, the phenanthroline skeleton can have a higher electron density and become more likely to interact with the metal or the metal compound. In particular, the use of a metal belonging to Group 3, 11, 12, or 13 as the metal or a metal of the metal compound makes it possible to suppress an increase in driving voltage and provide a tandem light-emitting device having favorable characteristics.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

Specific examples of the organic compound having a phenanthroline skeleton having an electron-donating substituent are shown in Structural Formulae (300) to (311).

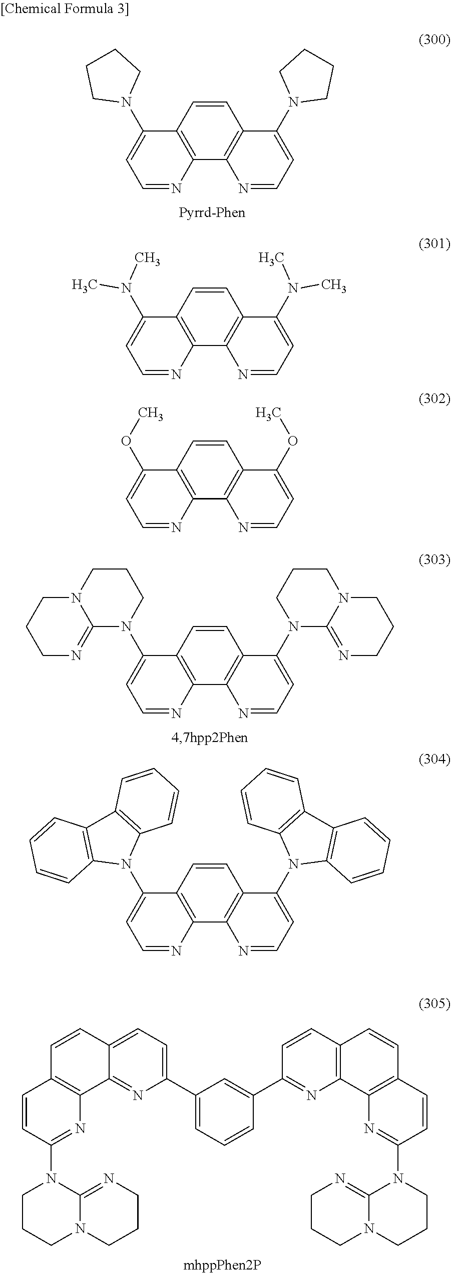

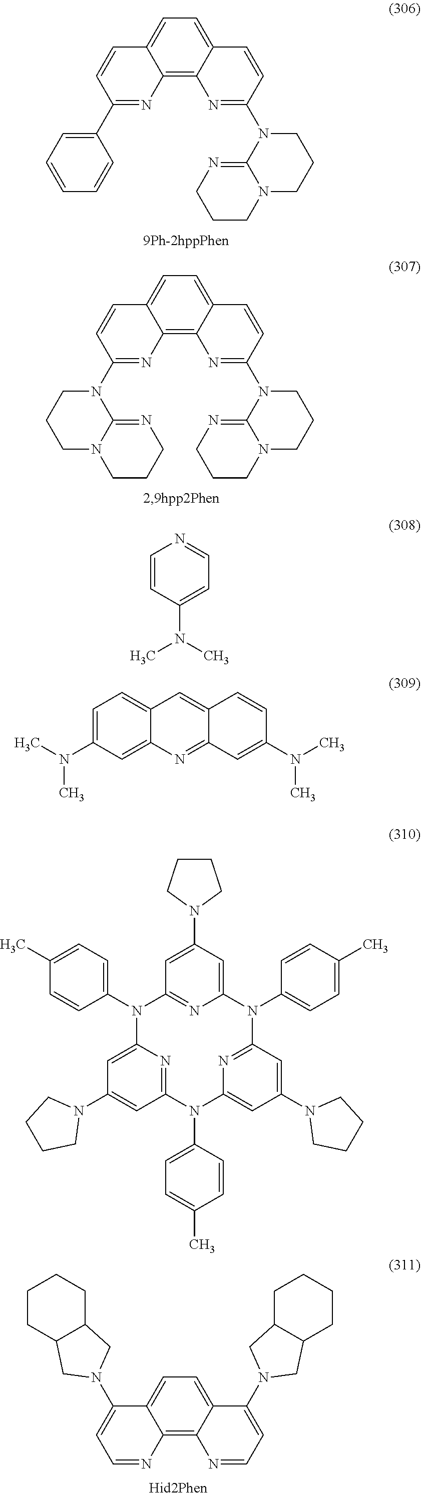

The first layer preferably includes a Group 1 or Group 2 element, especially lithium or a lithium compound, and the twelfth organic compound having a phenanthroline skeleton having an electron-donating substituent, in which case the tandem light-emitting device can have a lower driving voltage and higher reliability. Moreover, the structure where the first layer includes a Group 1 or Group 2 element, especially lithium or a lithium compound, and the twelfth organic compound having a phenanthroline skeleton having an electron-donating substituent is preferable because it is possible to inhibit an increase in driving voltage due to processing of the organic compound layer of the light-emitting device by a photolithography method.

In the intermediate layer having the above-described structure, the twelfth organic compound is particularly preferably an organic compound having, among phenanthroline skeletons, a 1,10-phenanthroline skeleton, in which case the twelfth organic compound is likely to interact with the metal or the metal compound because two nitrogen atoms of the organic compound can be coordinated to the metal.

In the case where an electron-donating group is introduced to a 1,10-phenanthroline skeleton, the electron-donating group is preferably substituted at the 4- and 7-positions of the 1,10-phenanthroline skeleton. Introducing an electron-donating group to the 4- and 7-positions of the 1,10-phenanthroline skeleton can increase the electron density of the nitrogen atoms at the 1- and 10-positions, thereby facilitating the interaction with the metal or the metal compound.

The first layer may further include an organic compound different from the twelfth organic compound. Note that the different organic compound preferably has an electron-transport property. It is particularly preferable that the organic compound have two or more heteroaromatic rings bonded or fused to each other and the two or more heteroaromatic rings have three or more heteroatoms in total. The first layer including such an organic compound can improve the heat resistance, the electron-transport property, and the like.

The second layer preferably includes a thirteenth organic compound having a hole-transport property. The second layer preferably further includes a substance exhibiting an acceptor property, and the substance exhibiting an acceptor property is preferably an organic compound exhibiting an acceptor property with respect to the thirteenth organic compound. The substance having an acceptor property is particularly preferably an organic compound having at least one of a halogen group and a cyano group, further preferably an organic compound having at least one of fluorine and a cyano group. Note that it is further preferable that the total number of halogen groups (fluorines) and cyano groups of the organic compound be four or more.

In the case where the second layer includes the thirteenth organic compound and the substance exhibiting an acceptor property with respect to the thirteenth organic compound, holes are generated by charge separation, and the holes are injected into the light-emitting unit on the cathode side through the thirteenth organic compound when voltage is applied between the first electrode and the second electrode. Thus, the light-emitting device described in this embodiment can have a low driving voltage.

The intermediate layer may include a third layer between the first layer and the second layer.

The third layer includes a substance having an electron-transport property and has functions of smoothly transferring and receiving electrons between the first layer and the second layer to reduce the driving voltage, and reducing the interaction between the first layer and the second layer to improve the reliability, for example.

The thickness of the third layer is preferably greater than or equal to 1 nm and less than or equal to 10 nm, further preferably greater than or equal to 2 nm and less than or equal to 5 nm, in which case an increase in driving voltage can be inhibited.

The light-emitting device described in this embodiment that has the above structure can have high current efficiency, low energy loss, and favorable characteristics. The display apparatus of one embodiment of the present invention that includes such a light-emitting device can achieve low power consumption, high reliability, high-luminance display, and high visibility.

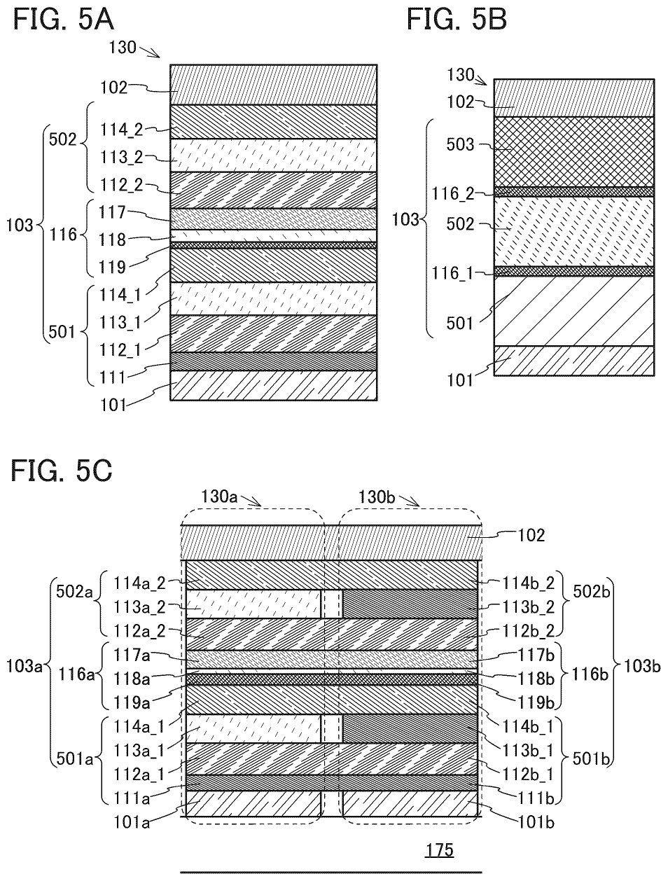

Next, light-emitting devices described in this embodiment will be described in detail with reference to drawings. FIG. 5A illustrates a light-emitting device 130 described in this embodiment. The light-emitting device described in this embodiment is a tandem light-emitting device and includes an organic compound layer 103 (also referred to as an EL layer) that includes a first light-emitting unit 501 including a first light-emitting layer 113_1, a second light-emitting unit 502 including a second light-emitting layer 113_2 and a second electron-transport layer 114_2, and an intermediate layer 116, between a first electrode 101 including an anode and a second electrode 102 including a cathode. Note that the first light-emitting unit may include a first electron-transport layer 114_1 between the first light-emitting layer 1131 and the intermediate layer 116.

In the light-emitting device 130, the second electron-transport layer 114_2 includes the eleventh organic compound having a triazine skeleton, and the intermediate layer 116 includes the twelfth organic compound having a phenanthroline skeleton. The second electron-transport layer 114_2 including the eleventh organic compound having a triazine skeleton is preferably in contact with the second electrode 102 in order to reduce power consumption.

Although a light-emitting device including one intermediate layer 116 and two light-emitting units is described as an example in this embodiment, a light-emitting device including n intermediate layer(s) (n is an integer greater than or equal to 1) and n+1 light-emitting units may be employed. For example, the light-emitting device 130 illustrated in FIG. 5B is an example of a tandem light-emitting device with n=2 that includes the first light-emitting unit 501, a first intermediate layer 1161, the second light-emitting unit 502, a second intermediate layer 1162, and a third light-emitting unit 503.

The first light-emitting unit 501 and the second light-emitting unit 502 may include a functional layer in addition to the above-described light-emitting layers and electron-transport layers. Although FIG. 5A illustrates the structure in which the first light-emitting unit 501 includes a hole-injection layer 111 and a first hole-transport layer 112_1 in addition to the first light-emitting layer 113_1 and the first electron-transport layer 114_1 and the second light-emitting unit 502 includes a second hole-transport layer 112_2 in addition to the second light-emitting layer 113_2 and the second electron-transport layer 114_2, the structure of the organic compound layer 103 in one embodiment of the present invention is not limited thereto and any of the layers may be omitted or other layers may be added. Typical examples of other layers include a carrier-blocking layer and an exciton-blocking layer.

The first electrode 101 includes the anode. The first electrode 101 may have a stacked-layer structure, in which case a layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may alternatively be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the composite material forming a second layer 117 in the intermediate layer 116 is used for the layer in contact with the anode (which is typically the hole-injection layer).

The hole-injection layer 111 is provided in contact with the anode and has a function of facilitating injection of holes into the organic compound layer 103 (the first light-emitting unit 501). The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-accepting property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups bond to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds. Alternatively, the hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example. The substance having an acceptor property can extract electrons from an adjacent hole-transport layer (or hole-transport material) by application of an electric field.

The hole-injection layer 111 is preferably formed using a composite material containing any of the aforementioned materials having an acceptor property and a substance having a hole-transport property.

As the substance having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the substance having a hole-transport property used in the composite material preferably has a hole mobility of 1×10⁻⁶ cm²/Vs or higher. The substance having a hole-transport property used in the composite material is preferably a compound having a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further fused to a carbazole ring or a dibenzothiophene ring is preferable.

Such a substance having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group bonds to nitrogen of an amine through an arylene group may be used. Note that the substance having a hole-transport property preferably has an N,N-bis(4-biphenyl)amino group to enable fabrication of a light-emitting device having a long lifetime.

Specific examples of the substance having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAaNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAββNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβMαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAPNB), 4-(3-biphenylyl)-4′-[4-(2-naphthyl)phenyl]-4″-phenyltriphenylamine (abbreviation: mTPBiAPNBi), 4-(4-biphenylyl)-4′-[4-(2-naphthyl)phenyl]-4″-phenyltriphenylamine (abbreviation: TPBiAPNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiPNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′: 6′,9″-tercarbazole (abbreviation: PSiCzGI).

Examples of aromatic amine compounds that can be used as the substance having a hole-transport property include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because it is easily deposited by evaporation.

The hole-transport layer (the first hole-transport layer 112_1 and the second hole-transport layer 112_2) includes an organic compound having a hole-transport property. The organic compound having a hole-transport property preferably has a hole mobility higher than or equal to 1×10⁻⁶ cm²/Vs.

Examples of the aforementioned substance having a hole-transport property include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton is preferable because these compounds are highly reliable and have high hole-transport properties to contribute to a reduction in driving voltage. Any of the organic compounds given as examples of the substance having a hole-transport property that is used in the composite material in the hole-injection layer 111 can also be suitably used as the material included in the hole-transport layer 112. Note that any of the above organic compounds deuterated as appropriate can also be used.

Note that the first hole-transport layer 112_1 and the second hole-transport layer 112_2 preferably include organic compounds having the same skeleton, and further preferably include the same compound. One or both of the first hole-transport layer 1121 and the second hole-transport layer 112_2 may have a stacked-layer structure. When the hole-transport layer 112 has a stacked-layer structure and a layer closer to the light-emitting layer 113 is formed using an organic compound having high electron tolerance and/or an organic compound having an electron-blocking property, the light-emitting device can have high reliability. In the case where the hole-transport layer 112 has a stacked-layer structure, the layer closer to the light-emitting layer 113 is preferably formed using a material having an excellent hole-transport property, a low electron-transport property, and a high LUMO level. The LUMO level of the material is preferably higher than the LUMO level of a material that has the highest constituent ratio or the highest LUMO level among the materials included in the light-emitting layer, further preferably by 0.30 eV or more. The material used for the layer closer to the light-emitting layer 113 is preferably an organic compound having an amine skeleton and a polycyclic heteroaromatic ring, further preferably an organic compound having an amine skeleton and a furan skeleton or a dibenzofuran skeleton. In the case where the hole-transport layer 112 has a stacked-layer structure, the use of the above-described material for the layer closer to the light-emitting layer 113 can prevent electrons from passing from the light-emitting layer 113 toward the first electrode 101, and thus, a display apparatus with high efficiency and a long lifetime can be manufactured. Note that in the hole-transport layer 112 having a stacked-layer structure, the layer closer to the first electrode 101 is formed using preferably an organic compound including an amine skeleton and a polycyclic hydrocarbon, further preferably an organic compound having an amine skeleton and a fluorene skeleton. The organic compound having an amine skeleton and a fluorene skeleton is preferable because its high reliability and high hole-transport property enable power consumption of the light-emitting device to be reduced.

The light-emitting layers (the first light-emitting layer 113_1 and the second light-emitting layer 1132) preferably include an emission center substance and a host material. At least one of the light-emitting layers includes the emission center substance, the first host material, and the second host material, both the first host material and the second host material are organic compounds, and one or both of the first host material and the second host material are deuterated. The first host material and the second host material are preferably a combination that forms an exciplex. Note that both the first light-emitting layer 113_1 and the second light-emitting layer 113_2 preferably have such a structure. The light-emitting layers may additionally include another material.

The first light-emitting layer 113_1 and the second light-emitting layer 113_2 preferably emit light of similar colors. For example, red, green, and blue pixels are often used in a full-color display apparatus. In a light-emitting device used in a red pixel, both the first light-emitting layer 113_1 and the second light-emitting layer 113_2 emit red light. In a green pixel, both of the two light-emitting layers emit green light. In a blue pixel, both of the two light-emitting layers emit blue light. In that case, the emission center substance included in the first light-emitting layer 113_1 and the emission center substance included in the second light-emitting layer 113_2 are preferably compounds whose emission spectra have a difference in maximum peak wavelength of less than or equal to 30 nm, further preferably less than or equal to 20 nm, still further preferably less than or equal to 10 nm. Further preferably, the same emission center substance is used for the first light-emitting layer 113_1 and the second light-emitting layer 113_2. Still further preferably, the materials used for the first light-emitting layer 113_1 and the second light-emitting layer 113_2 are identical to each other.

The emission center substance can be a fluorescent substance, a phosphorescent substance, a substance exhibiting thermally activated delayed fluorescence (TADF), or any other light-emitting substance.

Examples of the fluorescent substance that can be used as the emission center substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N″,N″,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPm, and 1,6BnfAPrn-03 are particularly preferable because of their high hole-trapping properties, high emission efficiency, or high reliability.

Examples of the phosphorescent substance that can be used as the emission center substance in the light-emitting layer are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-KN)carbazole-2,1-diyl-κC′)platinum(II) (abbreviation: PtON-TBBI). These compounds emit phosphorescent light with a blue hue and have an emission peak in the wavelength range from 450 nm to 520 nm. A compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: [Ir(5mtpy-d₆)₂(mbfpypy-iPr-d₄)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]), and tris{2-[5-(methyl-d₃)-4-phenyl-2-pyridinyl-κN]phenyl-κC}iridium(III) (abbreviation: [Ir(5m4dppy-d₃)₃]); organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′:3′,1″-terphenyl]-2′-yl)-2-pyridinyl-κN]phenyl-κC²}-2-pyridinyl-κN)phenolato-KO]platinum(II) (abbreviation: Pt(4tButpppypyp-mmtBup)); and rare earth metal complexes such as tris(acetylacetonato)(monophenanthroline)terbium(III) (abbreviation: [Tb(acac)₃(Phen)]). These compounds mainly emit phosphorescent light with a green hue and have an emission peak in the wavelength range from 500 nm to 600 nm. Note that the organometallic iridium complexes including a pyrimidine skeleton have distinctively high reliability or emission efficiency and thus are particularly preferable. A compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C″)iridium(III) (abbreviation: [Ir(piq)₃]), bis(1-phenylisoquinolinato-N,C²′)iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit phosphorescent light with a red hue and have an emission peak in the wavelength range from 600 nm to 700 nm. The organometallic iridium complexes having a pyrazine skeleton can provide red light emission with favorable chromaticity. A compound obtained by substituting deuterium for part of hydrogen in any of these compounds can also be used.

Note that in one embodiment of the present invention, the use of a deuterated compound as the emission center substance improves the emission efficiency. Thus, the emission center substance is preferably a deuterated material.

Besides the above phosphorescent compounds, known phosphorescent compounds may be selected and used.

Examples of the TADF material include a fullerene, a derivative thereof, an acridine, a derivative thereof, and an eosin derivative. Another example is a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

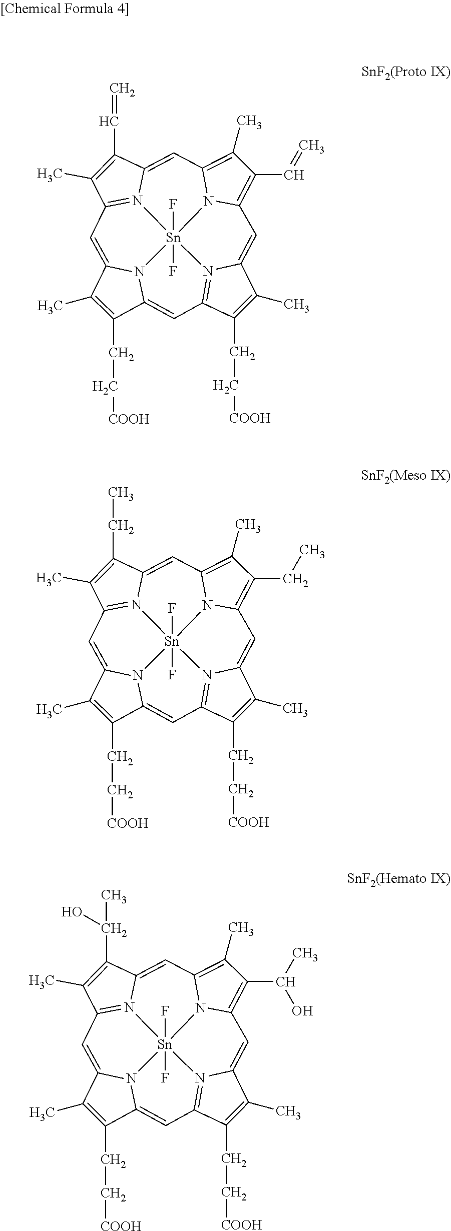

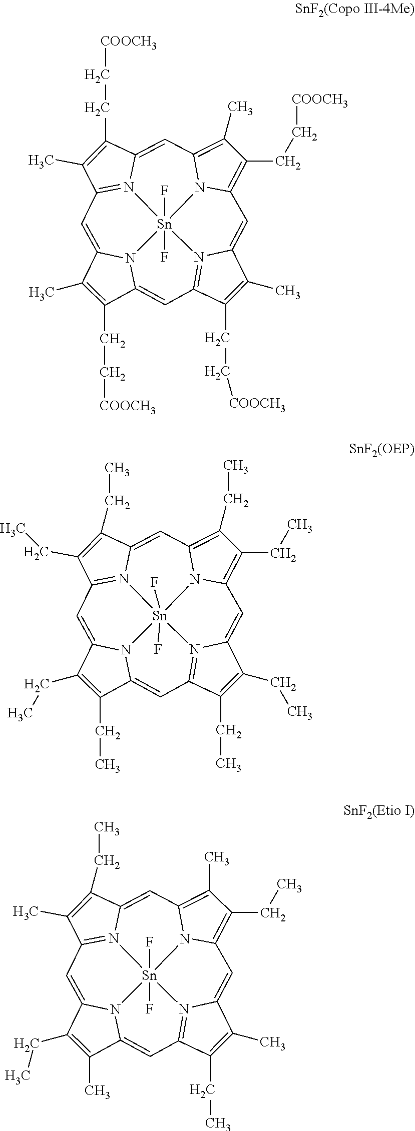

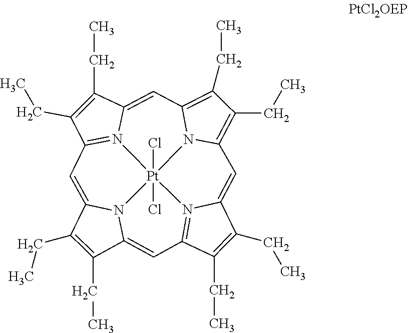

Alternatively, it is possible to use a heterocyclic compound having one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring directly bonds to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group bonds may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

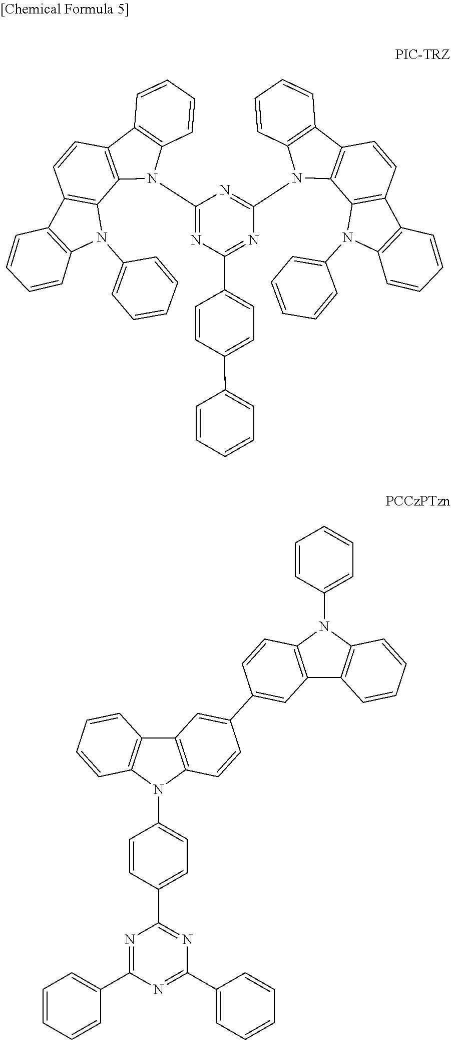 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

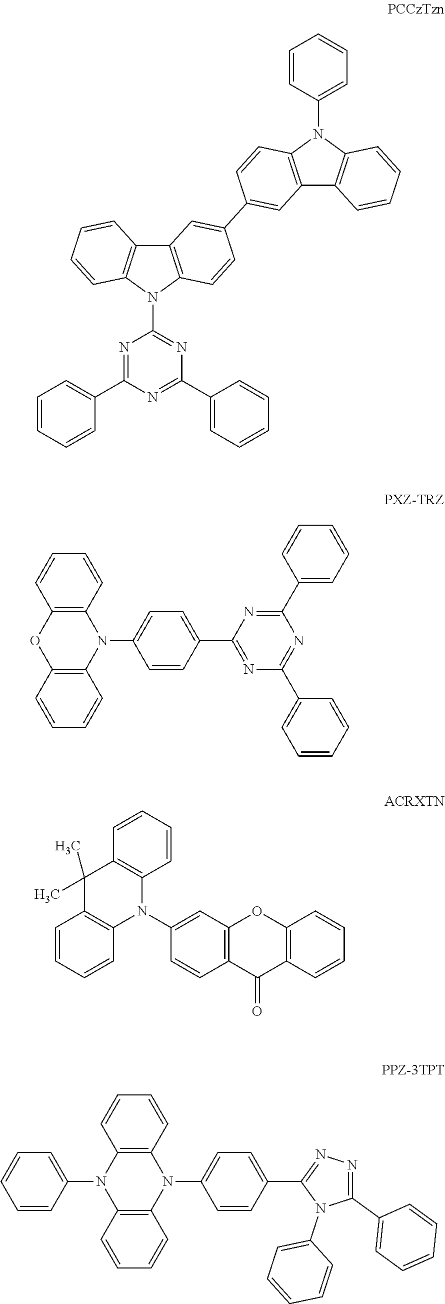 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

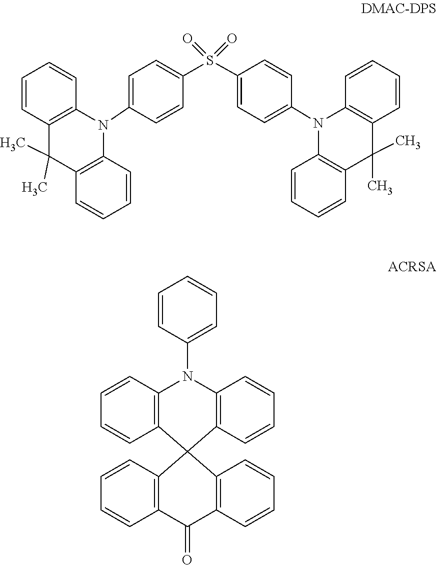

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specifically, a material having the following molecular structure can be used.

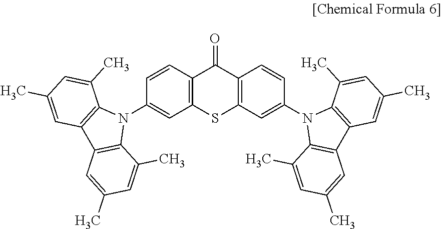

Note that a TADF material is a material having a small difference between the S₁ level and the T₁ level and a function of converting triplet excitation energy into singlet excitation energy by reverse intersystem crossing. Thus, a TADF material enables upconversion of triplet excitation energy into singlet excitation energy (i.e., reverse intersystem crossing) using a small amount of thermal energy and can efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the shorter wavelength side is the S₁ level and the level of energy with a wavelength of the line obtained by extrapolating a tangent to the phosphorescent spectrum at a tail on the shorter wavelength side is the T₁ level, the difference between the S₁ level and the T₁ level of the TADF material is preferably smaller than or equal to 0.30 eV, further preferably smaller than or equal to 0.20 eV.

When a TADF material is used as the light-emitting substance, the S₁ level of the host material is preferably higher than that of the TADF material. In addition, the T₁ level of the host material is preferably higher than that of the TADF material.

Since the host material for the light-emitting layer having the structure of one embodiment of the present invention has already been described in detail, the repeated description is omitted. The light-emitting device described in this embodiment, which is a tandem light-emitting device, includes a plurality of light-emitting layers. Thus, some of the light-emitting layers do not have the above structure in some cases. In the light-emitting layer not having the above structure, the host material(s) can be any of various carrier-transport materials such as an organic compound having an electron-transport property and/or an organic compound having a hole-transport property.

The organic compound having a hole-transport property is preferably an organic compound having an amine skeleton or a π-electron rich heteroaromatic ring, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to a carbazole ring or a dibenzothiophene ring is preferable.

Such a substance having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group bonds to nitrogen of an amine through an arylene group may be used. Note that the substance having a hole-transport property is preferably an organic compound having an N,N-bis(4-biphenyl)amino group to enable fabrication of a light-emitting device having a long lifetime.

As such an organic compound, any of the following organic compounds is preferable, for example. Examples include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′: 6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

An organic compound having a π-electron deficient heteroaromatic ring is preferable as the organic compound having an electron-transport property. Examples of the organic compound having a π-electron deficient heteroaromatic ring include an organic compound that includes a heteroaromatic ring having an azole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have high electron-transport properties to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

The organic compound having a π-electron deficient heteroaromatic ring is preferably any of the following organic compounds, for example. Examples include organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), and 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm); and organic compounds that include a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn). The organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have high electron-transport properties to contribute to a reduction in driving voltage.

As the TADF material that can be used as the host material, the above materials mentioned as the TADF material that can be used as the emission center substance can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is highly effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Thus, the T₁ level of the TADF material is preferably higher than that of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no 7t bond are poor in carrier transport performance, whereby the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the emission center substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further fused to carbazole because the HOMO level of the host material having a benzocarbazole skeleton is higher than that of the host material having a carbazole skeleton by approximately 0.1 eV and thus holes enter the host material easily. In particular, the host material preferably has a dibenzocarbazole skeleton because the HOMO level of the host material having a dibenzocarbazole skeleton is higher than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, a benzofluorene skeleton or a dibenzofluorene skeleton may be used instead of a carbazole skeleton. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: PN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property is 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength of a lowest-energy-side absorption band of the light-emitting substance, in which case energy can be transferred smoothly and light emission can be obtained efficiently. The use of such a structure is preferable because the driving voltage can also be reduced.

The first electron-transport layer 114_1 is a layer including a substance that has an electron-transport property. The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound that has a π-electron deficient heteroaromatic ring is preferably one or more of an organic compound that includes a heteroaromatic ring having an azole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton, and is particularly preferably an organic compound that includes a heteroaromatic ring having a triazine skeleton.

As the organic compound having an electron-transport property that can be used in the first electron-transport layer 114_1, any of the aforementioned organic compounds that can be used as the organic compound having an electron-transport property that serves as the host material in the first light-emitting layer 113_1 and the second light-emitting layer 113_2 can be used. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have high electron-transport properties to contribute to a reduction in driving voltage.

The second electron-transport layer 114_2 is, as described above, a layer including the eleventh organic compound having a triazine skeleton. The details thereof are described above and not repeated here.

Note that the first electron-transport layer 114_1 preferably includes the organic compound having a triazine skeleton to reduce power consumption. In particular, the first electron-transport layer 114_1 preferably includes an organic compound having a triazine skeleton that is identical to the eleventh organic compound having a triazine skeleton, which is included in the second electron-transport layer 114_2, in order to prevent the complication of a manufacturing apparatus and offer a cost advantage in raw material procurement.

Alternatively, in the case where the first electron-transport layer 114_1 includes an organic compound not having a triazine skeleton, the light-emitting device can have favorable characteristics owing to easy control of carrier transport. The organic compound not having a triazine skeleton is preferably an organic compound that includes a heteroaromatic ring having a pyridine skeleton or an organic compound that includes a heteroaromatic ring having a diazine (pyrimidine or pyrazine) skeleton.

The intermediate layer 116 includes the twelfth organic compound having a phenanthroline skeleton. As illustrated in FIG. 5A, the intermediate layer 116 preferably includes a first layer 119 including the twelfth organic compound having a phenanthroline skeleton. The intermediate layer 116 preferably includes the second layer 117 including the thirteenth organic compound having a hole-transport property and a substance having an acceptor property. The second layer 117 is positioned closer to the second electrode 102 than the first layer 119 is. The intermediate layer 116 may include a third layer 118 between the first layer 119 and the second layer 117.

The details of the first layer are described above and not repeated here.

The first layer 119 may further include an organic compound having an electron-transport property. As the organic compound having an electron-transport property, any of the aforementioned organic compounds that can be used as the organic compound having an electron-transport property that serves as the host material in the first light-emitting layer 113_1 and the second light-emitting layer 113_2 can be used. The organic compound having an electron-transport property is preferably an organic compound having two or more heteroaromatic rings that are bonded or fused to each other and have three or more heteroatoms in total, in which case the resistance to a photolithography method can be improved and an increase in driving voltage can be inhibited.

Note that the first layer 119 may have a stacked-layer structure of a layer including an organic compound and a layer including a metal or a metal compound and positioned closer to the cathode than the layer including an organic compound is, or may be a mixed layer of an organic compound and a metal or a metal compound. The first layer 119 is preferably the mixed layer because it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer 119 is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a different distribution from the organic compound; thus, the analysis results of diffusion and mixing can be distinguished from each other.

The second layer 117 preferably includes the thirteenth organic compound having a hole-transport property. The second layer 117 preferably further includes a substance exhibiting an acceptor property, and the substance exhibiting an acceptor property is preferably an organic compound exhibiting an acceptor property with respect to the thirteenth organic compound.

In the case where the second layer 117 includes the thirteenth organic compound and the substance exhibiting an acceptor property with respect to the thirteenth organic compound, holes are generated by charge separation, and the holes are injected into the second light-emitting unit 502 on the cathode side through the thirteenth organic compound when voltage is applied between the first electrode 101 and the second electrode 102. Thus, the light-emitting device 130 described in this embodiment can have a low driving voltage.

As the thirteenth organic compound having a hole-transport property, any of a variety of organic compounds such as aromatic amine compounds, heteroaromatic compounds, aromatic hydrocarbons, and high molecular compounds (e.g., oligomers, dendrimers, and polymers) can be used. Note that the thirteenth organic compound preferably has a hole mobility of 1×10⁻⁶ cm²/Vs or higher. The thirteenth organic compound preferably has a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group bonds to nitrogen of an amine through an arylene group may be used. Note that the organic compound having a hole-transport property preferably has an N,N-bis(4-biphenyl)amino group to enable fabrication of a light-emitting device having a long lifetime.

The above-described organic compound having a hole-transport property can specifically be any of the organic compounds given as examples of the organic compound having a hole-transport property that can be used in the hole-injection layer 111.

The substance having an acceptor property can be, for example, any of the substances given as examples of the organic compound having an acceptor property that can be used in the hole-injection layer 111. An organic compound having at least one of a halogen group and a cyano group is particularly preferable, and an organic compound having at least one of fluorine and a cyano group is further preferable. Note that it is further preferable that the total number of halogen groups (fluorines) and cyano groups of the organic compound be four or more. Examples of the organic compound having at least one of a halogen group and a cyano group include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

Note that the material having an acceptor property preferably has an electron-accepting property with respect to the thirteenth organic compound having a hole-transport property. When the material having an acceptor property has an electron-accepting property with respect to the thirteenth organic compound, charge separation occurs and the second layer 117 can function as a charge-generation layer and functions as an intermediate layer of the tandem light-emitting device. A signal is preferably observed by electron spin resonance in the second layer 117. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³.

The third layer 118 includes a substance having an electron-transport property and has functions of preventing the interaction between the first layer 119 and the second layer 117 and smoothly transferring and receiving electrons therebetween to reduce the driving voltage, and reducing the interaction between the first layer 119 and the second layer 117 to improve the reliability, for example.

The LUMO level of the substance having an electron-transport property that is included in the third layer 118 is preferably between the LUMO level of the substance having an acceptor property in the second layer 117 and the LUMO level of the organic compound included in a layer in contact with the first layer 119 in the light-emitting unit on the anode side (e.g., the first electron-transport layer 114_1 in the first light-emitting unit 501 in FIG. 5A).

A specific energy level of the LUMO level of the substance having an electron-transport property that is used in the third layer 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet further preferably higher than or equal to −4.30 eV and lower than or equal to −3.30 eV, in which case an increase in driving voltage can be inhibited. Note that the substance having an electron-transport property that is used in the third layer 118 is preferably a phthalocyanine-based material or a metal complex having a metal-oxygen bond and an aromatic ligand.

Specific examples of the substance having an electron-transport property that is used in the third layer 118 include perylenetetracarboxylic acid derivatives such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), and 3,4,9,10-perylenetetracarboxyl-bis-benzimidazole (abbreviation: PTCBI), (C₆₀—Iₕ)[5,6]fullerene (abbreviation: C₆₀), and (C₇₀-D₅ₕ)[5,6]fullerene (abbreviation: C₇₀). It is also possible to use a compound including a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The thickness of the third layer 118 is preferably greater than or equal to 1 nm and less than or equal to 10 nm, further preferably greater than or equal to 2 nm and less than or equal to 5 nm.

Note that the second light-emitting unit 502 includes no hole-injection layer because the second layer 117 in the intermediate layer 116 functions as a hole-injection layer; however, the second light-emitting unit 502 may include a hole-injection layer.

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Group 1 and Group 2 of the periodic table, such as alkali metals (e.g., lithium (Li) and cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. Specific examples thereof include alkali metals, alkaline earth metals, rare earth metals, compounds thereof, and complexes thereof, such as lithium fluoride (LiF), cesium fluoride (CsF), calcium fluoride (CaF₂), 8-hydroxyquinolinato-lithium (abbreviation: Liq), and Yb, and electrides. Examples of the electride include a substance in which electrons are added at high concentration to calcium oxide-aluminum oxide. Note that a mixture of two or more of these materials may be used as a cathode material. In the case where the second electrode 102 has a stacked-layer structure, a material having high conductivity can be used for the layer(s) other than the cathode, regardless of the work function.

Note that the second electron-transport layer 114_2 is preferably in contact with the second electrode 102. When the second electron-transport layer 114_2 is in contact with the second electrode 102, the light-emitting device can have excellent electron-injection and electron-transport properties, a low driving voltage, and low power consumption.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like can be used.

Different film formation methods may be used to form the electrodes or the layers described above.

FIG. 5C illustrates two adjacent light-emitting devices (a light-emitting device 130a and a light-emitting device 130b) included in the display apparatus of one embodiment of the present invention. Structure example 1 is preferably used in at least one of the light-emitting device 130a and the light-emitting device 130b.

The light-emitting device 130a includes an organic compound layer 103a between a first electrode 101a and the second electrode 102 over an insulating layer 175. The organic compound layer 103a has a structure in which a first light-emitting unit 501a and a second light-emitting unit 502a are stacked with an intermediate layer 116a therebetween. Although FIG. 5C illustrates an example in which the two light-emitting units are stacked, three or more light-emitting units may be stacked. The first light-emitting unit 501a includes a hole-injection layer 111a, a first hole-transport layer 112a_1, a first light-emitting layer 113a_1, and a first electron-transport layer 114a_1. The intermediate layer 116a includes a second layer 117a, a third layer 118a, and a first layer 119a. The third layer 118a may be present or absent. The second light-emitting unit 502a includes a second hole-transport layer 112a_2, a second light-emitting layer 113a_2, and a second electron-transport layer 114a_2.

The light-emitting device 130b includes an organic compound layer 103b between a first electrode 101b and the second electrode 102 over the insulating layer 175. The organic compound layer 103b has a structure in which a first light-emitting unit 501b and a second light-emitting unit 502b are stacked with an intermediate layer 116b therebetween. Although FIG. 5C illustrates an example in which the two light-emitting units are stacked, three or more light-emitting units may be stacked. The first light-emitting unit 501b includes a hole-injection layer 111b, a first hole-transport layer 112b_1, a first light-emitting layer 113b_1, and a first electron-transport layer 114b_1. The intermediate layer 116b includes a second layer 117b, a third layer 118b, and a first layer 119b. The third layer 118b may be present or absent. The second light-emitting unit 502b includes a second hole-transport layer 112b_2, a second light-emitting layer 113b_2, and a second electron-transport layer 114b_2.

The second electron-transport layer 114a_2b and the second electron-transport layer 114b_2b preferably include the eleventh organic compound having a triazine skeleton. The first layer 119a and the first layer 119b each include the twelfth organic compound having a phenanthroline skeleton.

The first light-emitting layer 113a_1 and the second light-emitting layer 113a_2 preferably emit light of similar colors. The emission center substance included in the first light-emitting layer 113a_1 and the emission center substance included in the second light-emitting layer 113c_2 are preferably compounds whose emission spectra have a difference in maximum peak wavelength of less than or equal to 30 nm, further preferably less than or equal to 20 nm, still further preferably less than or equal to 10 nm. It is further preferable that the first light-emitting layer 113a_1 and the second light-emitting layer 113c_2 include the same emission center substance. Furthermore, the materials used for the first light-emitting layer 113a_1 and the second light-emitting layer 113a_2 are preferably identical to each other. One of, preferably both of, the first light-emitting layer 113a_1 and the second light-emitting layer 113a_2 preferably has the above-described structure of the light-emitting layer of one embodiment of the present invention.

The first light-emitting layer 113b_1 and the second light-emitting layer 113b_2 preferably emit light of similar colors. The emission center substance included in the first light-emitting layer 113a_1 and the emission center substance included in the second light-emitting layer 113a_2 are preferably compounds whose emission spectra have a difference in maximum peak wavelength of less than or equal to 30 nm, further preferably less than or equal to 20 nm, still further preferably less than or equal to 10 nm. It is further preferable that the first light-emitting layer 113a_1 and the second light-emitting layer 113a_2 include the same emission center substance. Furthermore, the materials used for the first light-emitting layer 113b_1 and the second light-emitting layer 113b_2 are preferably identical to each other. One of, preferably both of, the first light-emitting layer 113b_1 and the second light-emitting layer 113b_2 preferably has the above-described structure of the light-emitting layer of one embodiment of the present invention.

It is preferable that the first light-emitting layer 113a_1 and the first light-emitting layer 113b_1 be separated from each other and the second light-emitting layer 113a_2 and the second light-emitting layer 113b_2 be separated from each other. It is preferable that the emission color(s) of the first light-emitting layer 113a_1 and the second light-emitting layer 113a_2 be different from the emission color(s) of the first light-emitting layer 113b_1 and the second light-emitting layer 113b_2. It is preferable that the emission center substance included in the first light-emitting layer 113a_1 and the emission center substance included in the first light-emitting layer 113b_1 be different substances from each other and the emission center substance included in the second light-emitting layer 113a_2 and the emission center substance included in the second light-emitting layer 113b_2 be different substances from each other.

Note that each of the pairs of the hole-injection layers 111a and 111b, the first hole-transport layers 112a_1 and 112b_1, the first electron-transport layers 114a_1 and 114b_1, the intermediate layers 116a and 116b (the second layers 117a and 117b, the third layers 118a and 118b, and the first layers 119a and 119b), the second hole-transport layers 112a_2 and 112b_2, and the second electron-transport layers 114a_2 and 114b_2 may be one continuous layer or may be separate layers independent of each other between the light-emitting device 130a and the light-emitting device 130b. When these layers are continuous layers, the light-emitting devices can be fabricated with high productivity at low cost. When the layers are separate layers between the light-emitting devices, the layers can be formed using materials suitable for their emission colors, thereby enabling the light-emitting devices or a display apparatus to have favorable characteristics. In particular, the second electron-transport layer 114a_2 and the second electron-transport layer 114b_2 are preferably one continuous layer, in which case both the light-emitting device 130a and the light-emitting device 130b can have favorable characteristics.

The second electron-transport layer 114a_2 and the second electron-transport layer 114b_2 being one continuous layer means that the second electron-transport layer 114a_2 and the second electron-transport layer 114b_2 are made of the same material. That is, when the second electron-transport layer 114a_2 and the second electron-transport layer 114b_2 are made of the same material, both the light-emitting device 130a and the light-emitting device 130b can have favorable characteristics. The second electron-transport layer 114a_2 and the second electron-transport layer 114b_2 further preferably have similar structures, and still further preferably have the same structure.

In the case where the emission center substances included in the first light-emitting layers 113a_1 and 113_1 are different substances from each other and the emission center substances included in the second light-emitting layers 113a_2 and 113b_2 are different substances from each other (e.g., in the case where the first light-emitting layer 113a_1 and the second light-emitting layer 113a_2 are blue fluorescent layers and the first light-emitting layer 113b_1 and the second light-emitting layer 113b_2 are green phosphorescent layers, in the case where the first light-emitting layers 113a_1 and 113a_2 are blue fluorescent layers and the first light-emitting layers 113b_1 and 113b_2 are red phosphorescent layers, or in the case where the first light-emitting layers 113a_1 and 113a_2 are green phosphorescent layers and the first light-emitting layers 113b_1 and 113b_2 are red phosphorescent layers), the light-emitting layers of the light-emitting devices 130a and 130b have different carrier balances. Therefore, in order to improve the performance of each of the light-emitting devices 130a and 130b, it is usually necessary to select and use an appropriate intermediate layer and an appropriate electron-transport layer for each light-emitting device. However, even when the second electron-transport layers 114a_2 and 114b_2 have the same structure, the use of the eleventh organic compound having a triazine skeleton in the second electron-transport layers 114a_2 and 114b_2 and the use of the twelfth organic compound having a phenanthroline skeleton in the first layers 119a and 119b can improve the performance of each of the light-emitting devices 130a and 130b. That is, both the productivity and the performance can be improved. Note that the first layers 119a and 119b may have the same structure.

Note that one continuous layer is a common layer formed across the light-emitting devices 130a and 130b.

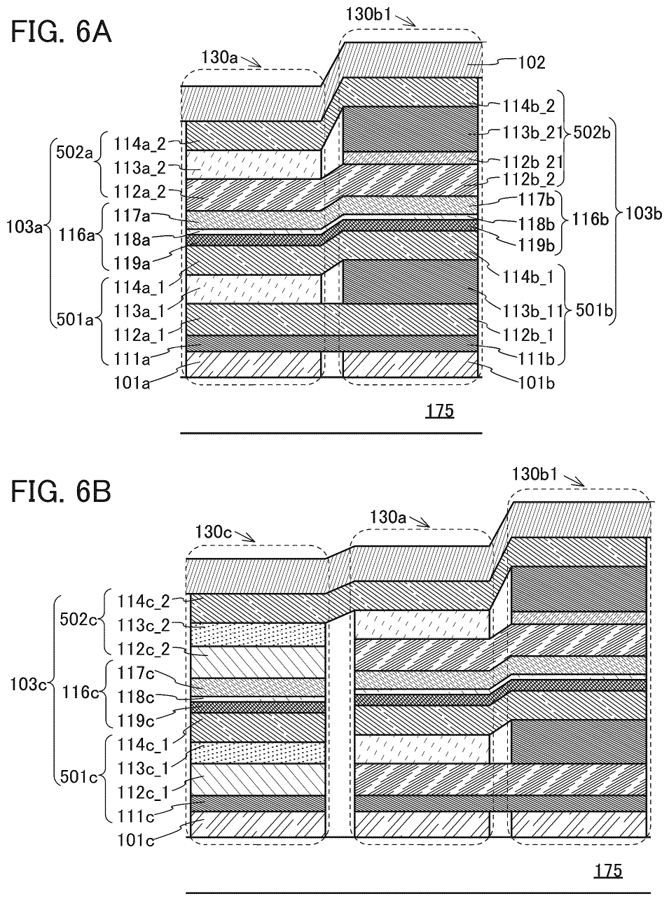

FIG. 6A is a variation example of FIG. 5C. The light-emitting device 130a and a light-emitting device 130b1 emit light of different colors and thus have different optical path lengths between the electrodes where light emitted from the light-emitting devices can be amplified using microcavity. In the light-emitting device 130bl, the distance between the electrodes can be adjusted by thickening light-emitting layers such as a light-emitting layer 113b_1 and a light-emitting layer 113b_21. Alternatively, the optical path length may be changed by thickening or adding a functional layer such as a hole-transport layer 112b_21.

FIG. 6B illustrates three adjacent light-emitting devices (the light-emitting device 130a, the light-emitting device 130b1, and a light-emitting device 130c) included in the display apparatus of one embodiment of the present invention.

The light-emitting device 130c includes an organic compound layer 103c between a first electrode 101c and the second electrode 102 over the insulating layer 175. The organic compound layer 103c has a structure in which a first light-emitting unit 501c and a second light-emitting unit 502c are stacked with an intermediate layer 116c therebetween. Although FIG. 6B illustrates an example in which the two light-emitting units are stacked, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 116c includes a second layer 117c, a third layer 118c, and a first layer 119c. The third layer 118c may be present or absent. The second light-emitting unit 502c includes a second hole-transport layer 112c_2, a second light-emitting layer 113c_2, and a second electron-transport layer 114c_2.

It is assumed here that the light-emitting device 130c emits light whose wavelength is shorter than those of light from the light-emitting devices 130a and 130bl. The distance between the electrodes in the light-emitting device 130c is adjusted by the thicknesses of the light-emitting layers 113c_1 and 113c_2, which are smaller than those of the light-emitting layers in the other two light-emitting devices.

The second electron-transport layer 114c_2 includes the eleventh organic compound having a triazine skeleton. The first layer 119c includes the twelfth organic compound having a phenanthroline skeleton.

The first light-emitting layer 113c_1 and the second light-emitting layer 113c_2 preferably emit light of similar colors. The emission center substance included in the first light-emitting layer 113a_1 and the emission center substance included in the second light-emitting layer 113a_2 are preferably compounds whose emission spectra have a difference in maximum peak wavelength of less than or equal to 30 nm, further preferably less than or equal to 20 nm, still further preferably less than or equal to 10 nm. It is further preferable that the first light-emitting layer 113a_1 and the second light-emitting layer 113a_2 include the same emission center substance. Furthermore, the materials used for the first light-emitting layer 113c_1 and the second light-emitting layer 113c_2 are preferably identical to each other. One of, preferably both of, the first light-emitting layer 113c_1 and the second light-emitting layer 113c_2 preferably has the above-described structure of the light-emitting layer of one embodiment of the present invention.

It is preferable that the first light-emitting layer 113a_1 and the first light-emitting layer 113c_1 be separated from each other and the second light-emitting layer 113a_2 and the second light-emitting layer 113c_2 be separated from each other. It is preferable that the emission color(s) of the first light-emitting layer 113a_1 and the second light-emitting layer 113a_2 be different from the emission color(s) of the first light-emitting layer 113c_1 and the second light-emitting layer 113c_2. It is preferable that the emission center substance included in the first light-emitting layer 113a_1 and the emission center substance included in the first light-emitting layer 113c_1 be different substances from each other and the emission center substance included in the second light-emitting layer 113a_2 and the emission center substance included in the second light-emitting layer 113c_2 be different substances from each other.

Note that each of the pairs of the hole-injection layers 111a and 111c, the first hole-transport layers 112a_1 and 112c_1, the first electron-transport layers 114a_1 and 114c_1, the intermediate layers 116a and 116c (the second layers 117a and 117c, the third layers 118a and 118c, and the first layers 119a and 119c), and the second hole-transport layers 112a_2 and 112c_2 in this example are separate layers independent of each other between the light-emitting device 130a and the light-emitting device 130c, and the second electron-transport layers 114a_2 and 114c_2 in this example are a continuous layer. In this manner, one light-emitting device may include both a continuous layer and a separate layer. This allows the light-emitting device or the display apparatus to balance productivity and performance. In particular, the second electron-transport layer 114a_2 and the second electron-transport layer 114c_2 are preferably one continuous layer, in which case both the light-emitting device 130a and the light-emitting device 130c can have favorable characteristics.

In the case where light-emitting devices exhibiting three colors consist of, for example, two light-emitting devices including fluorescent emission center substances and one light-emitting device including a phosphorescent emission center substance, the light-emitting devices including the fluorescent emission center substances preferably have one continuous carrier-transport layer, and the light-emitting device including the phosphorescent emission center substance preferably has a carrier-transport layer separated from that in the light-emitting devices exhibiting the other emission colors. Alternatively, in the case where light-emitting devices exhibiting three colors consist of two light-emitting devices including phosphorescent emission center substances and one light-emitting device including a fluorescent emission center substance, the light-emitting devices including the phosphorescent emission center substances preferably have one continuous carrier-transport layer, and the light-emitting device including the fluorescent emission center substance preferably has a carrier-transport layer separated from that in the light-emitting devices exhibiting the other emission colors.

The light-emitting device that is described in this embodiment and has such a structure can have high current efficiency, low energy loss, and favorable characteristics. A display apparatus of one embodiment of the present invention that includes such a light-emitting device can achieve low power consumption, high reliability, high-luminance display, and high visibility. This embodiment can be freely combined with any of the other embodiments and the examples.

### Embodiment 2

In this embodiment, Structure example 2 of a light-emitting device that can be used in the display apparatus of one embodiment of the present invention will be described.

### Structure Example 2

The light-emitting device employing Structure example 2 differs from the light-emitting device employing Structure example 1 described in Embodiment 1 in that two kinds of substances functioning as host materials (the first host material and the second host material) do not include deuterium, and the other components in Structure example 2 are the same as those in Structure example 1. As described above, Structure example 1 achieves higher reliability with the use of an organic compound(s) including deuterium as one or both of the first host material and the second host material. Therefore, in the case where Structure example 2 is used in the display apparatus of one embodiment of the present invention, Structure example 1 is preferably used in combination. For example, it is preferable that Structure example 1 be used in any one of the subpixels 110R, 110G, and 110B illustrated in FIG. 2B and Structure example 2 be used in another one or two thereof. In the display apparatus of one embodiment of the present invention, the area of the subpixel using Structure example 2 can be larger than the area of the subpixel using Structure example 1 with higher reliability; thus, the reliability of the pixel using Structure example 2 can be further increased and the reliability of the whole pixel can be increased.

For example, in a tandem light-emitting device including two light-emitting layers of a third light-emitting layer and a fourth light-emitting layer, the third light-emitting layer preferably includes a third emission center substance, a fifth organic compound, and a sixth organic compound and the fourth light-emitting layer preferably includes a seventh organic compound and an eighth organic compound. Preferably, the fifth organic compound and the seventh organic compound each correspond to the first host material, the sixth organic compound and the eighth organic compound each correspond to the second host material, and the third light-emitting layer and the fourth light-emitting layer each have the above-described structure of the light-emitting layer.

Specifically, the fifth organic compound and the seventh organic compound have an electron-transport property, and preferably include a π-electron deficient heteroaromatic ring. The sixth organic compound and the eighth organic compound have a hole-transport property, and preferably include a π-electron rich heteroaromatic ring or an aromatic amine skeleton. A combination of the fifth and sixth organic compounds and a combination of the seventh and eighth organic compounds each preferably form an exciplex. The difference in the T₁ level between the fifth and sixth organic compounds and between the seventh and eighth organic compounds is preferably less than or equal to 0.20 eV, further preferably less than or equal to 0.15 eV, still further preferably less than or equal to 0.10 eV. The other structures described above can also be used for each light-emitting layer by replacing the fifth host material with “fifth organic compound” or “seventh organic compound” and replacing the sixth host material with “sixth organic compound” or “eighth organic compound”.

Note that in this specification and the like, the terms “fifth organic compound”, “sixth organic compound”, “seventh organic compound”, “eighth organic compound”, and the like can also be used to describe Structure example 1.

The examples of the organic compound having an electron-transport property and the organic compound having a hole-transport property described in Structure example 1 can be referred to for the organic compounds that can be used as the first host material and the second host material in Structure example 2.

The light-emitting device that is described in this embodiment and has such a structure can have high current efficiency, low energy loss, and favorable characteristics. A display apparatus of one embodiment of the present invention that includes such a light-emitting device can achieve low power consumption, high reliability, high-luminance display, and high visibility. This embodiment can be freely combined with any of the other embodiments and the examples.

### Embodiment 3

In this embodiment, Structure example 3 of a light-emitting device that can be used in the display apparatus of one embodiment of the present invention will be described.

### Structure Example 3

The light-emitting device employing Structure example 3 differs from the light-emitting devices employing Structure example 1 and Structure example 2 in that the light-emitting layer includes a light-emitting substance and one kind of substance functioning as a host material; in other words, Structure example 3 is the same as Structure example 1 and Structure example 2 except for the structure of the light-emitting layer. As described above, two kinds of substances functioning as host materials (the first host material and the second host material) are used to increase the emission efficiency in Structure example 1 and Structure example 2. Therefore, in the case where Structure example 3 is used in the display apparatus of one embodiment of the present invention, Structure example 1 is preferably used in combination. For example, it is preferable that Structure example 1 be used in any one of the subpixels 110R, 110G, and 110B illustrated in FIG. 2B, Structure example 2 be used in another, and Structure example 3 be used in the other. In the display apparatus of one embodiment of the present invention, the area of the subpixel using Structure example 3 can be larger than the area of the subpixels using Structure example 1 and Structure example 2 with higher reliability; thus, the luminance of the pixel using Structure example 3 can be increased and the reliability of the whole pixel can be increased.

For example, in a tandem light-emitting device including two light-emitting layers of a fifth light-emitting layer and a sixth light-emitting layer, the fifth light-emitting layer includes a fifth emission center substance and a ninth organic compound, and the sixth light-emitting layer includes a tenth organic compound. The ninth organic compound and the tenth organic compound each correspond to the host material.

In Structure example 3, the emission center substance is preferably a fluorescent substance. In the case where the emission center substance is a fluorescent substance, the emission efficiency is less likely to decrease even when only one kind of host material is used, as compared with the case where the emission center substance is a phosphorescent material. The examples of the organic compound in Structure example 1 can be referred to for the fluorescent substance that can be used as the emission center substance and the host material in Structure example 3.

This embodiment can be freely combined with any of the other embodiments and the examples.

### Embodiment 4

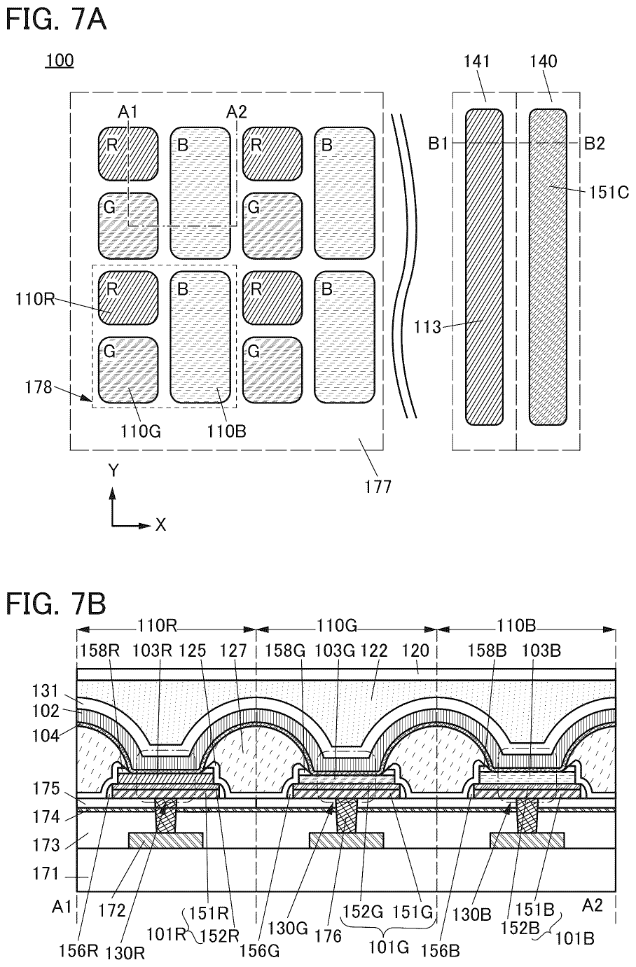

As illustrated in FIGS. 7A and 7B, a plurality of the light-emitting devices 130 are formed over the insulating layer 175 to constitute a display apparatus. In this embodiment, a display apparatus of another embodiment of the present invention will be described in detail.

A display apparatus 100 includes a pixel portion 177 in which a plurality of the pixels 178 are arranged in a matrix. The pixel 178 includes the subpixel 110R, the subpixel 110G, and the subpixel 110B.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more.

In this specification and the like, the row direction and the column direction are sometimes referred to as the X direction and the Y direction, respectively. The X direction and the Y direction intersect with each other and are perpendicular to each other, for example.

FIG. 7A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. In the case where the region 141 is provided, the region 141 is provided between the pixel portion 177 and the connection portion 140. In the case where the region 141 is provided, an organic compound layer is provided in the region 141. A conductive layer 151C is provided in the connection portion 140.

Although FIG. 7A illustrates an example where the region 141 and the connection portion 140 are positioned on the right side of the pixel portion 177, there is no particular limitation on the positions of the region 141 and the connection portion 140. The number of regions 141 and the number of connection portions 140 can each be one or two or more.

FIG. 7B is an example of a cross-sectional view along the dashed-dotted line A1-A2 in FIG. 7A. As illustrated in FIG. 7B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 bonds to the protective layer 131 with a resin layer 122. An inorganic insulating layer 125 and an insulating layer 127 over the inorganic insulating layer 125 are preferably provided between adjacent light-emitting devices 130.

Although FIG. 7B illustrates cross sections of a plurality of the inorganic insulating layers 125 and a plurality of the insulating layers 127, the inorganic insulating layers 125 are preferably connected to each other and the insulating layers 127 are preferably connected to each other when the display apparatus 100 is seen from above.

In FIG. 7B, a light-emitting device 130R, a light-emitting device 130G, and a light-emitting device 130B are illustrated as the light-emitting devices 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission light-emitting apparatus where light is emitted in the direction opposite to a substrate over which light-emitting devices are formed. Note that the display apparatus of one embodiment of the present invention may be of a bottom-emission type.

The light-emitting device 130R includes a first electrode (pixel electrode) 101R including a conductive layer 151R and a conductive layer 152R, an organic compound layer 103R over the first electrode, a common layer 104 over the organic compound layer 103R, and the second electrode (common electrode) 102 over the common layer. Although the common layer 104 is not necessarily provided, it is preferable to provide the common layer 104 to reduce damage to the organic compound layer 103R during processing.

The light-emitting device 130G includes a first electrode (pixel electrode) 101G including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing.

The light-emitting device 130B has a structure as described in Embodiment 2. The light-emitting device 130B includes a first electrode (pixel electrode) 101B including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, a stack of the organic compound layer 103B and the common layer 104 corresponds to the organic compound layer 103 in Embodiment 2; in the case where the common layer 104 is not provided, the organic compound layer 103B corresponds to the organic compound layer 103 in Embodiment 2.

Note that the common layer 104 is preferably an electron-transport layer. In the case where the common layer 104 is an electron-transport layer, it is preferable that the electron-transport layer have a stacked-layer structure, and it is further preferable that, among the stacked layers, a layer on the second electrode side be the common layer 104 and a layer on the light-emitting layer side be the organic compound layer 103.

The light-emitting devices 130R and 130G are also manufactured through a photolithography process.

In the light-emitting device 130, one of the pixel electrode and the common electrode functions as an anode and the other functions as a cathode. The description is hereinafter made on the assumption that the pixel electrode functions as the anode and the common electrode functions as the cathode unless otherwise specified.

The organic compound layers 103R, 103G, and 103B are island-shaped layers that are independent of each other on a light-emitting device basis. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an organic compound film and processing the organic compound film by a photolithography method.

The organic compound layer 103 is preferably provided to cover the top surface and the side surface of the first electrode (pixel electrode) of the light-emitting device 130. In this case, the aperture ratio of the display apparatus 100 can be easily increased as compared with the structure where an end portion of the organic compound layer 103 is positioned inward from an end portion of the pixel electrode. Covering the side surface of the pixel electrode of the light-emitting device 130 with the organic compound layer 103 can inhibit the pixel electrode from being in contact with the second electrode 102; hence, a short circuit of the light-emitting device 130 can be inhibited.

In the display apparatus of one embodiment of the present invention, the first electrode (pixel electrode) of the light-emitting device preferably has a stacked-layer structure. For example, in the example illustrated in FIG. 7B, the first electrode of the light-emitting device 130 is a stack of a conductive layer 151 and a conductive layer 152.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layers 151 and 152 may each have a stacked-layer structure of a plurality of layers that include different materials. In this case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. For example, in the case where the conductive layer 151 has a stacked-layer structure of two or more layers, a layer in contact with the conductive layer 152 can be formed using a material that can be used for the conductive layer 152.

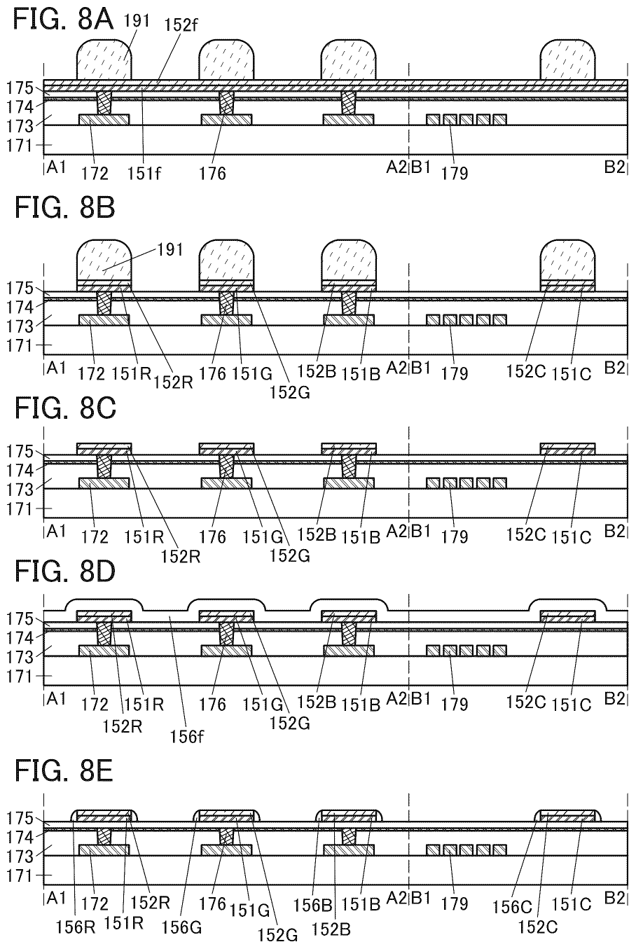

Next, an example of a method for manufacturing the display apparatus 100 having the structure illustrated in FIG. 7A is described with reference to FIGS. 8A to 8E, FIGS. 9A and 9B, FIGS. 10A to 10D, FIGS. 11A to 11C, FIGS. 12A to 12C, and FIGS. 13A to 13C.

### Manufacturing Method Example 1

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display apparatus (e.g., insulating films, semiconductor films, and conductive films) can also be formed by a wet film-formation method such as spin coating, dipping, spray coating, ink-jetting, dispensing, screen printing, offset printing, doctor blade coating, slit coating, roll coating, curtain coating, or knife coating.

Thin films included in the display apparatus can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblasting method, or the like can be used.

In the manufacturing process of the light-emitting device, an organic compound that is excited by absorbing light is used. The excited organic compound is highly likely to react with oxygen or water in the air in some cases. In other words, when the organic compound is irradiated with light having a wavelength that is absorbed by the organic compound in the presence of oxygen, a degradation product might be generated in the organic compound.

In view of the above, in the case where a substrate over which the organic compound is formed is exposed to the air during processing by a photolithography method, the processing is preferably performed in an environment where lighting is appropriately controlled. The processing is ideally performed under lighting with a wavelength which does not excite the organic compound that would be excited by absorbing light; to ensure illuminance or color rendering properties high enough not to lower the work efficiency, it is preferable to use lighting using a light source whose shortest-wavelength emission edge among emission edges in the emission spectrum is less than or equal to 600 nm, preferably less than or equal to 580 nm.

For example, it is preferable to use yellow light (light of a fluorescent lamp or a light-emitting diode (LED)), which does not include light with a wavelength shorter than 500 nm, for the lighting. It is also preferable to use orange light (light of a fluorescent lamp or a light-emitting diode (LED)), which does not include light with a wavelength shorter than 530 nm. A low-pressure sodium lamp can also be used. An incandescent lamp, a fluorescent lamp, a light-emitting diode (LED), a halogen lamp, or sunlight can be used, for example, in combination with an optical filter that can block light with a short wavelength. As the optical filter that can block light with a short wavelength, a band-pass filter or a long-pass filter (short-wavelength cut filter) can be used, for example. The above lighting can result in low illuminance.

First, as illustrated in FIG. 8A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 8A, openings reaching the conductive layer 172 are formed in the insulating layers 175, 174, and 173. Then, the plugs 176 are formed to fill the openings.

Subsequently, as illustrated in FIG. 8A, a conductive film 151f to be the conductive layers 151R, 151G, 151B, and 151C and a conductive film 152f to be the conductive layers 152R, 152G, and 152B and a conductive layer 152C are formed over the plugs 176 and the insulating layer 175. For the conductive film 151f, a metal material can be used, for example. For the conductive film 152f, an oxide containing one or more selected from indium, tin, zinc, gallium, titanium, aluminum, and silicon can be used.

Then, as illustrated in FIG. 8A, a resist mask 191 is formed over the conductive film 152f. The resist mask 191 can be formed by application of a photosensitive material (photoresist), light exposure, and development.

Subsequently, as illustrated in FIG. 8B, the conductive films 151f and 152f in a region not overlapping with the resist mask 191 are removed, for example. In this manner, the conductive layers 151 and 152 are formed.

Next, the resist mask 191 is removed as illustrated in FIG. 8C. The resist mask 191 can be removed by ashing using oxygen plasma, for example.

Then, as illustrated in FIG. 8D, an insulating film 156f to be an insulating layer 156R, an insulating layer 156G, an insulating layer 156B, and an insulating layer 156C is formed over the conductive layers 152R, 152G, 152B, and 152C and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 8E, the insulating film 156f is processed, thereby forming the insulating layers 156R, 156G, 156B, and 156C.

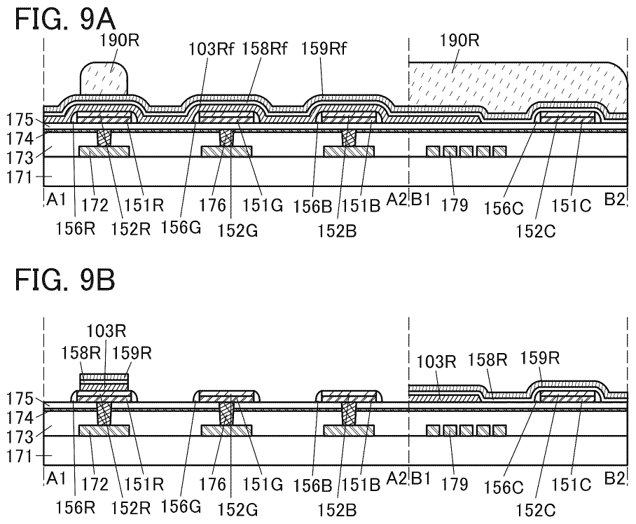

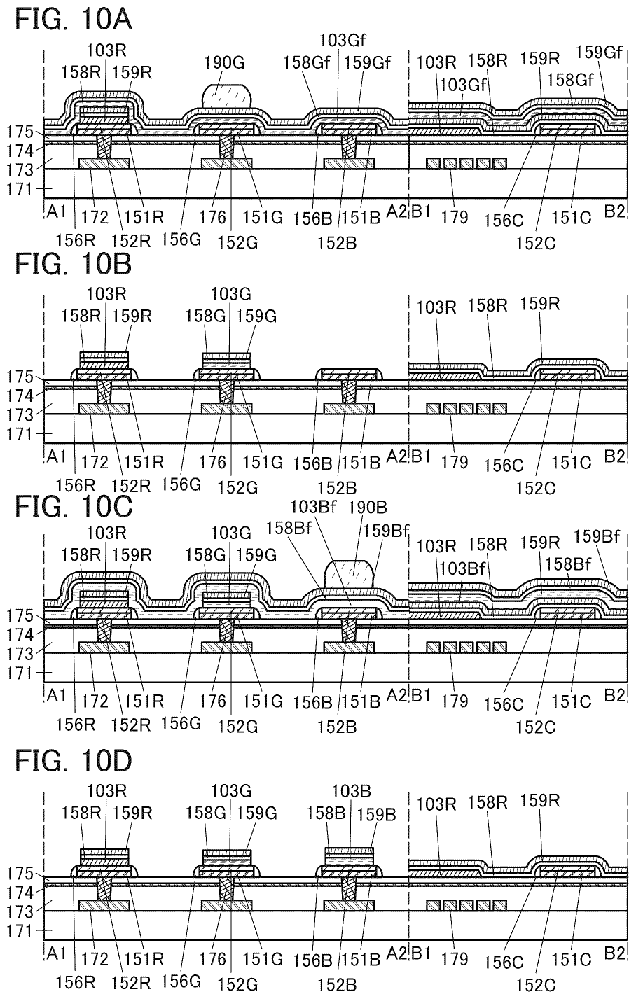

Next, as illustrated in FIG. 9A, an organic compound film 103Rf is formed over the conductive layers 152R, 152G, and 152B and the insulating layer 175. As illustrated in FIG. 9A, the organic compound film 103Rf is not formed over the conductive layer 152C.

Then, as illustrated in FIG. 9A, a sacrificial film 158Rf and a mask film 159Rf are formed.

Providing the sacrificial film 158Rf over the organic compound film 103Rf can reduce damage to the organic compound film 103Rf in the manufacturing process of the display apparatus, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. The light-emitting device used in the display apparatus of one embodiment of the present invention includes the first compound, and thus enables the display apparatus to have high display quality even when manufactured through a heating process at higher temperature.

The sacrificial film 158Rf and the mask film 159Rf are preferably films that can be removed by a wet etching method or a dry etching method.

The sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in light exposure for patterning and deterioration of the organic compound film 103Rf can be inhibited.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound including the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 9A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the manufacturing process of the display apparatus.

Next, as illustrated in FIG. 9B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that a sacrificial layer 158R is formed.

The use of a wet etching method can reduce damage to the organic compound film 103Rf in processing of the sacrificial film 158Rf and the mask film 159Rf, as compared with the case of using a dry etching method. In the case of using a wet etching method, it is preferable to use an alkaline aqueous solution such as a developer or a tetramethylammonium hydroxide (TMAH) aqueous solution or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 9B, the organic compound film 103Rf is processed, so that the organic compound layer 103R is formed. For example, part of the organic compound film 103Rf is removed using the mask layer 159R and the sacrificial layer 158R as a hard mask, thereby forming the organic compound layer 103R.

Accordingly, as illustrated in FIG. 9B, the stacked-layer structure of the organic compound layer 103R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and Group 18 elements such as He and Ar as the etching gas, for example. Alternatively, a gas containing oxygen and at least one of the above is preferably used as the etching gas. Alternatively, an oxygen gas may be used as the etching gas.

Then, as illustrated in FIG. 10A, an organic compound film 103Gf to be the organic compound layer 103G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 10A, a sacrificial film 158Gf and a mask film 159Gf are formed in this order. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Next, as illustrated in FIG. 10B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that a sacrificial layer 158G is formed. Next, the organic compound film 103Gf is processed, so that the organic compound layer 103G is formed.

Then, an organic compound film 103Bf is formed as illustrated in FIG. 10C.

The organic compound film 103Bf can be formed by a method similar to that for forming the organic compound film 103Rf. The organic compound film 103Bf can have a structure similar to that of the organic compound film 103Rf.

Subsequently, as illustrated in FIG. 10C, a sacrificial film 158Bf and a mask film 159Bf are formed in this order. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 10D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that a sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask, thereby forming the organic compound layer 103B.

Accordingly, as illustrated in FIG. 10D, the stacked-layer structure of the organic compound layer 103B, the sacrificial layer 158B, and the mask layer 159B remains over the conductive layer 152B. The mask layers 159R and 159G are exposed.

The side surfaces of the organic compound layers 103R, 103G, and 103B are preferably perpendicular or substantially perpendicular to their formation surfaces. For example, the angles between the formation surfaces and these side surfaces are each preferably greater than or equal to 60° and less than or equal to 90°.

The distance between two adjacent layers among the organic compound layers 103R, 103G, and 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be defined, for example, as the distance between opposite end portions of two adjacent layers among the organic compound layers 103R, 103G, and 103B. Shortening the distance between the island-shaped organic compound layers can provide a display apparatus having high resolution and a high aperture ratio. In addition, the distance between the first electrodes of adjacent light-emitting devices can also be reduced to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

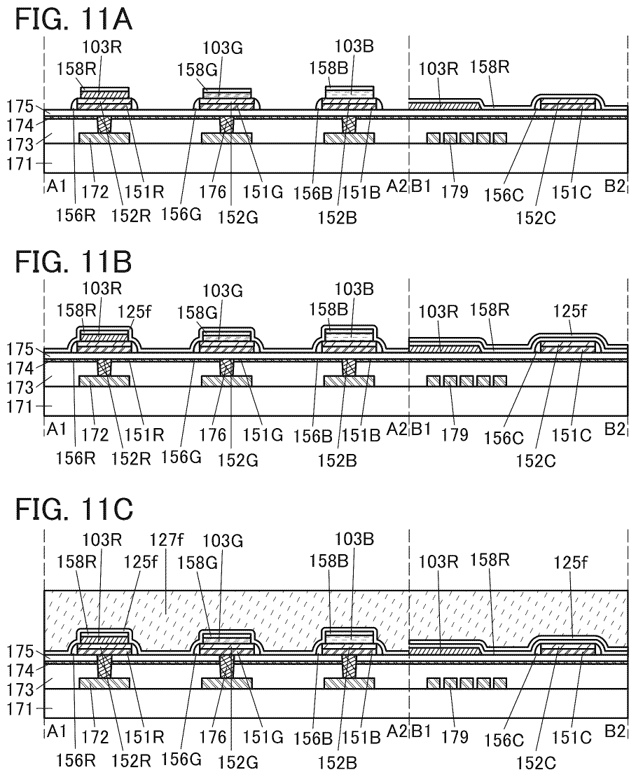

Next, as illustrated in FIG. 11A, the mask layers 159R, 159G, and 159B are preferably removed.

The step of removing the mask layers can be performed by a method similar to that for the step of processing the mask films. Specifically, by using a wet etching method, damage to the organic compound layer 103 at the time of removing the mask layers can be reduced as compared with the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 11B.

Then, as illustrated in FIG. 11C, an insulating film 127f to be the insulating layer 127 is formed over the inorganic insulating film 125f.

The substrate temperatures at the time of forming the inorganic insulating film 125f and the insulating film 127f are each preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

The insulating film 127f is preferably formed by the aforementioned wet film-formation method. For example, the insulating film 127f is preferably formed by spin coating using a photosensitive material, and specifically, preferably formed using a photosensitive resin composition containing an acrylic resin.

Then, part of the insulating film 127f is exposed to visible light or ultraviolet rays. The insulating layer 127 is formed in regions that are sandwiched between any two of the conductive layers 152R, 152G, and 152B and around the conductive layer 152C.

The width of the insulating layer 127 that is to be formed later can be controlled with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

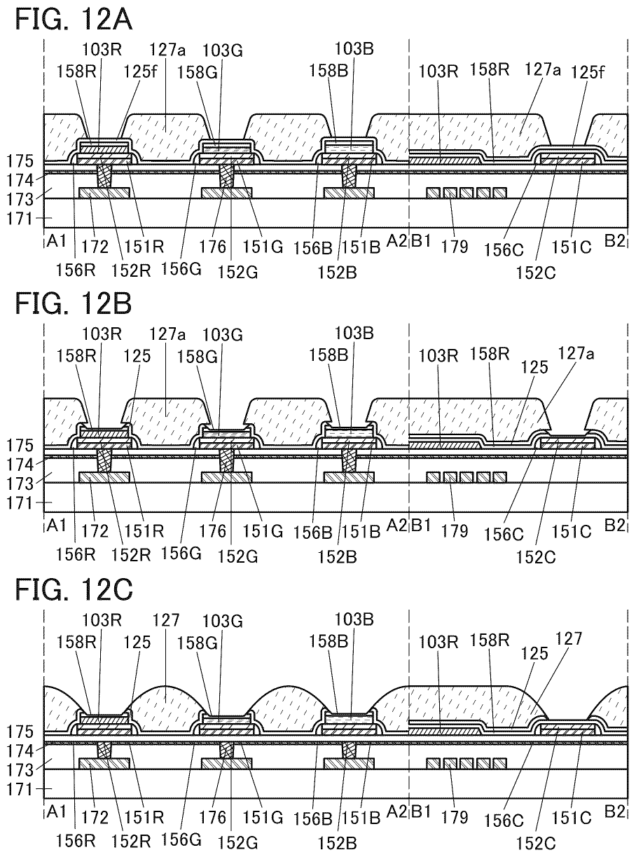

Next, as illustrated in FIG. 12A, development is performed to remove the exposed region of the insulating film 127f, so that an insulating layer 127a is formed.

Subsequently, as illustrated in FIG. 12B, etching treatment is performed using the insulating layer 127a as a mask, thereby removing part of the inorganic insulating film 125f and reducing the thicknesses of parts of the sacrificial layers 158R, 158G, and 158B. Thus, the inorganic insulating layer 125 is formed under the insulating layer 127a. Moreover, the surfaces of the thin portions of the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layers 103R, 103G, and 103B, as compared with the case of using a dry etching method. For example, the wet etching can be performed using an alkaline solution. For instance, TMAH, which is an alkaline solution, can be used for the wet etching of an aluminum oxide film. Alternatively, an acid solution including fluoride can also be used. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) is provided as each of the sacrificial layers 158R, 158G, and 158B, diffusion of oxygen into the organic compound layers 103R, 103G, and 103B can be inhibited.

Then, heat treatment (also referred to as post-baking) is performed. The heat treatment can change the insulating layer 127a into the insulating layer 127 having a tapered side surface (FIG. 12C). The heat treatment is performed at a temperature lower than the upper temperature limit of the organic compound layers. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, the adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

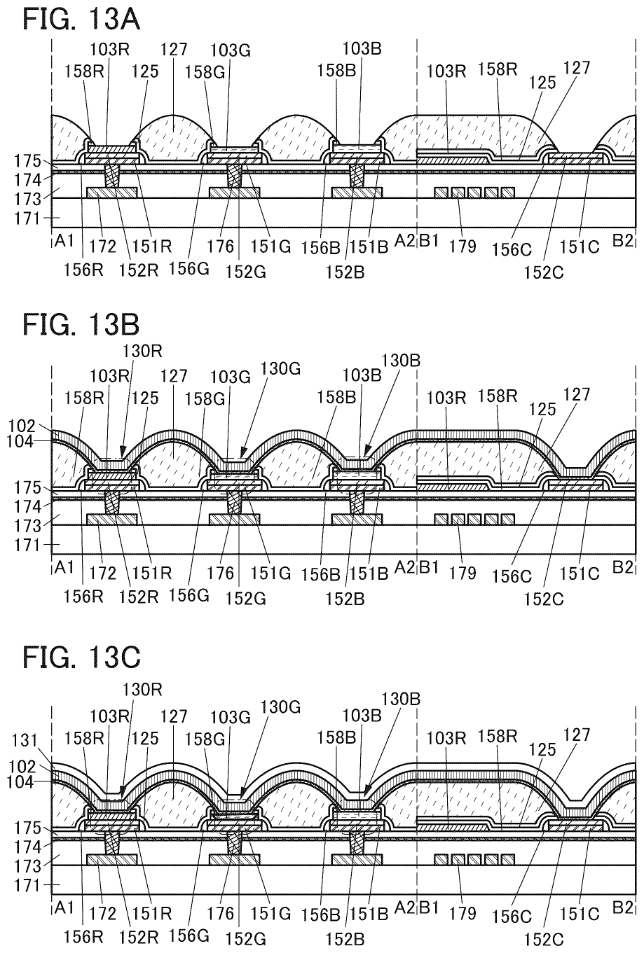

Next, as illustrated in FIG. 13A, etching treatment is performed using the insulating layer 127 as a mask, thereby removing parts of the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 13A illustrates an example where part of an end portion of the sacrificial layer 158G (specifically a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layers 103R, 103G, and 103B, as compared with the case of using a dry etching method. Wet etching can be performed using an alkaline solution or an acid solution, for example. An aqueous solution is preferably used in order that the organic compound layer 103 is not dissolved.

Next, as illustrated in FIG. 13B, a common electrode 155 is formed over the organic compound layers 103R, 103G, and 103B, the conductive layer 152C, and the insulating layer 127. The common electrode 155 can be formed by a sputtering method, a vacuum evaporation method, or the like.

Then, as illustrated in FIG. 13C, the protective layer 131 is formed over the common electrode 155. The protective layer 131 can be formed by a vacuum evaporation method, a sputtering method, a CVD method, an ALD method, or the like. Note that the protective layer 131 may also function as a cap layer. For example, with the use of a material having an ordinary refractive index (no) of 1.90 or greater at a wavelength of 450 nm, an ordinary refractive index (no) of 1.80 or greater at a wavelength of 520 nm, or an ordinary refractive index (no) of 1.75 or greater at a wavelength of 630 nm, the total reflection of light from the organic compound layer 103 by the cap layer can be inhibited, leading to an increase in light extraction efficiency.

In order to prevent air exposure of the light-emitting device that has yet to be incorporated in the display apparatus, a sealing film may be provided over the protective layer 131. The sealing film can be formed using a material that is less likely to transmit impurities such as oxygen and water easily. Specifically, an alumina oxide film is preferably provided by an ALD method. Note that in order to prevent air exposure of the light-emitting device in which the sealing film has yet to be provided after the protective layer 131 is formed, the light-emitting device is preferably transferred into an ALD apparatus in a glove box containing a nitrogen atmosphere after the protective layer 131 is formed. Here, the oxygen concentration in the glove box is preferably lower than or equal to 100 ppm, further preferably lower than or equal to 10 ppm, still further preferably lower than or equal to 1 ppm.

Then, the substrate 120 bonds to the protective layer 131 or the sealing film using the resin layer 122, so that the display apparatus can be manufactured. In the method for manufacturing the display apparatus of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display apparatus and inhibit generation of defects. Alternatively, a microlens array is provided over the protective layer 131 or the sealing film before bonding of the substrate 120 and then the substrate 120 is bonded, whereby a display apparatus including the microlens array can be manufactured.

As described above, in the method for manufacturing the display apparatus of one embodiment of the present invention, the island-shaped organic compound layers 103R, 103G, and 103B are formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be obtained. Moreover, even a display apparatus that includes tandem light-emitting devices formed by a photolithography method can offer favorable performance.

### Embodiment 5

In this embodiment, a display apparatus of one embodiment of the present invention will be described.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and laptop personal computers, a monitor of a computer and the like, digital signage, and a large game machine such as a pachinko machine.

### [Display Module]

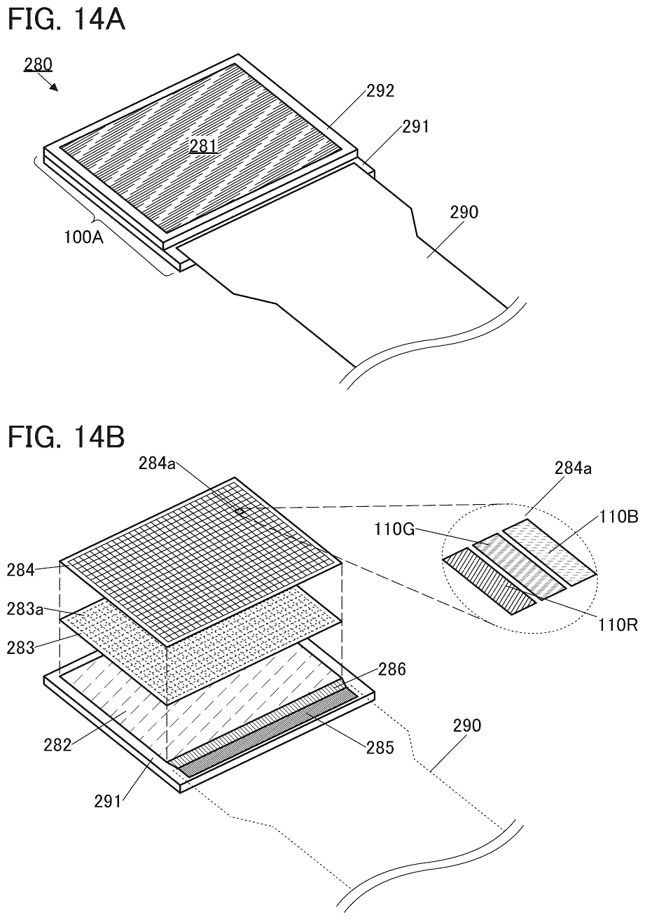

FIG. 14A is a perspective view of a display module 280. The display module 280 includes a display apparatus 100A and an FPC 290. Note that the display apparatus included in the display module 280 is not limited to the display apparatus 100A and may be any of display apparatuses 100B to 100G described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 14B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 14B. The pixels 284a can employ any of the structures described in the above embodiment.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high definition, and thus can be suitably used for a VR device such as an HMD or a glasses-type AR device. For example, even in the case of a structure in which the display portion of the display module 280 is seen through a lens, pixels of the extremely-high-definition display portion 281 included in the display module 280 are prevented from being recognized when the display portion is magnified by the lens, so that display providing a high sense of immersion can be performed. Without being limited thereto, the display module 280 can be suitably used for electronic appliances including a relatively small display portion.

### [Display Apparatus 100A]

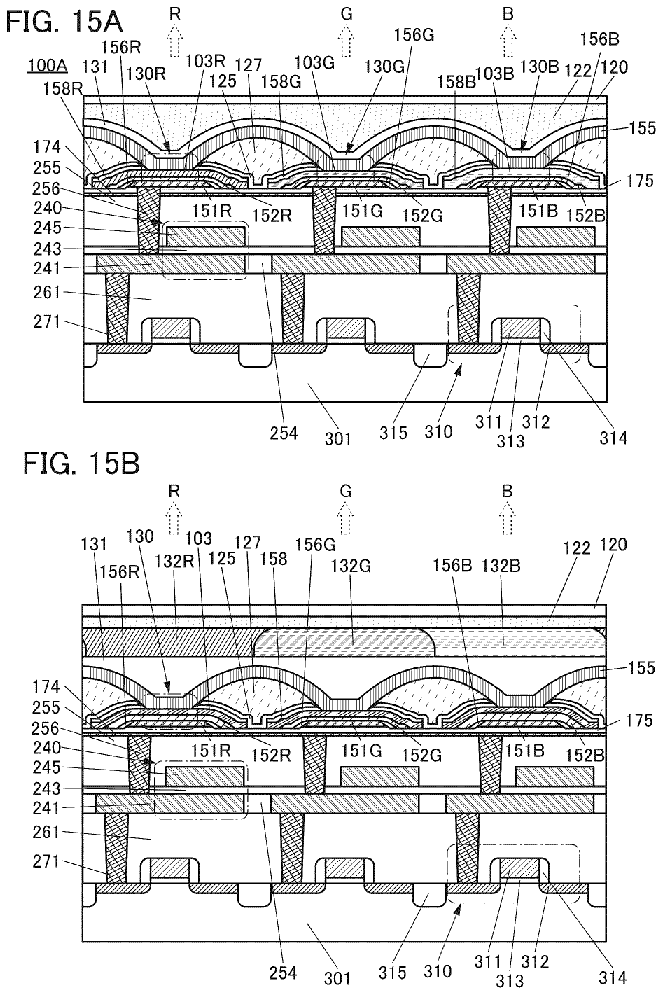

The display apparatus 100A illustrated in FIG. 15A includes a substrate 301, the light-emitting devices 130R, 130G, and 130B, a capacitor 240, and a transistor 310.

The substrate 301 corresponds to the substrate 291 in FIGS. 14A and 14B. The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity serving as a dopant, and function as a source and a drain. The insulating layer 314 is provided to cover a side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 bonds to the protective layer 131 with the resin layer 122. Embodiment 4 can be referred to for the details of the light-emitting device 130 and the components thereover up to the substrate 120. The substrate 120 corresponds to the substrate 292 in FIG. 14A.

FIG. 15B illustrates a variation example of the display apparatus 100A illustrated in FIG. 15A. The display apparatus illustrated in FIG. 15B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 15B, the light-emitting device 130 can emit white light, for example. The coloring layer 132R, the coloring layer 132G, and the coloring layer 132B can transmit red light, green light, and blue light, respectively, for example.

### [Display Apparatus 100B]

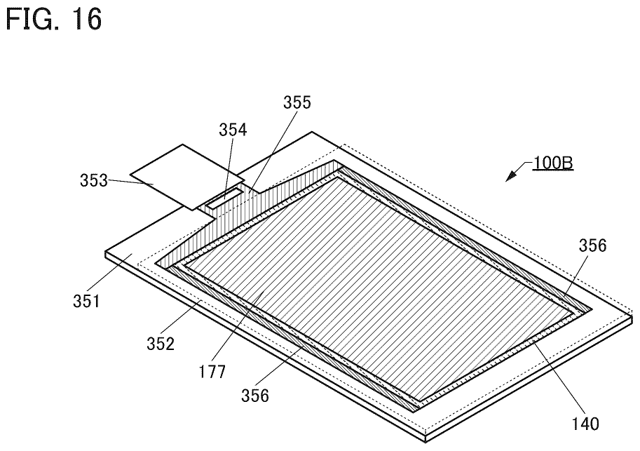

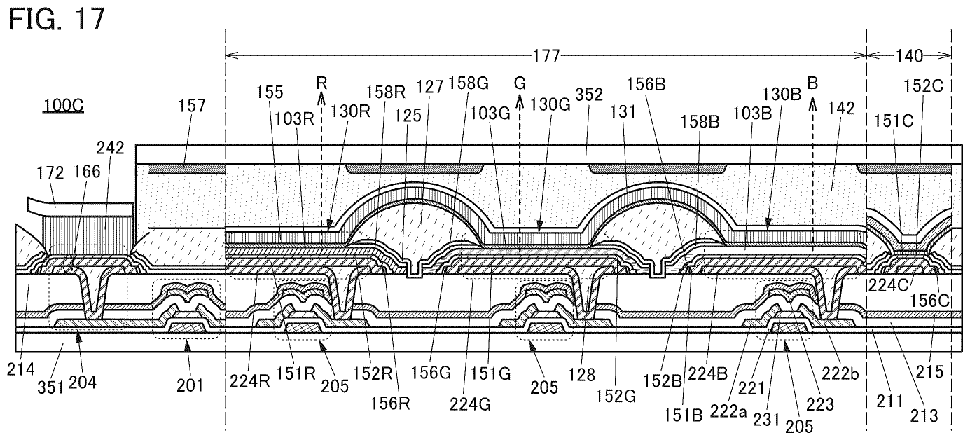

FIG. 16 is a perspective view of the display apparatus 100B, and FIG. 17 is a cross-sectional view of the display apparatus 100C.

In the display apparatus 100B, a substrate 352 and a substrate 351 are bonded to each other. In FIG. 16, the substrate 352 is denoted by a dashed line.

The display apparatus 100B includes the pixel portion 177, the connection portion 140, a circuit 356, a wiring 355, and the like. FIG. 16 illustrates an example where an IC 354 and an FPC 353 are mounted on the display apparatus 100B. Thus, the structure illustrated in FIG. 16 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 16 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 17 illustrates the display apparatus 100C as an example of cross sections of part of a region including the FPC 353, part of the circuit 356, part of the pixel portion 177, part of the connection portion 140, and part of a region including an end portion of the display apparatus 100B in FIG. 16.

### [Display Apparatus 100C]

The display apparatus 100C illustrated in FIG. 17 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. An edge portion of the conductive layer 151R is positioned outward from an edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering an opening provided in the insulating layer 214. A layer 128 is embedded in the depression portion.

The layer 128 has a function of filling the depression portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 17, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-shaped adhesive layer 142.

FIG. 17 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 17, the insulating layer 156C is provided to include a region overlapping with the side surface of the conductive layer 151C.

The display apparatus 100C has a top-emission structure. Light from the light-emitting device is emitted toward the substrate 352. For the substrate 352, a material having a high visible-light-transmitting property is preferably used. The pixel electrode includes a material that reflects visible light, and the counter electrode (the common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layers 211, 213, and 215.

An organic insulating layer is suitable for the insulating layer 214 functioning as a planarization layer.

Each of the transistors 201 and 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate.

A connection portion 204 is provided in a region of the substrate 351 where the substrate 352 does not overlap. In the connection portion 204, one of the source electrode and the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

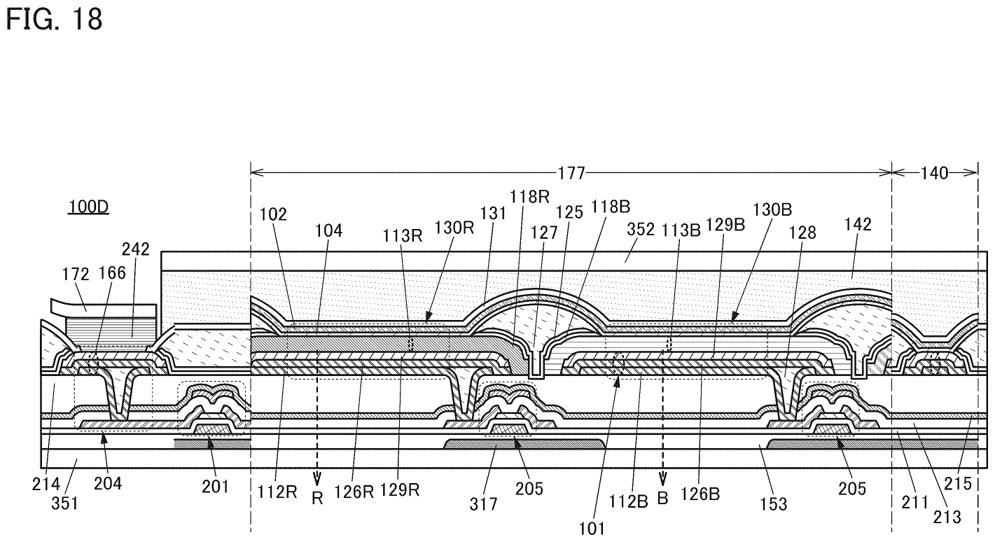

The display apparatus 100D illustrated in FIG. 18 differs from the display apparatus 100C illustrated in FIG. 17 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 18 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 18, the light-emitting device 130G is also provided.

Although FIG. 18 and the like illustrate an example where the top surface of the layer 128 includes a flat portion, there is no particular limitation on the shape of the layer 128.

### [Display Apparatus 100E]

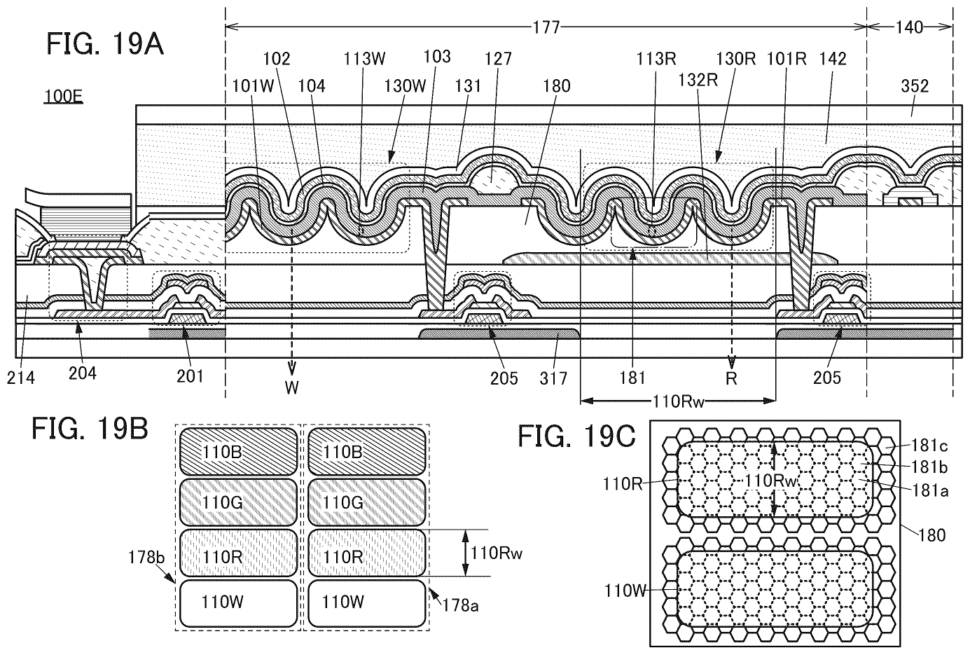

The display apparatus 100E illustrated in FIG. 19A is an example of a bottom-emission display apparatus different from the display apparatus 100D illustrated in FIG. 18. The display apparatus 100E is different from the display apparatus 100D in including an organic resin layer 180. Note that the reference numerals of the components that are the same as those in FIG. 18 are sometimes omitted, and the description for FIG. 18 is referred to for the details of such components.

FIG. 19B shows a top-view layout of the pixels 178 (pixels 178a and 178b) including the subpixels 110 (the subpixels 110R, 110G, 110B and 110W). FIG. 19C is a top view of the organic resin layer 180 in a region where the subpixels 110R and 110G included in the pixel 178 are formed. Note that the width between the light-blocking layer 317 and another light-blocking layer 317 corresponds to a width 110Rw in the light-emitting region of the subpixel 110R.

As illustrated in FIG. 19A, the organic resin layer 180 is provided over the insulating layer 214. As illustrated in FIG. 19C and the region surrounded by the dashed-dotted line in FIG. 19A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. When the depressed portion 181c is provided, light that has been emitted in the region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portions 181a and 181b may be provided in contact with each other or may have a flat surface therebetween.

Although the top surface shape and the cross-sectional shape of the depressed portion are hexagonal (FIG. 19C) and semicircular (FIG. 19A), respectively, other shapes may be employed as needed. Examples of a top surface shape of the depressed portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For the organic resin layer 180, for example, a resin that can be used as a color filter that transmits red, blue, or green light and absorbs light of the other colors or a resin that includes carbon black as a pigment and functions as a black matrix can be used.

The first electrodes 101 (the first electrode 101R and a first electrode 101W) are provided over the organic resin layer 180, and the organic compound layer 103 is provided over the first electrodes 101. End portions of the first electrode 101 and the organic compound layer 103 may be covered with the insulating layer 127.

The first electrode 101 formed over the organic resin layer 180 also has a depressed portion along the depressed portion of the organic resin layer 180. The organic compound layer 103 formed over the first electrode 101 also has a depressed portion along the depressed portion of the first electrode 101. The common layer 104 formed over the organic compound layer 103 also has a depressed portion along the depressed portion of the organic compound layer 103. The second electrode 102 formed over the common layer 104 also has a depressed portion along the depressed portion of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102 and bonded to the substrate 352 with the use of the adhesive layer 142.

Although not illustrated in FIGS. 19A to 19C, the light-emitting devices 130G and 130B are also provided.

### [Display Apparatus 100F]

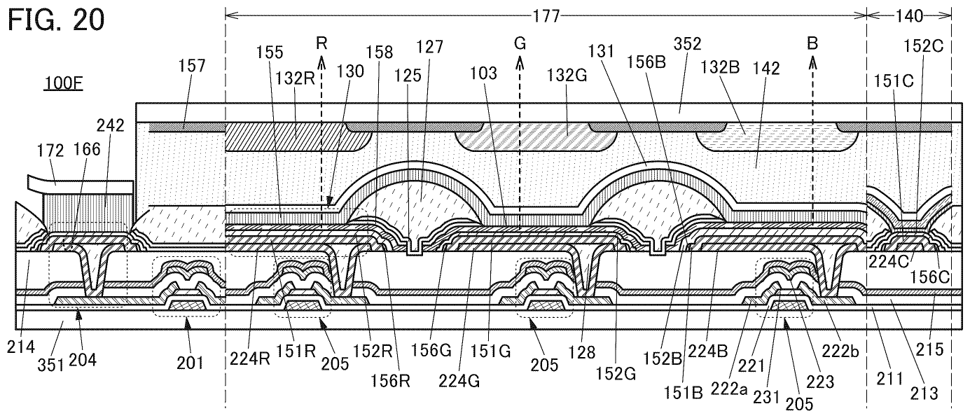

The display apparatus 100F illustrated in FIG. 20 is a variation example of the display apparatus 100C illustrated in FIG. 17 and differs from the display apparatus 100C mainly in including the coloring layers 132R, 132G, and 132B.

In the display apparatus 100F, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display apparatus 100F, the light-emitting device 130 can emit white light, for example. The coloring layer 132R, the coloring layer 132G, and the coloring layer 132B can transmit red light, green light, and blue light, respectively, for example. Note that in the display apparatus 100F, the coloring layers 132R, 132G, and 132B may be provided between the protective layer 131 and the adhesive layer 142.

### [Display Apparatus 100G]

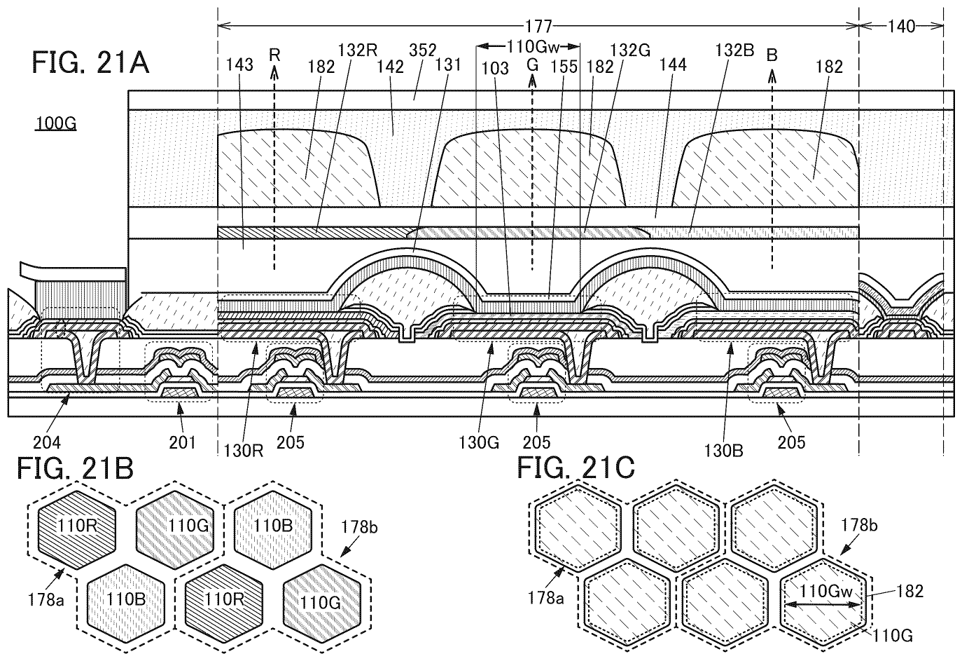

The display apparatus 100G illustrated in FIG. 21A is a variation example of the display apparatus 100F illustrated in FIG. 20 and includes microlenses 182 over the coloring layers 132R, 132G, and 132B. Note that the reference numerals of the components that are the same as those in FIG. 20 are sometimes omitted, and the description for FIG. 20 is referred to for the details of such components.

FIG. 21B shows a top-view layout of the pixels 178 (the pixels 178a and 178b) including the subpixels 110 (the subpixels 110R, 110G, and 110B). FIG. 21C is atop view of the microlens 182 in a region where the subpixels 110R, 110G, and 110B included in the pixel 178 are formed. Note that the width of the region where the common electrode 155 and the organic compound layer 103 are in contact with each other corresponds to a width 110Gw in the light-emitting region of the subpixel 110G.

In the display apparatus 100G illustrated in FIG. 21A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 21C, the microlens 182 is preferably provided for each of the subpixels in the region where the subpixel is formed.

Although the top surface shape of the microlens 182 is illustrated as a hexagon in FIG. 21C, other shapes may be employed as needed. Examples of atop surface shape of the microlens 182 include polygons such as a triangle, a tetragon (including a rectangle and a square), and a pentagon; these polygons with rounded corners; an ellipse; and a circle.

The microlenses 182 can be formed using a material similar to that of the organic resin layer 180.

This embodiment can be combined as appropriate with any of the other embodiments and the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances in this embodiment each include the display apparatus of one embodiment of the present invention in a display portion. The display apparatus of one embodiment of the present invention has low power consumption and high reliability. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and laptop personal computers, a monitor of a computer and the like, digital signage, and a large game machine such as a pachinko machine.

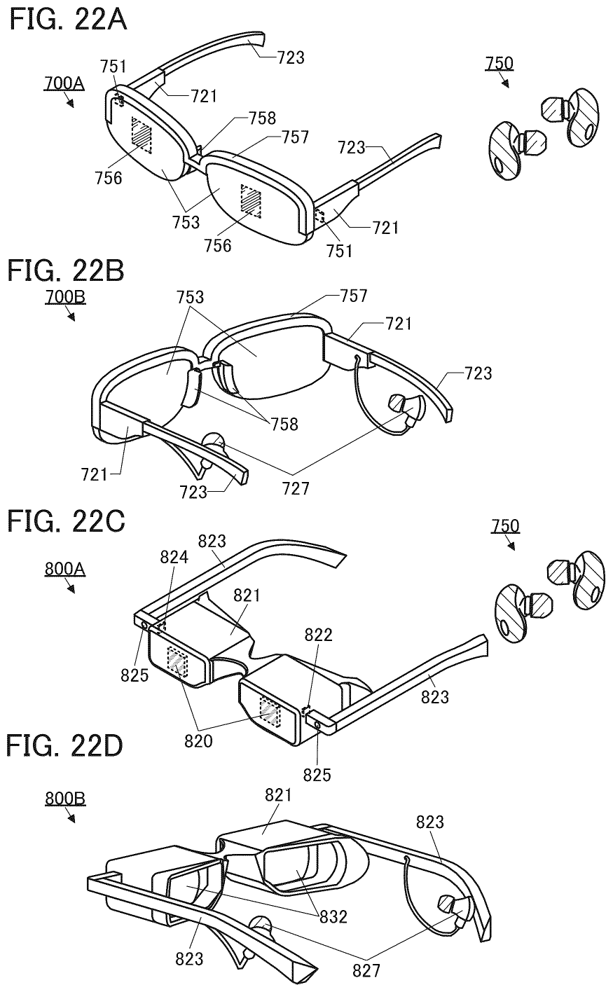

Examples of head-mounted wearable devices will be described with reference to FIGS. 22A to 22D.

An electronic appliance 700A illustrated in FIG. 22A and an electronic appliance 700B illustrated in FIG. 22B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic appliances can be highly reliable.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 22C and an electronic appliance 800B illustrated in FIG. 22D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic appliances can be highly reliable.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 22B includes earphone portions 727. Part of the wiring that connects the earphone portion 727 and the control portion may be positioned inside the housing 721 or the wearing portion 723.

Similarly, the electronic appliance 800B in FIG. 22D includes earphone portions 827. For example, the earphone portion 827 can be connected to the control portion 824 by a wiring.

As described above, both the glasses-type device (e.g., the electronic appliances 700A and 700B) and the goggles-type device (e.g., the electronic appliances 800A and 800B) are preferable as the electronic appliance of one embodiment of the present invention.

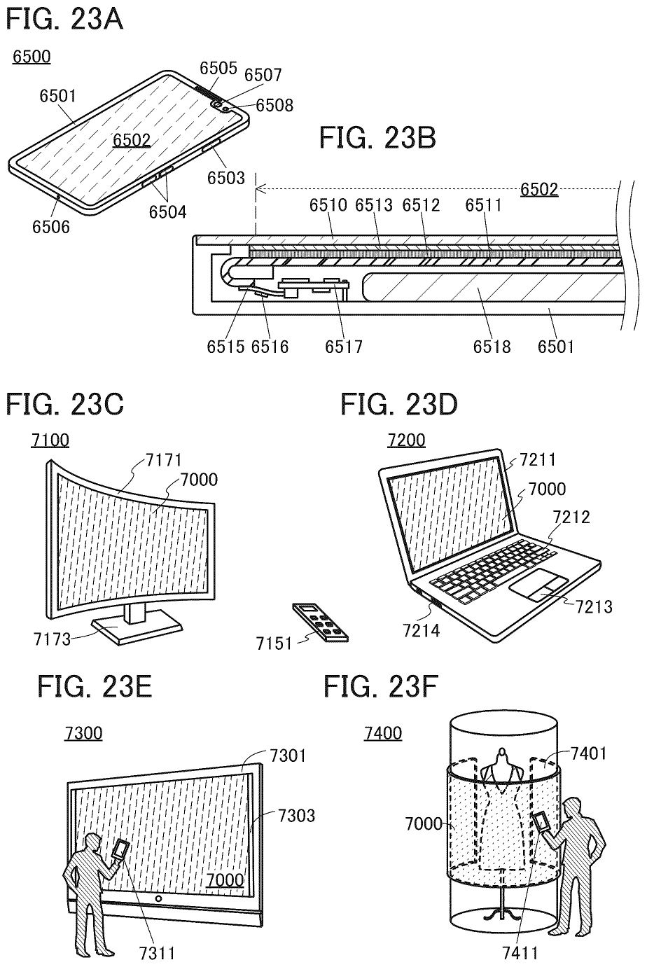

An electronic appliance 6500 illustrated in FIG. 23A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502. Thus, the electronic appliance can be highly reliable.

FIG. 23B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used for the display panel 6511. Thus, the electronic appliance can be extremely lightweight. Since the display panel 6511 is extremely thin, the battery 6518 with high capacity can be mounted without an increase in the thickness of the electronic appliance. Moreover, part of the display panel 6511 is folded back so that the portion connected to the FPC 6515 is provided on the back side of the pixel portion, whereby the electronic device can have a narrow bezel.

FIG. 23C illustrates an example of a television device. In a television device 7100, a display portion 7000 is incorporated in a housing 7171. Here, the housing 7171 is supported by a stand 7173.

The display apparatus of one embodiment of the present invention can be used for the display portion 7000. Thus, the electronic appliance can be highly reliable.

Operation of the television device 7100 illustrated in FIG. 23C can be performed with an operation switch provided in the housing 7171 and a separate remote control 7151.

FIG. 23D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used for the display portion 7000. Thus, the electronic appliance can be highly reliable.

FIGS. 23E and 23F illustrate examples of digital signage that can be used for store windows, showcases, and the like.

Digital signage 7300 illustrated in FIG. 23E includes a housing 7301, the display portion 7000, a speaker 7303, and the like. The digital signage 7300 can also include an LED lamp, operation keys (including a power switch and an operation switch), a connection terminal, a variety of sensors, a microphone, and the like.

FIG. 23F illustrates digital signage 7400 attached to a cylindrical pillar 7401. The digital signage 7400 includes the display portion 7000 provided along a curved surface of the pillar 7401.

In FIGS. 23E and 23F, the display apparatus of one embodiment of the present invention can be used for the display portion 7000. Thus, the electronic appliances can be highly reliable.

A larger area of the display portion 7000 can increase the amount of information that can be provided at a time. The display portion 7000 having a larger area attracts more attentions, so that the effectiveness of the advertisement can be increased, for example.

Specifically, in the case where the display apparatus of one embodiment of the present invention is used for the digital signage 7400 illustrated in FIG. 23F that displays advertisements and the like, the display apparatus being a light-transmitting panel can increase the flexibility of representation in advertising. A light-transmitting display apparatus can be manufactured, for example, by using a wiring and a support member each of which is formed of a conductive film that transmits visible light and adjusting the distance between pixel electrodes.

The use of the tandem light-emitting device of one embodiment of the present invention in addition to the wiring and the support member each of which is formed of the conductive film that transmits visible light can increase the luminance per pixel. That is, favorable display can be performed even when the aperture ratio of the display apparatus is decreased; thus, the light-transmitting property of the display portion of the display apparatus can be increased. Accordingly, such a structure is suitably used in the light-transmitting display apparatus of one embodiment of the present invention.

As illustrated in FIGS. 23E and 23F, it is preferable that the digital signage 7300 or the digital signage 7400 can work with an information terminal 7311 or an information terminal 7411, such as a smartphone that a user has, through wireless communication.

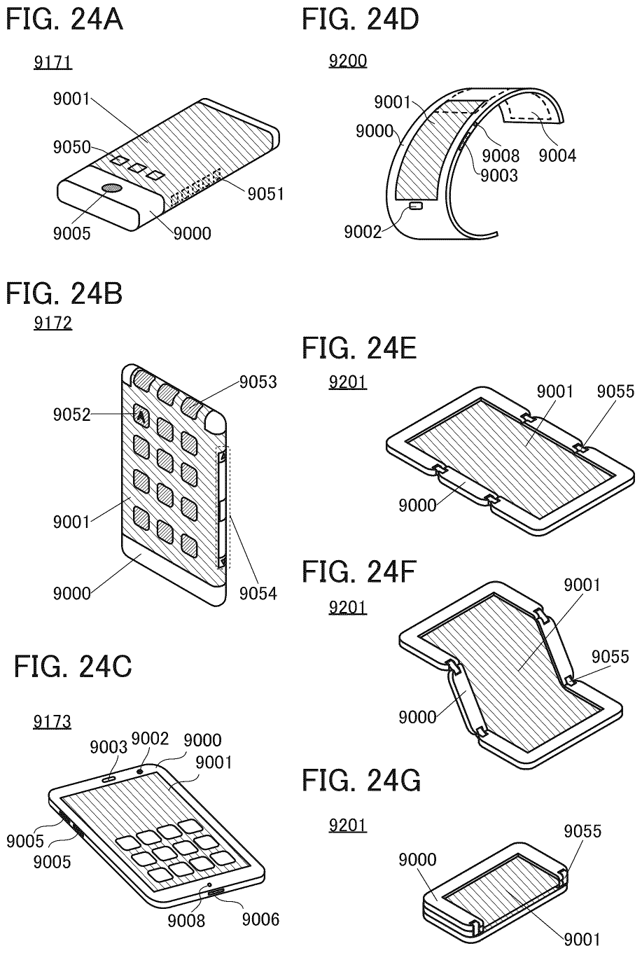

Electronic appliances illustrated in FIGS. 24A to 24G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 24A to 24G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances in FIGS. 24A to 24G are described in detail below.

FIG. 24A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 24A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 24B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed so as to be seen from above the portable information terminal 9172, with the portable information terminal 9172 put in a breast pocket of his/her clothes.

FIG. 24C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 24D is a perspective view of a watch-type portable information terminal 9200. The portable information terminal 9200 can be used as a Smartwatch (registered trademark), for example. The portable information terminal 9200 may include the operation key 9005 as a button for operation on the left side surface of the housing 9000 and the sensor 9007 on the bottom surface of the housing 9000. Although the housing 9000 having a curved bangle shape is illustrated as an example, a belt or the like may be used in combination with the housing 9000 to make the portable information terminal 9200 wearable. The display surface of the display portion 9001 is curved, and an image can be displayed on the curved display surface. A power storage device 9004 may have a curved shape along the housing 9000. The power storage device 9004 has flexibility and can be bent in accordance with a change in shape when the user puts on or takes off the portable information terminal 9200. Note that a charge control IC connected to the power storage device 9004 may be provided. Furthermore, for example, mutual communication between the portable information terminal 9200 and a headset capable of wireless communication can be performed, and thus hands-free calling is possible. The portable information terminal 9200 can perform mutual data transmission wirelessly with another information terminal and can be charged with wireless power feeding. Note that the connection terminal 9006 may be provided in the housing 9000 so that data transmission and charging operation may be performed by wire.

FIGS. 24E to 24G are perspective views of a foldable portable information terminal 9201. FIG. 24E is a perspective view showing the portable information terminal 9201 that is opened. FIG. 24G is a perspective view showing the portable information terminal 9201 that is folded. FIG. 24F is a perspective view showing the portable information terminal 9201 that is shifted from one of the states in FIGS. 24E and 24G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with any of the other embodiments and the examples. In this specification, in the case where a plurality of structure examples are shown in one embodiment, the structure examples can be combined as appropriate.

### Example 1

This example will describe specific manufacturing methods and characteristics of light-emitting devices R1-a to R1-c, G1, and B1 that can be used in the display apparatus of one embodiment of the present invention and comparative light-emitting devices R1, G1, and B1. Moreover, the description will be made on estimation of power consumption of display apparatuses of embodiments of the present invention including these light-emitting devices. The structural formulae of main compounds used in the light-emitting devices are shown below.

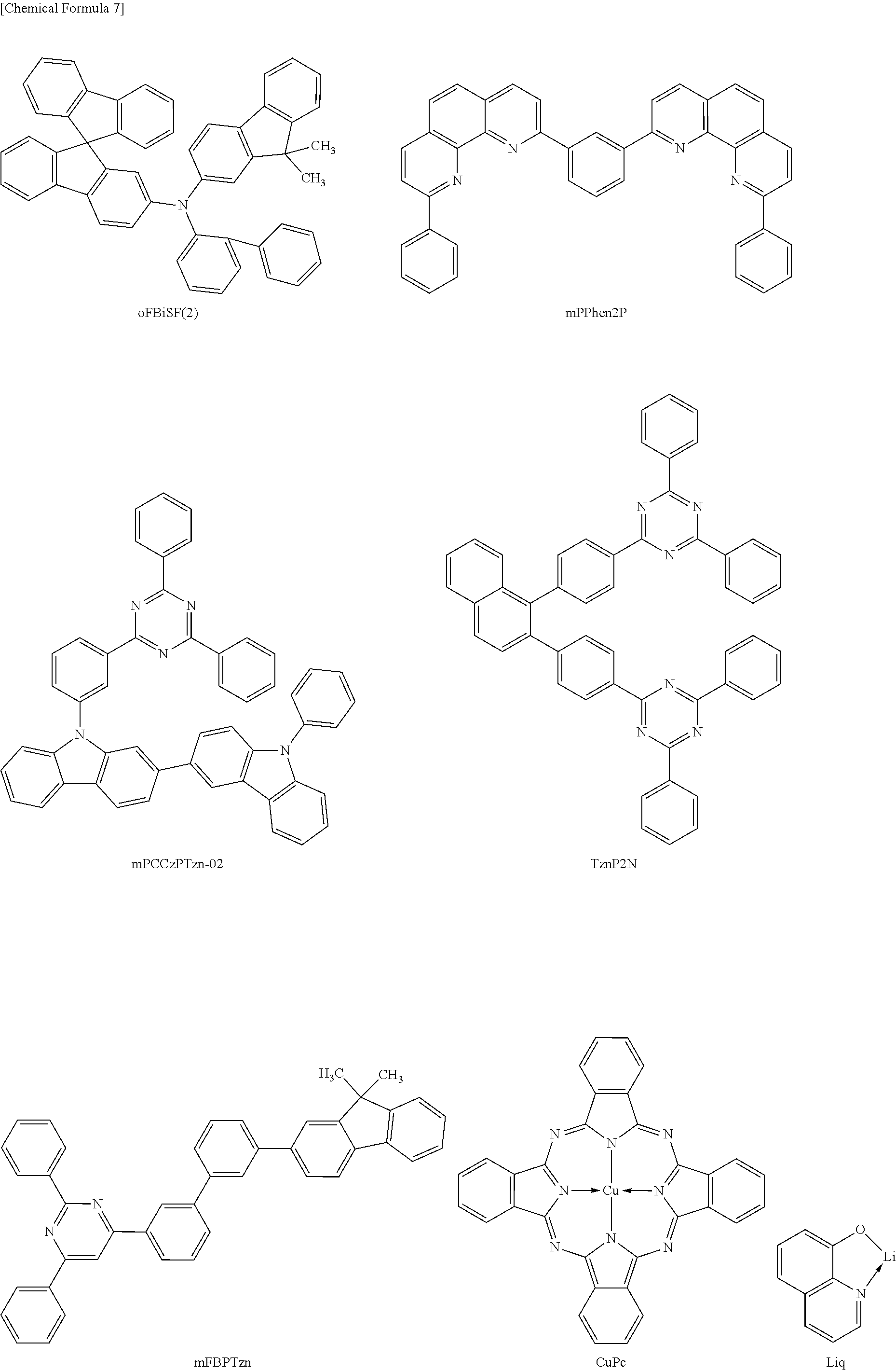

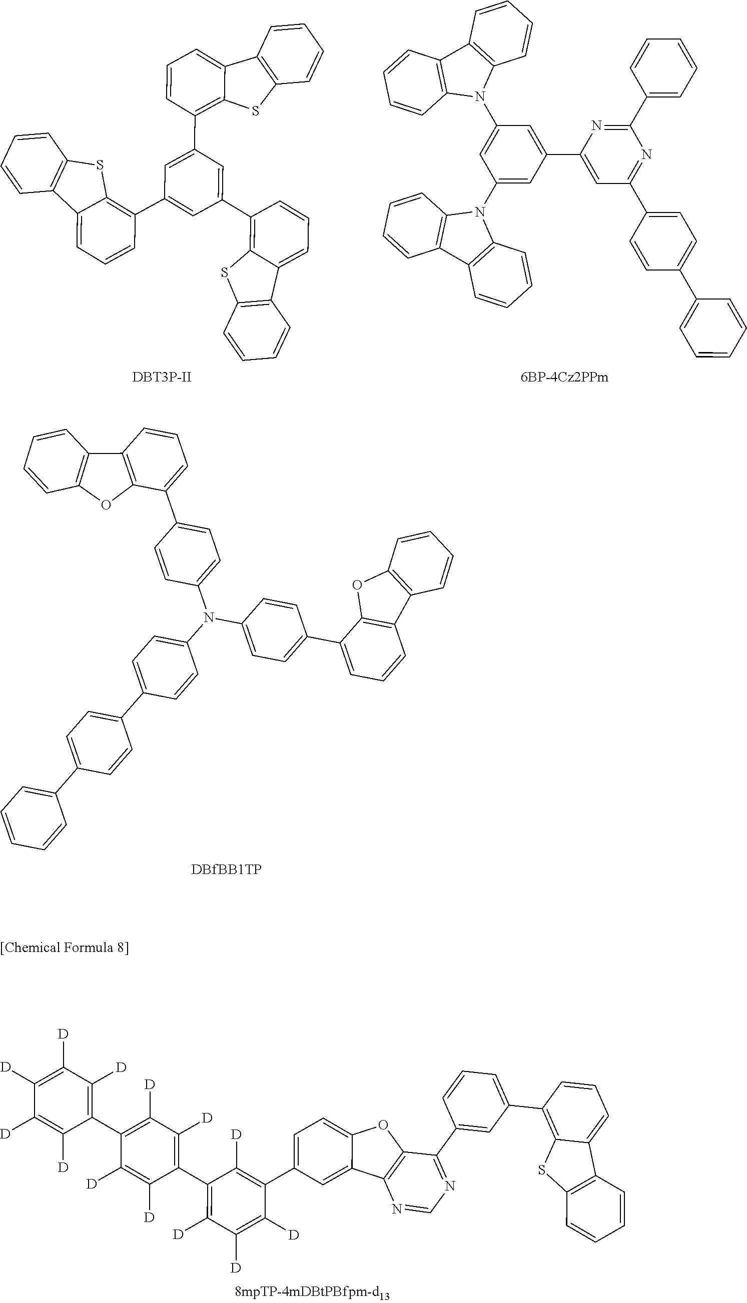 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; [2H]c1c([2H])c([2H])c(-c2c([2H])c([2H])c(-c3c([2H])c([2H])c([2H])c(-c4ccc5oc6c(-c7cccc(-c8cccc9c8sc8ccccc89)c7)ncnc6c5c4)c3[2H])c([2H])c2[2H])c([2H])c1[2H]]

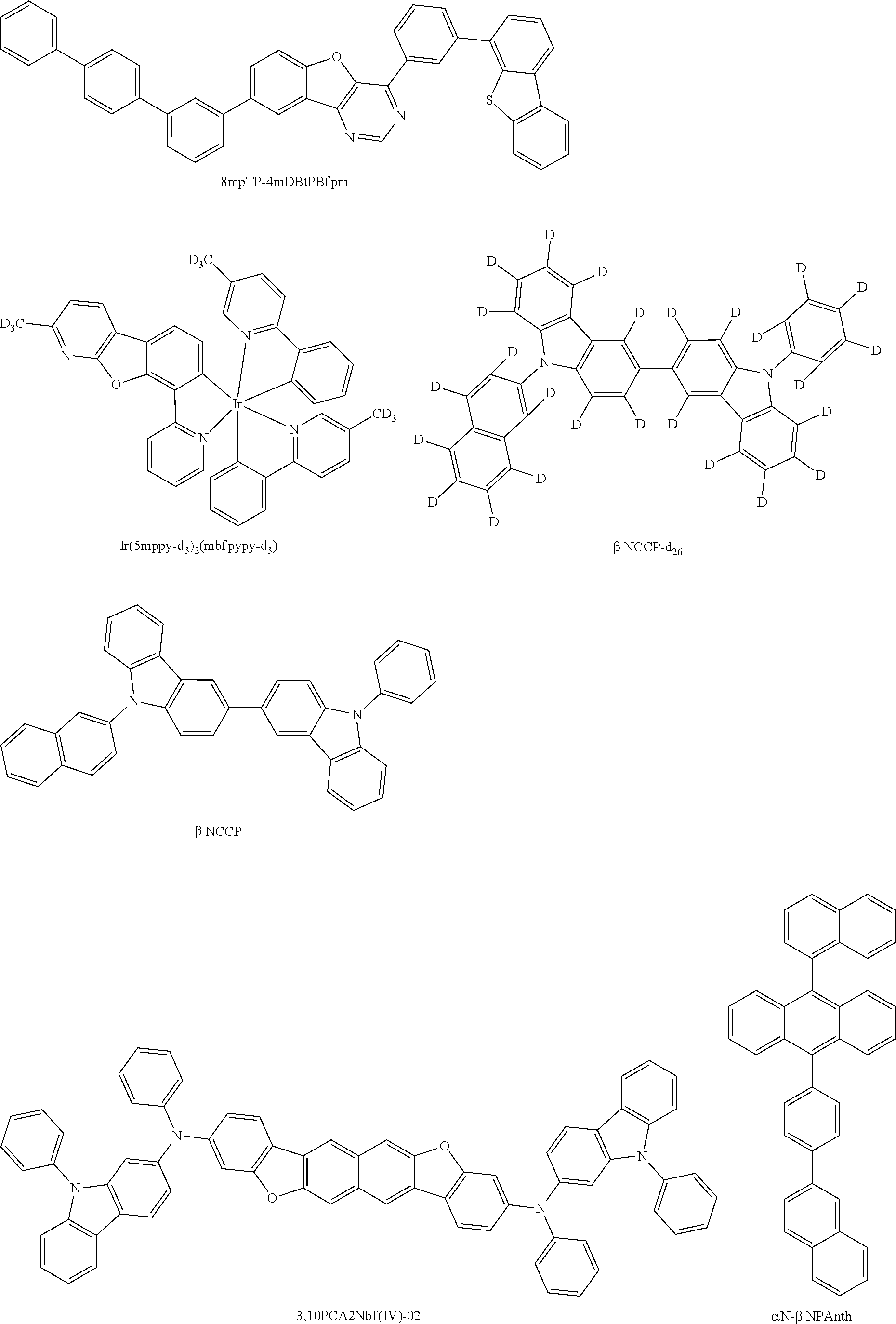

### (Method 1 For Manufacturing Light-Emitting Devices)

A method for manufacturing the light-emitting devices used in this example is described.

### <Method for Manufacturing Light-Emitting Device R1-a>

First, 100-nm-thick silver (Ag) and 85-nm-thick indium tin oxide containing silicon oxide (ITSO) were stacked over a glass substrate sequentially from the substrate side by a sputtering method as a reflective electrode and a transparent electrode, respectively, whereby the first electrode 101 with a size of 2 mm×2 mm was formed. Note that the transparent electrode functions as an anode, and the transparent electrode and the reflective electrode are collectively regarded as the first electrode 101.

Next, in pretreatment for forming the light-emitting device over the substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, over the first electrode 101, the hole-injection layer 111 was formed to a thickness of 10 nm by co-evaporation of N-(biphenyl-2-yl)-N-(9,9-dimethylfluoren-2-yl)-9,9′-spirobi[9H-fluoren]-2-amine (abbreviation: oFBiSF(2)) and a fluorine-containing material having an electron-acceptor property with a molecular weight of 672 (OCHD-003) at a weight ratio of 1:0.03.

Over the hole-injection layer 111, the first hole-transport layer was formed to a thickness of 140 nm by evaporation of oFBiSF(2).

Next, over the first hole-transport layer, the first light-emitting layer was formed to a thickness of 40 nm by co-evaporation of 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), 9-(2-naphthyl)-9′-phenyl-3,3′-bi-9H-carbazole (abbreviation: βNCCP), and OCPG-006, a material that exhibits red phosphorescence, at a weight ratio of 8mpTP-4mDBtPBfpm-d₁₃:bNCCP:OCPG-006 of 0.4:0.6:0.05. Note that 8mpTP-4mDBtPBfpm-d₁₃ is an organic compound including deuterium, 8mpTP-4mDBtPBfpm-d₁₃ and βNCCP form an exciplex in combination, and OCPG-006 is an organometallic complex that exhibits phosphorescence.

Then, the first electron-transport layer was formed to a thickness of 10 nm by evaporation of 9-[3-(4,6-diphenyl-1,3,5-triazin-2-yl)phenyl]-9′-phenyl-2,3′-bi-9H-carbazole (abbreviation: mPCCzPTzn-02).

After the first electron-transport layer was formed, the first layer was formed to a thickness of 5 nm by co-evaporation of 2,2′-(1,3-phenylene)bis(9-phenyl-1,10-phenanthroline) (abbreviation: mPPhen2P) as the second organic compound having a phenanthroline skeleton and lithium oxide (Li₂O) such that the weight ratio of mPPhen2P to Li₂O was 1:0.02. Then, the third layer was formed to a thickness of 2 nm by evaporation of copper phthalocyanine (abbreviation: CuPc). Furthermore, the second layer was formed to a thickness of 10 nm by co-evaporation of oFBiSF(2) and OCHD-003 at a weight ratio of 1:0.15. Thus, the intermediate layer was formed.

Over the intermediate layer, the second hole-transport layer was formed to a thickness of 75 nm by evaporation of oFBiSF(2).

Over the second hole-transport layer, 8mpTP-4mDBtPBfpm-d₁₃, βNCCP, and OCPG-006 were deposited by co-evaporation such that the thickness was 40 nm and the weight ratio of 8mpTP-4mDBtPBfpm-d₁₃:βNCCP:OCPG-006 was 0.4:0.6:0.05, whereby the second light-emitting layer was formed.

After that, 2-[3′-(9,9-dimethyl-9H-fluoren-2-yl)biphenyl-3-yl]-4,6-diphenyl-1,3,5-triazine (abbreviation: mFBPTzn) was deposited to a thickness of 10 nm, and then 2,2′-[1,2-naphthalenediyldi(4,1-phenylene)]bis(4,6-diphenyl-1,3,5-triazine) (abbreviation: TznP2N) and 8-hydroxyquinolinato-lithium (abbreviation: Liq) were deposited by co-evaporation such that the thickness was 25 nm and the weight ratio of TznP2N to Liq was 1:1, whereby the second electron-transport layer was formed.

Then, Liq was deposited by evaporation to a thickness of 1 nm and silver (Ag) and magnesium (Mg) were deposited by co-evaporation such that the thickness was 15 nm and the volume ratio of Ag to Mg was 1:0.1, whereby the second electrode 102 was formed. Over the second electrode 102, 4,4′,4″-(benzene-1,3,5-triyl)tri(dibenzothiophene) (abbreviation: DBT3P-II) was deposited to a thickness of 70 nm as a cap layer to improve light extraction efficiency.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device R1-a was fabricated.

### <Method for Manufacturing Light-Emitting Device R1-b>

The light-emitting device R1-b was manufactured in the same manner as the light-emitting device R1-a except that the first light-emitting layer and the second light-emitting layer were each formed by co-evaporation of 8-(1,1′:4′,1″-terphenyl-3-yl)-4-[3-(dibenzothiophen-4-yl)phenyl]-[1]benzofuro-[3,2-d]pyrimidine (abbreviation: 8mpTP-4mDBtPBfpm), 9-(2-naphthyl-1,3,4,5,6,7,8-d₇)-9′-(phenyl-2,3,4,5,6-d₅)-3,3′-bi-9H-carbazole-1,1′,2,2′,4,4′,5,5′,6,6′,7,7,8,8′-d₁₄ (abbreviation: βNCCP-d₂₆), and OCPG-006 such that the weight ratio of 8mpTP-4mDBtPBfpm:βNCCP-d₂₆:OCPG-006 was 0.4:0.6:0.05.

### <Method for Manufacturing Light-Emitting Device R1-c>

The light-emitting device R1-c was manufactured in the same manner as the light-emitting device R1-a except that the first light-emitting layer and the second light-emitting layer were each formed by co-evaporation of 8mpTP-4mDBtPBfpm-d₁₃, βNCCP-d₂₆, and OCPG-006 such that the weight ratio of 8mpTP-4mDBtPBfpm-d₁₃:βNCCP-d₂₆:OCPG-006 was 0.4:0.6:0.05.

### <Method for Manufacturing Comparative Light-Emitting Device R1>

The comparative light-emitting device R1 was manufactured in the same manner as the light-emitting device R1-a except that the second electron-transport layer was formed using 4-[3,5-bis(9H-carbazol-9-yl)phenyl]-2-phenyl-6-(biphenyl-4-yl)pyrimidine (abbreviation: 6BP-4Cz2PPm) instead of TznP2N in the light-emitting device R1-a, and the first light-emitting layer and the second light-emitting layer were each formed by co-evaporation of 8mpTP-4mDBtPBfpm, βNCCP, and OCPG-006 at a weight ratio of 0.4:0.6:0.05.

### <Method for Manufacturing Light-Emitting Device G1>

The light-emitting device G1 was manufactured in the same manner as the light-emitting device R1-a except that the thickness of the first hole-transport layer was 80 nm, the thickness of the second hole-transport layer was 50 nm, and the first light-emitting layer and the second light-emitting layer were each formed by co-evaporation of 8mpTP-4mDBtPBfpm, βNCCP, and [2-d₃-methyl-8-(2-pyridinyl-cN)benzofuro[2,3-b]pyridine-κC]bis[2-(5-d₃-methyl-2-pyridinyl-KN2)phenyl-κC]iridium(III) (abbreviation: [Ir(5mppy-d₃)₂(mbfpypy-d₃)]) at a weight ratio of 0.5:0.5:0.1.

### <Method for Manufacturing Comparative Light-Emitting Device G1>

The comparative light-emitting device G1 was manufactured in the same manner as the light-emitting device G1 except that 6BP-4Cz2PPm was used instead of TznP2N in the second electron-transport layer.

### <Method for Manufacturing Light-Emitting Device B1>

The light-emitting device B1 was manufactured in the same manner as the light-emitting device R1-a except that the first hole-transport layer and the second hole-transport layer were each formed by depositing oFBiSF(2) to a thickness of 35 nm and then depositing N,N-bis[4-(dibenzofuran-4-yl)phenyl]-4-amino-p-terphenyl (abbreviation: DBfBB1TP) to a thickness of 10 nm by evaporation, and the first light-emitting layer and the second light-emitting layer were each formed to a thickness of 25 nm by co-evaporation of 9-(1-naphthyl)-10-[4-(2-naphthyl)phenyl]anthracene (abbreviation: αN-βNPAnth) and N,N-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02) such that the weight ratio of αN-βNPAnth to 3,10PCA2Nbf(IV)-02 was 1:0.015.

### <Method for Manufacturing Comparative Light-Emitting Device B1>

The comparative light-emitting device B1 was manufactured in the same manner as the light-emitting device B1 except that 6BP-4Cz2PPm was used instead of TznP2N in the second electron-transport layer.

The device structures of the light-emitting devices R1-a to R1-c, G1, and B1 and the comparative light-emitting devices R1, G1, and B1 are shown below.

TABLE 1

| | | | | |
|---|---|---|---|---|
| Thickness | Light-emitting | Light-emitting | Light-emitting | Comparative light- |
| (nm) | device R1-a | device R1-b | device R1-c | emitting device R1 |

| Cap layer | | 70 | DBT3P-II | |
|---|---|---|---|---|
| Second | 2 | 15 | Ag:Mg (1:0.1) | |
| electrode | 1 | 1 | Liq | |
| Second | b | 25 | TznP2N:Liq | 6BP-4Cz2PPm:Liq |
| electron-transport | | | (1:1) | (1:1) |

| | | | |
|---|---|---|---|
| layer | a | 10 | mFBPTzn |

| | | | | | |
|---|---|---|---|---|---|
| Second light-emitting | 40 | 8mpTP- | 8mpTP- | 8mpTP- | 8mpTP- |
| layer | | 4mDBtPBfpm- | 4mDBtPBfpm:βNCCP- | 4mDBtPBfpm- | 4mDBtPBfpm:βNCCP:OCPG- |

| | | | |
|---|---|---|---|
| d₁₃:βNCCP:OCPG- | d₂₆:OCPG- | d₁₃:βNCCP- | 006 |
| 006 | 006 | d₂₆:OCPG- | (0.4:0.6:0.05) |
| (0.4:0.6:0.05) | (0.4:0.6:0.05) | 006 | |
| | | (0.4:0.6:0.05) | |

| Second hole-transport layer | | 75 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | 10 | mPCCzPTzn-02 | | | |
|---|---|---|---|---|---|
| First light-emitting layer | 40 | 8mpTP- | 8mpTP- | 8mpTP- | 8mpTP- |

| | | | |
|---|---|---|---|
| 4mDBtPBfpm- | 4mDBtPBfpm:βNCCP- | 4mDBtPBfpm- | 4mDBtPBfpm:βNCCP:OCPG- |
| d₁₃:βNCCP:OCPG- | d₂₆:OCPG- | d₁₃:βNCCP- | 006 |
| 006 | 006 | d₂₆:OCPG-006 | (0.4:0.6:0.05) |
| (0.4:0.6:0.05) | (0.4:0.6:0.05) | (0.4:0.6:0.05) | |

| First hole-transport layer | | 140 | oFBiSF(2) |
|---|---|---|---|
| First hole-injection layer | | 10 | oFBiSF(2):OCHD-003 (1:0.03) |
| First electrode | 2 | 85 | ITSO |
| | 1 | 100 | Ag |

TABLE 2

| | | Thickness | Light-emitting | Comparative light- |
|---|---|---|---|---|
| | | (nm) | device G1 | emitting device G1 |
| Cap layer | | 70 | DBT3P-II | |
| Second electrode | 2 | 15 | Ag:Mg (1:0.1) | |
| | 1 | 1 | Liq | |
| Second electron- | b | 25 | TznP2N: Liq | 6BP-4Cz2PPm:Liq |
| transport layer | | | (1:1) | (1:1) |

| | | |
|---|---|---|
| a | 10 | mFBPTzn |

| Second light-emitting layer | | 40 | 8mpTP-4mDBtPBfpm:βNCCP:Ir(5mppy- |
|---|---|---|---|
| | | | d₃)₂(mbfpypy-d₃) (0.5:0.5:0.1) |
| Second hole-transport layer | | 50 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 40 | 8mpTP-4mDBtPBfpm:βNCCP:Ir(5mppy- |
| | | | d₃)₂(mbfpypy-d₃) (0.5:0.5:0.1) |
| First hole-transport layer | | 80 | oFBiSF(2) |
| First hole-injection layer | | 10 | oFBiSF(2):OCHD-003 (1:0.03) |
| First electrode | 2 | 85 | ITSO |
| | 1 | 100 | Ag |

TABLE 3

| | | | | Comparative |
|---|---|---|---|---|
| | | Thickness | Light-emitting | light-emitting |
| | | (nm) | device B1 | device B1 |
| Cap layer | | 70 | DBT3P-II | |
| Second electrode | 2 | 15 | Ag:Mg (1:0.1) | |
| | 1 | 1 | Liq | |
| Second electron- | b | 25 | TznP2N:Liq | 6BP- |
| transport layer | | | (1:1) | 4Cz2PPm:Liq |
| | | | | (1:1) |

| | a | 10 | mFBPTzn |
|---|---|---|---|
| Second light-emitting layer | | 25 | αN-βNPAnth:3,10PCA2Nbf(IV)- |
| | | | 02 (1:0.015) |
| Second hole-transport layer | b | 10 | DBfBB1TP |
| | a | 35 | oFBiSF(2) |

| | | | |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 25 | αN-βNPAnth:3,10PCA2Nbf(IV)- |
| | | | 02 (1:0.015) |
| First hole-transport layer | b | 10 | DBfBB1TP |
| | a | 35 | oFBiSF(2) |
| First hole-injection layer | | 10 | oFBiSF(2):OCHD-003 (1:0.03) |
| First electrode | 2 | 85 | ITSO |
| | 1 | 100 | Ag |

### (Characteristics 1 of Light-Emitting Devices)

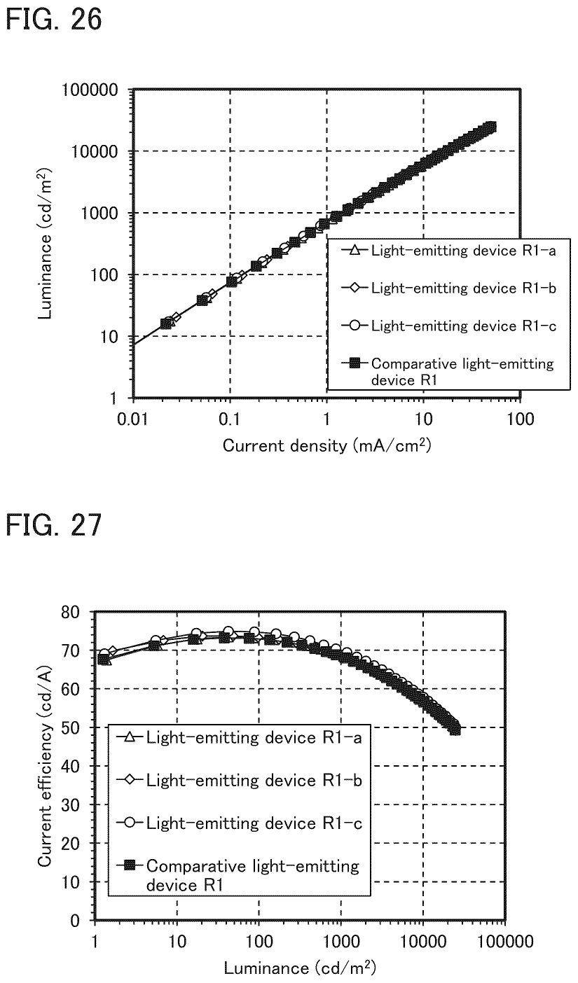

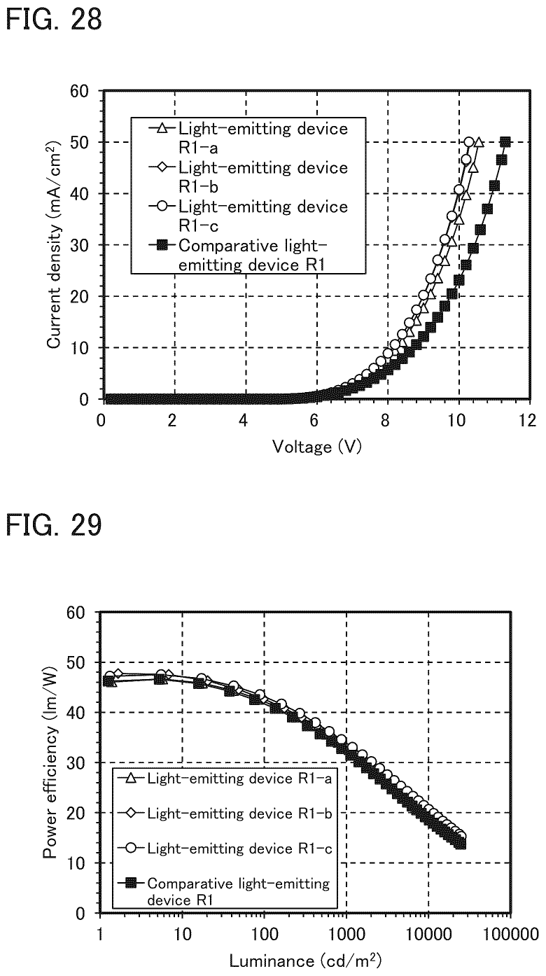

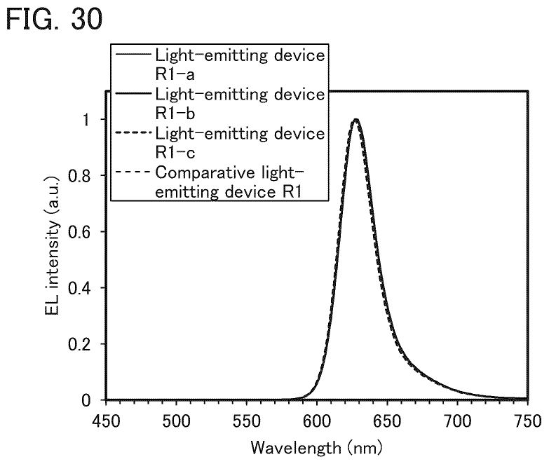

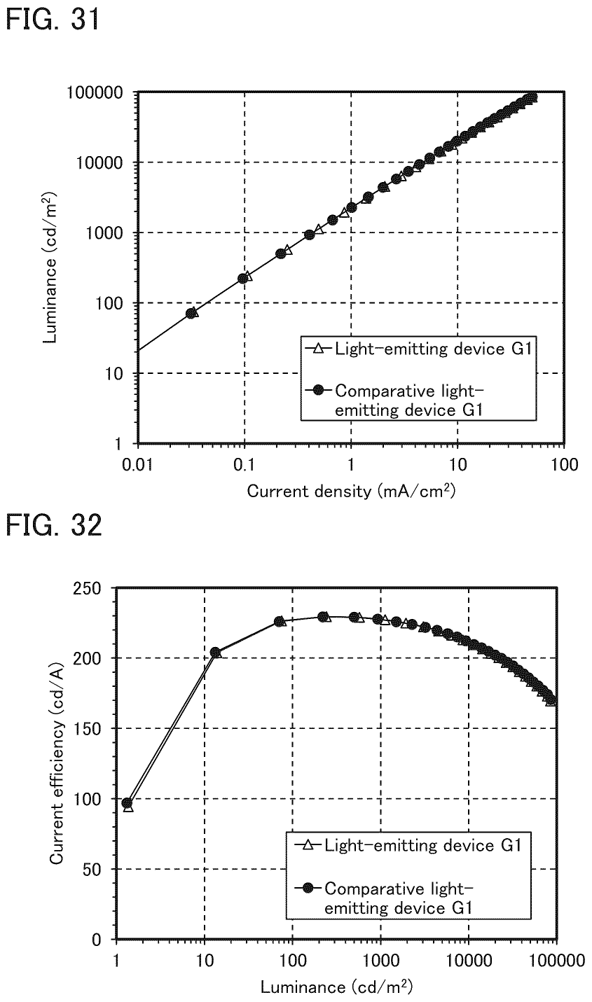

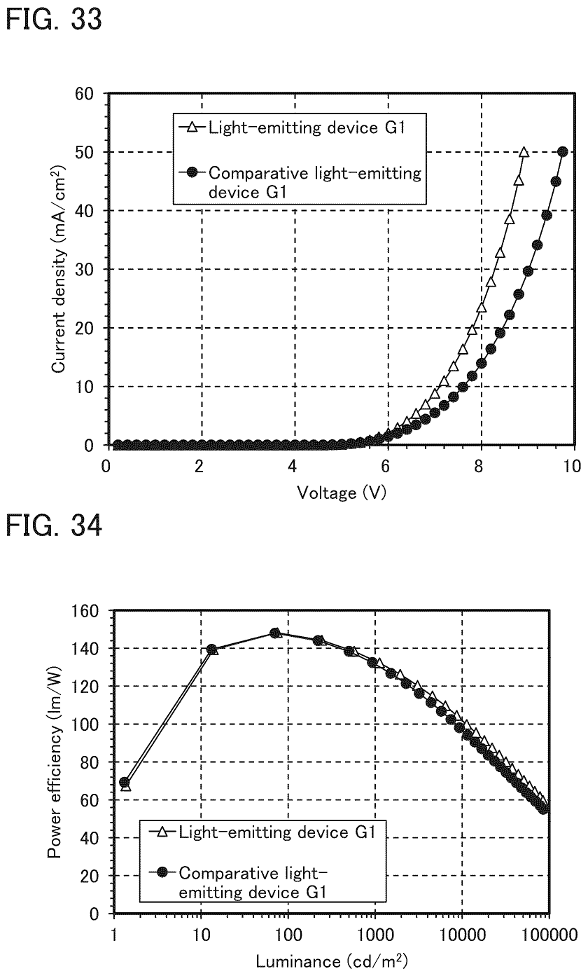

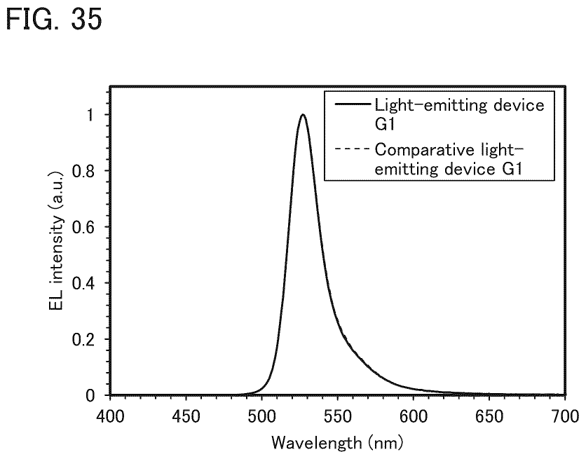

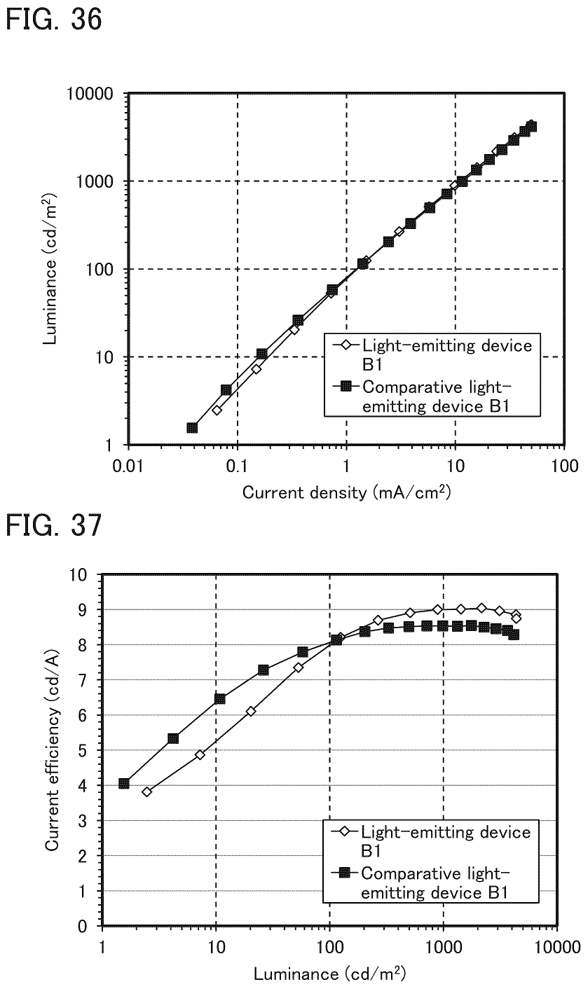

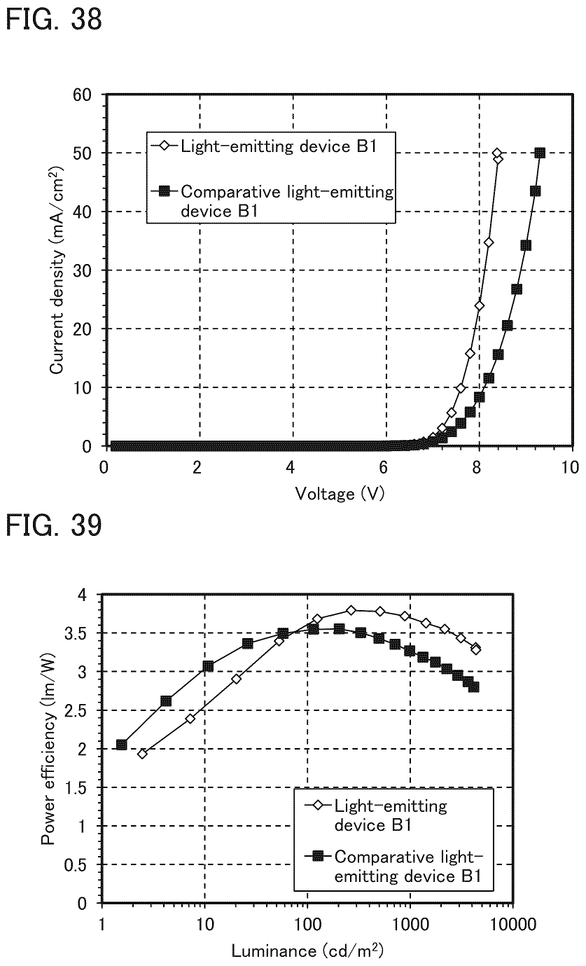

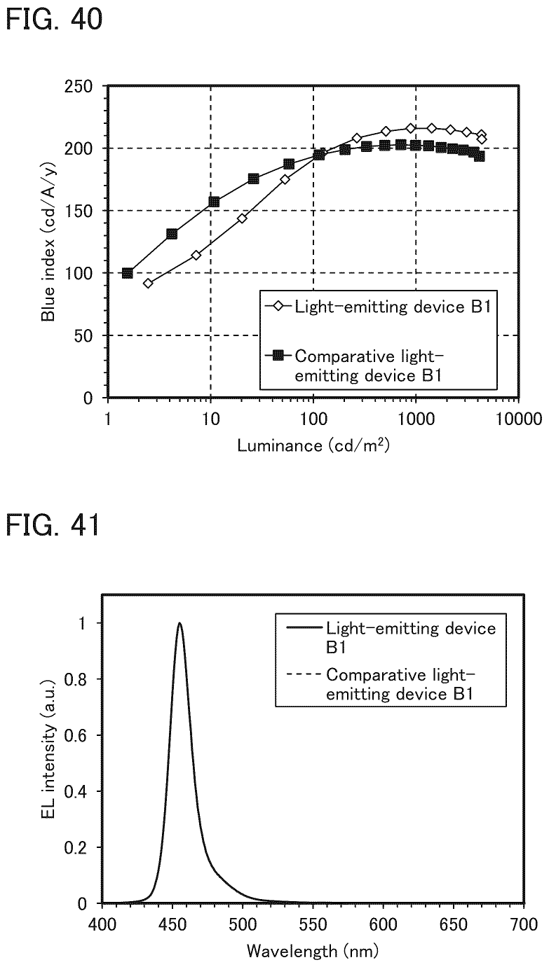

FIG. 26, FIG. 27, FIG. 28. FIG. 29, and FIG. 30 respectively show the luminance-current density characteristics, current efficiency-luminance characteristics, current density-voltage characteristics, power efficiency-luminance characteristics, and electroluminescence spectra of the light-emitting devices R1-a to R1-c and the comparative light-emitting device R1. FIG. 31, FIG. 32, FIG. 33, FIG. 34, and FIG. 35 respectively show the luminance-voltage characteristics, current efficiency-luminance characteristics, current density-voltage characteristics, power efficiency-luminance characteristics, and electroluminescence spectra of the light-emitting device G1 and the comparative light-emitting device G1. FIG. 36, FIG. 37, FIG. 38, FIG. 39, FIG. 40, and FIG. 41 respectively show the luminance-current density characteristics, current efficiency-luminance characteristics, current density-voltage characteristics, power efficiency-luminance characteristics, blue index-luminance characteristics, and electroluminescence spectra of the light-emitting device B2 and the comparative light-emitting device B2.

### <Characteristics of Light-Emitting Devices R1-a to R1-c and Comparative Light-Emitting Device R1>

Table 4 shows the main characteristics of the light-emitting devices R1-a to R1-c and the comparative light-emitting device R1 at a luminance of approximately 1000 cd/m². In this example, the luminance, CIE chromaticity, and electroluminescence spectra were measured at room temperature with a spectroradiometer (SR-UL1R, TOPCON TECHNOHOUSE CORPORATION).

TABLE 4

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting device R1-a | 6.6 | 0.063 | 1.6 | 0.69 | 0.30 | 68 | 33 |
| Light-emitting device R1-b | 6.4 | 0.051 | 1.3 | 0.70 | 0.30 | 69 | 34 |
| Light-emitting device R1-c | 6.4 | 0.049 | 1.2 | 0.69 | 0.31 | 70 | 35 |
| Comparative light-emitting | 6.8 | 0.066 | 1.7 | 0.69 | 0.30 | 68 | 31 |
| device R1 | | | | | | | |

FIGS. 26 to 30 and Table 4 reveal that red light emission with an electroluminescence spectrum peak wavelength of around 627 nm was obtained from any of the light-emitting devices R1-a to R1-c and the comparative light-emitting device R1. Although the light-emitting devices R1-a to R1-c and the comparative light-emitting device R1 have high current efficiency, FIG. 28 shows that the light-emitting devices R1-a to R1-c have favorable characteristics with a lower driving voltage and lower power consumption than the comparative light-emitting device R1. This indicates that the light-emitting devices R1-a to R1-c are tandem light-emitting devices with favorable characteristics. It is thus found that when an organic compound including deuterium is used as at least one of the first host material and the second host material and an organic compound having a triazine skeleton is used in the second electron-transport layer, the light-emitting device can have favorable characteristics with a lower driving voltage and lower power consumption.

FIG. 28 also demonstrates that among the light-emitting devices R1-a to R1-c, the light-emitting device R1-a has the lowest driving voltage and lowest power consumption. This indicates that the driving voltage is lower in the case where the organic compounds including deuterium are used as both the first host material and the second host material than in the case where the organic compound including deuterium is used as only either the first host material or the second host material.

Here, 8mpTP-4mDBtPBfpm is an organic compound in which the deuteriums of 8mpTP-4mDBtPBfpm-d₁₃ are replaced with protium, and βNCCP is an organic compound in which the deuteriums of βNCCP-d₂₆ are replaced with protium.

FIG. 42 shows the measured emission spectra of an evaporated film of 8mpTP-4mDBtPBfpm-d₁₃, an evaporated film of βNCCP-d₂₆, and a film (mixed film) in which 8mpTP-4mDBtPBfpm-d₁₃ and βNCCP-d₂₆ were deposited by co-evaporation at a weight ratio of 1:1. The emission spectrum of the co-evaporated film shifts to the longer wavelength side than the emission spectra of the organic compounds, indicating that a combination of 8mpTP-4mDBtPBfpm-d₁₃ and βNCCP-d₂₆ forms an exciplex. Note that a combination of 8mpTP-4mDBtPBfpm and βNCCP-d₂₆ and a combination of 8mpTP-4mDBtPBfpm-d₁₃ and βNCCP similarly form an exciplex.

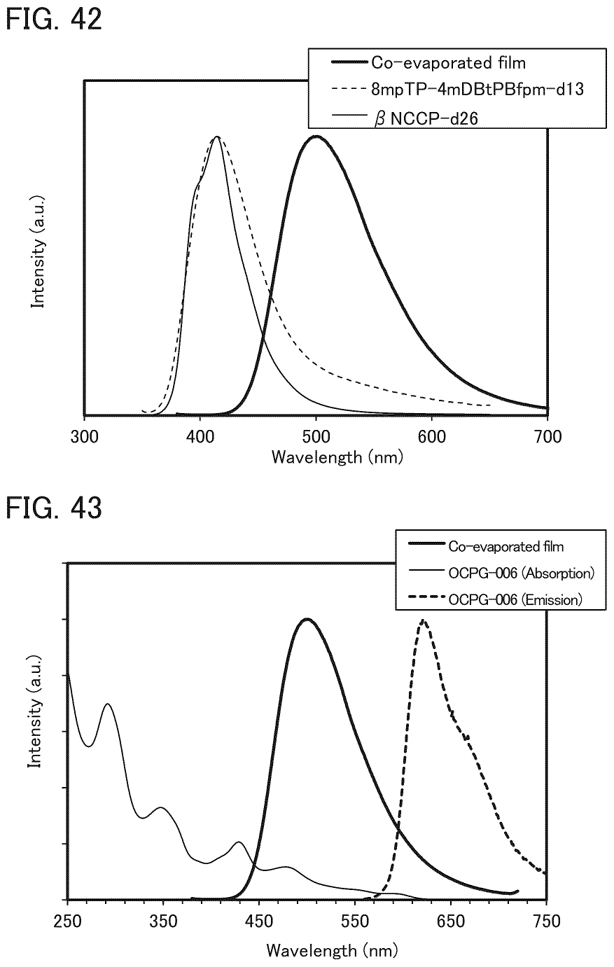

FIG. 43 shows the PL spectrum of a film (mixed film) in which 8mpTP-4mDBtPBfpm-d₁₃ and βNCCP-d₂₆ were deposited by co-evaporation at a weight ratio of 1:1 (the PL spectrum of the exciplex), and the absorption spectrum and PL spectrum of OCPG-006, which is an emission center substance. As can be seen from FIG. 43, the emission edge (442 nm) on the shorter wavelength side of the PL spectrum of the exciplex of 8mpTP-4mDBtPBfpm-d₁₃ and βNCCP-d₂₆ is positioned at a shorter wavelength than the absorption edge (622 nm) on the longer wavelength side of the absorption spectrum of OCPG-006. When the PL spectrum of the exciplex of 8mpTP-4mDBtPBfpm-d₁₃ and βNCCP-d₂₆ and the absorption edge of OCPG-006 in the light-emitting layer of the light-emitting device R1-c have such a positional relation, excitation energy can be efficiently transferred to OCPG-006. Furthermore, the emission edge on the shorter wavelength side of the PL spectrum of each of the exciplex formed by 8mpTP-4mDBtPBfpm and βNCCP-d₂₆ and the exciplex formed by 8mpTP-4mDBtPBfpm-d₁₃ and βNCCP satisfies a similar positional relation; thus, excitation energy can be efficiently transferred to OCPG-006 also in the light-emitting layers of the light-emitting devices R1-a and R1-b.

Note that the PL spectrum of the exciplex was measured using the co-evaporated film of 8mpTP-4mDBtPBfpm-d₁₃ and βNCCP-d₂₆. The PL spectrum and absorption spectrum of OCPG-006 were measured with a solution of OCPG-006 using dichloromethane as a solvent.

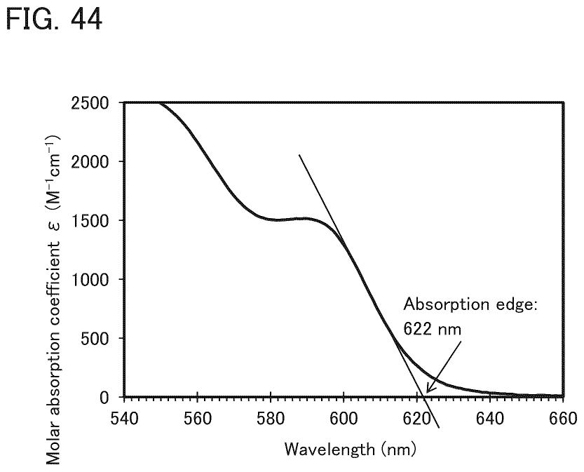

The absorption edge on a longer wavelength side of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum was determined as the intersection of a tangent and the horizontal axis or the baseline. The tangent was drawn at which the slope on a shorter wavelength side of the shortest-wavelength peak (or the shortest-wavelength shoulder peak) of the PL spectrum has the maximum value. FIG. 44 shows an example of determining the absorption edge on the longer wavelength side of the absorption spectrum of OCPG-006. The absorption edge of OCPG-006 can be thus determined to be 622 nm.

The HOMO level of βNCCP-d₂₆, which is an organic compound having a hole-transport property, was −5.60 eV. The HOMO level of βNCCP was −5.62 eV. The HOMO level of 8mpTP-4mDBtPBfpm-d₁₃, which is an organic compound having an electron-transport property, was −6.3 eV (a reference value). The HOMO level of 8mpTP-4mDBtPBfpm was −6.2 eV (a reference value). The LUMO level of βNCCP-d₂₆ was −2.19 eV. The LUMO level of βNCCP was −2.21 eV. The LUMO level of 8mpTP-4mDBtPBfpm-d₁₃ was −3.01 eV. The LUMO level of 8mpTP-4mDBtPBfpm was −3.01 eV.

Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property as described above, the light-emitting devices R1-a to R1-c were found to have a structure capable of efficiently forming an exciplex.

The HOMO level and the LUMO level were obtained through a cyclic voltammetry (CV) measurement. In the cyclic voltammetry (CV) measurement, the values (E) of HOMO and LUMO levels were calculated on the basis of an oxidation peak potential (Eₚₐ) and a reduction peak potential (E_{pc}), which were obtained by changing the potential of a working electrode with respect to a reference electrode. In the measurement, the HOMO level and the LUMO level were obtained by potential scanning in the positive direction and potential scanning in the negative direction, respectively. The scanning speed in the measurement was 0.1 V/sec. Specifically, a standard oxidation-reduction potential (Eₒ) (=(Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby the values (E) (=Eₓ−Eₒ) of HOMO and LUMO levels were obtained. Note that the reversible oxidation-reduction wave was obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

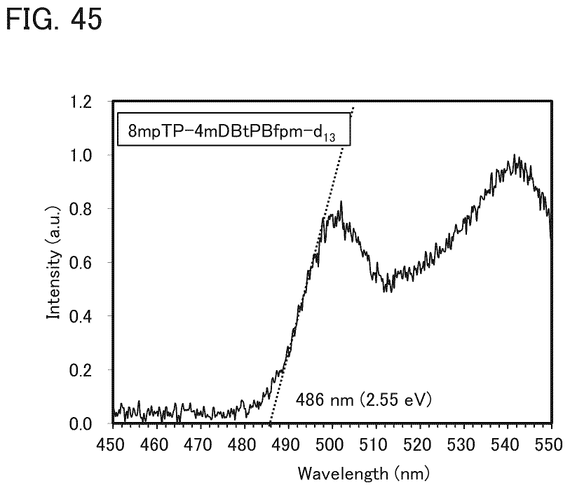

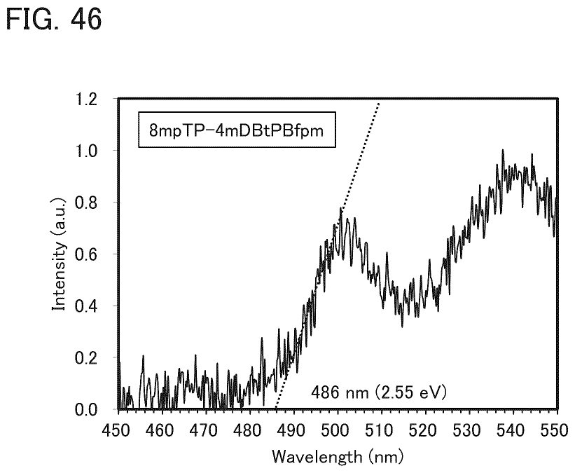

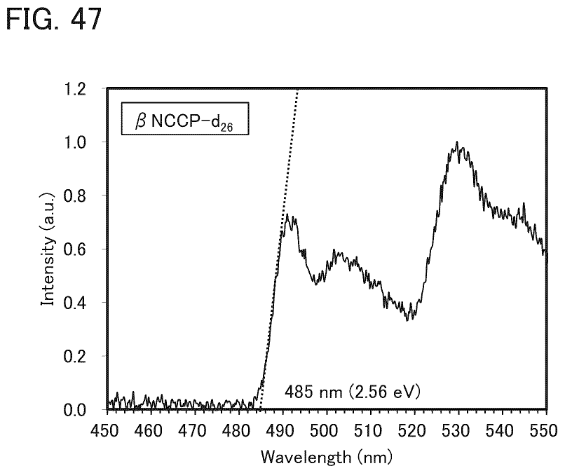

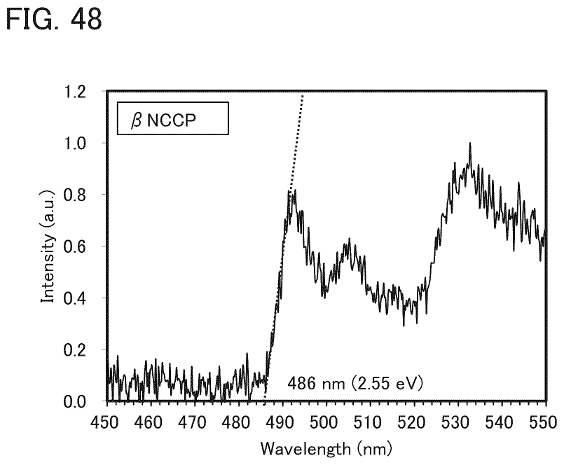

The T₁ levels of 8mpTP-4mDBtPBfpm-d₁₃, 8mpTP-4mDBtPBfpm, βNCCP-d₂₆, and βNCCP were measured. For calculation of the T₁ level, a thin film obtained by forming a 50-nm-thick sample over a quartz substrate was used and a PL emission spectrum (phosphorescence spectrum) was measured at a measurement temperature of 10 K. The measurement was performed with a PL microscope LabRAM HR-PL (produced by HORIBA, Ltd.) and a He—Cd laser (325 nm) as excitation light. Note that the emission edge was determined as the intersection of a tangent and the horizontal axis (representing wavelength) or the baseline. As shown in FIGS. 45 to 48, the tangent is drawn to have the maximum slope at a point on the shorter wavelength side of the shortest-wavelength peak (or the shortest-wavelength shoulder peak) of the emission spectrum (phosphorescence spectrum). The T₁ levels of the organic compounds are shown below. As a result of the measurement, the T₁ level of 8mpTP-4mDBtPBfpm-d₁₃ was 2.55 eV, the T₁ level of 8mpTP-4mDBtPBfpm was 2.55 eV, the T₁ level of βNCCP-d₂₆ was 2.56 eV, and the T₁ level of βNCCP was 2.55 eV. As described above, in the light-emitting devices R1-a to R1-c in which one or both of the first host material and the second host material are deuterated, the difference in the T₁ level between the first host material and the second host material is 0.20 eV or less, and the efficiency of energy transfer from the triplet excited state is improved by the influence of deuterium; thus, deterioration of the first host material and the second host material can be inhibited.

The phosphorescence lifetimes of βNCCP, βNCCP-d₂₆, 8mpTP-4mDBtPBfpm, and 8mpTP-4mDBtPBfpm-d₁₃ and the rate of change in phosphorescence lifetime owing to deuteration are shown below. Note that the excitation wavelength of βNCCP and βNCCP-d₂₆ was 330 nm and the measured wavelength was 515 nm. The excitation wavelength of 8mpTP-4mDBtPBfpm and 8mpTP-4mDBtPBfpm-d₁₃ was 320 nm and the measured wavelength was 515 nm. The results show that the phosphorescence lifetime of 8mpTP-4mDBtPBfpm-d₁₃ is 1.80 times that of 8mpTP-4mDBtPBfpm, and the phosphorescence lifetime of βNCCP-d₂₆ is 3.18 times that of βNCCP. That is, the phosphorescence lifetime of 8mpTP-4mDBtPBfpm-d₁₃ was 1.50 times or more that of 8mpTP-4mDBtPBfpm, and the phosphorescence lifetime of βNCCP-d₂₆ was 3.00 times or more that of βNCCP. It was thus found that in the light-emitting devices R1-a to R1-c, deuterium included in one or both of the first host material and the second host material inhibits intramolecular vibration of the deuterated organic compound in the T₁ state and inhibits nonradiative transition from the T₁ state to a more stable state; hence, the efficiency of energy transfer to the phosphorescent substance is improved to achieve high reliability.

TABLE 5

| | Phosphorescence | |
|---|---|---|
| | lifetime (sec) | Rate |
| 8mpTP-4mDBtPBfpm | 2.98 | 1.80 |
| 8mpTP-4mDBtPBfpm-d₁₃ | 5.35 | |
| βNCCP | 1.63 | 3.18 |
| βNCCP-d₂₆ | 5.18 | |

The phosphorescence lifetime was defined as follows: the time at which the light amount becomes 50% of that at the start of the measurement in the measured data was set as t=0 as shown in FIG. 25, and the time taken for the light amount to attenuate to 1/e that at t=0 was regarded as the phosphorescence lifetime. In the graphs in FIG. 25, the time at which the intensity reaches 50% of that at the start of the measurement in the measured data is set as the time 0 s, the light amount at 0 s is regarded as 1, and the time taken for the light amount to become 1/e that at 0 s is the phosphorescence lifetime.

The measurement was performed at liquid nitrogen temperature (77 K) with FP-8600 produced by JASCO Corporation, in which a liquid nitrogen cooling unit PMU-830 was set. A solution of a material was prepared in a glove box of LABstarM13 (1250/780) produced by MBRAUN in the following manner: a sample was dissolved in 2-MeTHF that had been subjected to freeze-pump-thaw, and the concentration of the solution was adjusted to approximately 1.2 E⁻⁴ M.

The prepared solution was put in a liquid sample cell (sample tube) LPH-140 for cooling produced by JASCO Corporation, the sample cell was put in a sample cell holder, and the sample cell holder was capped with a fixing nut. After liquid nitrogen was injected into a Dewar condenser of the cooling unit of FP-8600, the sample cell was taken out from the globe box and then cooled in the Dewar condenser filled with the liquid nitrogen in the instrument.

Time-resolved measurement was performed in the following manner: the sample cell was irradiated with excitation light for approximately 30 seconds and the emission intensity attenuating after the excitation light was blocked by a shutter was measured at 10 ms intervals. For use in the phosphorescence lifetime measurement, the wavelength including as little fluorescence as possible was selected after comparison between an emission spectrum in the phosphorescence mode and an emission spectrum in the fluorescence mode. The excitation wavelength used for the measurement can be appropriately selected, and is preferably 330 nm. The band widths of the excitation light and the measured light are each approximately 10 nm. Since light emission ideally attenuates single-exponentially, the time taken for the emission intensity to attenuate to 1/e with reference to the time at which the light amount becomes 50% of that at the beginning of the measurement can be defined as the phosphorescence lifetime.

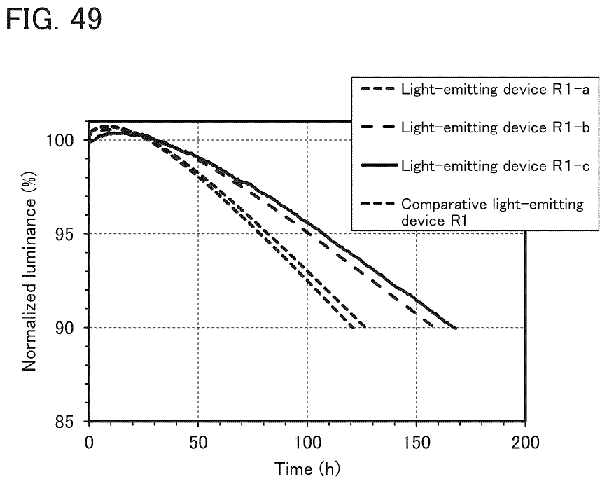

FIG. 49 shows the time dependence of normalized luminance of the light-emitting devices R1-a to R1-c and the comparative light-emitting device R1 at a current density of 75 mA/cm².

FIG. 49 demonstrates that the light-emitting devices R1-a to R1-c have a smaller time-dependent change in normalized luminance than the comparative light-emitting device R1, and the light-emitting device R1-c in particular has the smallest time-dependent change in normalized luminance and thus has high reliability.

### <Characteristics of Light-Emitting Device G1 and Comparative Light-Emitting Device G1>

Table 6 shows the main characteristics of the light-emitting device G1 and the comparative light-emitting device G1 at a luminance of approximately 1000 cd/m².

TABLE 6

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting | 5.4 | 0.020 | 0.49 | 0.23 | 0.73 | 227 | 132 |
| device G1 | | | | | | | |
| Comparative | 5.4 | 0.016 | 0.41 | 0.23 | 0.73 | 228 | 132 |
| light-emitting | | | | | | | |
| device G1 | | | | | | | |

FIGS. 31 to 35 and Table 6 reveal that green light emission with an electroluminescence spectrum peak wavelength of 527 nm was obtained from both the light-emitting device G1 and the comparative light-emitting device G1. Although both the light-emitting device G1 and the comparative light-emitting device G1 have high current efficiency, the light-emitting device G1 has higher current efficiency in a high-luminance region. Moreover, the light-emitting device G1 was found to have favorable characteristics with a lower driving voltage and lower power consumption than the comparative light-emitting device G1. This indicates that the light-emitting device G1 is a tandem light-emitting device with favorable characteristics. It was thus found that the use of the organic compound having a triazine skeleton for the second electron-transport layer enables the light-emitting device to have favorable characteristics with a lower driving voltage and lower power consumption.

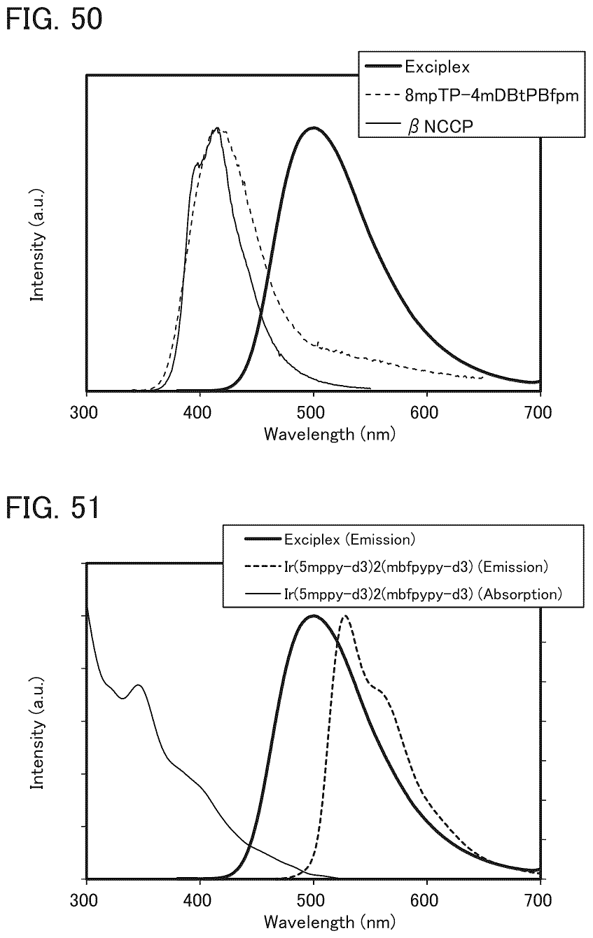

FIG. 50 shows the measured PL spectra of an evaporated film of 8mpTP-4mDBtPBfpm, an evaporated film of βNCCP, and a film (mixed film) in which 8mpTP-4mDBtPBfpm and βNCCP were deposited by co-evaporation at a weight ratio of 1:1. The PL spectrum of the co-evaporated film is shifted to the longer wavelength side than the PL spectra of the organic compounds as shown in the graph, demonstrating that a combination of 8mpTP-4mDBtPBfpm and βNCCP forms an exciplex.

FIG. 51 shows the PL spectrum of a film (mixed film) in which 8mpTP-4mDBtPBfpm and βNCCP were deposited by co-evaporation at a weight ratio of 1:1 (the PL spectrum of the exciplex), and the absorption spectrum and PL spectrum of Ir(5mppy-d₃)₂(mbfpypy-d₃), which is an emission center substance.

As can be seen from FIG. 51, the emission edge (442 nm) on the shorter wavelength side of the PL spectrum of the exciplex of 8mpTP-4mDBtPBfpm and βNCCP is positioned at a shorter wavelength than the absorption edge (526 nm) on the longer wavelength side of the absorption spectrum of Ir(5mppy-d₃)₂(mbfpypy-d₃). When the PL spectrum of the exciplex of 8mpTP-4mDBtPBfpm and βNCCP and the absorption edge of Ir(5mppy-d₃)₂(mbfpypy-d₃) have such a positional relation, excitation energy can be efficiently transferred to Ir(5mppy-d₃)₂(mbfpypy-d₃) in the light-emitting device G1.

The energy (2.48 eV) at the peak wavelength (500 nm) of the PL spectrum of the exciplex formed by 8mpTP-4mDBtPBfpm and βNCCP is higher than the energy (2.35 eV) at the peak wavelength (528 nm) of the PL spectrum of Ir(5mppy-d₃)₂(mbfpypy-d₃). The difference between the energy of the peak of the PL spectrum of the exciplex and the energy of the peak of the PL spectrum of Ir(5mppy-d₃)₂(mbfpypy-d₃) is less than or equal to 0.20 eV. Such a relation between the energy of the peak of the PL spectrum of the exciplex and the energy of the peak of the PL spectrum of Ir(5mppy-d₃)₂(mbfpypy-d₃) enables efficient transfer of excitation energy to Ir(5mppy-d₃)₂(mbfpypy-d₃) in the light-emitting device G1.

The difference between the energy (2.48 eV) at the peak wavelength (500 nm) of the PL spectrum of the exciplex formed by 8mpTP-4mDBtPBfpm and βNCCP and the energy (2.36 eV) at the wavelength (526 nm) of the absorption edge on the longer wavelength side of the absorption spectrum of Ir(5mppy-d₃)₂(mbfpypy-d₃) is less than or equal to 0.20 eV. Such a relation between the energy of the peak of the PL spectrum of the exciplex and the energy of the absorption edge on the longer wavelength side of the absorption spectrum of Ir(5mppy-d₃)₂(mbfpypy-d₃) enables efficient transfer of excitation energy to Ir(5mppy-d₃)₂(mbfpypy-d₃) in the light-emitting device G1.

Note that the PL spectrum of the exciplex was measured using the co-evaporated film of 8mpTP-4mDBtPBfpm and βNCCP. The PL spectrum and absorption spectrum of Ir(5mppy-d₃)₂(mbfpypy-d₃) were measured with a solution of Ir(5mppy-d₃)₂(mbfpypy-d₃) using chloroform as a solvent.

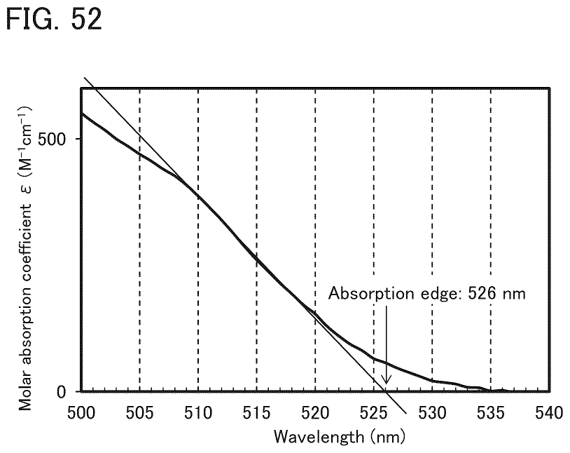

The absorption edge of the absorption spectrum was determined as the intersection between a tangent and the horizontal axis or the baseline. The tangent was drawn to have the maximum slope at a point on the longer wavelength side of the longest-wavelength peak (or the longest-wavelength shoulder peak) of the absorption spectrum. The emission edge on a shorter wavelength side of the PL spectrum was determined as the intersection of a tangent and the horizontal axis or the baseline. The tangent was drawn at which the slope on a shorter wavelength side of the shortest-wavelength peak (or the shortest-wavelength shoulder peak) of the PL spectrum has the maximum value. FIG. 52 shows an example of obtaining the absorption edge of the absorption spectrum of Ir(5mppy-d₃)₂(mbfpypy-d₃). The absorption edge of Ir(5mppy-d₃)₂(mbfpypy-d₃) can be thus determined to be 526 nm.

As described above, the HOMO level of βNCCP, which is an organic compound having a hole-transport property, was −5.62 eV; the HOMO level of 8mpTP-4mDBtPBfpm, which is an organic compound having an electron-transport property, was −6.2 eV (a reference value); the LUMO level of βNCCP was −2.21 eV; and the LUMO level of 8mpTP-4mDBtPBfpm was −3.01 eV. Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device G1 was found to have a structure in which an exciplex can be formed more efficiently.

The HOMO level and the LUMO level of Ir(5mppy-d₃)₂(mbfpypy-d₃) were −5.32 eV and −2.39 eV, respectively. The energy difference between the HOMO level and the LUMO level of the exciplex was 2.61 eV corresponding to the energy difference between the HOMO level (−5.62 eV) of βNCCP, which is the organic compound having a hole-transport property, and the LUMO level (−3.01 eV) of 8mpTP-4mDBtPBfpm, which is the organic compound having an electron-transport property. The energy difference (2.93 eV) between the HOMO level (−5.32 eV) and the LUMO level (−2.39 eV) corresponding to the band gap of Ir(5mppy-d₃)₂(mbfpypy-d₃) was found to be larger than the energy difference between the HOMO level and the LUMO level of the exciplex. Note that the values of the HOMO level and the LUMO level were obtained in a manner similar to the above method.

### <Characteristics of Light-Emitting Device B1 and Comparative Light-Emitting Device B1>

Table 7 shows the main characteristics of the light-emitting device B1 and the comparative light-emitting device B1 at a luminance of approximately 1000 cd/m².

TABLE 7

| | | | Current | | | Current | Power | |
|---|---|---|---|---|---|---|---|---|
| | Voltage | Current | density | Chromaticity | Chromaticity | efficiency | efficiency | BI |
| | (V) | (mA) | (mA/cm²) | x | y | (cd/A) | (lm/W) | (cd/A/y) |
| Light-emitting | 7.6 | 0.39 | 9.9 | 0.15 | 0.04 | 9.0 | 3.7 | 216 |
| device B1 | | | | | | | | |
| Comparative | 8.2 | 0.46 | 11.6 | 0.15 | 0.04 | 8.5 | 3.3 | 202 |
| light-emitting | | | | | | | | |
| device B1 | | | | | | | | |

FIGS. 36 to 41 and Table 7 reveal that blue light emission with an electroluminescence spectrum peak wavelength of 455 nm was obtained from both the light-emitting device B1 and the comparative light-emitting device B1. Although both the light-emitting device B1 and the comparative light-emitting device B1 have high current efficiency, the light-emitting device B1 has favorable characteristics with lower power consumption because of its lower driving voltage than the comparative light-emitting device B1. The light-emitting device B1 was found to have a high blue index. This indicates that the light-emitting device B1 is a tandem light-emitting device with favorable characteristics. In addition, the light-emitting device B1 has especially favorable characteristics particularly at a practical luminance of 500 cd/cm² or higher. It was thus found that the use of the organic compound having a triazine skeleton for the second electron-transport layer enables the light-emitting device to have favorable characteristics with a lower driving voltage and lower power consumption.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, the BI, which is current efficiency based on a y chromaticity value as one of the indicators of color purity of blue, is suitably used as a means for showing efficiency of blue light emission in some cases. The light-emitting device with a higher BI can be regarded as a blue-light-emitting device having higher efficiency for a display.

Here, the second electron-transport layers of the light-emitting devices R1-a to R1-c, G1, and B1 include the same material (the first organic compound having a triazine skeleton). Thus, the light-emitting devices of different emission colors can each have favorable characteristics even when the second electron-transport layers of the light-emitting devices are made of the same material.

### (Power Consumption Estimation 1)

Assuming that a display apparatus 1-a of this example includes the light-emitting devices R1-a, G1, and B1 respectively in red, green, and blue subpixels; a display apparatus 1-b of this example includes the light-emitting devices R1-b, G1, and B1 respectively in red, green, and blue subpixels; a display apparatus 1-c of this example includes the light-emitting devices R1-c, G1, and B1 respectively in red, green, and blue subpixels; and a comparative display apparatus 1 includes the comparative light-emitting devices R1, G1, and B1 respectively in red, green, and blue subpixels, the power consumption of their display portions (except for power consumption of driving transistors, driver circuits, and the like) was estimated. Note that each of the light-emitting devices assumed to be used in the display apparatuses is a tandem light-emitting device, and the same emission center substance is used in the plurality of light-emitting layers in each of the light-emitting devices. Thus, the display apparatuses are side-by-side display apparatuses.

The conditions of the display apparatuses assumed for the estimation are as follows.

TABLE 8

| | |
|---|---|
| Panel size | 5 inches (16:9) |
| Panel area | 68.9 cm² |
| Aperture ratio | 30% |
| Effective luminance | Full white 1000 cd/m² |
| Circular polarizing plate | w/o |

First, in each of the display apparatuses under the above-described conditions, the luminance (effective luminance) of the light-emitting devices of RGB to obtain 1000 cd/m² emission of white light with CIE 1931 chromaticity coordinates (x, y)=(0.31, 0.33) when the display apparatus is made to emit white light from the entire screen was calculated.

Next, the luminance (intrinsic luminance) required to obtain the calculated effective luminance of the light-emitting devices of RGB was calculated in consideration of aperture ratios that are different between the emission colors. Assuming that the aperture ratios of the red, green, and blue subpixels in the comparative display apparatus 1 were each 10%, the aperture ratios in the display apparatuses were estimated in consideration of the time dependence of normalized luminance of the light-emitting devices shown in FIG. 49.

As shown in the following table, for the light-emitting devices R1-a to R1-c, an increase rate A of LT₉₅ (the time at which the luminance decreases by 5% from the initial 100%) relative to LT₉₅ of the comparative light-emitting device R1 was obtained from the results in FIG. 49; a rate B of current with which the same LT₉₅ reliability as the comparative light-emitting device R1 was obtained given that LT₉₅ is inversely proportional to the 1.7th power of the initial luminance; and a ratio C of the aperture ratio of the red subpixel having the same reliability as the comparative light-emitting device R1 was obtained by calculating the reciprocal of B. The aperture ratio of each emission color was obtained using this value.

TABLE 9

| | LT₉₅ (h) | A | B | C |
|---|---|---|---|---|
| Light-emitting device R1-a | 82 | 1.04 | 1.08 | 0.929 |
| Light-emitting device R1-b | 101 | 1.29 | 1.53 | 0.652 |
| Light-emitting device R1-c | 108 | 1.38 | 1.72 | 0.581 |
| Comparative light-emitting | 79 | — | — | — |
| device R1 | | | | |

The intrinsic luminance is the luminance at which each light-emitting device actually emits light in order to obtain the effective luminance of 1000 cd/m² when the display apparatus is made to emit white light with CIE 1931 chromaticity coordinates (x, y)=(0.31, 0.33) from the entire screen. In the case where the total aperture ratio is 30% and the aperture ratio of each emission color is 10%, the intrinsic luminance is approximately ten times the effective luminance.

From the measurement results of the light-emitting devices described above and the intrinsic luminance, the current density and voltage for making each light-emitting device emit light at the intrinsic luminance can be obtained. In other words, in each of the display apparatuses under the above-described conditions, the current density and voltage of each light-emitting device to obtain 1000 cd/m² luminance emission of white light with CIE 1931 chromaticity coordinates (x, y)=(0.31, 0.33) when the display apparatus is made to emit white light from the entire screen can be obtained.

The power consumption is calculated by multiplying the amount of current by the voltage. The amount of current is calculated by multiplying the current density, the panel area, and the aperture ratio. The amount of current can be calculated by multiplying the current density calculated in the previous paragraph by 68.9 cm², the panel area of the estimated display apparatus (a diagonal size of 5 inches and an aspect ratio of 16:9), and the aperture ratio of each emission color, and moreover, the power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display apparatus (except for the power consumption of driving transistors, driver circuits, and the like) can be obtained.

Tables 10 to 13 show the aperture ratio of each emission color for calculating power consumption and the calculated power consumption of the display apparatuses 1-a, 1-b, and 1-c, and the comparative display apparatus 1, respectively.

TABLE 10
Display apparatus 1-a

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m² | (cd/A) | (mA/cm²) | (mA) | (V) | (mW) |
| Red | 9.5 | 0.69 | 0.30 | 240 | 2516 | 64.9 | 3.9 | 25.4 | 7.29 | 185.5 |
| Green | 10.2 | 0.22 | 0.73 | 707 | 6903 | 215.6 | 3.2 | 22.6 | 6.25 | 141.1 |
| Blue | 10.2 | 0.15 | 0.04 | 54 | 524 | 8.9 | 5.9 | 41.5 | 7.41 | 307.8 |
| Full white | — | 0.31 | 0.33 | 1000 | — | 76.9 | — | 89.6 | — | 634.4 |

TABLE 11
Display apparatus 1-b

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 7.4 | 0.70 | 0.30 | 239 | 3248 | 63.5 | 5.1 | 25.9 | 7.44 | 193.1 |
| Green | 11.3 | 0.22 | 0.73 | 707 | 6248 | 216.6 | 2.9 | 22.5 | 6.18 | 139.2 |
| Blue | 11.3 | 0.15 | 0.04 | 54 | 474 | 8.9 | 5.3 | 41.7 | 7.37 | 307.4 |
| Full white | — | 0.31 | 0.33 | 1000 | — | 76.4 | — | 90.2 | — | 639.7 |

TABLE 12
Display apparatus 1-c

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 6.7 | 0.69 | 0.31 | 241 | 3571 | 64.3 | 5.6 | 25.8 | 7.53 | 194.4 |
| Green | 11.6 | 0.22 | 0.73 | 705 | 6067 | 216.9 | 2.8 | 22.4 | 6.17 | 138.2 |
| Blue | 11.6 | 0.15 | 0.04 | 54 | 462 | 8.9 | 5.2 | 41.8 | 7.36 | 307.4 |
| Full white | — | 0.31 | 0.33 | 1000 | — | 76.6 | — | 90.0 | — | 640.0 |

TABLE 13
Comparative display apparatus 1

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.30 | 238 | 2384 | 64.9 | 3.7 | 25.3 | 7.52 | 190.2 |
| Green | 10.0 | 0.23 | 0.73 | 707 | 7073 | 215.5 | 3.3 | 22.6 | 6.56 | 148.4 |
| Blue | 10.0 | 0.15 | 0.04 | 54 | 543 | 8.5 | 6.4 | 43.9 | 7.84 | 344.5 |
| Full white | — | 0.31 | 0.33 | 1000 | — | 75.0 | — | 91.9 | — | 683.1 |

Tables 10 to 13 demonstrate that the display apparatuses 1-a to 1-c each have higher current efficiency in white light emission and a lower driving voltage than the comparative display apparatus 1. Tables 10 to 13 also demonstrate that the display apparatuses 1-a to 1-c each have lower power consumption than the comparative display apparatus 1.

As shown in Tables 10 to 13, when the aperture ratio of each emission color was estimated in consideration of the time dependence of normalized luminance of the light-emitting devices, the aperture ratio of the red subpixel in each of the display apparatuses 1-a to 1-c was lower than the aperture ratio of the red subpixel in the comparative display apparatus 1, and the aperture ratios of the green subpixel and the blue subpixel in each of the display apparatuses 1-a to 1-c were higher than the aperture ratios of the green subpixel and the blue subpixel in the comparative display apparatus 1. The current densities required for the green subpixel and the blue subpixel in each of the display apparatuses 1-a to 1-c were lower than the current densities required for the green subpixel and the blue subpixel in the comparative display apparatus 1. In each of the display apparatuses 1-a to 1-c, the aperture ratio of the red subpixel was lower than the aperture ratios of the blue subpixel and the green subpixel.

These results show that the use of the light-emitting devices 1R-a to 1R-c each having a smaller time dependence of normalized luminance for a red subpixel enables the aperture ratio of the red subpixel to be further reduced. Accordingly, the aperture ratios of the green subpixel and the blue subpixel can be further increased, and the current densities required for light emission of the green and blue light-emitting devices can be further reduced, demonstrating that the reliability is increased as a whole.

### Example 2

This example will describe specific manufacturing methods and characteristics of light-emitting devices R2, G2, and B2 that can be used in the display apparatus of one embodiment of the present invention and comparative light-emitting devices R2, G2, and B2. Moreover, the description will be made on estimation of power consumption of display apparatuses of embodiments of the present invention including these light-emitting devices. Structural formulae of main compounds used in the light-emitting devices are the same as those in Example 1.

### (Method 2 for Manufacturing Light-Emitting Devices)

A method for manufacturing the light-emitting devices used in this example is described.

### <Methods for Manufacturing Light-Emitting Device R2 and Comparative Light-Emitting Device R2>

The methods for manufacturing the light-emitting device R2 and the comparative light-emitting device R2 are the same as the respective methods for manufacturing the light-emitting device R1-c and the comparative light-emitting device R1 described in Example 1.

### <Method for Manufacturing Light-Emitting Device G2>

The light-emitting device G2 was manufactured in the same manner as the light-emitting device R1-a described in Example 1 except that the thickness of the first hole-transport layer was 80 nm, the thickness of the second hole-transport layer was 50 nm, and the first light-emitting layer and the second light-emitting layer were each deposited by co-evaporation of 8mpTP-4mDBtPBfpm-d₁₃, βNCCP-d₂₆, and Ir(5mppy-d₃)₂(mbfpypy-d₃) at a weight ratio of 0.5:0.5:0.1.

### <Method for Manufacturing Comparative Light-Emitting Device G2>

The comparative light-emitting device G2 was manufactured in the same manner as the light-emitting device G2 except that TznP2N in the second electron-transport layer was replaced with 6BP-4Cz2PPm, 8mpTP-4mDBtPBfpm-d₁₃ was replaced with 8mpTP-4mDBtPBfpm, and βNCCP-d₂₆ was replaced with βNCCP.

### <Methods for Manufacturing Light-Emitting Device B2 and Comparative Light-Emitting Device B2>

The methods for manufacturing the light-emitting device B2 and the comparative light-emitting device B2 are the same as the respective methods for manufacturing the light-emitting device B1 and the comparative light-emitting device B1 described in Example 1.

Tables 14 to 16 show the device structures of the light-emitting devices R2, G2, and B2 and the comparative light-emitting R2, G2, and B2.

TABLE 14

| | | Thickness | Light-emitting | Comparative light- |
|---|---|---|---|---|
| | | (nm) | device R2 | emitting device R2 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | | |
|---|---|---|
| a | 10 | mFBPTzn |

| | | | |
|---|---|---|---|
| Second light-emitting layer | 40 | 8mpTP- | 8mpTP- |

| | |
|---|---|
| 4mDBtPBfpm-d₁₃:βNCCP- | 4mDBtPBfpm:βNCCP:OCPG- |
| d₂₆:OCPG-006 | 006 |
| (0.4:0.6:0.05) | (0.4:0.6:0.05) |

| Second hole-transport layer | | 75 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | 10 | mPCCzPTzn-02 | |
|---|---|---|---|
| First light-emitting layer | 40 | 8mpTP- | 8mpTP- |

| | |
|---|---|
| 4mDBtPBfpm-d₁₃:βNCCP- | 4mDBtPBfpm:βNCCP:OCPG- |
| d₂₆:OCPG-006 | 006 |
| (0.4:0.6:0.05) | (0.4:0.6:0.05) |

| First hole-transport layer | | 140 | oFBiSF(2) |
|---|---|---|---|
| First hole-injection layer | | 10 | oFBiSF(2):OCHD-003 (1:0.03) |
| First | 2 | 85 | ITSO |
| electrode | 1 | 100 | Ag |

TABLE 15

| | | Thickness | Light-emitting | Comparative light- |
|---|---|---|---|---|
| | | (nm) | device G2 | emitting device G2 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | | |
|---|---|---|
| a | 10 | mFBPTzn |

| | | | |
|---|---|---|---|
| Second light-emitting layer | 40 | 8mpTP- | 8mpTP- |

| | |
|---|---|
| 4mDBtPBfpm-d₁₃:βNCCP- | 4mDBtPBfpm:βNCCP:Ir(5mppy- |
| d₂₆:Ir(5mppy- | d₃)₂(mbfpypy-d₃) |
| d₃)₂(mbfpypy-d₃) | (0.5:0.5:0.1) |
| (0.5:0.5:0.1) | |

| Second hole-transport layer | | 50 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | 10 | mPCCzPTzn-02 | |
|---|---|---|---|
| First light-emitting layer | 40 | 8mpTP- | 8mpTP- |

| | |
|---|---|
| 4mDBtPBfpm-d₁₃:βNCCP- | 4mDBtPBfpm:βNCCP:Ir(5mppy- |
| d₂₆:Ir(5mppy- | d₃)₂(mbfpypy-d₃) |
| d₃)₂(mbfpypy-d₃) | (0.5:0.5:0.1) |
| (0.5:0.5:0.1) | |

| First hole-transport layer | | 80 | oFBiSF(2) |
|---|---|---|---|
| First hole-injection layer | | 10 | oFBiSF(2):OCHD-003 (1:0.03) |
| First | 2 | 85 | ITSO |
| electrode | 1 | 100 | Ag |

TABLE 16

| | | Thickness | Light-emitting | Comparative light- |
|---|---|---|---|---|
| | | (nm) | device B2 | emitting device B2 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | a | 10 | mFBPTzn |
|---|---|---|---|
| Second light- | | 25 | αN-βNPAnth:3,10PCA2Nbf(IV)-02 |
| emitting layer | | | (1:0.015) |
| Second hole- | b | 10 | DBfBB1TP |
| transport layer | a | 35 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |
| First electron-transport layer | | 10 | mPCCzPTzn-02 |
| First light-emitting layer | | 25 | αN-βNPAnth:3,10PCA2Nbf(IV)-02 |
| | | | (1:0.015) |
| First hole- | b | 10 | DBfBB1TP |
| transport layer | a | 35 | oFBiSF(2) |
| First hole-injection layer | | 10 | oFBiSF(2):OCHD-003 (1:0.03) |
| First | 2 | 85 | ITSO |
| electrode | 1 | 100 | Ag |

### (Characteristics 2 Of Light-Emitting Devices)

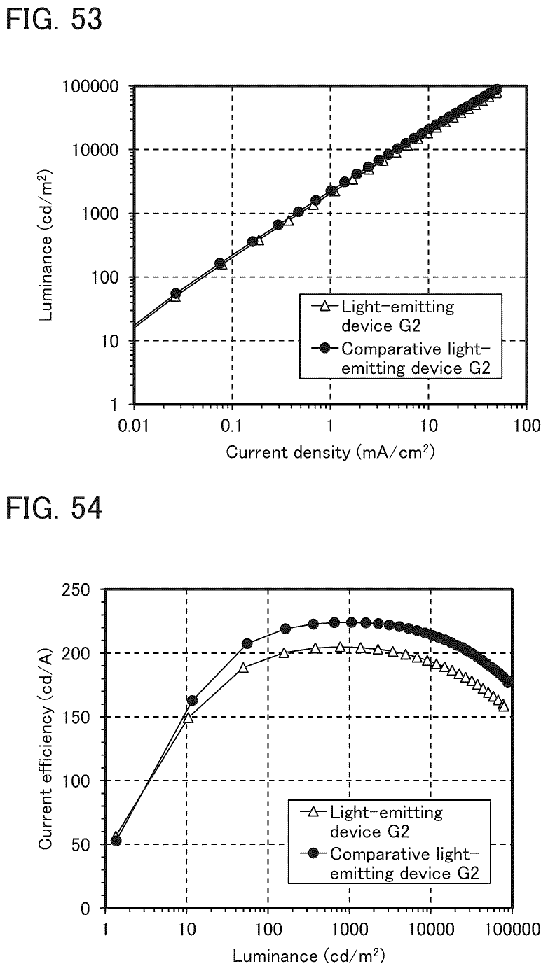

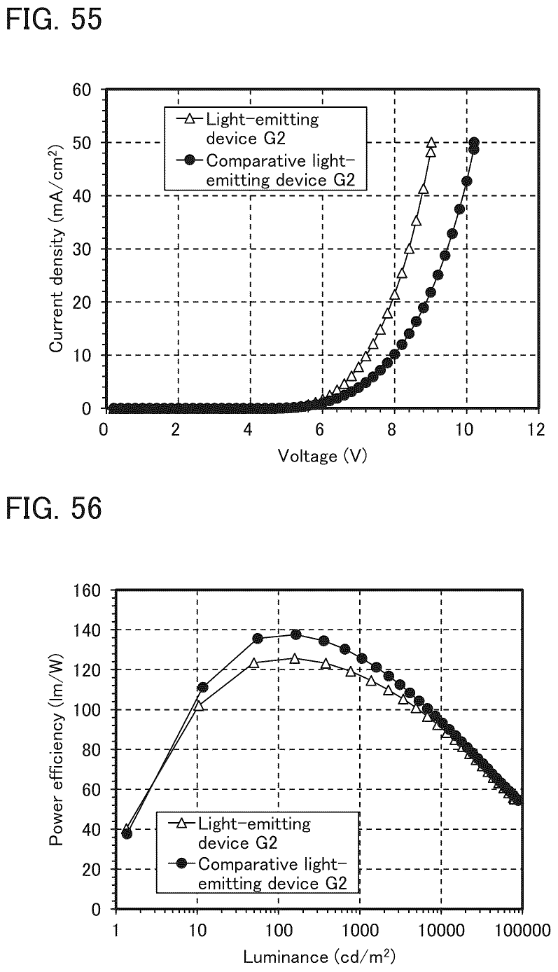

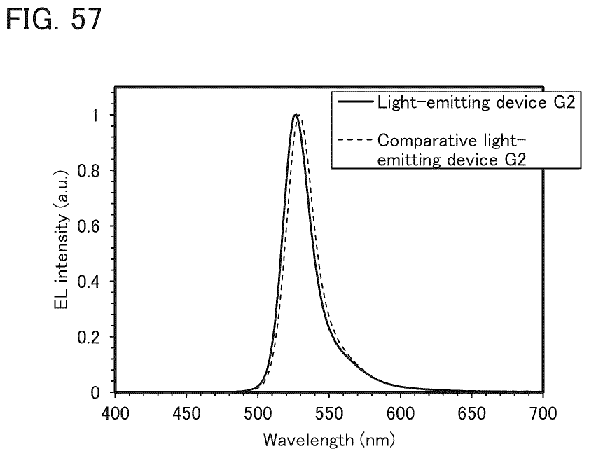

FIGS. 53, 54, 55, 56, and 57 respectively show the luminance-current density characteristics, current efficiency-luminance characteristics, current density-voltage characteristics, power efficiency-luminance characteristics, and electroluminescence spectra of the light-emitting device G2 and the comparative light-emitting device G2. Note that the characteristics of the light-emitting device R2 and the comparative light-emitting device R2 are the same as those of the light-emitting device R1-c and the comparative light-emitting device R1. The characteristics of the light-emitting device B2 and the comparative light-emitting device B2 are the same as those of the light-emitting device B1 and the comparative light-emitting device B1.

### <Characteristics of Light-Emitting Device G2 and Comparative Light-Emitting Device G2>

Table 17 shows the main characteristics of the light-emitting device G2 and the comparative light-emitting device G2 at a luminance of approximately 1000 cd/m². In this example, the luminance, CIE chromaticity, and electroluminescence spectra were measured at room temperature with a spectroradiometer (SR-UL1R, TOPCON TECHNOHOUSE CORPORATION).

TABLE 17

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting device G2 | 5.4 | 0.015 | 0.38 | 0.22 | 0.73 | 205 | 119 |
| Comparative light- | 5.6 | 0.019 | 0.47 | 0.23 | 0.73 | 224 | 126 |
| emitting device G2 | | | | | | | |

FIGS. 53 to 57 and Table 17 reveal that green light emission with an electroluminescence spectrum peak wavelength of around 527 nm was obtained from both the light-emitting device G2 and the comparative light-emitting device G2. This indicates that the light-emitting device G2 is a tandem light-emitting device with favorable characteristics. It is thus found that the use of the organic compound having a triazine skeleton for the second electron-transport layer enables the light-emitting device to have favorable characteristics with a lower driving voltage and lower power consumption.

As described in Example 1, 8mpTP-4mDBtPBfpm-d₁₃ and βNCCP-d₂₆ form an exciplex in combination.

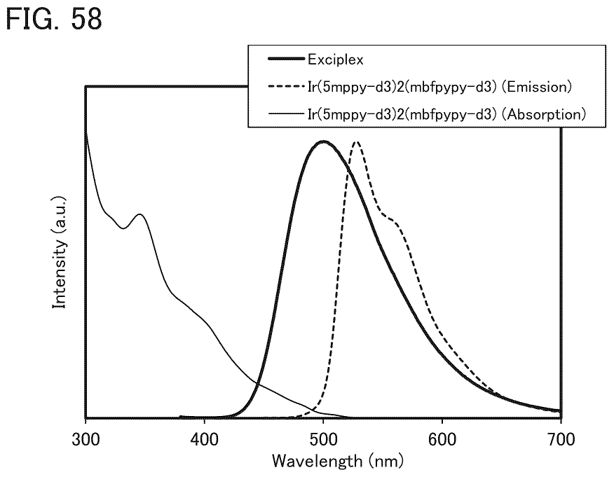

FIG. 58 shows the emission spectrum of a film (mixed film) in which 8mpTP-4mDBtPBfpm-d₁₃ and βNCCP-d₂₆ were deposited by co-evaporation at a weight ratio of 1:1 (the emission spectrum of the exciplex), and the absorption spectrum and emission spectrum of Ir(5mppy-d₃)₂(mbfpypy-d₃), which is an emission center substance.

As can be seen from FIG. 58, the emission edge (442 nm) on the shorter wavelength side of the PL spectrum of the exciplex of 8mpTP-4mDBtPBfpm-d₁₃ and βNCCP-d₂₆ is positioned at a shorter wavelength than the absorption edge (526 nm) on the longer wavelength side of the absorption spectrum of Ir(5mppy-d₃)₂(mbfpypy-d₃). When the PL spectrum of the exciplex of 8mpTP-4mDBtPBfpm-d₁₃ and βNCCP-d₂₆ and the absorption edge of Ir(5mppy-d₃)₂(mbfpypy-d₃) have such a positional relation, excitation energy can be efficiently transferred to Ir(5mppy-d₃)₂(mbfpypy-d₃) in the light-emitting device G2. As in Example 1, the PL spectrum of the exciplex was measured using the co-evaporated film of 8mpTP-4mDBtPBfpm-d₁₃ and βNCCP-d₂₆. The PL spectrum and absorption spectrum of Ir(5mppy-d₃)₂(mbfpypy-d₃) were measured with a solution of Ir(5mppy-d₃)₂(mbfpypy-d₃) using chloroform as a solvent.

The energy (2.48 eV) at the peak wavelength (500 nm) of the PL spectrum of the exciplex formed by 8mpTP-4mDBtPBfpm-d₁₃ and βNCCP-d₂₆ is higher than the energy (2.35 eV) at the peak wavelength (528 nm) of the PL spectrum of Ir(5mppy-d₃)₂(mbfpypy-d₃). The difference between the energy of the peak of the PL spectrum of the exciplex and the energy of the peak of the PL spectrum of Ir(5mppy-d₃)₂(mbfpypy-d₃) is less than or equal to 0.20 eV. Such a relation between the energy of the peak of the PL spectrum of the exciplex and the energy of the peak of the PL spectrum of Ir(5mppy-d₃)₂(mbfpypy-d₃) enables efficient transfer of excitation energy to Ir(5mppy-d₃)₂(mbfpypy-d₃) in the light-emitting device G2.

The difference between the energy (2.48 eV) at the peak wavelength (500 nm) of the PL spectrum of the exciplex formed by 8mpTP-4mDBtPBfpm-d₁₃ and βNCCP-d₂₆ and the energy (2.36 eV) at the wavelength (526 nm) of the absorption edge on the longer wavelength side of the absorption spectrum of Ir(5mppy-d₃)₂(mbfpypy-d₃) is less than or equal to 0.20 eV. Such a relation between the energy of the peak of the PL spectrum of the exciplex and the energy of the absorption edge on the longer wavelength side of the absorption spectrum of Ir(5mppy-d₃)₂(mbfpypy-d₃) enables efficient energy transfer in the light-emitting device G2.

As described in Example 1, the HOMO level of βNCCP-d₂₆, which is an organic compound having a hole-transport property, was −5.60 eV; the HOMO level of 8mpTP-4mDBtPBfpm-d₁₃, which is an organic compound having an electron-transport property, was −6.3 eV (a reference value); the LUMO level of βNCCP-d₂₆ was −2.19 eV; and the LUMO level of 8mpTP-4mDBtPBfpm-d₁₃ was −3.01 eV.

Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device G2 was found to have a structure in which an exciplex can be formed efficiently.

The HOMO level and the LUMO level of Ir(5mppy-d₃)₂(mbfpypy-d₃) were −5.32 eV and −2.39 eV, respectively. The energy difference between the HOMO level and the LUMO level of the exciplex of 8mpTP-4mDBtPBfpm-d₁₃ and βNCCP-d₂₆ was 2.59 eV corresponding to the energy difference between the HOMO level (−5.60 eV) of βNCCP-d₂₆, which is the organic compound having a hole-transport property, and the LUMO level (−3.01 eV) of 8mpTP-8mpTP-4mDBtPBfpm-d₁₃, which is the organic compound having an electron-transport property. The energy difference (2.93 eV) between the HOMO level (−5.32 eV) and the LUMO level (−2.39 eV) corresponding to the band gap of Ir(5mppy-d₃)₂(mbfpypy-d₃) was found to be larger than the energy difference between the HOMO level and the LUMO level of the exciplex. Note that the methods for measuring the HOMO level, LUMO level, and T₁ level of the organic compound were as described in Example 1.

As described in Example 1, the T₁ level of 8mpTP-4mDBtPBfpm-d₁₃ was 2.55 eV and the T₁ level of βNCCP-d₂₆ was 2.56 eV. As described above, in the light-emitting device G2 in which both of the first host material and the second host material are deuterated, the difference in the T₁ level between the first host material and the second host material is 0.20 eV or less, and the efficiency of energy transfer from the triplet excited state is improved by the influence of deuterium; thus, deterioration of the first host material and the second host material can be inhibited.

The phosphorescence lifetimes of βNCCP-d₂₆ and 8mpTP-4mDBtPBfpm-d₁₃ are as described in Example 1. It was thus found that in the light-emitting device G2, deuterium included in both of the first host material and the second host material inhibits intramolecular vibration of the deuterated organic compounds in the T₁ state and inhibits nonradiative transition from the T₁ state to a more stable state; hence, the efficiency of energy transfer to the phosphorescent substance is improved to achieve high reliability.

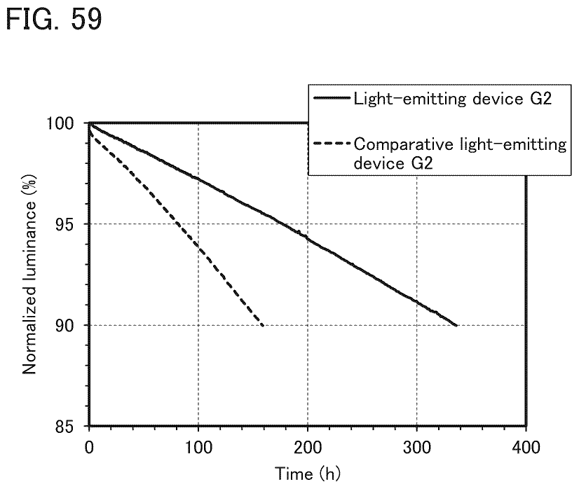

FIG. 59 shows the time dependence of normalized luminance of the light-emitting device G2 and the comparative light-emitting device G2 at a current density of 50 mA/cm².

FIG. 59 demonstrates that the light-emitting device G2 has a smaller time-dependent change in normalized luminance than the comparative light-emitting device G2 and thus has high reliability.

Here, the second electron-transport layers of the light-emitting devices R2, G2, and B2 include the same material (the first organic compound having a triazine skeleton). Thus, the light-emitting devices of different emission colors can each have favorable characteristics even when the second electron-transport layers of the light-emitting devices are made of the same material.

### (Power Consumption Estimation 2)

A display apparatus 2 of this example including the light-emitting devices R2, G2, and B2 respectively in red, green, and blue subpixels and a comparative display apparatus 2 including the comparative light-emitting devices R2, G2, and B2 respectively in red, green, and blue subpixels were assumed, and the power consumption of their display portions (except for the power consumption of driving transistors, driver circuits, and the like) was estimated. Note that the conditions of the display apparatuses assumed for the estimation and the calculation method are the same as those in Example 1. The aperture ratios of the subpixels of the respective emission colors were estimated in consideration of the time dependence of normalized luminance of the light-emitting devices shown in FIG. 49 and FIG. 59.

Table 18 and Table 19 show the aperture ratio of each emission color for calculating power consumption and the calculated power consumption of the display apparatus 2 and the comparative display apparatus 2, respectively.

TABLE 18
Display apparatus 2

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 9.4 | 0.69 | 0.31 | 245 | 2601 | 65.9 | 3.9 | 25.6 | 7.22 | 184.7 |
| Green | 4.4 | 0.22 | 0.74 | 702 | 16026 | 188.3 | 8.5 | 25.7 | 7.07 | 181.6 |
| Blue | 16.2 | 0.15 | 0.04 | 54 | 331 | 8.7 | 3.8 | 42.3 | 7.25 | 306.9 |
| Full white | — | 0.31 | 0.33 | 1000 | — | 73.6 | — | 93.6 | — | 673.3 |

TABLE 19
Comparative display apparatus 2

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.30 | 237 | 2365 | 65.0 | 3.6 | 25.1 | 7.51 | 188.4 |
| Green | 10.0 | 0.23 | 0.73 | 709 | 7090 | 217.3 | 3.3 | 22.5 | 6.84 | 153.8 |
| Blue | 10.0 | 0.15 | 0.04 | 54 | 544 | 8.5 | 6.4 | 44.1 | 7.84 | 345.7 |
| Full white | — | 0.31 | 0.33 | 1000 | — | 75.2 | — | 91.6 | — | 687.9 |

Table 18 and Table 19 show that the driving voltage of the display apparatus 2 is lower than that of the comparative display apparatus 2, and the power consumption of the display apparatus 2 is lower than that of the comparative display apparatus 2.

As shown in Table 18 and Table 19, when the aperture ratio of each emission color was estimated in consideration of the time dependence of normalized luminance of the light-emitting devices, the aperture ratios of the red subpixel and the green subpixel in the display apparatus 2 were lower than the aperture ratios of the red subpixel and the green subpixel in the comparative display apparatus 2, and the aperture ratio of the blue subpixel in the display apparatus 2 was higher than the aperture ratio of the blue subpixel in the comparative display apparatus 2. The current density required for the blue subpixel in the display apparatus 2 was lower than the current density required for the blue subpixel in the comparative display apparatus 2. In the display apparatus 2, the aperture ratios of the red subpixel and the green subpixel were lower than the aperture ratio of the blue subpixel.

These results show that the use of the light-emitting devices 2R and 2G each having a smaller time dependence of normalized luminance for a red subpixel and a green subpixel enables the aperture ratios of the red subpixel and the green subpixel to be further reduced. Accordingly, the aperture ratio of the blue subpixel can be further increased, and the current density required for light emission of the blue light-emitting device can be further reduced, demonstrating that the reliability is increased as a whole.

### Example 3

This example will describe specific manufacturing methods and characteristics of light-emitting devices R3-a, R3-b, G3, and B3 that can be used in the display apparatus of one embodiment of the present invention and comparative light-emitting device R3-a, R3-b, G3, and B3. Moreover, the description will be made on estimation of power consumption of display apparatuses of embodiments of the present invention including these light-emitting devices. The structural formulae of main compounds used in the light-emitting devices are shown below.

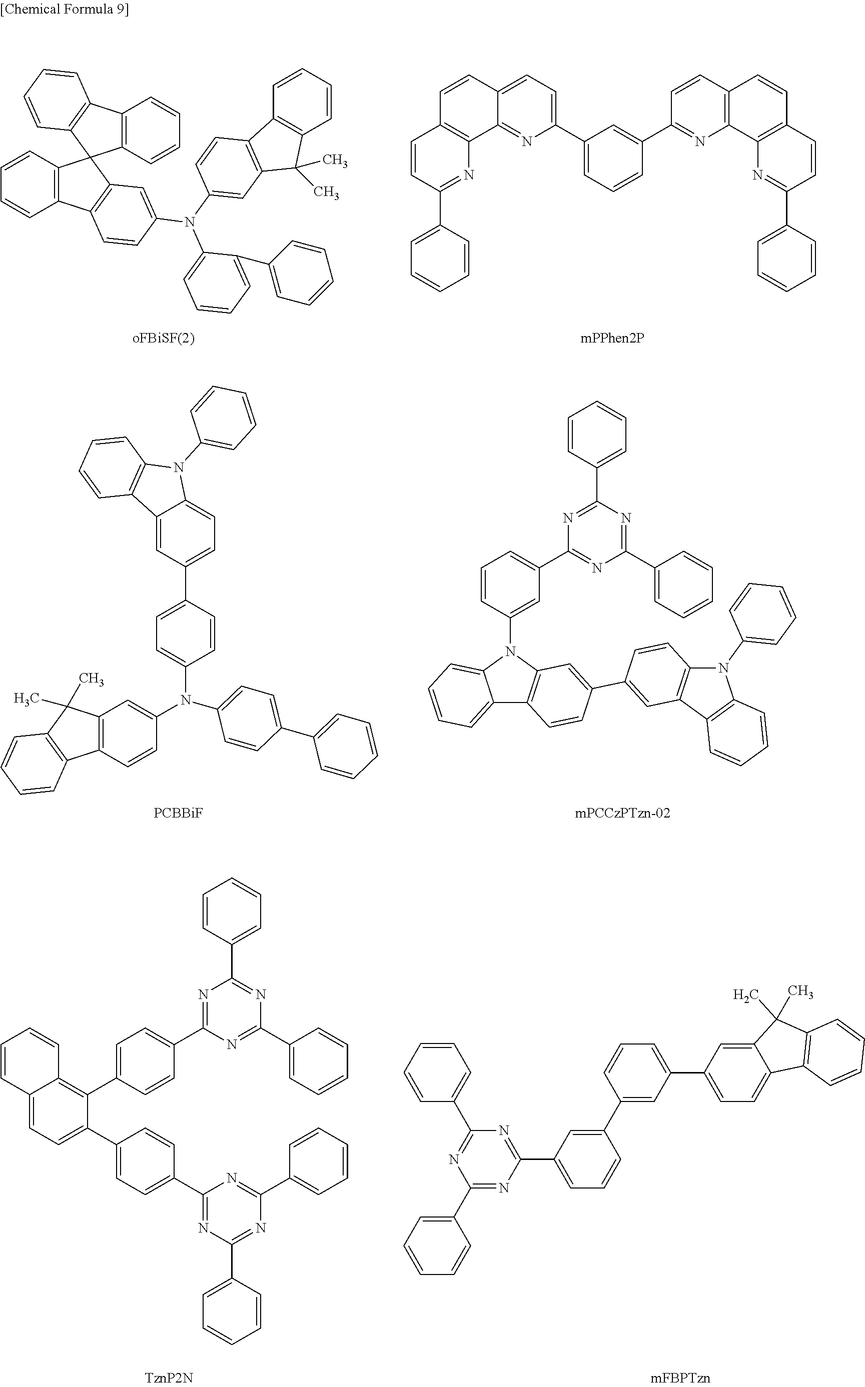

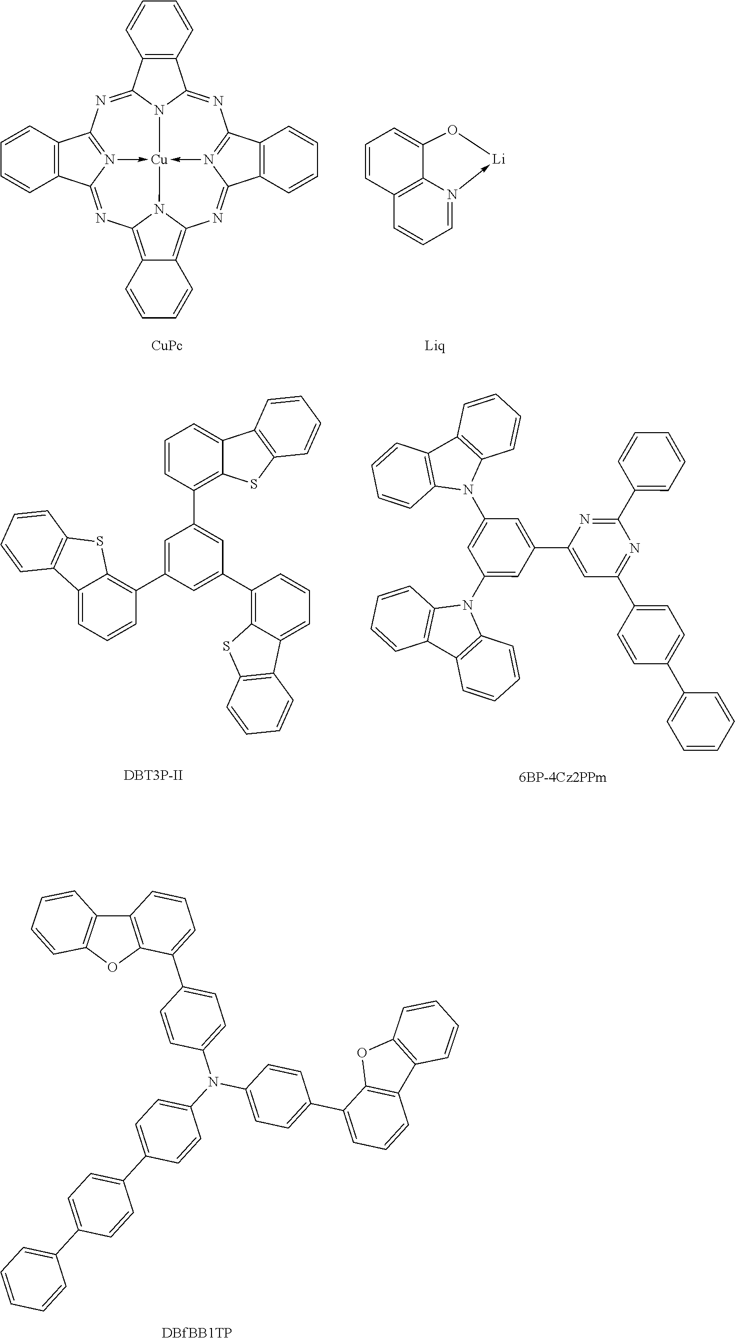

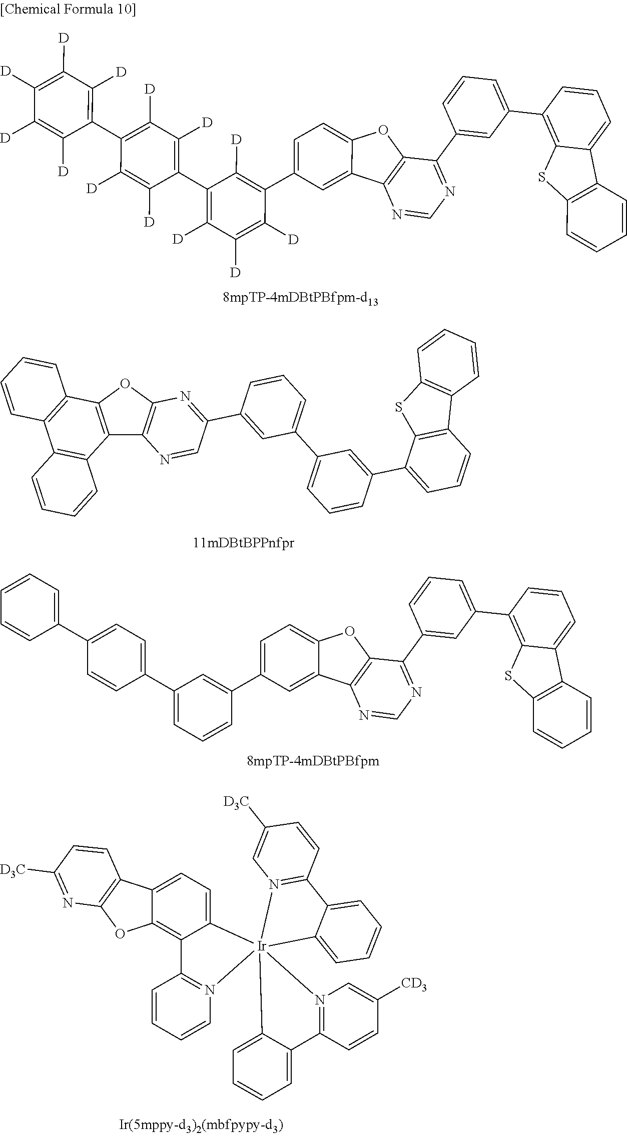

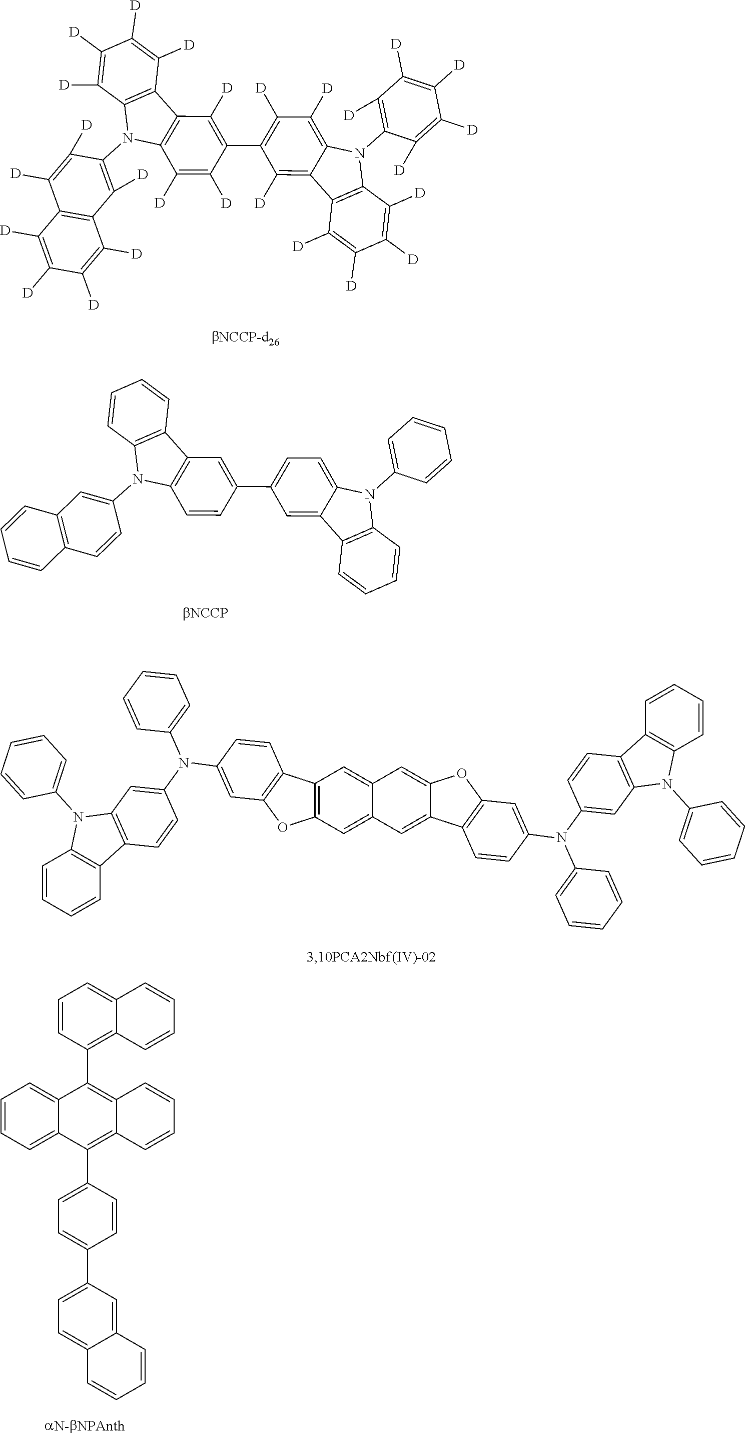

### (Method 3 for Manufacturing Light-Emitting Devices)

A method for manufacturing the light-emitting devices used in this example is described.

### <Method for Manufacturing Light-Emitting Device R3-a>

The light-emitting device R3-a was manufactured in the same manner as the light-emitting device R1-a described in Example 1 except that the first light-emitting layer and the second light-emitting layer were each deposited by co-evaporation of 11-[3′-(dibenzothiophen-4-yl)biphenyl-3-yl]phenanthro[9′,10′:4,5]furo(2,3-b)pyrazine (abbreviation: 11mDBtBPPnfpr), βNCCP-d₂₆, and OCPG-006 at a weight ratio of 0.4:0.6:0.05.

### <Method for Manufacturing Light-Emitting Device R3-b>

The light-emitting device R3-b was manufactured in the same manner as the light-emitting device R1-a described in Example 1 except that the first light-emitting layer and the second light-emitting layer were each deposited by co-evaporation of 8mpTP-4mDBtPBfpm-d₃, N-(biphenyl-4-yl)-N-[4-(9-phenyl-9H-carbazol-3-yl)phenyl]-9,9-dimethyl-9H-fluoren-2-amine (abbreviation: PCBBiF), and OCPG-006 at a weight ratio of 0.7:0.3:0.05.

### <Method for Manufacturing Comparative Light-Emitting Device R3-a>

The comparative light-emitting device R3-a was manufactured in the same manner as the light-emitting device R1-a described in Example 1 except that TznP2N was replaced with 6BP-4Cz2PPm in the second electron-transport layer, and the first light-emitting layer and the second light-emitting layer were each deposited by co-evaporation of 11mDBtBPPnfpr, βNCCP, and OCPG-006 at a weight ratio of 0.4:0.6:0.05.

### <Method for Manufacturing Comparative Light-Emitting Device R3-b>

The comparative light-emitting device R3-b was manufactured in the same manner as the light-emitting device R1-a described in Example 1 except that TznP2N was replaced with 6BP-4Cz2PPm in the second electron-transport layer, and the first light-emitting layer and the second light-emitting layer were each deposited by co-evaporation of 8mpTP-4mDBtPBfpm, PCBBiF, and OCPG-006 at a weight ratio of 0.7:0.3:0.05.

### <Methods for Manufacturing Light-Emitting Device G3 and Comparative Light-Emitting Device G3>

The methods for manufacturing the light-emitting device G3 and the comparative light-emitting device G3 are the same as the respective methods for manufacturing the light-emitting device G1 and the comparative light-emitting device G1 described in Example 1.

### <Methods for Manufacturing Light-Emitting Device B3 and Comparative Light-Emitting Device B3>

The methods for manufacturing the light-emitting device B3 and the comparative light-emitting device B3 are the same as the respective methods for manufacturing the light-emitting device B1 and the comparative light-emitting device B1 described in Example 1.

Tables 20 to 22 show the device structures of the light-emitting devices R3-a, R3-b, G3, and B3 and the comparative light-emitting devices R3-a, R3-b, G1, and B1.

TABLE 20

| | | |
|---|---|---|
| | Light-emitting | Light-emitting |
| Thickness (nm) | device R3-a | device R3-b |

| Cap layer | | 70 | DBT3P-II |
|---|---|---|---|
| Second electrode | 2 | 15 | Ag:Mg (1:0.1) |
| | 1 | 1 | Liq |
| Second electron- | b | 25 | TznP2N:Liq |
| transport layer | | | (1:1) |
| | a | 10 | mFBPTzn |

| | | | |
|---|---|---|---|
| Second light-emitting layer | 40 | 11mDBtBPPnfpr:βNCCP- | 8mpTP- |

| | |
|---|---|
| d₂₆:OCPG-006 | 4mDBtPBfpm- |
| (0.4:0.6:0.05) | d₁₃:PCBBiF:OCPG- |
| | 006 (0.7:0.3:0.05) |

| Second hole-transport layer | | 75 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| | | |
|---|---|---|
| First electron-transport layer | 10 | mPCCzPTzn-02 |

| | | | |
|---|---|---|---|
| First light-emitting layer | 40 | 11mDBtBPPnfp:βNCCP- | 8mpTP- |

| | |
|---|---|
| d₂₆:OCPG-006 | 4mDBtPBfpm- |
| (0.4:0.6:0.05) | d₁₃:PCBBiF:OCPG- |
| | 006 (0.7:0.3:0.05) |

| First hole-transport layer | | 140 | oFBiSF(2) |
|---|---|---|---|
| First hole-injection layer | | 10 | oFBiSF(2):OCHD-003 (1:0.03) |
| First electrode | 2 | 85 | ITSO |
| | 1 | 100 | Ag |

| | |
|---|---|
| Comparable | Comparable |
| light-emitting | light-emitting |
| device R3-a | device R3-b |

| Cap layer | | DBT3P-II |
|---|---|---|
| Second electrode | 2 | Ag:Mg (1:0.1) |
| | 1 | Liq |
| Second electron- | b | 6BP-4Cz2PPm:Liq |
| transport layer | | (1:1) |
| | a | mFBPTzn |

| Second light-emitting layer | 11mDBtBPPnfpr:βNCCP:OCPG- | 8mpTP- |
|---|---|---|
| | 006 (0.4:0.6:0.05) | 4mDBtPBfpm:PCBBiF:OCPG- |
| | | 006 (0.7:0.3:0.05) |

| Second hole-transport layer | | oFBiSF(2) |
|---|---|---|
| Intermediate | Second layer | oFBiSF(2):OCHD-003 (1:0.15) |
| layer | Third layer | CuPc |
| | First layer | mPPhen2P:Li₂O (1:0.02) |

| First electron-transport layer | mPCCzPTzn-02 | |
|---|---|---|
| First light-emitting layer | 11mDBtBPPnfpr:βNCCP:OCPG- | 8mpTP- |
| | 006 (0.4:0.6:0.05) | 4mDBtPBfpm:PCBBiF:OCPG- |
| | | 006 (0.7:0.3:0.05) |

| First hole-transport layer | | oFBiSF(2) |
|---|---|---|
| First hole-injection layer | | oFBiSF(2):OCHD-003 (1:0.03) |
| First electrode | 2 | ITSO |
| | 1 | Ag |

TABLE 21

| | | Thickness | Light-emitting | Comparative light- |
|---|---|---|---|---|
| | | (nm) | device G3 | emitting device G3 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | a | 10 | mFBPTzn |
|---|---|---|---|
| Second light-emitting layer | | 40 | 8mpTP-4mDBtPBfpm:βNCCP:Ir(5mppy- |
| | | | d₃)₂(mbfpypy-d₃) (0.5:0.5:0.1) |
| Second hole-transport layer | | 50 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |
| First electron-transport layer | | 10 | mPCCzPTzn-02 |
| First light-emitting layer | | 40 | 8mpTP-4mDBtPBfpm:βNCCP:Ir(5mppy- |
| | | | d₃)₂(mbfpypy-d₃) (0.5:0.5:0.1) |
| First hole-transport layer | | 80 | oFBiSF(2) |
| First hole-injection layer | | 10 | oFBiSF(2):OCHD-003 (1:0.03) |
| First | 2 | 85 | ITSO |
| electrode | 1 | 100 | Ag |

TABLE 22

| | | Thickness | Light-emitting | Comparative light- |
|---|---|---|---|---|
| | | (nm) | device B3 | emitting device B3 |
| Cap layer | | 70 | DBT3P-II | |
| Second | 2 | 15 | Ag:Mg (1 :0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | a | 10 | mFBPTzn |
|---|---|---|---|
| Second light-emitting layer | | 25 | αN-βNPAnth:3,10PCA2Nbf(IV)-02 |
| | | | (1:0.015) |
| Second hole- | b | 10 | DBfBB1TP |
| transport layer | a | 35 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |
| First electron-transport layer | | 10 | mPCCzPTzn-02 |
| First light-emitting layer | | 25 | αN-βNPAnth:3,10PCA2Nbf(IV)-02 |
| | | | (1:0.015) |
| First hole-transport | b | 10 | DBfBB1TP |
| layer | a | 35 | oFBiSF(2) |
| First hole-injection layer | | 10 | oFBiSF(2):OCHD-003 (1:0.03) |
| First | 2 | 85 | ITSO |
| electrode | 1 | 100 | Ag |

### (Characteristics 3 of Light-Emitting Devices)

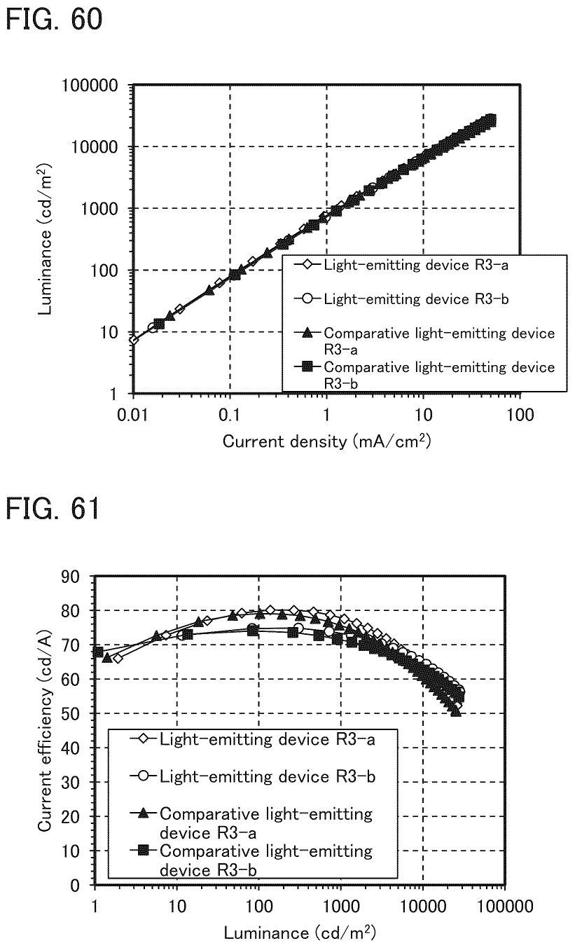

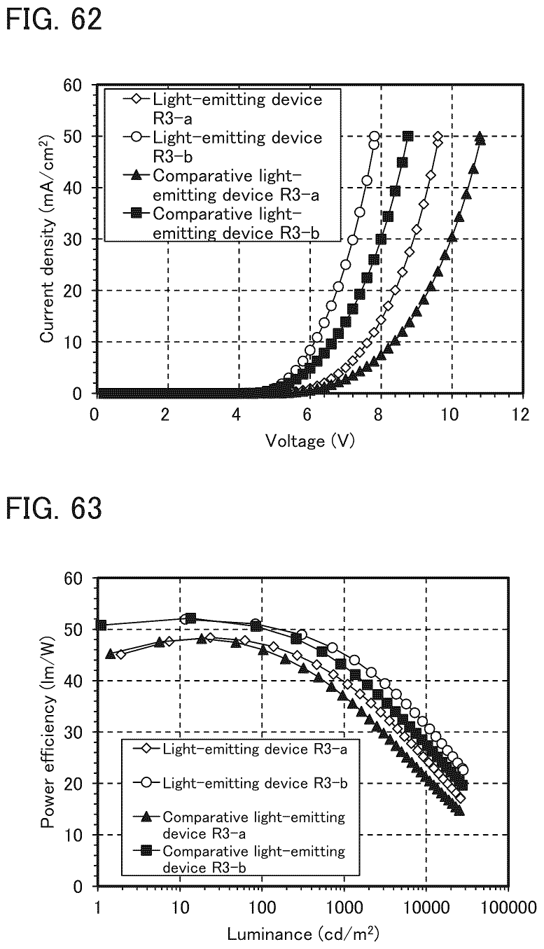

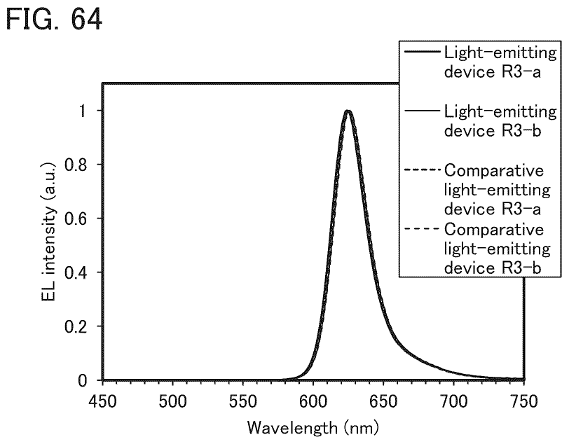

FIG. 60, FIG. 61, FIG. 62, FIG. 63, and FIG. 64 respectively show the luminance-current density characteristics, current efficiency-luminance characteristics, current density-voltage characteristics, power efficiency-luminance characteristics, and electroluminescence spectra of the light-emitting devices R3-a and R3-b and the comparative light-emitting devices R3-a and R3-b. Note that the characteristics of the light-emitting device G3 and the comparative light-emitting device G3 are the same as those of the light-emitting device G1 and the comparative light-emitting device G1. The characteristics of the light-emitting device B3 and the comparative light-emitting device B3 are the same as those of the light-emitting device B1 and the comparative light-emitting device B1.

### <Characteristics of Light-Emitting Devices R3-a and R3-b and Comparative Light-Emitting Devices R3-a and R3-b>

Table 23 shows the main characteristics of the light-emitting devices R3-a and R3-b and the comparative light-emitting devices R3-a and R3-b at a luminance of approximately 1000 cd/m². In this example, the luminance, CIE chromaticity, and electroluminescence spectra were measured at room temperature with a spectroradiometer (SR-UL1R, TOPCON TECHNOHOUSE CORPORATION).

TABLE 23

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting device R3-a | 6.2 | 0.057 | 1.42 | 0.69 | 0.31 | 78 | 39 |
| Light-emitting device R3-b | 5.0 | 0.039 | 0.97 | 0.69 | 0.31 | 74 | 46 |
| Comparative light-emitting | 6.4 | 0.050 | 1.26 | 0.69 | 0.31 | 76 | 37 |
| device R3-a | | | | | | | |
| Comparative light-emitting | 5.2 | 0.050 | 1.26 | 0.69 | 0.31 | 72 | 43 |
| device R3-b | | | | | | | |

FIGS. 60 to 64 and Table 23 reveal that red light emission with an electroluminescence spectrum peak wavelength of around 625 nm was obtained from the light-emitting device R3-a, the light-emitting device R3-b, the comparative light-emitting device R3-a, and the comparative light-emitting device R3-b. Although the light-emitting device R3-a, the light-emitting device R3-b, the comparative light-emitting device R3-a, and the comparative light-emitting device R3-b have high current efficiency, FIG. 62 shows that the light-emitting devices R3-a and R3-b have favorable characteristics with a lower driving voltage and lower power consumption than the comparative light-emitting devices R3-a and R3-b. This indicates that the light-emitting devices R3-a and R3-b are tandem light-emitting devices with favorable characteristics. It is thus found that when an organic compound including deuterium is used as at least one of the first host material and the second host material and an organic compound having a triazine skeleton is used in the second electron-transport layer, the light-emitting device can have favorable characteristics with a lower driving voltage and lower power consumption.

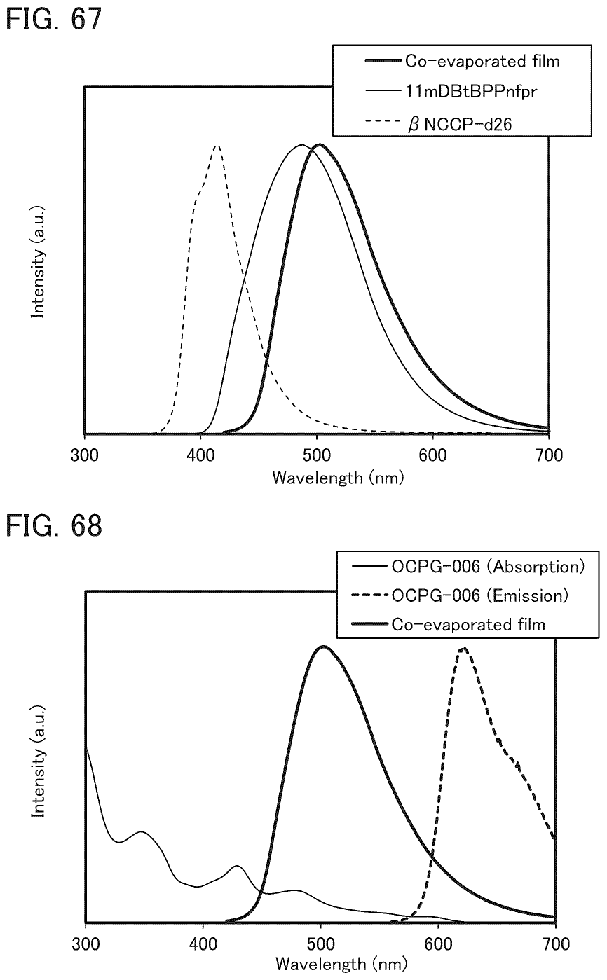

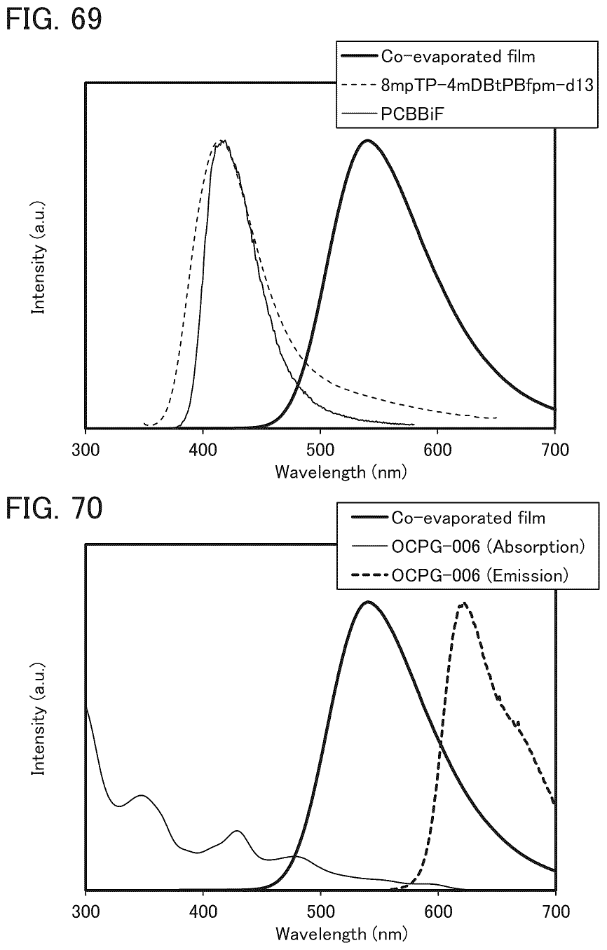

FIG. 67 shows the measured emission spectra of an evaporated film of 11mDBtBPPnfpr, an evaporated film of βNCCP-d₂₆, and a film (mixed film) in which 11mDBtBPPnfpr and βNCCP-d₂₆ were deposited by co-evaporation such that the weight ratio of 11mDBtBPPnfpr to βNCCP-d₂₆ was 1:1. FIG. 69 shows the measured emission spectra of an evaporated film of 8mpTP-4mDBtPBfpm-d₁₃, an evaporated film of PCBBiF, and a film (mixed film) in which 8mpTP-4mDBtPBfpm-d₁₃ and PCBBiF were deposited by co-evaporation at a weight ratio of 1:1. The emission spectra of the co-evaporated films shift to the longer wavelength side than the emission spectra of the organic compounds, indicating that a combination of 8mpTP-4mDBtPBfpm and βNCCP-d₂₆ forms an exciplex and a combination of 8mpTP-4mDBtPBfpm-d₁₃ and PCBBiF forms an exciplex.

FIG. 68 shows the PL spectrum of a film (mixed film) in which 11mDBtBPPnfpr and βNCCP-d₂₆ were deposited by co-evaporation at a weight ratio of 1:1 (the PL spectrum of the exciplex), and the absorption spectrum and PL spectrum of OCPG-006, which is an emission center substance. FIG. 70 shows the PL spectrum of a film (mixed film) in which 8mpTP-4mDBtPBfpm-d₁₃ and PCBBiF were deposited by co-evaporation at a weight ratio of 1:1 (the PL spectrum of the exciplex), and the absorption spectrum and PL spectrum of OCPG-006, which is an emission center substance.

As can be seen from FIG. 68, the emission edge (446 nm) on the shorter wavelength side of the PL spectrum of the exciplex of 11mDBtBPPnfpr and βNCCP-d₂₆ is positioned at a shorter wavelength than the absorption edge (622 nm) on the longer wavelength side of the absorption spectrum of OCPG-006. As can be seen from FIG. 69, the emission edge (477 nm) on the shorter wavelength side of the PL spectrum of the exciplex of 8mpTP-4mDBtPBfpm-d₁₃ and PCBBiF is positioned at a shorter wavelength than the absorption edge (622 nm) on the longer wavelength side of the absorption spectrum of OCPG-006. When the PL spectra of the exciplexes and the absorption edge of OCPG-006 have such a positional relation, excitation energy can be efficiently transferred to OCPG-006 in the light-emitting devices R3-a and R3-b.

The energy (2.30 eV) at the peak wavelength (540 nm) of the PL spectrum of the exciplex formed by 8mpTP-4mDBtPBfpm-d₁₃ and PCBBiF is higher than the energy (2.00 eV) at the peak wavelength (621 nm) of the PL spectrum of OCPG-006. The difference between the energy of the peak of the PL spectrum of the exciplex and the energy of the peak of the PL spectrum of OCPG-006 is less than or equal to 0.30 eV. Such a relation between the energy of the peak of the PL spectrum of the exciplex and the energy of the peak of the PL spectrum of OCPG-006 enables efficient transfer of excitation energy to OCPG-006 in the light-emitting device R3-b.

The difference between the energy (2.30 eV) at the peak wavelength (540 nm) of the PL spectrum of the exciplex formed by 8mpTP-4mDBtPBfpm-d₁₃ and PCBBiF and the energy (1.99 eV) at the wavelength (622 nm) of the absorption edge on the longer wavelength side of the absorption spectrum of OCPG-006 is 0.30 eV. Such a relation between the energy of the peak of the PL spectrum of the exciplex and the energy of the absorption edge on the longer wavelength side of the absorption spectrum of OCPG-006 enables efficient transfer of excitation energy to OCPG-006 in the light-emitting device R3-b.

Note that the PL spectra of the exciplexes were measured using the co-evaporated films of the materials. The PL spectrum and absorption spectrum of OCPG-006 were measured with a solution of OCPG-006 using dichloromethane as a solvent. The PL spectra of the exciplexes and 11mDBtBPPnfpr were measured with a fluorescence spectrophotometer (FP-8600, produced by JASCO Corporation). The PL spectrum of PCBBiF was measured with a fluorescence spectrophotometer (FS920, produced by Hamamatsu Photonics K.K.).

The HOMO level of βNCCP-d₂₆, which is an organic compound having a hole-transport property, was −5.60 eV. The HOMO level of PCBBiF was −5.36 eV. The HOMO level of 8mpTP-4mDBtPBfpm-d₁₃, which is an organic compound having an electron-transport property, was −6.3 eV (a reference value). The HOMO level of 11mDBtBPPnfpr was −6.16 eV. The LUMO level of βNCCP-d₂₆ was −2.19 eV. The LUMO level of PCBBiF was −2.00 eV. The LUMO level of 8mpTP-4mDBtPBfpm-d₁₃ was −3.01 eV. The LUMO level of 11mDBtBPPnfpr was −3.02 eV.

Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property as described above, the light-emitting devices R3-a and R3-b were found to have a structure capable of efficiently forming an exciplex.

The HOMO level and the LUMO level of OCPG-006 were −5.26 eV and −2.69 eV, respectively. The energy difference between the HOMO level and the LUMO level of the exciplex of 8mpTP-4mDBtPBfpm-d₁₃ and PCBBiF was 2.35 eV corresponding to the energy difference between the HOMO level (−5.36 eV) of PCBBiF, which is the organic compound having a hole-transport property, and the LUMO level (−3.01 eV) of 8mpTP-8mpTP-4mDBtPBfpm-d₁₃, which is the organic compound having an electron-transport property. The energy difference (2.57 eV) between the HOMO level (−5.26 eV) and the LUMO level (−2.69 eV) corresponding to the band gap of OCPG-006 was found to be larger than the energy difference between the HOMO level and the LUMO level of the exciplex.

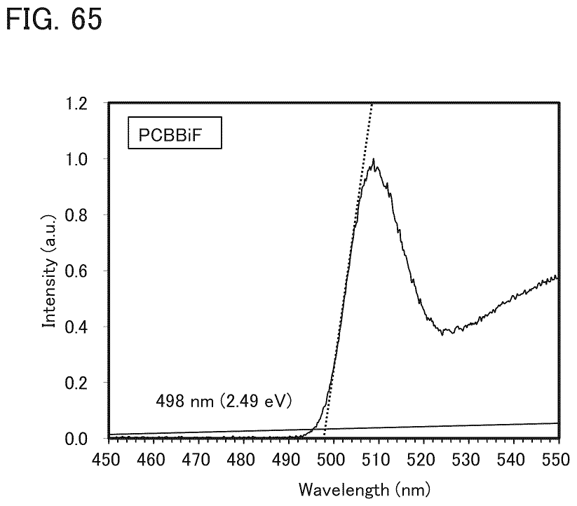

The T₁ level of PCBBiF was measured by the method described in Example 1 (see FIG. 65). As a result of the measurement, the T₁ level of PCBBiF was 2.49 eV. As described in Example 1, the T₁ level of 8mpTP-4mDBtPBfpm-d₁₃ was 2.55 eV and the T₁ level of βNCCP-d₂₆ was 2.56 eV. As described above, in the light-emitting device R3-b in which one or both of the first host material and the second host material are deuterated, the difference in the T₁ level between the first host material and the second host material is 0.20 eV or less, and the efficiency of energy transfer from the triplet excited state is improved by the influence of deuterium; thus, deterioration of the first host material and the second host material can be inhibited.

The phosphorescence lifetimes of βNCCP-d₂₆ and 8mpTP-4mDBtPBfpm-d₁₃ are as described in Example 1. It was thus found that in the light-emitting devices R3-a and R3-b, deuterium included in one or both of the first host material and the second host material inhibits intramolecular vibration of the deuterated organic compound in the T₁ state and inhibits nonradiative transition from the T₁ state to a more stable state; hence, the efficiency of energy transfer to the phosphorescent substance is improved to achieve high reliability.

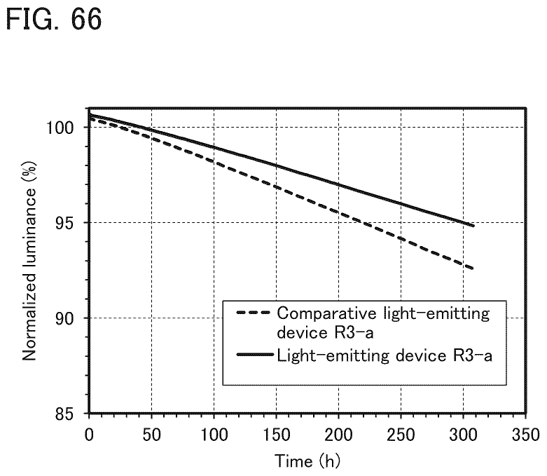

FIG. 66 shows the time dependence of normalized luminance of the light-emitting device R3-a and the comparative light-emitting device R3-a at a current density of 75 mA/cm².

FIG. 66 demonstrates that the light-emitting device R3-a has a smaller time-dependent change in normalized luminance than the comparative light-emitting device R3-a and thus has high reliability. Although not shown, a time-dependent change in normalized luminance of the light-emitting device R3-b was equivalent to a time-dependent change in normalized luminance of the comparative light-emitting device R3-b.

Here, the second electron-transport layers of the light-emitting devices R3-a, R3-b, G3, and B3 include the same material (the first organic compound having a triazine skeleton). Thus, the light-emitting devices of different emission colors can each have favorable characteristics even when the second electron-transport layers of the light-emitting devices are made of the same material.

### (Power Consumption Estimation 3)

Assuming that a display apparatus 3-a of this example including the light-emitting devices R3-a, G3, and B3 respectively in red, green, and blue subpixels; a display apparatus 3-b of this example including the light-emitting devices R3-b, G3, and B3 respectively in red, green, and blue subpixels; and a comparative display apparatus 3 including the comparative light-emitting devices R3-a, G3, and B3 respectively in red, green, and blue subpixels, the power consumption of their display portions (except for the power consumption of driving transistors, driver circuits, and the like) was estimated. Note that the conditions of the display apparatuses assumed for the estimation and the calculation method are the same as those in Example 1. The aperture ratios of the subpixels of the respective emission colors were estimated in consideration of the time dependence of normalized luminance of the light-emitting devices shown in FIG. 66.

Tables 24 to 27 show the aperture ratio of each emission color for calculating power consumption and the calculated power consumption of the display apparatus 3-a, the display apparatus 3-b, the comparative display apparatus 3-a, and the comparative display apparatus 3-b, respectively.

TABLE 24
Display apparatus 3-a

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 6.8 | 0.69 | 0.31 | 246 | 3596 | 71.8 | 5.0 | 23.6 | 7.01 | 165.4 |
| Green | 11.6 | 0.22 | 0.73 | 701 | 6048 | 216.9 | 2.8 | 22.3 | 6.16 | 137.2 |
| Blue | 11.6 | 0.15 | 0.04 | 54 | 464 | 8.9 | 5.2 | 41.8 | 7.36 | 307.5 |
| Full white | — | 0.31 | 0.33 | 1000 | — | 78.7 | — | 87.6 | — | 610.0 |

TABLE 25
Display apparatus 3-b

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.31 | 242 | 2421 | 71.2 | 3.4 | 23.4 | 5.46 | 127.8 |
| Green | 10.0 | 0.22 | 0.73 | 704 | 7042 | 215.4 | 3.3 | 22.5 | 6.26 | 141.0 |
| Blue | 10.0 | 0.15 | 0.04 | 54 | 537 | 8.9 | 6.0 | 41.5 | 7.42 | 308.0 |
| Full white | — | 0.31 | 0.33 | 1000 | — | 78.8 | — | 87.5 | — | 576.9 |

TABLE 26
Comparative display apparatus 3-a

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.31 | 242 | 2422 | 71.6 | 3.4 | 23.3 | 7.17 | 167.3 |
| Green | 10.0 | 0.23 | 0.73 | 703 | 7035 | 215.5 | 3.3 | 22.5 | 6.55 | 147.4 |
| Blue | 10.0 | 0.15 | 0.04 | 54 | 543 | 8.5 | 6.4 | 43.9 | 7.84 | 344.6 |
| Full white | — | 0.31 | 0.33 | 1000 | — | 76.8 | — | 89.8 | — | 659.3 |

TABLE 27
Comparative display apparatus 3-b

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.31 | 240 | 2402 | 69.1 | 3.5 | 24.0 | 5.75 | 137.7 |
| Green | 10.0 | 0.23 | 0.73 | 706 | 7055 | 215.5 | 3.3 | 22.6 | 6.56 | 147.9 |
| Blue | 10.0 | 0.15 | 0.04 | 54 | 543 | 8.5 | 6.4 | 43.9 | 7.84 | 344.5 |
| Full white | — | 0.31 | 0.33 | 1000 | — | 76.2 | — | 90.4 | — | 630.2 |

Tables 24 to 27 show that the display apparatuses 3-a and 3-b have higher current efficiency in white light emission and a lower driving voltage than the respective comparative display apparatuses 3-a and 3-b. Tables 24 to 27 also demonstrate that the display apparatuses 3-a and 3-b have lower power consumption than the comparative display apparatuses 3-a and 3-b.

As shown in Table 23 and Table 25, when the aperture ratio of each emission color was estimated in consideration of the time dependence of normalized luminance of the light-emitting devices, the aperture ratio of the red subpixel in the display apparatus 3-a was lower than the aperture ratio of the red subpixel in each of the comparative display apparatuses 3-a and 3-b, and the aperture ratios of the green subpixel and the blue subpixel in each of the display apparatus 3-a were higher than the aperture ratios of the green subpixel and the blue subpixel in each of the comparative display apparatuses 3-a and 3-b. The current densities required for the green subpixel and the blue subpixel in the display apparatus 3-a were lower than the current densities required for the green subpixel and the blue subpixel in each of the comparative display apparatuses 3-a and 3-b. In the display apparatus 3-a, the aperture ratio of the red subpixel was lower than the aperture ratios of the blue subpixel and the green subpixel.

These results show that when the light-emitting device R3-a with a smaller time-dependent change in normalized luminance is used in the red subpixel, the aperture ratio of the red subpixel can be further reduced, the aperture ratios of the green subpixel and the blue subpixel can be further increased, and the current densities required for the green subpixel and the blue subpixel can be further reduced. Thus, the reliability was found to be increased as a whole.

It was also found that the use of the light-emitting device R3-b in the red subpixel reduces the power consumption of the display apparatus.

### Example 4

This example will describe estimation of power consumption of display apparatuses using light-emitting devices R4, G4, and B4 that can be used in the display apparatus of one embodiment of the present invention and comparative light-emitting devices R4, G4, and B4. Structural formulae of main compounds used in the light-emitting devices are the same as those in Example 3.

### (Method 4 for Manufacturing Light-Emitting Devices)

The methods for manufacturing the light-emitting device R4 and the comparative light-emitting device R4 are the same as the respective methods for manufacturing the light-emitting device R3-a and the comparative light-emitting device R3-a described in Example 3. The methods for manufacturing the light-emitting device G4 and the comparative light-emitting device G4 are the same as the respective methods for manufacturing the light-emitting device R2 and the comparative light-emitting device R2 described in Example 2. The methods for manufacturing the light-emitting device B4 and the comparative light-emitting device B4 are the same as the respective methods for manufacturing the light-emitting device B1 and the comparative light-emitting device B1 described in Example 1.

Tables 28 to 30 show the device structures of the light-emitting devices R4, G4, and B4 and the comparative light-emitting devices R4, G4, and B4.

TABLE 28

| | | Thickness | Light-emitting | Comparative light- |
|---|---|---|---|---|
| | | (nm) | device R4 | emitting device R4 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | | |
|---|---|---|
| a | 10 | mFBPTzn |

| | | | |
|---|---|---|---|
| Second light-emitting layer | 40 | 11mDBtBPPnfp:βNCCP- | 11mDBtBPPnfpr:βNCCP:OCPG- |

| | |
|---|---|
| d₂₆:OCPG-006 | 006 |
| (0.4:0.6:0.05) | (0.4:0.6:0.05) |

| Second hole-transport layer | | 75 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | 10 | mPCCzPTzn-02 | |
|---|---|---|---|
| First light-emitting layer | 40 | 11mDBtBPPnfp:βNCCP- | 11mDBtBPPnfpr:βNCCP:OCPG- |

| | |
|---|---|
| d₂₆:OCPG-006 | 006 |
| (0.4:0.6:0.05) | (0.4:0.6:0.05) |

| First hole-transport layer | | 140 | oFBiSF(2) |
|---|---|---|---|
| First hole-injection layer | | 10 | oFBiSF(2):OCHD-003 (1:0.03) |
| First | 2 | 85 | ITSO |
| electrode | 1 | 100 | Ag |

TABLE 29

| | | Thickness | Light-emitting | Comparative light- |
|---|---|---|---|---|
| | | (nm) | device G4 | emitting device G4 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | | |
|---|---|---|
| a | 10 | mFBPTzn |

| | | | |
|---|---|---|---|
| Second light-emitting layer | 40 | 8mpTP- | 8mpTP- |

| | |
|---|---|
| 4mDBtPBfpm-d₁₃:βNCCP- | 4mDBtPBfpm:βNCCP:Ir(5mppy- |
| d₂₆:Ir(5mppy- | d₃)₂(mbfpypy-d₃) |
| d₃)₂(mbfpypy-d₃) | (0.5:0.5:0.1) |
| (0.5:0.5:0.1) | |

| Second hole-transport layer | | 50 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | 10 | mPCCzPTzn-02 | |
|---|---|---|---|
| First light-emitting layer | 40 | 8mpTP-4mDBtPBfpm- | 8mpTP- |

| | |
|---|---|
| d₁₃:βNCCP-d₂₆:Ir(5mppy- | 4mDBtPBfpm:βNCCP:Ir(5mppy- |
| d₃)₂(mbfpypy-d₃) | d₃)₂(mbfpypy-d₃) |
| (0.5:0.5:0.1) | (0.5:0.5:0.1) |

| First hole-transport layer | | 80 | oFBiSF(2) |
|---|---|---|---|
| First hole-injection layer | | 10 | oFBiSF(2):OCHD-003 (1:0.03) |
| First | 2 | 85 | ITSO |
| electrode | 1 | 100 | Ag |

TABLE 30

| | | Thickness | Light-emitting | Comparative light- |
|---|---|---|---|---|
| | | (nm) | device B4 | emitting device B4 |
| Cap layer | | 70 | DBT3P-II | |
| Second | 2 | 15 | Ag:Mg (1:0.1) | |
| electrode | 1 | 1 | Liq | |
| Second electron- | b | 25 | TznP2N:Liq | 6BP-4Cz2PPm:Liq |
| transport layer | | | (1:1) | (1:1) |

| | a | 10 | mFBPTzn |
|---|---|---|---|
| Second light-emitting layer | | 25 | αN-βNPAnth:3,10PCA2Nbf(IV)-02 |
| | | | (1:0.015) |
| Second hole-transport | b | 10 | DBfBB1TP |
| layer | a | 35 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |
| First electron-transport layer | | 10 | mPCCzPTzn-02 |
| First light-emitting layer | | 25 | αN-βNPAnth:3,10PCA2Nbf(IV)-02 |
| | | | (1:0.015) |
| First hole-transport | b | 10 | DBfBB1TP |
| layer | a | 35 | oFBiSF(2) |
| First hole-injection layer | | 10 | oFBiSF(2):OCHD-003 (1:0.03) |
| First | 2 | 85 | ITSO |
| electrode | 1 | 100 | Ag |

### (Characteristics 4 Of Light-Emitting Devices)

The characteristics of the light-emitting device R4 and the comparative light-emitting device R4 are the same as those of the light-emitting device R3-a and the comparative light-emitting device R3-a described in Example 3. The characteristics of the light-emitting device G4 and the comparative light-emitting device G4 are the same as those of the light-emitting device G2 and the comparative light-emitting device G2 described in Example 2. The characteristics of the light-emitting device B4 and the comparative light-emitting device B4 are the same as those of the light-emitting device B1 and the comparative light-emitting device B1 described in Example 1.

### (Power Consumption Estimation 4)

A display apparatus 4 of this example including the light-emitting devices R4, G4, and B4 respectively in red, green, and blue subpixels and a comparative display apparatus 4 including the comparative light-emitting devices R4, G4, and B4 respectively in red, green, and blue subpixels were assumed, and the power consumption of their display portions (except for the power consumption of driving transistors, driver circuits, and the like) was estimated. Note that the conditions of the display apparatuses assumed for the estimation and the calculation method are the same as those in Example 1. The aperture ratios of the subpixels of the respective emission colors were estimated in consideration of the time dependence of normalized luminance of the light-emitting devices shown in FIG. 59 and FIG. 66.

Table 31 and Table 32 show the calculated power consumption of the display apparatus 4 and the comparative display apparatus 4, respectively.

TABLE 31
Display apparatus 4

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 9.5 | 0.69 | 0.31 | 250 | 2623 | 73.7 | 3.6 | 23.3 | 6.75 | 157.6 |
| Green | 4.4 | 0.22 | 0.74 | 697 | 15996 | 188.3 | 8.5 | 25.5 | 7.07 | 180.3 |
| Blue | 16.1 | 0.15 | 0.04 | 54 | 333 | 8.8 | 3.8 | 42.3 | 7.26 | 307.0 |
| Full white | — | 0.31 | 0.33 | 1000 | — | 75.6 | — | 91.2 | — | 644.9 |

TABLE 32
Comparative display apparatus 4

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.31 | 240 | 2404 | 71.6 | 3.4 | 23.1 | 7.16 | 165.7 |
| Green | 10.0 | 0.23 | 0.73 | 705 | 7052 | 217.4 | 3.2 | 22.4 | 6.83 | 152.8 |
| Blue | 10.0 | 0.15 | 0.04 | 54 | 545 | 8.5 | 6.4 | 44.1 | 7.85 | 345.8 |
| Full white | — | 0.31 | 0.33 | 1000 | — | 76.9 | — | 89.6 | — | 664.3 |

Table 31 and Table 32 show that the driving voltage of the display apparatus 4 is lower than that of the comparative display apparatus 4, and the power consumption of the display apparatus 4 is lower than that of the comparative display apparatus 4.

As shown in Table 31 and Table 32, when the aperture ratio of each emission color was estimated in consideration of the time dependence of normalized luminance of the light-emitting devices, the aperture ratios of the red subpixel and the green subpixel in the display apparatus 4 were lower than the aperture ratios of the red subpixel and the green subpixel in the comparative display apparatus 4, and the aperture ratio of the blue subpixel in the display apparatus 4 was higher than the aperture ratio of the blue subpixel in the comparative display apparatus 4. The current density required for the blue subpixel in the display apparatus 4 was lower than the current density required for the blue subpixel in the comparative display apparatus 4. In the display apparatus 4, the aperture ratios of the red subpixel and the green subpixel were lower than the aperture ratio of the blue subpixel.

These results show that the use of the light-emitting devices 4R and 4G each having a smaller time dependence of normalized luminance for a red subpixel and a green subpixel enables the aperture ratios of the red subpixel and the green subpixel to be further reduced. Accordingly, the aperture ratio of the blue subpixel can be further increased, and the current density required for light emission of the blue light-emitting device can be further reduced, demonstrating that the reliability is increased as a whole.

As shown in Examples 1 to 4, the display apparatus including the following tandem light-emitting device has favorable characteristics with low power consumption. In the tandem light-emitting device, the light-emitting layer includes the emission center substrate, the first host material, and the second host material, one or both of the first host material and the second host material are deuterated, the second electron-transport layer includes the first organic compound having a triazine skeleton, the intermediate layer includes a mixed layer of the second organic compound having a phenanthroline skeleton and lithium or a lithium compound, and the difference between maximum peak wavelengths in emission spectra of a plurality of light-emitting layers is less than or equal to 30 nm.

### Example 5

This example will describe specific manufacturing methods and characteristics of light-emitting device R5, G5, and B5 that can be used in the display apparatus of one embodiment of the present invention and a comparative light-emitting device G5. Moreover, the description will be made on estimation of power consumption of display apparatuses of embodiments of the present invention including these light-emitting devices. The structural formulae of main compounds used in the light-emitting devices are shown below.

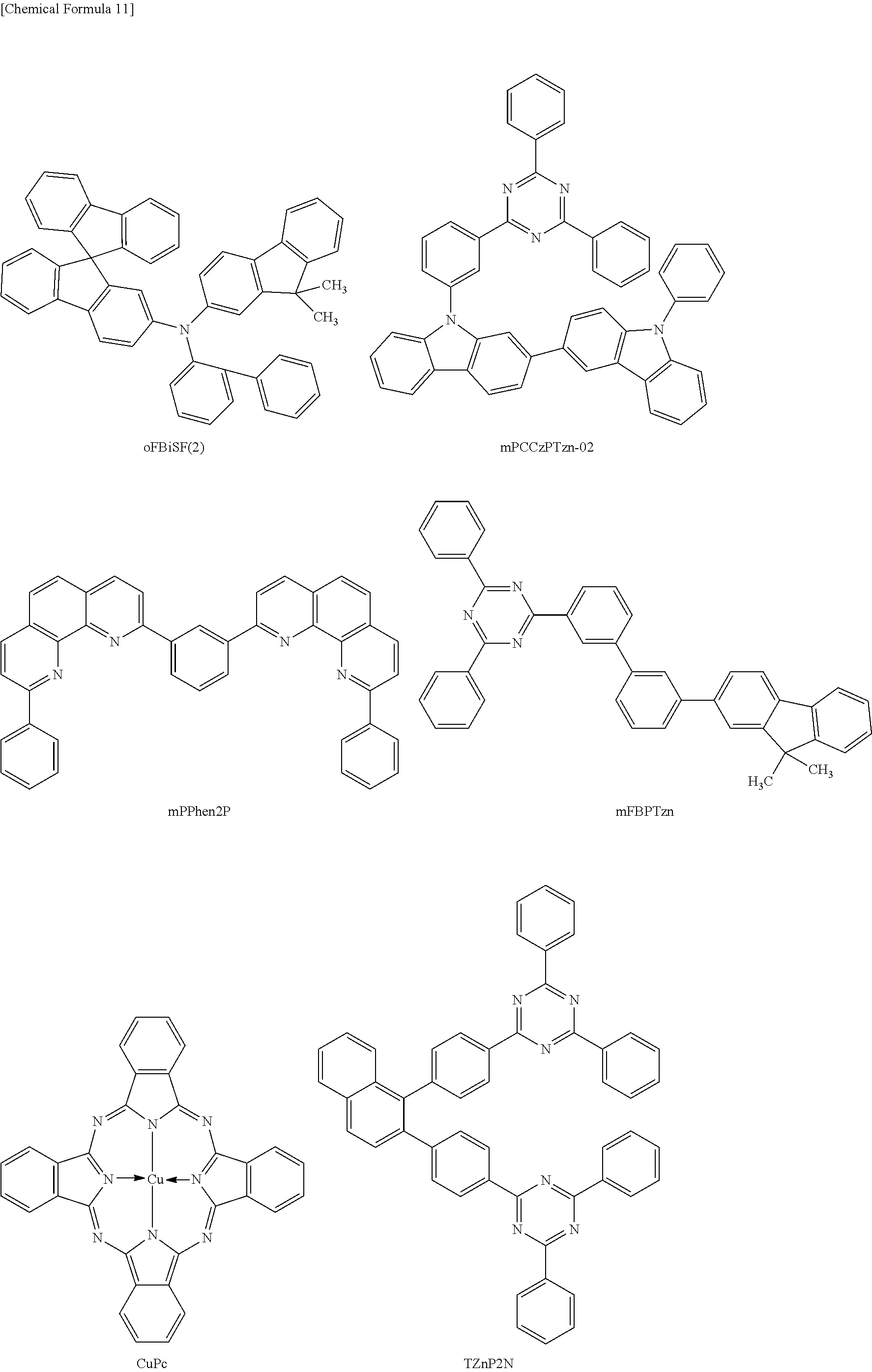

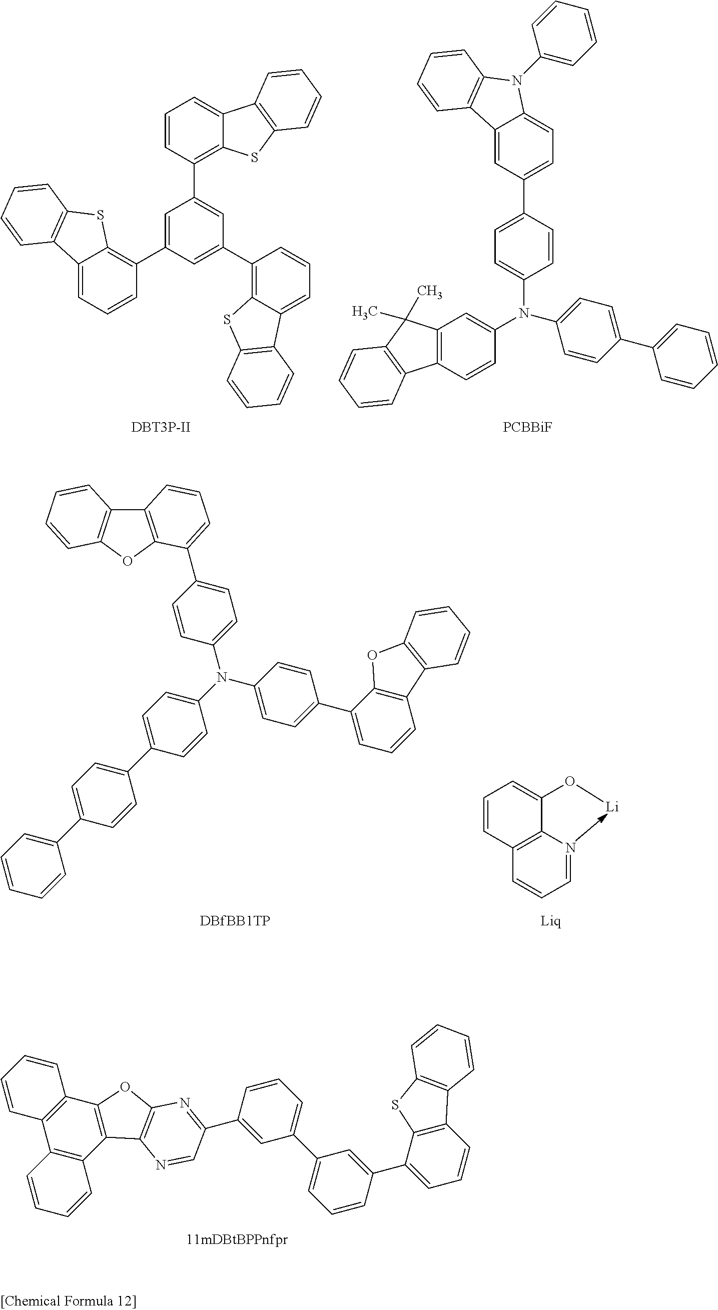

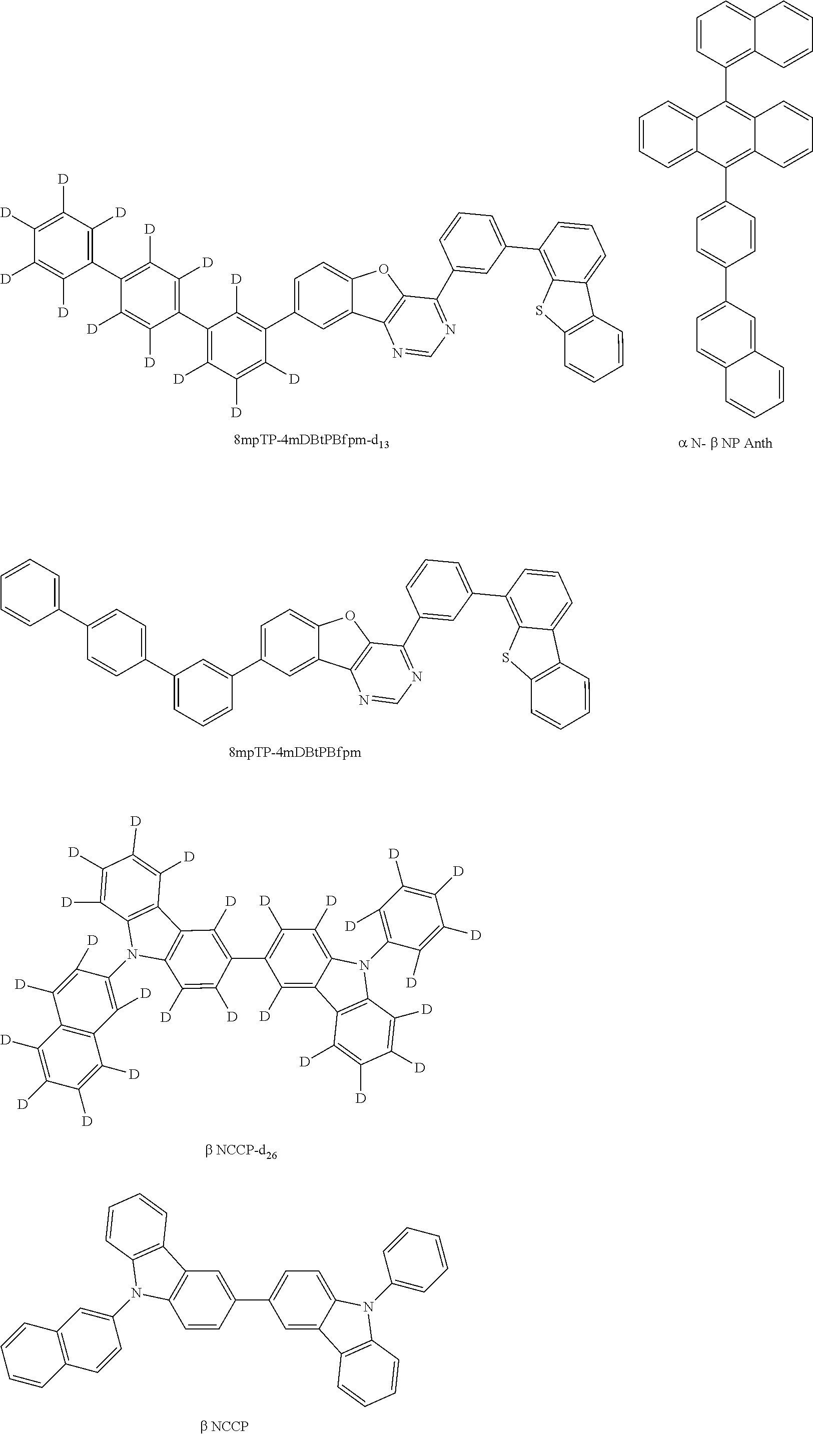

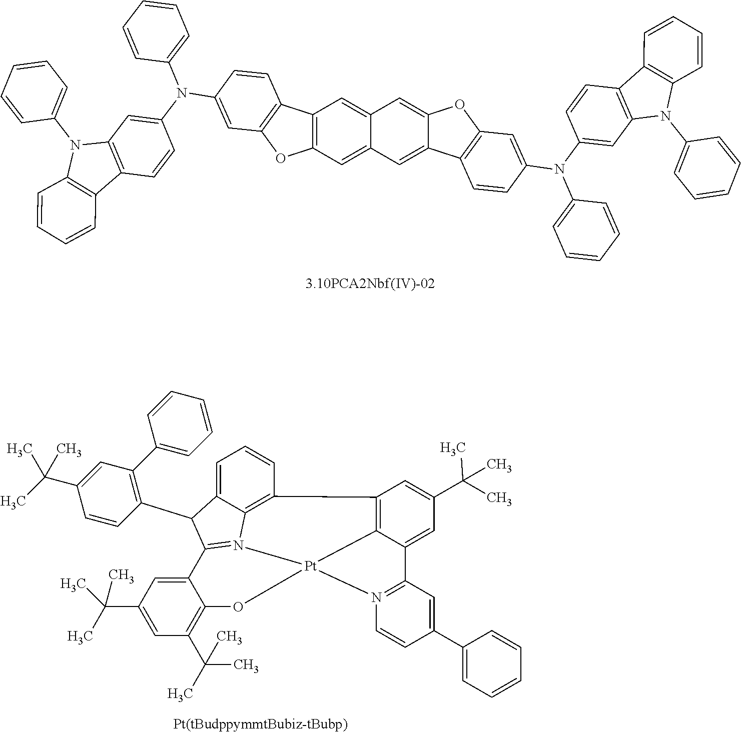

### (Method 5 for Manufacturing Light-Emitting Devices)

A method for manufacturing the light-emitting devices used in this example is described.

### <Method for Manufacturing Light-Emitting Device R5>

The light-emitting device R5 differs from the light-emitting device R1-a described in Example 1 in that the first light-emitting layer and the second light-emitting layer were each deposited to a thickness of 40 nm by co-evaporation of 11mDBtBPPnfpr, PCBBiF, and OCPG-006 at a weight ratio of 0.7:0.3:0.05; the first layer of the intermediate layer was deposited to a thickness of 5 nm by co-evaporation of mPPhen2P and ytterbium (Yb) to have a volume ratio of mPPhen2P:Yb of 1:0.02; the second electrode 102 was formed by depositing LiF and Yb by co-evaporation such that the thickness was 1.5 nm and the volume ratio of LiF to Yb was 2:1 and then depositing Ag and Mg by co-evaporation such that the thickness was 15 nm and the volume ratio of Ag to Mg was 1:0.1; and the thickness of the first hole-transport layer was 160 nm. The other components were formed in the same manner as those in the light-emitting device R1-a.

### <Method for Manufacturing Light-Emitting Device G5>

The light-emitting device G5 was manufactured in the same manner as the light-emitting device R5 except that the thickness of the first hole-transport layer was 90 nm, the thickness of the second hole-transport layer was 65 nm, and the first light-emitting layer and the second light-emitting layer were each deposited by co-evaporation of 8mpTP-4mDBtPBfpm-d₁₃, βNCCP-d₂₆, and (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) at a weight ratio of 0.5:0.5:0.1.

### <Method for Manufacturing Comparative Light-Emitting Device G5>

The comparative light-emitting device G5 was manufactured in the same manner as the light-emitting device G5 except that the thickness of the first hole-transport layer was 80 nm, and the first light-emitting layer and the second light-emitting layer were each deposited by co-evaporation of 8mpTP-4mDBtPBfpm, βNCCP, and Pt(tBudppymmtBubiz-tBubp) at a weight ratio of 0.5:0.5:0.1.

### <Method for Manufacturing Light-Emitting Device B5>

The light-emitting device B5 was manufactured in the same manner as the light-emitting device R5 except that the first hole-transport layer and the second hole-transport layer were each formed by depositing oFBiSF(2) to a thickness of 40 nm and then depositing DBfBB1TP to a thickness of 10 nm by evaporation, and the first light-emitting layer and the second light-emitting layer were each deposited to a thickness of 25 nm by co-evaporation of αN-βNPAnth and 3,10PCA2Nbf(IV)-02 at a weight ratio of 1:0.015.

The element structures of the light-emitting device R5, the light-emitting device G5, the comparative light-emitting device G5, and the light-emitting device B5 are shown below.

TABLE 33

| | | Thickness | Light-emitting |
|---|---|---|---|
| | | (nm) | device R5 |
| Cap layer | | 70 | DBT3P-II |
| Second | 2 | 15 | Ag:Mg (1:0.1) |
| electrode | 1 | 1.5 | LiF:Yb (2:1) |
| Second electron- | b | 25 | TznP2N:Liq (1:1) |
| transport layer | a | 10 | mFBPTzn |
| Second light-emitting layer | | 40 | 11mDBtBPPnfpr:PCBBiF:OCPG-006 (0.7:0.3:0.05) |
| Second hole-transport layer | | 75 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Yb (1:0.02) |
| First electron-transport layer | | 10 | mPCCzPTzn-02 |
| First light-emitting layer | | 40 | 11mDBtBPPnfpr:PCBBiF:OCPG-006 (0.7:0.3:0.05) |
| First hole-transport layer | | 160 | oFBiSF(2) |
| First hole-injection layer | | 10 | oFBiSF(2):OCHD-003 (1:0.03) |
| First | 2 | 85 | ITSO |
| electrode | 1 | 100 | Ag |

TABLE 34

| | | |
|---|---|---|
| Thickness | Light-emitting | Comparative light- |
| (nm) | device G5 | emitting device G5 |

| Cap layer | | 70 | DBT3P-II |
|---|---|---|---|
| Second | 2 | 15 | Ag:Mg (1:0.1) |
| electrode | 1 | 1.5 | LiF:Yb (2:1) |
| Second electron- | b | 25 | TznP2N:Liq (1:1) |
| transport layer | a | 10 | mFBPTzn |

| | | | |
|---|---|---|---|
| Second light-emitting layer | 40 | 8mpTP- | 8mpTP- |

| | |
|---|---|
| 4mDBtPBfpm- | 4mDBtPBfpm:βNCCP:Pt(tBudppymmtBubiz- |
| d₁₃:βNCCP- | tBubp) |
| d₂₆:Pt(tBudppymmtBubiz- | (0.5:0.5:0.1) |
| tBubp) | |
| (0.5:0.5:0.1) | |

| Second hole-transport layer | | 65 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Yb (1:0.02) |

| First electron-transport layer | 10 | mPCCzPTzn-02 | |
|---|---|---|---|
| First light-emitting layer | 40 | 8mpTP- | 8mpTP- |
| | | 4mDBtPBfpm-d₁₃:βNCCP- | 4mDBtPBfpm:βNCCP:Pt(tBudppymmtBubiz- |
| | | d₂₆:Pt(tBudppymmtBubiz-tBubp) | tBubp) |
| | | (0.5:0.5:0.1) | (0.5:0.5:0.1) |
| First hole-transport layer | — | oFBiSF(2) (90 nm) | oFBiSF(2) (80 nm) |

| First hole-injection layer | | 10 | oFBiSF(2):OCHD-003 (1:0.03) |
|---|---|---|---|
| First | 2 | 85 | ITSO |
| electrode | 1 | 100 | Ag |

TABLE 35

| | | Thickness | Light-emitting |
|---|---|---|---|
| | | (nm) | device B5 |
| Cap layer | | 70 | DBT3P-II |
| Second | 2 | 15 | Ag:Mg (1:0.1) |
| electrode | 1 | 1.5 | LiF:Yb (2:1) |
| Second electron- | b | 25 | TznP2N:Liq (1:1) |
| transport layer | a | 10 | mFBPTzn |
| Second light-emitting layer | | 25 | αN-βNPAnth:3,10PCA2Nbf(IV)-02 (1:0.015) |
| Second hole- | 2 | 10 | DBfBB1TP |
| transport layer | 1 | 40 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Yb (1:0.02) |
| First electron-transport layer | | 10 | mPCCzPTzn-02 |
| First light-emitting layer | | 25 | αN-βNPAnth:3,10PCA2Nbf(IV)-02 (1:0.015) |
| First hole-transport | 2 | 10 | DBfBB1TP |
| layer | 1 | 40 | oFBiSF(2) |
| First hole-injection layer | | 10 | oFBiSF(2):OCHD-003 (1:0.03) |
| First | 2 | 85 | ITSO |
| electrode | 1 | 100 | Ag |

### (Characteristics 5 Of Light-Emitting Devices)

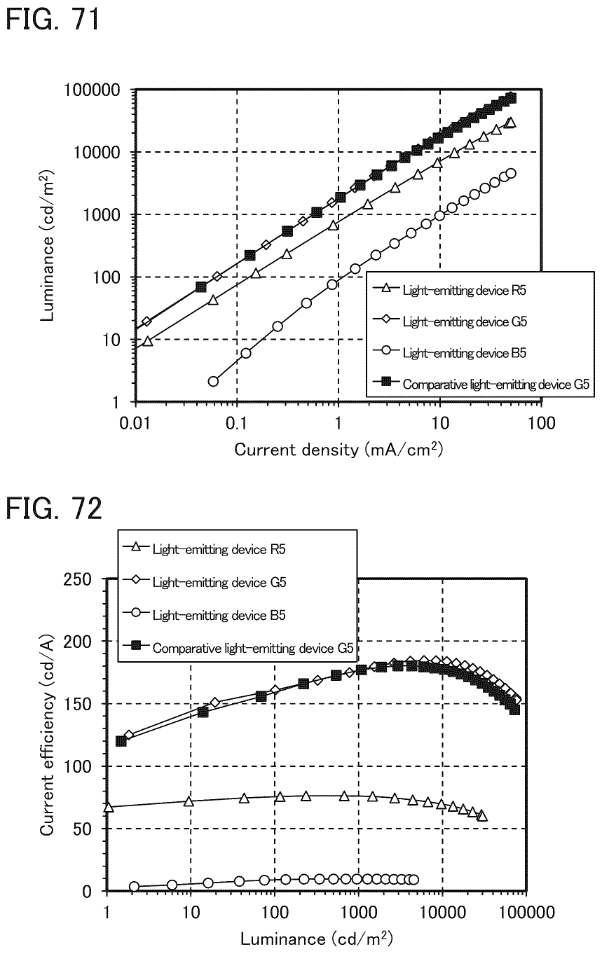

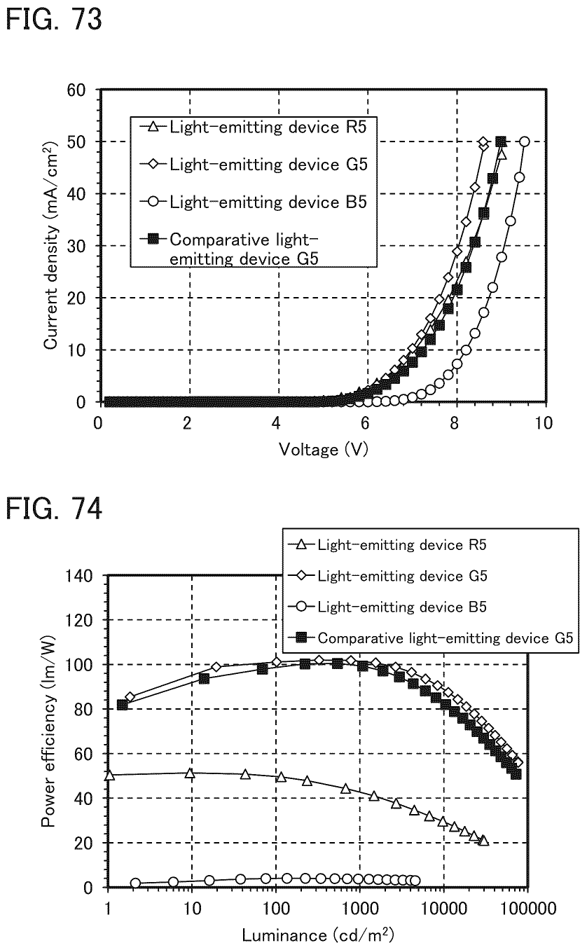

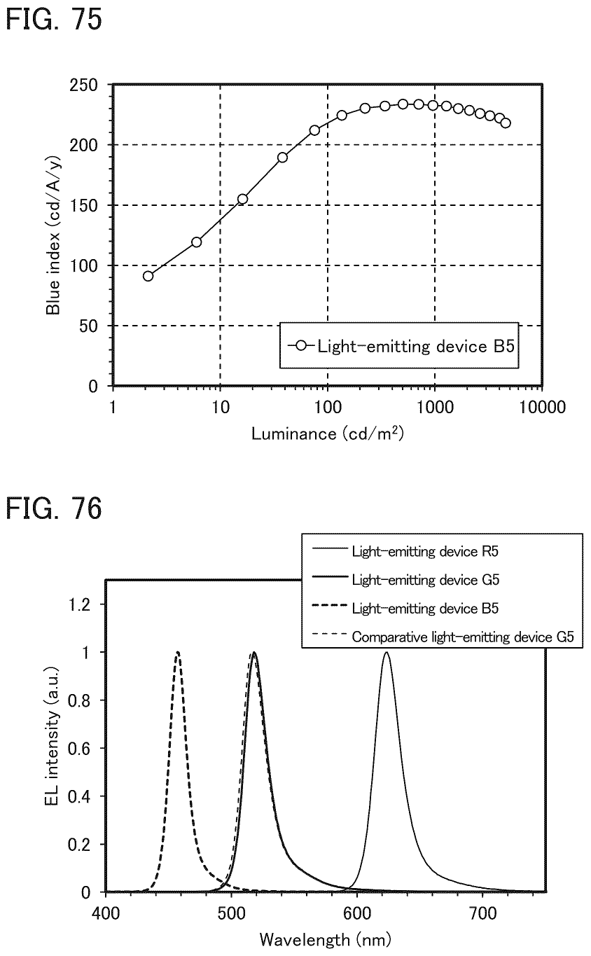

FIGS. 71, 72, 73, 74, and 76 respectively show the luminance-current density characteristics, current efficiency-luminance characteristics, current density-voltage characteristics, power efficiency-luminance characteristics and electroluminescence spectra of the light-emitting device R5, the light-emitting device G5, the comparative light-emitting device G5, and the light-emitting device B5. FIG. 75 shows the blue index-luminance characteristics of the light-emitting device B5.

Table 36 shows the main characteristics of the light-emitting devices R5, G5, and B5 and the comparative light-emitting device G5 at a luminance of approximately 1000 cd/m². In this example, the luminance, CIE chromaticity, and electroluminescence spectra were measured at room temperature with a spectroradiometer (SR-UL1R, TOPCON TECHNOHOUSE CORPORATION).

TABLE 36

| | | | Current | | | Current | Power | |
|---|---|---|---|---|---|---|---|---|
| | Voltage | Current | density | Chromaticity | Chromaticity | efficiency | efficiency | BI |
| | (V) | (mA) | (mA/cm²) | x | y | (cd/A) | (lm/W) | (cd/A/y) |
| Light-emitting device R5 | 5.4 | 0.035 | 0.89 | 0.69 | 0.31 | 76 | 44 | — |
| Light-emitting device G5 | 5.4 | 0.018 | 0.45 | 0.16 | 0.75 | 175 | 102 | — |
| Light-emitting device B5 | 8.0 | 0.29 | 7.3 | 0.14 | 0.041 | 10 | 3.8 | 233 |
| Comparative light- | 5.6 | 0.024 | 0.61 | 0.16 | 0.74 | 177 | 99 | — |
| emitting device G5 | | | | | | | | |

FIGS. 71 to 76 and Table 36 reveal that the light-emitting device R5 emitted red light whose electroluminescence spectrum had a peak wavelength of around 624 nm. The light-emitting device G5 was found to emit green light whose electroluminescence spectrum had a peak wavelength of around 518 nm. The light-emitting device B5 was found to emit blue light whose electroluminescence spectrum had a peak wavelength of around 457 nm. FIGS. 72 to 74 reveal that the light-emitting device G5 had favorable characteristics with a lower driving voltage, higher power efficiency, and lower power consumption than the comparative light-emitting device G5.

This indicates that the light-emitting device G5 is a tandem light-emitting device with favorable characteristics. It was thus found that when an organic compound including deuterium is used as at least one of the first host material and the second host material and an organic compound having a triazine skeleton is used in the second electron-transport layer, the light-emitting device can have favorable characteristics with a lower driving voltage and lower power consumption.

As described in Example 1, 8mpTP-4mDBtPBfpm is an organic compound in which the deuteriums of 8mpTP-4mDBtPBfpm-d₁₃ are replaced with protium, and βNCCP is an organic compound in which the deuteriums of βNCCP-d₂₆ are replaced with protium. It is thus found that deuterium included in the first host material and the second host material inhibits intramolecular vibration of the deuterated organic compounds in the T₁ state and inhibits nonradiative transition from the T₁ state to a more stable state; hence, the efficiency of energy transfer to the phosphorescent substance is improved. This indicates that the light-emitting device G5 has higher reliability than the comparative light-emitting device G5.

As shown in FIG. 42, 8mpTP-4mDBtPBfpm-d₁₃ and βNCCP-d₂₆ form an exciplex in combination.

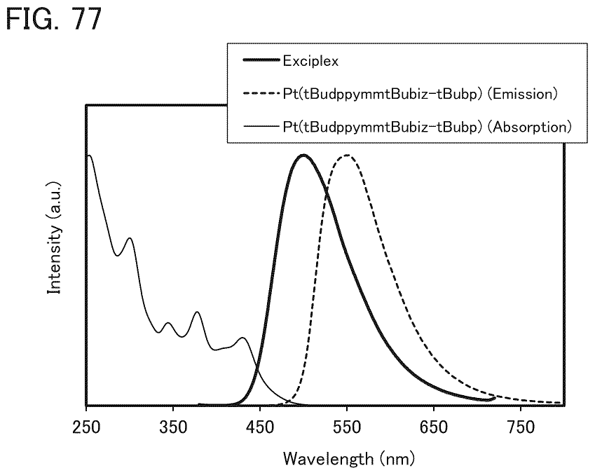

FIG. 77 shows the emission spectrum of a film (mixed film) in which 8mpTP-4mDBtPBfpm-d₁₃ and βNCCP-d₂₆ were deposited by co-evaporation at a weight ratio of 1:1 (the emission spectrum of the exciplex), and the absorption spectrum and emission spectrum of Pt(tBudppymmtBubiz-tBubp), which is an emission center substance. The PL spectrum and absorption spectrum of Pt(tBudppymmtBubiz-tBubp) were measured in a solution containing dichloromethane as a solvent.

As can be seen from FIG. 77, the emission edge (442 nm) on the shorter wavelength side of the PL spectrum of the exciplex of 8mpTP-4mDBtPBfpm-d₁₃ and βNCCP-d₂₆ is positioned at a shorter wavelength than the absorption edge (461 nm) on the longer wavelength side of the absorption spectrum of Pt(tBudppymmtBubiz-tBubp). When the PL spectrum of the exciplex of 8mpTP-4mDBtPBfpm-d₁₃ and βNCCP-d₂₆ and the absorption edge of Pt(tBudppymmtBubiz-tBubp) have such a positional relation, excitation energy can be efficiently transferred to Pt(tBudppymmtBubiz-tBubp) in the light-emitting device G5.

The peak wavelength (500 nm) of the PL spectrum of the exciplex formed by 8mpTP-4mDBtPBfpm-d₁₃ and βNCCP-d₂₆ is shorter than the peak wavelength (552 nm) of the PL spectrum of Pt(tBudppymmtBubiz-tBubp). When the peak wavelength of the PL spectrum of the exciplex and the peak wavelength of the PL spectrum of Pt(tBudppymmtBubiz-tBubp) have such a relation, energy can be efficiently transferred.

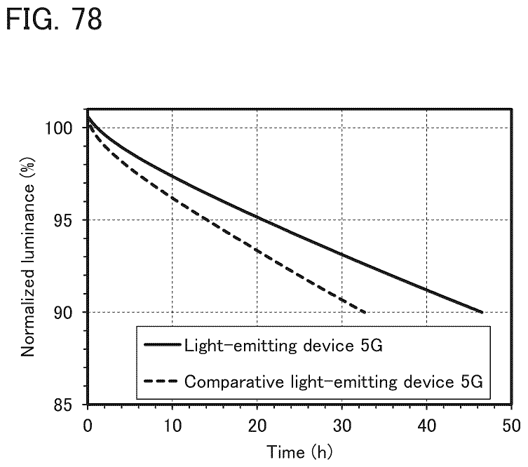

FIG. 78 shows the time dependence of normalized luminance of the light-emitting device G5 and the comparative light-emitting device G5 at a current density of 50 mA/cm².

FIG. 78 demonstrates that the light-emitting device G5 has a smaller time-dependent change in normalized luminance than the comparative light-emitting device G5 and thus has high reliability.

Here, the second electron-transport layers of the light-emitting devices R5, G5, and B5 include the same material (the first organic compound having a triazine skeleton). Thus, the light-emitting devices of different emission colors can each have favorable characteristics even when the second electron-transport layers of the light-emitting devices are made of the same material.

### (Power Consumption Estimation 5)

A display apparatus 5 of this example including the light-emitting devices R5, G5, and B5 respectively in red, green, and blue subpixels and a comparative display apparatus 5 including the comparative light-emitting devices R5, G5, and B5 respectively in red, green, and blue subpixels were assumed, and the power consumption of their display portions (except for the power consumption of driving transistors, driver circuits, and the like) was estimated. Note that each of the light-emitting devices assumed to be used in both of the display apparatuses is a tandem light-emitting device, and the same emission center substance is used in the plurality of light-emitting layers in each of the light-emitting devices. Thus, the display apparatuses are side-by-side display apparatuses. Note that the conditions of the display apparatuses assumed for the estimation and the calculation method are the same as those in Example 1.

As shown in the following table, for the light-emitting device G5, the increase rate A of LT₉₅ (the time at which the luminance decreases by 5% from the initial 100%) relative to LT₉₅ of the comparative light-emitting device G5 was obtained from the results in FIG. 78; the rate B of current with which the same LT₉₅ reliability as the comparative light-emitting device G5 was obtained given that LT₉₅ is inversely proportional to the 1.7th power of the initial luminance; and the ratio C of the aperture ratio of the red subpixel having the same reliability as the comparative light-emitting device G5 was obtained by calculating the reciprocal of B. The aperture ratio of each emission color was obtained using this value.

TABLE 37

| | LT₉₅ (h) | A | B | C |
|---|---|---|---|---|
| Light-emitting device G5 | 21 | 1.48 | 1.94 | 0.516 |
| Comparative light-emitting device G5 | 14 | — | — | — |

Table 38 and Table 39 show the calculated power consumption of the display apparatus 5 and the comparative display apparatus 5, respectively.

TABLE 38
Display apparatus 5

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 11.9 | 0.69 | 0.31 | 280 | 2351 | 74.9 | 3.1 | 25.8 | 6.09 | 157.0 |
| Green | 6.2 | 0.16 | 0.75 | 668 | 10865 | 183.9 | 5.9 | 25.0 | 6.57 | 164.7 |
| Blue | 11.9 | 0.14 | 0.04 | 51 | 430 | 9.6 | 4.5 | 36.7 | 7.71 | 282.9 |
| Full white | — | 0.31 | 0.33 | 1000 | — | 78.7 | — | 87.5 | — | 604.6 |

TABLE 39
Comparative display apparatus 5

| | Aperture | | | Effective | Intrinsic | Current | Current | | | Power |
|---|---|---|---|---|---|---|---|---|---|---|
| | ratio | Chromaticity | Chromaticity | luminance | luminance | efficiency | density | Current | Voltage | consumption |
| | (%) | x | y | (cd/m²) | (cd/m²) | (cd/A) | (mA/cm²) | (mA) | (V) | (mW) |
| Red | 10.0 | 0.69 | 0.31 | 284 | 2835 | 74.4 | 3.8 | 26.3 | 6.23 | 163.6 |
| Green | 10.0 | 0.16 | 0.74 | 666 | 6657 | 179.2 | 3.7 | 25.6 | 6.46 | 165.4 |
| Blue | 10.0 | 0.14 | 0.04 | 51 | 508 | 9.7 | 5.3 | 36.2 | 7.81 | 282.4 |
| Full white | — | 0.31 | 0.33 | 1000 | — | 78.3 | — | 88.0 | — | 611.5 |

Table 38 and Table 39 show that the display apparatus 5 has higher current efficiency in white light emission and a lower driving voltage than the comparative display apparatus 5. Moreover, the power consumption of the display apparatus 5 is lower than that of the comparative display apparatus 5.

As shown in Table 38 and Table 39, when the aperture ratio of each emission color was estimated in consideration of the time dependence of normalized luminance of the light-emitting devices, the aperture ratio of the green subpixel in the display apparatus 5 was lower than the aperture ratio of the green subpixel in the comparative display apparatus 5, and the aperture ratios of the red subpixel and the blue subpixel in the display apparatus 5 were higher than the aperture ratios of the red subpixel and the blue subpixel in the comparative display apparatus 5. The current densities required for the red subpixel and the blue subpixel in the display apparatus 5 were lower than the current densities required for the red subpixel and the blue subpixel in the comparative display apparatus 5. In the display apparatus 5, the aperture ratio of the green subpixel was lower than the aperture ratios of the red subpixel and the blue subpixel.

These results show that the use of the light-emitting device G5 having a smaller time dependence of normalized luminance for a green subpixel enables the aperture ratio of the green subpixel to be further reduced. Accordingly, the aperture ratios of the red and blue subpixels can be further increased, and the current densities required for light emission of the red and blue light-emitting devices can be further reduced, demonstrating that the reliability is increased as a whole. This application is based on Japanese Patent Application Serial No. 2024-056317 filed with Japan Patent Office on Mar. 29, 2024, the entire contents of which are hereby incorporated by reference.

What is claimed is:

1. A display apparatus comprising:
a pixel comprising a first subpixel and a second subpixel,
wherein an area of the first subpixel is smaller than an area of the second subpixel,
wherein the first subpixel comprises a first light-emitting device,
wherein the second subpixel comprises a second light-emitting device,
wherein the first light-emitting device comprises a first electrode, a second electrode, a first intermediate layer, a first light-emitting layer, and a second light-emitting layer,
wherein the first intermediate layer is positioned between the first electrode and the second electrode,
wherein the first light-emitting layer is positioned between the first electrode and the first intermediate layer,
wherein the second light-emitting layer is positioned between the first intermediate layer and the second electrode,
wherein the first light-emitting layer comprises a first emission center substance, a first organic compound, and a second organic compound,
wherein the second light-emitting layer comprises a second emission center substance, a third organic compound, and a fourth organic compound,
wherein the first organic compound and the third organic compound each comprise a π-electron deficient heteroaromatic ring,
wherein the second organic compound and the fourth organic compound each comprise a π-electron rich heteroaromatic ring or an aromatic amine skeleton,
wherein at least one of the first organic compound, the second organic compound, the third organic compound, and the fourth organic compound comprises deuterium,
wherein a difference between a maximum peak wavelength of an emission spectrum of the first emission center substance and a maximum peak wavelength of an emission spectrum of the second emission center substance is less than or equal to 30 nm,
wherein the second light-emitting device comprises a third electrode, a fourth electrode, a second intermediate layer, a third light-emitting layer, and a fourth light-emitting layer,
wherein the second intermediate layer is positioned between the third electrode and the fourth electrode,
wherein the third light-emitting layer is positioned between the third electrode and the second intermediate layer,
wherein the fourth light-emitting layer is positioned between the second intermediate layer and the fourth electrode, and
wherein the third light-emitting layer and the fourth light-emitting layer emit light with a hue different from a hue of light emitted from the first light-emitting layer and a hue of light emitted from the second light-emitting layer.

2. The display apparatus according to claim 1,
wherein the third light-emitting layer comprises a third emission center substance, a fifth organic compound, and a sixth organic compound,
wherein the fourth light-emitting layer comprises a fourth emission center substance, a seventh organic compound, and an eighth organic compound,
wherein the fifth organic compound and the seventh organic compound each comprise a π-electron deficient heteroaromatic ring,
wherein the sixth organic compound and the eighth organic compound each comprise a π-electron rich heteroaromatic ring or an aromatic amine skeleton, and
wherein a difference between a maximum peak wavelength of an emission spectrum of the third emission center substance and a maximum peak wavelength of an emission spectrum of the fourth emission center substance is less than or equal to 30 nm.

3. The display apparatus according to claim 1,
wherein a combination of the first organic compound and the second organic compound forms a first exciplex, and
wherein a combination of the third organic compound and the fourth organic compound forms a second exciplex.

4. The display apparatus according to claim 3,
wherein a difference between a lowest triplet excited level of the first organic compound and a lowest triplet excited level of the second organic compound is less than or equal to 0.30 eV, and
wherein a difference between a lowest triplet excited level of the third organic compound and a lowest triplet excited level of the fourth organic compound is less than or equal to 0.30 eV.

5. The display apparatus according to claim 3,
wherein an emission edge on a shorter wavelength side of the first exciplex is positioned at a shorter wavelength than an absorption edge on a longer wavelength side of the first emission center substance, and
wherein an emission edge on a shorter wavelength side of the second exciplex is positioned at a shorter wavelength than an absorption edge on a longer wavelength side of the second emission center substance.

6. The display apparatus according to claim 3,
wherein an energy of an emission spectrum peak of the first exciplex is higher than an energy of an emission spectrum peak of the first emission center substance,
wherein a difference between the energy of the emission spectrum peak of the first exciplex and the energy of the emission spectrum peak of the first emission center substance is less than or equal to 0.35 eV,
wherein an energy of an emission spectrum peak of the second exciplex is higher than an energy of an emission spectrum peak of the second emission center substance, and
wherein a difference between the energy of the emission spectrum peak of the second exciplex and the energy of the emission spectrum peak of the second emission center substance is less than or equal to 0.35 eV.

7. The display apparatus according to claim 2,
wherein a combination of the fifth organic compound and the sixth organic compound forms a third exciplex, and
wherein a combination of the seventh organic compound and the eighth organic compound forms a fourth exciplex.

8. The display apparatus according to claim 1,
wherein at least one of the first intermediate layer and the second intermediate layer comprises a mixed layer comprising an eleventh organic compound and one of lithium and a lithium compound, and
wherein the eleventh organic compound comprises a phenanthroline skeleton.

9. The display apparatus according to claim 1,
wherein the first light-emitting device comprises a first electron-transport layer between the first light-emitting layer and the first intermediate layer, and a second electron-transport layer between the second light-emitting layer and the second electrode,
wherein the second light-emitting device comprises a third electron-transport layer between the third light-emitting layer and the second intermediate layer, and a fourth electron-transport layer between the fourth light-emitting layer and the fourth electrode,
wherein at least one of the second electron-transport layer and the fourth electron-transport layer comprises a twelfth organic compound, and
wherein the twelfth organic compound comprises a triazine skeleton.

10. A display apparatus comprising:
a pixel comprising a first subpixel, a second subpixel, and a third subpixel,
wherein an area of the first subpixel and an area of the second subpixel are each smaller than an area of the third subpixel,
wherein the first subpixel comprises a first light-emitting device,
wherein the second subpixel comprises a second light-emitting device,
wherein the third subpixel comprises a third light-emitting device,
wherein the first light-emitting device comprises a first electrode, a second electrode, a first intermediate layer, a first light-emitting layer, and a second light-emitting layer,
wherein the first intermediate layer is positioned between the first electrode and the second electrode,
wherein the first light-emitting layer is positioned between the first electrode and the first intermediate layer,
wherein the second light-emitting layer is positioned between the first intermediate layer and the second electrode,
wherein the first light-emitting layer comprises a first emission center substance, a first organic compound, and a second organic compound,
wherein the second light-emitting layer comprises a second emission center substance, a third organic compound, and a fourth organic compound,
wherein the first organic compound and the third organic compound each comprise a π-electron deficient heteroaromatic ring,
wherein the second organic compound and the fourth organic compound each comprise a π-electron rich heteroaromatic ring or an aromatic amine skeleton,
wherein at least one of the first organic compound, the second organic compound, the third organic compound, and the fourth organic compound comprises deuterium,
wherein a difference between a maximum peak wavelength of an emission spectrum of the first emission center substance and a maximum peak wavelength of an emission spectrum of the second emission center substance is less than or equal to 30 nm,
wherein the second light-emitting device comprises a third electrode, a fourth electrode, a second intermediate layer, a third light-emitting layer, and a fourth light-emitting layer,
wherein the second intermediate layer is positioned between the third electrode and the fourth electrode,
wherein the third light-emitting layer is positioned between the third electrode and the second intermediate layer,
wherein the fourth light-emitting layer is positioned between the second intermediate layer and the fourth electrode,
wherein the third light-emitting layer comprises a third emission center substance, a fifth organic compound, and a sixth organic compound,
wherein the fourth light-emitting layer comprises a fourth emission center substance, a seventh organic compound, and an eighth organic compound,
wherein the fifth organic compound and the seventh organic compound each comprise a π-electron deficient heteroaromatic ring,
wherein the sixth organic compound and the eighth organic compound each comprise a π-electron rich heteroaromatic ring or an aromatic amine skeleton,
wherein a difference between a maximum peak wavelength of an emission spectrum of the third emission center substance and a maximum peak wavelength of an emission spectrum of the fourth emission center substance is less than or equal to 30 nm,
wherein the third light-emitting layer and the fourth light-emitting layer emit light with a hue different from a hue of light emitted from the first light-emitting layer and a hue of light emitted from the second light-emitting layer,
wherein the third light-emitting device comprises a fifth electrode, a sixth electrode, a third intermediate layer, a fifth light-emitting layer, and a sixth light-emitting layer,
wherein the third intermediate layer is positioned between the fifth electrode and the sixth electrode,
wherein the fifth light-emitting layer is positioned between the fifth electrode and the third intermediate layer,
wherein the sixth light-emitting layer is positioned between the third intermediate layer and the sixth electrode, and
wherein the fifth light-emitting layer and the sixth light-emitting layer emit light with a hue different from the hue of light emitted from the first light-emitting layer, the second light-emitting layer, the third light-emitting layer, and the fourth light-emitting layer.

11. The display apparatus according to claim 10,
wherein the area of the first subpixel is smaller than the area of the second subpixel, and
wherein at least one of the fifth organic compound, the sixth organic compound, the seventh organic compound, and the eighth organic compound comprises deuterium.

12. The display apparatus according to claim 10,
wherein a combination of the first organic compound and the second organic compound forms a first exciplex, and
wherein a combination of the third organic compound and the fourth organic compound forms a second exciplex.

13. The display apparatus according to claim 12,
wherein a difference between a lowest triplet excited level of the first organic compound and a lowest triplet excited level of the second organic compound is less than or equal to 0.30 eV, and
wherein a difference between a lowest triplet excited level of the third organic compound and a lowest triplet excited level of the fourth organic compound is less than or equal to 0.30 eV.

14. The display apparatus according to claim 12,
wherein an emission edge on a shorter wavelength side of the first exciplex is positioned at a shorter wavelength than an absorption edge on a longer wavelength side of the first emission center substance, and
wherein an emission edge on a shorter wavelength side of the second exciplex is positioned at a shorter wavelength than an absorption edge on a longer wavelength side of the second emission center substance.

15. The display apparatus according to claim 12,
wherein an energy of an emission spectrum peak of the first exciplex is higher than an energy of an emission spectrum peak of the first emission center substance,
wherein a difference between the energy of the emission spectrum peak of the first exciplex and the energy of the emission spectrum peak of the first emission center substance is less than or equal to 0.35 eV,
wherein an energy of an emission spectrum peak of the second exciplex is higher than an energy of an emission spectrum peak of the second emission center substance, and
wherein a difference between the energy of the emission spectrum peak of the second exciplex and the energy of the emission spectrum peak of the second emission center substance is less than or equal to 0.35 eV.

16. The display apparatus according to claim 12,
wherein a combination of the fifth organic compound and the sixth organic compound forms a third exciplex, and
wherein a combination of the seventh organic compound and the eighth organic compound forms a fourth exciplex.

17. The display apparatus according to claim 10,
wherein at least one of the first intermediate layer and the second intermediate layer comprises a mixed layer comprising an eleventh organic compound and one of lithium and a lithium compound, and
wherein the eleventh organic compound comprises a phenanthroline skeleton.

18. The display apparatus according to claim 10,
wherein the first light-emitting device comprises a first electron-transport layer between the first light-emitting layer and the first intermediate layer, and a second electron-transport layer between the second light-emitting layer and the second electrode,
wherein the second light-emitting device comprises a third electron-transport layer between the third light-emitting layer and the second intermediate layer, and a fourth electron-transport layer between the fourth light-emitting layer and the fourth electrode,
wherein at least one of the second electron-transport layer and the fourth electron-transport layer comprises a twelfth organic compound, and
wherein the twelfth organic compound comprises a triazine skeleton.
